(19) United States
(12) Patent Application Publication
(10) Pub. No.: US 2026/0177620 A1
(43) Pub. Date: Jun. 25, 2026

(54) MICRO-ELECTROMECHANICAL SWITCH SYSTEMS WITH DIAGNOSTIC CAPABILITY USING DIGITAL MODEL

(71) Applicant: Analog Devices International Unlimited Company, Co. Limerick (IE)

(72) Inventors: Padraig L. Fitzgerald, Mallow (IE); Naiqian Ren, Limerick (IE); Richard T. Anslow, Limerick (IE); Alan J. O'Donnell, Castletroy (IE); Thomas O’Shea, Kanturk (IE); Finbarr O'Leary, Sixmilebridge (IE); James Patrick Ryan, Co. Limerick (IE); John Ross Wallrabenstein, Lafayette, IN (US); David Aherne, Limerick (IE); Michael P. Lynch, Bruff (IE); Michael James Twohig, Co. Cork (IE); Jonathan Ephraim David Hurwitz, Edinburgh (GB); Patrick Martin McGuinness, Pallaskenry (IE); David J. Clarke, Patrickswell (IE); Stephen Cuddy, Galway (IE); Danail Baylov, Limerick (IE); Blas Bogado, Dublin (IE)

(21) Appl. No.: 19/428,042

(22) Filed: Dec. 19, 2025

Related U.S. Application Data
(60) Provisional application No. 63/737,545, filed on Dec. 20, 2024.
(60) Provisional application No. 63/802,512, filed on May 8, 2025.
(60) Provisional application No. 63/805,908, filed on May 14, 2025.
(60) Provisional application No. 63/812,804, filed on May 27, 2025.
(60) Provisional application No. 63/826,369, filed on Jun. 18, 2025.
(60) Provisional application No. 63/827,819, filed on Jun. 20, 2025.
(60) Provisional application No. 63/830,337, filed on Jun. 25, 2025.
(60) Provisional application No. 63/830,400, filed on Jun. 25, 2025.

(51) Int. Cl. G01R 31/327; H01H 59/00; H02H 1/00; H02H 7/22; H02H 9/00; H02H 9/02; H02J 1/00

(52) U.S. Cl. CPC G01R 31/3271; H01H 59/0009; H02H 1/0007; H02H 7/222; H02H 9/005; H02H 9/025; H02J 1/001; H01H 2059/0054

(57) ABSTRACT

The disclosed technology relates generally to switching devices and more particularly to switching devices employing micro-electromechanical system (MEMS) switches. The switching devices can serve as circuit breakers for protecting electrical systems against certain electrical events. The switching devices can be configured to monitor and control one or both the MEMS switches and the electrical systems being protected. The disclosed technology additionally relates to systems including the switching devices and methods of using the switching devices.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims priority to U.S. Provisional Application No. 63/737,545, filed Dec. 20, 2024, U.S. Provisional Application No. 63/802,512, filed May 8, 2025, U.S. Provisional Application No. 63/805,908, filed May 14, 2025, U.S. Provisional Application No. 63/812,804, filed May 27, 2025, U.S. Provisional Application No. 63/826,369 filed Jun. 18, 2025, U.S. Provisional Application No. 63/827,819 filed Jun. 20, 2025, U.S. Provisional Application No. 63/830,337 filed Jun. 25, 2025, U.S. Provisional Application No. 63/830,400 filed Jun. 25, 2025. The entire content of each of the applications referenced in this paragraph is hereby incorporated by reference herein for all purposes and made a part of this specification.

### BACKGROUND

### Field

The disclosed technology generally relates to devices for protecting electrical systems from electrical overstress (EOS) and other electrical faults, and more particularly to circuit breakers configured to detect, monitor, and/or protect against such faults in electrical systems using microelectromechanical (MEMS) switches.

### Description of the Related Art

Electronic systems can be exposed to various electrical fault conditions, including but not limited to electrical overstress (EOS) events, excessive current, electric arcing and the like. Such faults may occur when an electronic device experiences voltage and/or current levels beyond its specified operating limits. For example, an electronic device can encounter transient signal events-short-duration electrical signals characterized by rapidly changing voltage and current and often associated with high power. These transient events can include electrostatic discharge (ESD) caused by an abrupt release of charge from an object or person to an electronic system, or sudden voltage/current spikes originating from the device's power source.

Electrical faults, such as transient signal events, can severely damage integrated circuits (ICs) due to overvoltage or overcurrent conditions and the resulting high-power dissipation in localized areas of the ICs. Excessive power dissipation can elevate IC temperature and lead to critical failures, including gate oxide breakdown, junction degradation, metal layer damage, surface charge accumulation, or combinations thereof.

To mitigate these risks, there is a need for solutions that can detect and protect a system from overvoltage and overcurrent conditions by controlling the corresponding electrical connection using a circuit breaker—particularly a compact, integrated circuit breaker designed for electronic systems. Such breakers can interrupt fault currents or disconnect circuits rapidly, preventing catastrophic damage while maintaining system reliability. Ensuring the performance of these circuit breakers can be also important as their ability to respond quickly and accurately under fault conditions directly impacts the protection of the electric or electronic system.

Furthermore, to diagnose failures or predict device lifespan, characterizing electrical faults in terms of voltage, current, power, energy, and duration can be valuable. Therefore, there is also a need for monitoring solutions that can detect, report, and provide at least semi-quantitative information about such electrical faults.

### SUMMARY

In some aspects, the techniques described herein relate to a switching device for controlling current flow between a modular circuit and a powered main circuit. The switching device includes: a first terminal to electrically connect to the powered main circuit; a second terminal to electrically connect to a load of the modular circuit; a current sense device and a micro-electro-mechanical systems (MEMS) switch module electrically connected in series to each other and between the first terminal and the second terminal; and a controller communicatively coupled to the current sense device and the MEMS switch module, the controller configured to cause the MEMS switch module to switch current flow therethrough based on a detected level of current flow through the current sense device during insertion, booting or removal of the modular circuit.

In some aspects, the techniques described herein relate to a system including a main circuit configured to electrically couple a plurality of modular circuits inserted into respective coupling slots. The system includes: a switching device configured to switch current flow between a modular circuit of the plurality of modular circuits and the main circuit in a powered state during insertion, booting or removal of the modular circuit; a power source powering the main circuit in the powered state and further powering the modular circuit when electrically coupled to the main circuit; wherein the switching device includes: a first terminal to electrically connect to the main circuit, a second terminal to electrically connect to a load of the modular circuit, and a current sense device and a micro-electro-mechanical systems (MEMS) switch module electrically connected in series to each other and between the first terminal and the second terminal, the MEMS switch module configured to switch current flow therethrough based on a detected level of current flow through the current sense device.

In some aspects, the techniques described herein relate to a method of controlling current flow between a modular circuit and a powered main circuit. The method includes: providing power to a system including the main circuit and a plurality of coupling slots for electrically coupling the main circuit and a plurality of modular circuits inserted into the coupling slots; inserting a modular circuit into one of the coupling slots or removing a modular circuit from one of the coupling slots; and switching current flow between the main circuit and the modular circuit being inserted into or removed from the one of the coupling slots using a switching device including a current sense device and a micro-electro-mechanical systems (MEMS) switch module electrically connected in series to each other.

In some aspects, the techniques described herein relate to an apparatus for protection of a high voltage system from electrical overstress (EOS) events. The apparatus includes: a protection device configured to be electrically connected between a high voltage module and a power supply for delivering power to the high voltage module; the protection device including a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from the power supply to the high voltage module.

In some aspects, the techniques described herein relate to a power supply for a high voltage system with protection from electrical overstress (EOS) events. The power supply includes: an output voltage generator; a protection device electrically connected to the output voltage generator and configured to further connect to a high voltage module; the protection device including a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from the output voltage generator to the high voltage module.

In some aspects, the techniques described herein relate to a high voltage system with protection from electrical overstress (EOS) events. The high voltage system includes: a high voltage module; a power supply for delivering power to the high voltage module; a protection device connected between the high voltage module and the power supply; the protection device including a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from power supply to the high voltage module.

In some aspects, the techniques described herein relate to a micro-electromechanical systems (MEMS) switch system configured with self-testing capability. The MEMS switch system includes: a first and second MEMS switch modules electrically connected in parallel between two terminals; a current sensor electrically connected in series with the first MEMS switch module and configured to generate a sensor signal; and a control logic communicatively coupled to the first and second MEMS switch modules and the current sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.

In some aspects, the techniques described herein relate to a micro-electromechanical systems (MEMS) switch system configured with self-testing capability. The MEMS switch system includes: a first and second MEMS switch modules electrically connected in parallel between two terminals; a temperature sensor in thermal communication with one or both of the first and second MEMS switch modules and configured to generate a sensor signal; a control logic communicatively coupled to the first and second MEMS switch modules and the temperature sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.

In some aspects, the techniques described herein relate to a micro-electromechanical systems (MEMS) switch system configured with self-testing capability. The MEMS switch system includes: a first and second MEMS switch modules electrically connected in parallel between two terminals; a voltage sensor connected between the two terminals and configured to generate a sensor signal; a control logic communicatively coupled to the first and second MEMS switch modules and the voltage sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.

In some aspects, the techniques described herein relate to a micro-electromechanical systems (MEMS) switch system configured with self-testing capability. The MEMS switch system includes: first and second MEMS switch modules electrically connected in series between two terminals, wherein each of the first and second MEMS switch modules is disposed between a pair of nodes; a current source configured to inject current into one or both of the nodes; a voltage sensing module configured to sense a voltage across the pair of nodes; and a control logic configured to: transmit a deactivation signal to the first MEMS switch module in an activated state while the second MEMS switch module remains in an activated state, inject current into a first pair of nodes having the first MEMS switch module disposed therebetween, flow the current through the first MEMS switch module and collect the current from the other of the first pair of nodes, detect a change in voltage across the first pair of nodes caused by the current, and determine a functionality of the first MEMS switch module from the change in voltage.

In some aspects, the techniques described herein relate to a micro-electromechanical systems (MEMS) switch system configured with switch self-evaluation. The MEMS switch system includes: a control and monitoring circuit; a MEMS switch electrically connected between two terminals and configured to serve as a circuit breaker providing a controlled electrical connection between the two terminals controlled by the control and monitoring circuit; and a physically unclonable function (PUF) circuit physically coupled to the MEMS switch and configured to repeatably generate a signal unique to the PUF circuit, in conjunction with operation of the MEMS switch, until a threshold condition causes the PUF circuit to be physically altered such that the PUF circuit no longer generates a same signal unique to the PUF circuit, wherein the control and monitoring circuit is configured to transmit switch monitoring data associated with the operation of the MEMS switch and a corresponding unique signal to an authentication circuit for authentication of the switch monitoring data using the corresponding unique signal.

In some aspects, the techniques described herein relate to a micro-electromechanical systems (MEMS) switch system with environment monitoring capability. The MEMS switch system includes: a first MEMS switch module electrically connected between two terminals; a control and monitoring circuit configured to control switching of the first MEMS switch module and to generate switch monitoring data associated with operation of the first MEMS switch module; and a physically unclonable function (PUF) circuit adjacently disposed to the first MEMS switch module and configured to repeatably generate a signal unique to the PUF circuit until a threshold environmental condition causes the PUF circuit to be physically altered such that the PUF circuit no longer generates a same signal unique to the PUF circuit, wherein the control and monitoring circuit is configured to transmit the switch monitoring data and a corresponding unique signal to an authentication circuit for authentication of the switch monitoring data using the corresponding unique signal.

In some aspects, the techniques described herein relate to a micro-electromechanical systems (MEMS) switch system including: a MEMS switch module configured to control an electrical connection between two voltage nodes; and a digital twin model including a digital representation of a physical state of the MEMS switch module, wherein the MEMS switch module and the digital twin model are communicatively coupled to each other and the digital twin model is configured to receive diagnostic data associated with the physical state of the MEMS switch module for determining a characteristic of the MEMS switch module.

In some aspects, the techniques described herein relate to a micro-electromechanical systems (MEMS) switch system configured with self-prognosis capability. The MEMS switch system including: a MEMS switch module electrically connected between two terminals; a diagnostic circuit communicatively coupled to the MEMS switch module, the diagnostic circuit configured to generate a diagnostic signal indicative of a state of health of the MEMS switch module; and a processing module configured to determine the state of health of the MEMS switch module based at least in part on the diagnostic signal.

In some aspects, the techniques described herein relate to a system configured with self-prognosis capability. The system includes: a plurality of system modules; a system diagnostic circuit communicatively coupled to the plurality of system modules and configured to generate a system diagnostic signal indicative of a state of health of the system; a system processing module configured to determine the state of health of the system based at least in part on the system diagnostic signal; and a micro-electromechanical systems (MEMS) switch module configured to control a connection to one or more of the system modules of the plurality of system modules, upon receiving a fault signal indicative of the state of health being below a predetermined threshold.

In some aspects, the techniques described herein relate to a micro-electromechanical systems (MEMS) switch system configured with self-prognosis capability. The MEMS switch system includes: a MEMS switch module configured to control an electrical connection between two voltage nodes of a system; and a monitoring system configured to generate diagnostic data indicative of a physical state of the MEMS switch module; and a processing system configured to receive the diagnostic data from the monitoring system and use a digital twin model to determine one or both of a characteristic and a state of health of the MEMS switch module based on the received diagnostic data, wherein the digital twin model includes a digital representation of at least the MEMS switch module.

In some aspects, the techniques described herein relate to a system configured with self-prognosis capability. The system includes: a plurality of system modules; a system digital twin model including a digital representation of a physical state of one or more of the system modules, wherein the system modules and the system digital twin model are communicatively coupled to each other and the system digital twin model is configured to receive system diagnostic data associated with the physical state of the one or more of the system modules for determining a characteristic of the one or more of the system modules; and a micro-electromechanical systems (MEMS) switch module configured to control a connection to one or more of the system modules upon receiving a fault signal indicative of the physical state of the one or more of the system modules being outside a predetermined range.

In some aspects, the techniques described herein relate to a micro-electromechanical systems (MEMS) switch system configured with self-prognosis capability. The MEMS switch system includes: a MEMS switch electrically connected between two terminals and configured to serve as a circuit breaker; a control and monitoring circuit configured to generate diagnostic data indicative of a physical state of the MEMS switch; a physically unclonable function (PUF) circuit physically coupled to the MEMS switch and configured to repeatably generate a signal unique to the PUF circuit until a threshold condition causes the PUF circuit to be physically altered such that the PUF circuit no longer generates a same signal unique to the PUF circuit; and a prognosis module configured to: authenticate the diagnostic data upon receiving the unique signal; and predict a future functionality of the MEMS switch module based at least in part on the authenticated diagnostic data.

In some aspects, the techniques described herein relate to a micro-electromechanical systems (MEMS) switch system configured with switch self-evaluation. The MEMS switch system includes: a first MEMS switch module electrically connected between two terminals; a control and monitoring circuit configured to generate switch evaluation data; a physically unclonable function (PUF) module configured to capture an operational or environmental condition of the first MEMS switch module and generate a PUF signal indicative of deviation of the operational or environmental condition from a specified condition, a control and processing module configured to receive the switch evaluation data and the PUF signal, and in conjunction with authenticating the PUF signal, process the switch evaluation data to evaluate performance of the first MEMS switch module.

In some aspects, the techniques described herein relate to a high current and high voltage system with integrated fault protection capability. The system includes: one or more system modules configured to be electrically connected to a power supply; a fault detection sensor coupled to the one or more system modules; a micro-electro-mechanical system (MEMS) switch module, the MEMS switch module integrated with the one or more system modules and configured to be electrically connected between the one or more system modules and the power supply; and a common processing module configured to control the one or more system modules and to protect the one or more system modules from an electrical fault by activating the MEMS switch module upon sensing the electrical fault with the fault detection sensor.

In some aspects, the techniques described herein relate to a motor drive system with integrated fault protection capability. The system includes: one or more system modules including a drive circuit electrically connected to a power supply and configured to drive an electric motor using electric power received from the power supply; a fault detection sensor coupled to the one or more system modules; micro-electro-mechanical system (MEMS) switch module, the MEMS switch module integrated with the one or more system modules and configured to be electrically connected between the one or more system modules and the power supply; and a common processing module configured to control the one or more system modules and to protect the one or more system modules from an electrical fault by activating the MEMS switch module upon sensing the electrical fault with the fault detection sensor.

### BRIEF DESCRIPTION OF THE DRAWINGS

Embodiments of this disclosure will now be described, by way of non-limiting example, with reference to the accompanying drawings.

FIG. 1A is a schematic diagram illustrating a symmetric micro-electromechanical systems (MEMS) teeter-totter switch.

FIG. 1B is a schematic diagram illustrating an asymmetric micro-electromechanical systems (MEMS) teeter-totter switch.

FIGS. 2A-2C schematically illustrate the asymmetric MEMS teeter-totter switch shown in FIG. 1B in a neutral state (FIG. 2A), in a first OFF state (FIG. 2B) actuated by a first actuation voltage, and a second OFF state (FIG. 2C) actuated by a second actuation voltage greater than the first actuation voltage.

FIGS. 3A-3C schematically illustrate an example asymmetric MEMS teeter-totter switch having a stopper, in a neutral state (FIG. 3A), in a first OFF state (FIG. 3B) actuated by a first actuation voltage, and a second OFF state (FIG. 3C) actuated by a second actuation voltage greater than the first actuation voltage.

FIG. 4A is a schematic diagram illustrating a top-view of an example symmetric MEMS teeter-totter switch.

FIG. 4B is a schematic diagram illustrating a top-view of an example asymmetric MEMS teeter-totter switch having two mechanical stoppers.

FIGS. 5A-5B are schematic diagrams illustrating a top-view (FIG. 5A) and a side cross-sectional view (FIG. 5B) of an example asymmetric MEMS teeter-totter switch having two mechanical stoppers.

FIGS. 6A-6C illustrate side cross-sectional views of intermediate structures at various stages of fabricating the asymmetric MEMS teeter-totter switch shown in FIG. 5A-5B.

FIG. 7 is a schematic diagram illustrating an example MEMS switch circuit (e.g., a circuit breaker circuit) formed by connecting two teeter-totter switches.

FIG. 8 schematically illustrates an example MEMS switch circuit (e.g., a circuit breaker) comprising a plurality of MEMS teeter-totter switches configured to connect/disconnect the terminals of an electronic circuit and allow high current and high voltage connection between the terminals.

FIG. 9A schematically illustrates a MEMS teeter-totter switch configured to electrically connect a contact electrode to an input voltage applied to the middle electrode with respect to a reference voltage when a control voltage is provided to a control electrode of the teeter-totter switch with respect to the same reference voltage.

FIG. 9B schematically illustrates a MEMS teeter-totter switch configured to electrically connect a contact electrode to an input voltage applied to the middle electrode with respect to a first reference voltage when a control voltage is provided to a control electrode of the teeter-totter switch with respect to a second reference voltage different from the first reference voltage.

FIG. 9C is a plot schematically illustrating the resistance of a conductive path established between the post and a contact electrode by the teeter-totter switch shown in FIG. 9A (solid line) and the teeter-totter switch shown in FIG. 9B (dashed line), as a function of the input volage provided to the middle electrode.

FIG. 10 schematically illustrates an example switching circuit comprising a MEMS switch and a control circuit configured to control the state of the MEMS switch.

FIG. 11A schematically illustrates another example switching circuit comprising a control circuit and a MEMS switch network comprising two or more MEMS switches.

FIG. 11B schematically illustrates temporal variation of example control signal voltage and the control voltage provided to the teeter-totter switch or teeter-totter switch network shown in FIG. 10 and FIG. 11A depicting the temporal alignment between the control signal voltage and the corresponding front and back control voltages.

FIG. 12 schematically illustrates the internal circuitry of a packaged integrated isolator circuit that may be used or included in the switching circuit shown in FIG. 11A.

FIG. 13 schematically illustrates an example switching circuit (e.g., circuit breaker circuitry) comprising optical isolators.

FIG. 14 schematically illustrates an example MEMS switch network controlled by optically isolated control voltages.

FIG. 15 schematically illustrates an example integrated MEMS switch system including a MEMS switch device controlled by an actuation and control circuit and an optical isolator configured to electrically isolate the actuation and control circuit from another circuitry that supply voltage(s) to the actuation and control circuit.

FIG. 16 schematically illustrates an example switching circuit comprising a MEMS switch protected by a field-effect transistor (FET), serving as a protective switch, and a control circuit configured to control the state of the MEMS switch.

FIG. 17 schematically illustrates example temporal variations of control signal voltage and front and back control voltages provided to the MEMS switch shown in FIG. 18 (top panel), and the gate voltage (V_{g}) provided to the FET (bottom panel) during transitioning from OFF to ON state and

FIG. 18 schematically illustrates another example of a circuit breaker comprising a MEMS switch, an electric overstress (EOS) protection device configured to protect the MEMS switch from unexpected transient signals, and a protective switch configured to protect the MEMS switch during a transition between ON and OFF states.

FIG. 19 schematically illustrates a system comprising a MEMS switch module integrated with one or more sensors and a control circuit to control the MEMS switch module and the one or more sensors.

FIGS. 20A-20B schematically illustrate a top view (FIG. 20A) and a cross-sectional side view (FIG. 20B) of an example MEMS switch comprising one or more integrated sensors.

FIG. 21 is a block diagram illustrating an example circuit breaker comprising a MEMS switch module protected by a protective switch and an EOS protection device and monitored using one or more sensors including a temperature sensor and a current sensor.

FIG. 22 schematically illustrates a backplane of a system comprising two power lines electrically connected to two server shelves configured to be powered through the backplane and communicate with the system.

FIG. 23A schematically illustrates an example hot swap controller (HSC) comprising a current sensing element and a control circuit, and an HSC switch controlled by the control circuit.

FIG. 23B is block diagram of another HSC configured to control current flowing from a first terminal of a card to a load based on a voltage provided to the load to ensure valid operation voltage and to protect the load.

FIG. 24 schematically illustrates a MEMS-based HSC comprising a current sensing element, a MEMS switch and a control circuit configured to control the MEMS switch based at least in part on a signal received from the current sensing element or a voltage drop along the current sensing element.

FIG. 25 schematically illustrates a MEMS-based HSC having three MEMS switches connected in parallel between the input and output switch ports of the MSC and configured to provide variable resistance.

FIG. 26 schematically illustrates an HSC that comprises a MEMS switch (or MEMS switch network) connected in parallel with a transistor switch between the input and output switch ports of the HSC.

FIG. 27A schematically illustrates an example HSC that includes an electro-mechanical relay configured to further control an electrical path between a power source and a load.

FIG. 27B schematically illustrates examples of the control pulses that may be provided to the MEMS switch, the solid-state switch, and the electro-mechanical relay of the HSC shown in FIG. 27A.

FIG. 28 schematically illustrates an example plasma system comprising a plasma power supply, a plasma chamber and an arc switch electrically connecting the plasma power supply to the plasma chamber under the control of a detection and extinguishing circuit.

FIG. 29 schematically illustrates an example of MEMS-based control circuit that may be used in the plasma system shown in FIG. 28 to control a protection device comprising a MEMS switch serving as the arc switch.

FIG. 30A schematically illustrates a dual transistor switch configured to provide a controlled electrical connection between two nodes connected to an alternating current voltage.

FIG. 30B schematically illustrates conductive paths and current flows established by the transistors of the dual transistor switch shown in FIG. 30A.

FIG. 30C schematically illustrates, a field-effect transistor quartet configured to provide a controlled electrical connection between two nodes connected to an alternating current voltage.

FIG. 31 schematically illustrates a MEMS-based control circuit configured to control a connection between an alternating current (AC) voltage node, e.g., an AC voltage node of the plasma system shown in FIG. 28, and a plasma power supply using a MEMS switch.

FIG. 32 schematically illustrates an example plasma system driven by a plasma power supply system comprising a MEMS switch configured to provide a controlled electrical connection between the plasma power supply and a plasma chamber.

FIG. 33 schematically illustrates an example MEMS switch circuit configured to test the performance of a MEMS switch module without interrupting an electrical connection established via the MEMS switch.

FIG. 34 schematically illustrates an example MEMS switch network comprising a plurality of MEMS switches arranged in a plurality of branches connected in parallel between a common input port and a common output port.

FIG. 35 schematically illustrates an example of MEMS switch circuit configured to test one or more MEMS switches by measuring a temperature of a die or substrate on which one or more MEMS switches are formed.

FIG. 36 schematically illustrates an example MEMS switch circuit configured to test one or more MEMS switch modules by measuring voltage drop(s) between the two ports of one or more MEMS switch modules.

FIG. 37 schematically illustrates an example of MEMS switch circuit configured to test one or more MEMS switch modules connected in series between two nodes and configured to stay open to electrically isolate the two nodes during a normal operational period of one or more circuits connected to the two nodes.

FIG. 38 schematically illustrates an example MEMS switch circuit configured to predict a future failure or estimate a lifetime of the MEMS switch modules therein without interrupting an electric connection between nodes connected via the MEMS switch module.

FIG. 39 schematically illustrates multiple nodes of a system in communication with a processing, control and alerting (PCA) system.

FIG. 40 schematically illustrates an example system comprising multiple nodes where at least some comprise a MEMS-based circuit breaker module.

FIG. 41 illustrates an example dynamic node monitoring system comprising multiple dynamic nodes in wireless communication with a processing, control, and alerting system.

FIG. 42 schematically illustrates another example system comprising a plurality of nodes connected to a PCA system.

FIGS. 43A-43B schematically illustrates a node comprising a physically unlockable function (PUF) and a MEMS switch module in communication with a PCA system configured to securely monitor and control the MEMS switch using the PUF.

FIG. 44 schematically illustrates a node comprising an authentication module configured to transmit data received from control and monitoring circuitry of a circuit breaker module upon authenticating a PUF signal associated with a MEMS circuit breaker module.

FIG. 45 schematically illustrates an example PUF module comprising multiple PUF units or circuits.

FIG. 46 illustrates a block diagram of a system comprising a device or a physical asset that is controlled and/or monitored by a PCA system comprising a digital twin (DT) of the device or physical asset.

FIG. 47 illustrates a block diagram of a system comprising a node or system and a processing system configured to generate a digital twin model (DTM) of one or more components, modules, and circuits in the node or system.

FIG. 48A schematically illustrates examples of intrinsic parameters of a MEMS switch and examples of extrinsic parameter that may affect the intrinsic parameters.

FIG. 48B schematically illustrates an example variation of a switching voltage of a MEMS switch as a function of cumulative time that the MEMS switch is kept in a state (e.g., ON state or OFF state) during a measurement period.

FIG. 49 is a block diagram illustrating data flow from a circuit breaker to a digital twin model (DTM) of the MEMS switch therein, and from the DTM to an action module configured to generate a recommendation, an alert, or a control signal to adjust an operational condition or control parameter of the circuit breaker.

FIG. 50A shows examples of measured values of activation voltages of a MEMS switch or MEMS switch module plotted against cumulative ON time (time kept in deactivation state) at different temperatures.

FIG. 50B shows results of multiplying the values of activation voltages shown in FIG. 50A measured at 85° C., 100° C., and 125° C., by temporal scaling factors plotted against a function of cumulative ON time.

FIG. 50C shows natural logarithm of the time (T50) it takes for deactivation threshold voltage of the MEMS switch (characterized in FIGS. 50A and 50B) to decay to 50% of its original value (prior to exposure to elevated temperature), as a function of inverse temperature of the MEMS switch.

FIG. 51A shows measured values of absolute ON resistance as a function of cumulative ON time for the MEMS switch characterized in FIGS. 50A-50C.

FIG. 51B shows measured values of absolute ON resistance as a function of number of switching actions for the MEMS switch characterized in FIGS. 50A-50C.

FIG. 52 shows failure probability distribution plot with 95% confidence interval for different RF powers transmitted/switched by a MEMS switch, plotted against the number of switching actions (number activation-deactivation cycles).

FIG. 53A is a block diagram of a smart monitoring system configured to receive a diagnostic signal or data from a system and monitor one or more of modules, circuits, and devices of the system based at least in part on the diagnostic data.

FIG. 53B is a block diagram of a system comprising a MEMS switch module that is capable of determining/predicting present and future functionality of the MEMS switch module and/or generating a mission profile for the MEMS switch module.

FIG. 54A is a block diagram of an example drive circuit for an electric motor.

FIG. 54B is a block diagram of a motor driven by a drive circuit connected to the power supply via a circuit breaker.

FIG. 55A is a block diagram of a motor drive system comprising a drive circuit configured to drive and control an electric motor.

FIG. 55B is a block diagram illustrating some of the circuits, devices, modules and sub-systems of the drive circuit shown in FIG. 55A.

FIG. 56A is a block diagram of an example server system comprising circuit breakers within one or both of a power rack and a server rack.

FIG. 56B schematically illustrates a portion of a high-voltage direct-current (HVDC) power rack. The inset shows a portion of the internal circuitry of one of power distribution units (PDUs) of the power rack comprising circuit breakers.

FIG. 56C schematically illustrates a portion of a high-voltage direct-current (HVDC) server rack and a portion of internal circuitry of a server shelf of the HVDC server rack.

FIG. 57A illustrates an example front end protection system of an electric vehicle (EV) charging system that includes one or more MEMS-based circuit breakers.

FIG. 57B schematically illustrates another example of an EV charging system comprising a MEMS switch module or a MEMS-based circuit breaker.

FIG. 58A schematically illustrates an example uninterruptable power supply (UPS) systems that uses a MEMS switch module and/or a MEMS-based circuit breaker between an AC electric source and a load.

FIG. 58B schematically illustrates an example system comprising a plurality of UPS units operating in parallel to supply power to several loads via a secure network (e.g., a power network).

FIG. 59 is a block diagram of an electrical system configured to perform a specified function or task using a plurality of modules.

FIG. 60A is a flow diagram illustrating an example process for maintaining the state of a MEMS switch during a power outage.

FIG. 60B is a flow diagram illustrating an example process for restoring the state of a MEMS switch after a power outage.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings. The headings provided herein are for convenience only and do not necessarily affect the scope or meaning of the claims.

In the embodiments of this disclosure, circuit breakers, modules, systems, and methods are described in connection with particular embodiments. It will be understood, however, that the principles and advantages of the embodiments can be used for any other systems, apparatus, or methods with a need for the technology disclosed herein. The elements and acts of the various embodiments of this disclosure can be combined to provide further embodiments. The acts of the methods discussed herein can be performed in any order as appropriate. Moreover, the acts of the methods discussed herein can be performed serially or in parallel, as appropriate. Moreover, any suitable principles and advantages of this disclosure in systems and in methods that include a micro-electromechanical systems (MEMS) switch configured to control an electric connection.

The principles and advantages described herein can be implemented in any system, apparatus, or electronic device that includes a MEMS switch for controlling an electric connection, to ensure the MEMS switch can properly control the electric connection when needed. Example systems that can include MEMS-based hot swap controller disclosed herein can include, but are not limited to, servers, data centers, storage systems, base stations, communication systems, etching plasma systems, cleaning plasma system, a corona system, or other systems that include a plasma firmed between two electrodes. The principles and advantages described herein could also be applied to any system that operates with high voltages and currents such as data centers, grid energy storage systems, EV charging systems and infrastructure.

MEMS Switches for High Current and/or High Power

Switches are integral to a wide variety of applications in a variety of industry sectors including telecommunications, aerospace, healthcare and consumer electronics, to name a few. Different switching technologies have different advantages and drawbacks. Desirable switching technology characteristics for some applications include wide bandwidth, fast switching speed, reliability, scalability and high-volume manufacturability. For example, drawbacks of electromechanical relay technologies can include narrow bandwidths, limited actuation lifetimes and large package sizes. In comparison, microelectromechanical systems (MEMS) switch technology has the potential to deliver higher bandwidth, higher reliability and smaller form factors, among other advantages, compared to electromechanical relays. Central to the MEMS switch technology is a micromachined beam switching element that is electrostatically actuated using metal-to-metal contacts via electrostatics.

One example application of the MEMS switch technology, is in circuit breakers. Circuit breakers are used in a wide variety of applications, including electric vehicle charging, secondary battery management, motor drives and industrial power supplies, to name a few. A circuit breaker uses a switch to interrupt power to a sensitive electronic load in the event of an over-current and/or over-voltage condition. The inventors have realized that MEMS switches have the potential to improve upon traditional electromechanical circuit breakers with respect to the above-mentioned drawbacks. However, existing MEMS switch technologies still face challenges for application in circuit breaker technologies due to, among other reasons, limited current and voltage handling capabilities. For example, some MEMS switches may be prone to rapid wear out or arcing of the beam switching element under high voltage and current conditions. To address these and other needs, disclosed herein are MEMS switches configured for high voltage and high current applications, and various systems and applications incorporating such MEMS switches.

Aspects of the present disclosure provide micro-electromechanical systems (MEMS) switches having a teeter-totter configuration, as well as methods of operating and fabricating such switches.

In some implementations, a MEMS switch (e.g., a cantilever-based switch) may comprise a conductive beam that is connected to a post formed on or over a substrate and can be configured to be pulled toward the substrate upon actuation. When the MEMS switch is not actuated, an elastic restoring force of the beam (or a hinge) may restore a predefined separation between a free end of the conductive beam and a contact electrode formed on the substrate, such that the MEMS switch becomes open or goes to an OFF state. In some cases, when the MEMS switch is actuates the free end of the conductive beam is pulled into contact with the contact electrode (e.g., by an electric force) such that the switch becomes closed (goes to an ON state) and establishes an electrical path between the contact electrode and the post. In some applications, the MEMS switch may be employed to controllably connect or disconnect two terminals of an electric circuit (e.g., a circuit breaker circuitry) connected to the MEMS switch.

In some embodiments, a MEMS switch may comprise a beam anchored to a substrate via a middle point of the beam such that both ends of the beam can be actuated to move toward the substrate. Such MEMS switch, herein referred to as teeter-totter switch may comprise a beam (e.g., a conductive beam) mechanically connected to an underlying substrate by a post (e.g., a conductive post) that supports the beam at a point between two opposite ends (e.g., free ends) of the beam. In some cases, the beam may be connected to the post by a hinge or hinge structure that may allow the beam to rotate with respect to the post. In some embodiments, the post may be symmetrically located with respect to two opposite ends of the beam. In some such embodiments, regardless of which one of the two ends are actuated (e.g., pulled toward the substrate), a vertical separation between the other end and the substrate can be substantially independent of which of the two ends is actuated. In some embodiments, the post may be asymmetrically located with respect to two opposite ends of the beam. For example, the post can be closer to a first end of the beam relative to a second end of the beam opposite the first end. In some such embodiments, when the post is closer to one end of the beam, actuating different ends may result in different vertical separations between the other end and the substrate.

In some cases, the post may serve as one or both of a mechanical pivot and a conductive path between the conductive beam and a middle conductive electrode (herein referred to as the middle electrode) formed on or within the substrate. In some embodiments, the beam may be configured to controllably pivot or tilt with respect to the substrate, e.g., by an electrostatic actuation mechanism to electromechanically couple one end of the beam to one of a pair of contact electrodes formed on the substrate. For example, an end of the beam may include a contact tip and upon actuation of that end, the contact tip can make electrical contact with a respective contact electrode on the substrate. In some cases, the middle electrode and one of the contact electrodes can be electrically connected to two different terminals of an electric circuit.

In some cases, in an ON state the second end of the beam may contact (be electromechanically coupled to) a contact electrode of the pair of contact electrodes to establish a conductive path between the contact electrode and the middle electrode via the beam and, in some cases, a contact tip disposed at the second end. In some cases, in an OFF state, the teeter-totter switch can be in a neutral state where one or both ends of the beam are disconnected from the respective contact electrodes. In some examples in the OFF state a vertical distance between an end of the beam and the respective contact electrode may be configured to prevent electric discharge or arcing at a target electric potential difference between that end and the respective contact electrode.

In some embodiments, a teeter-totter switch may be used as a two-port switch, e.g., by electrically shorting the middle electrode and one of the contact electrodes. For example, a first contact electrode of the teeter-totter switch can be electrically connected to its middle electrode and the teeter-totter switch may be configured to control electric connection between a second contact electrode of the teeter-totter switch and the middle electrode (and the post). In some such embodiments, in the OFF state, a second end of the beam may be disconnected from a second contact electrode and a first end of the beam can be in contact with the first contact electrode. In some embodiments, e.g., when the first electrode is shorted to the middle electrode, the teeter-totter switch may be actuated from the OFF state to the ON state by actuating the beam (e.g., by pulling the second end toward the substrate) to electromechanically disconnect its first end from the first contact electrode and to electromechanically connect its second end to the second contact electrode. In these embodiments, the teeter-totter switch may be actuated from the ON state back to the OFF state by actuating the beam (e.g., by pulling the first end toward the substrate) to electromechanically disconnect its second end from the second contact electrode and electromechanically connecting its first end to the first contact. In some embodiments, e.g., when the teeter-totter switch is used in a circuit breaker between two terminals, the middle electrode may be electrically connected to a first terminal and the second contact electrode may be electrically connected to a second terminal. In these embodiments, the OFF state may be referred to as activated state of MEMS switch where the electric connection between the two terminal is disconnected by the circuit breaker. Accordingly, in these embodiments, the ON state may be referred to as deactivated state of MEMS switch where an electric connection is established between the two terminals via the beam of the teeter-totter switch.

In some examples, when the post is asymmetrically positioned respect to the first and second ends of the beam and the teeter-totter switch is in OFF state, the vertical distance between the second end of the beam and the second contact electrode, herein referred to as an OFF state gap, can be larger than a corresponding vertical distance for a teeter-totter switch having a post symmetrically positioned with respect to the first and second ends of the beam. Advantageously, a larger OFF-state gap may allow the teeter-totter switch to be used for high voltage switching, as a larger vertical separation between the second end and the respective contact electrode in the OFF state (e.g., when the switch is activated) can provide electrical isolation at a higher voltage by increasing the breakdown voltage at which electric arcing may occur. As such, an asymmetric teeter-totter switch can be used for higher voltage applications, compared to some of the existing symmetric teeter-totter switches. In some cases, an upper bound for a voltage that may be switched by a teeter-totter switch may be referred to as the operating voltage (Vₘ) of the teeter-totter switch. The OFF-state gap for a teeter-totter switch, which is configured as a two-port device, may be further increased by positioning the post closer to an end of the beam (e.g., the second end) closer to the contact electrode that is shorted to the middle electrode and/or increasing the length of the beam. The inventors have found that, by tuning the OFF-state gap, operational voltage of the teeter-totter switch may be increased.

In some embodiments, a larger OFF state gap, provided by a longer beam or position the post closer to one end of the beam, can increase the stress on the hinge, the post and/or the beam, in particular when the teeter-totter switch in the OFF state. In some cases, excessive stress may reduce the lifetime of the teeter-totter switch and increase the complexity of a reliable mechanical design for anchoring of the beam to the substrate (e.g., the complexity of a hinge that connected the beam to the post). The inventors have discovered that the stress transferred to the beam, post, and/or the hinge, may be reduced by forming a mechanical stopper under the beam. In some implementations, upon actuation of the teeter-totter switch, the mechanical stopper contacts the substrate and allows the beam to tilt or pivot around a contact point between the mechanical stopper and the substrate, thereby reducing the stress on the beam, hinge and/or the post. In some implementations, the mechanical stopper may be disposed close to or at the longitudinal position of the post with respect to the two ends of the beam. In some implementations, the mechanical stopper may be disposed in a longitudinal position between the post and one end of the beam, e.g., the first end when the first contact electrode is shorted to the middle electrode. In various implementations, a teeter-totter switch may comprise two mechanical posts (e.g., at the same longitudinal position and different lateral positions with respect to the beam).

In some embodiments, the electrostatic actuation mechanism used for controlling or actuating a teeter-totter switch may comprise electrostatic forces applied on the beam by two capacitors formed on the opposite sides of the post, each capacitor comprising a conductive control electrode (herein referred to as control electrode) formed on the substrate and a portion of the beam above the control electrode. As such, to change the state of the teeter-totter switch from the OFF state to an ON state (e.g., to put the second end of the beam in contact with the respective contact electrode), and vice versa, a sufficiently large voltage (herein referred to as switching voltage, Vₛ) may be applied across one of the two capacitors.

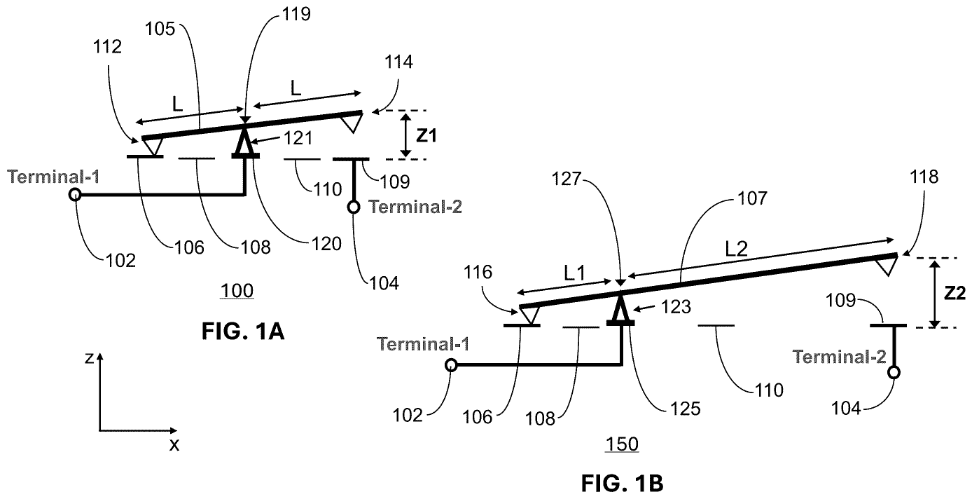

FIG. 1A is a schematic diagram of a symmetric MEMS teeter-totter switch 100. In some embodiments, the symmetric MEMS teeter-totter switch 100 may comprise a beam 105, a post 121, two contact electrodes 106, 109, two control electrodes 108, 110, and a middle electrode 120 formed over a substrate (not shown).

In some embodiments, the beam 105 may be extended from a first end (or a first edge) 112 to a second end 114 (or a second edge) and a have width (w) in a transverse direction normal the longitudinal direction (e.g., normal to the x and z-axes). In some embodiments, the beam 105 may be positioned to form one or more mechanical connections (e.g., via one or more hinges) with the anchor or post 121, which may be disposed on the substrate (e.g. a silicon substrate). In some cases, the anchoring point or region 119 of the beam 105, which is mechanically connected to the post 121, may be symmetrically positioned with respect to the first and second ends 112, 114, of the beam 105, such that a first distance (L) between the anchoring point or region 119 and the first end 112 is substantially equal to a second distance (L) between the anchoring point or region 119 and the second end 114.

In some embodiments, the beam 105 and the post 121 may comprise a conductive material, such as gold, aluminum, copper, nickel, a metal alloy or any other suitable electrically conductive material. In some cases, a structural material of the beam (e.g., the conductive material) may be selected to provide a desired level of stiffness to the beam 105, for example to avoid bending when subjected to a force or torque (e.g., electrostatic force or torque used to actuate the beam) during operation of the teeter-totter switch. In some embodiments, the beam 105 may comprise a single material or a uniform material composition (e.g., a single alloy). In other embodiments, the beam 105 may comprise a multilayer structure where at least two layers are composed of different materials. For example, the beam 105 may comprise a first structural material that provides mechanical stiffness and a second structural material that provides electric conductivity. In some cases, the beam 105 may comprise two separate regions having different material compositions.

In some cases, the beam 105 may be constructed to substantially resist bending during operation of the teeter-totter switch 100, while the hinge(s) that connect the beam 105 to the post 121 may be constructed to allow for rotation of the beam about the post 121.

In some embodiments, the middle electrode 120 may be electrically connected with the post 121. In some such embodiments, the middle electrode 120 may be formed between the post 121 and the substrate (not shown) and can be in direct contact with the post 121. In some embodiments, the middle electrode 120 can be electrically connected to a first terminal 102 (e.g., an input terminal) and one of the first and second contact electrodes 106, 109 (the second contact electrode 109 in the example shown), may be electrically connected to a second terminal 104 (e.g., an output terminal) of an electronic circuit (e.g., a circuit breaker). In some implementations, the first and second terminals 102, 104, can be high voltage input and low voltage outputs of a circuit breaker, respectively. In some embodiments, the teeter-totter switch 100 may be configured to control an electrical connection between the first and second terminals 102, 104, by closing and opening an electrical path between the first and second terminals 102, 104 via the beam 105 and the post 121. In some examples, when the teeter-totter switch is in an ON state, the second end 114 of the beam 105 can be in electrical contact with the second contact electrode 109 to establish a conductive path between the first and second terminals 102, 104. In some examples, when the teeter-totter switch 100 is in an OFF state, the first end of the beam 105 can be in electrical contact with the first contact electrode 106, and the second end 114 of the beam 105 can be at a vertical distance (Z1, along z-axis) from the second contact electrode 109 to electrically isolate the first and second terminals 102, 104. In some implementations, contact tips may be formed on either end of the beam 105 to improve electrical contact between the beam 105 and the respective contact electrodes 106, 109.

In some embodiments, the teeter-totter switch 100 may include a pair of control electrodes 108, 110, configured to form two capacitive actuators on opposite sides of the post 121 with respect to lateral direction (x-axis) where each capacitive actuator is formed between a control electrode and a portion of the beam 105 above the control electrode and is configured to exert an attractive force to the receptive portion of the beam 105 to pull down an end of the beam closer to the control electrode. In some examples, a first control electrode 108 may be formed between the first contact electrode 106 and the middle electrode 120 and/or the post 121 and a second control electrode 110 may be formed between the second contact electrode 109 and the middle electrode 120 and/or the post 121. In some cases, to change the state of the teeter-totter switch 100 from the OFF state to the ON state (e.g., to put the second end 114 of the beam 105 in contact with the second contact electrode 109), a sufficiently large voltage (herein referred to as switching voltage, Vₛ) may be applied across the second capacitor formed between the beam 105 and the second control electrode 110, and to change the state of the teeter-totter switch 100 from the ON state to the OFF state (e.g., to disconnect the first end 114 of the beam 105 from second contact electrode), a sufficiently large voltage (equal or larger than Vₛ) may be applied across the first capacitor formed between the beam 105 and the first control electrode 108. In some cases, in the OFF state, the first end 112 of the beam 105 can be in contact with the first contact electrode 106 (e.g., to maximize the OFF-state gap size Z1 and further to close the electric loop between the beam 105 and the post 121 when the middle electrode 120 is electrically connected to the first contact electrode 106). In some cases, the teeter-totter switch 100 can be in a neutral state when both ends of the beam 105 are disconnected from the respective contact electrodes.

In some embodiments, in the ON state, when the second contact electrode 109 is in contact with the second end 114, the resistance of an electrical path established by the teeter-totter switch 100, e.g., between the first and second terminals 102, 104, may change as a function of the electrostatic force applied on the beam 105, e.g., by providing a electric potential difference between the second control electrode 110 and the beam 105. As such, in some cases, a switching voltage, Vₛ, provided to the control electrode 110 may be larger than a voltage that not only puts the second end 114 in contact with the second contact electrode 109 but also provides a conductive path with a resistance lower than a desired value. In some cases, a switching voltage Vₛ for actuating a MEMS switch from the OFF state to the ON state may be an actuation voltage that establishes a conductive path via the MEMS switch with a resistance equal or below a specified ON-state resistance.

In some embodiments, when the teeter-totter switch 100 is in OFF state, a voltage difference provided between the first and second terminals 102, 104, may be limited by the vertical distance Z1, or the OFF-state gap of the teeter-totter switch 100, and the corresponding breakdown voltage between the second end 114 of the beam 105. As such it can be advantageous to increase the vertical distance Z1 such that the teeter-totter switch 100 can switch at larger voltages. In various implementations, Z1 can be increased by increasing one or both of the height of the post 121 (e.g., along the z-axis), the total length (2L) of the beam 105, and/or by bringing the post 121 closer to the first end 112 (making the teeter-totter switch asymmetric).

FIG. 1B schematically illustrates an asymmetric MEMS teeter-totter switch 150 according to embodiments. The teeter-totter switch 150 comprises a conductive post 123 positioned closer to a first end 116 of a conductive beam 107, relative to a second end 118 of the conductive beam 107 opposite the first end 116. In some embodiments, the teeter-totter switch 150 may comprise one or more features described above with respect to the teeter-totter switch 100. In some examples, a first distance (L1) between the anchoring point or region 127 of the beam 107 (where the beam 107 is mechanically connected to the post 123) and the first end 116 is smaller than a second distance (L2) between the anchoring region 127 of the beam 107 and the second end 118 by at least 3%, at least 5%, at least 7%, at least 10%, at least 15%, or at least 20%, or a value in a range defined by any of these values, of the total length of the conductive beam (e.g., L1+L2). In some embodiments, the post 123 can be disposed closer to the first end 116 relative to the second end 118 of the beam 107 by at least 3%, at least 5%, at least 7%, at least 10%, at least 15%, or at least 20% of the length of the conductive beam 107 (e.g., L1+L2). Advantageously, when the total lengths of the beams 105 and 107, and the heights of the posts 121 and 123 are substantially equal, and the teeter-totter switches 100 and 150 are in the OFF state, the vertical distance Z2 can be larger than the vertical distance Z1. As a result, the dielectric (air) gap between the second contact electrode 109 and second end 118 of beam 107 (OFF-state gap of the asymmetric teeter-totter switch 150) can have a larger breakdown voltage compared to the dielectric (air) gap between the second contact electrode 109 and the second end 114 of the beam 105 (OFF-state gap of the symmetric teeter-totter switch 100). As such, in some embodiments, an upper limit for the operating voltage (Vₘ) of the asymmetric teeter-totter switch 150 (FIG. 1B) can be greater than that of the symmetric teeter-totter switch 100 (FIG. 1A). Advantageously, the asymmetric teeter-totter switch 150 can be used in high voltage electronic circuits (e.g., high voltage circuit breakers) to control electrical connection between terminals having voltage differences greater than 100 volts, 150 volts, 200 volts, 300 volts, 400 volts, 500 volts, or a voltage in a range defined by any of these values, or larger values.

As disclosed herein, the first contact electrode 106 of the asymmetric teeter-totter switch 150, which is closer to the post 123, may be referred to as the back contact electrode of the asymmetric teeter-totter switch 150 and the second contact electrode 109 of the asymmetric teeter-totter switch 150, which is farther from the post 123 (compared to the first contact electrode 106), may be referred to as the front contact electrode of the asymmetric teeter-totter switch 150. In some cases, the terminals of an electronic circuit (e.g., a circuit breaker circuitry) may be electrically connected to the middle electrode 125 and the front contact electrode 109 of the asymmetric teeter-totter switch 150, such that in the OFF state, the electric isolation is provided by the gap between the second end 118 of the beam 107 and the front contact electrode 109 that is larger, thereby allowing for tolerance against a larger voltage difference. In some such cases, the teeter-totter switch 150 may be configured as a two-port device and the middle electrode 125 can be electrically connected to the first contact electrode 106.

As disclosed herein, a MEMS switch such as an asymmetric teeter-totter switch may be referred to as being activated when the end of the conductive beam that is farther away from the conductive post is lifted and not in electrical contact with the respective contact electrode. For example, the asymmetric teeter-totter switch 150 as illustrated in FIG. 1B may be referred to as being in the activated state, with the second contact electrode 109 and the second end 118 of the beam 107 are electrically disconnected from each other. Conversely, a MEMS switch such as an asymmetric teeter-totter switch may be referred to as being deactivated when the end of the conductive beam that is closer to the conductive post is lifted and not in electrical contact with the respective contact electrode. For example, the asymmetric teeter-totter switch 150 may be referred to as being in the deactivated state when the first contact electrode 106 and the first end 116 of the beam 107 are electrically disconnected from each other.

In some various implementations, MEMS teeter-totter switches 100 and 150 may be used to disable/enable the electrical connection between two circuit elements, or to route signals to/from one of two circuit elements. In yet other embodiments, multiple teeter-totter switches may be used to perform more complex functions.

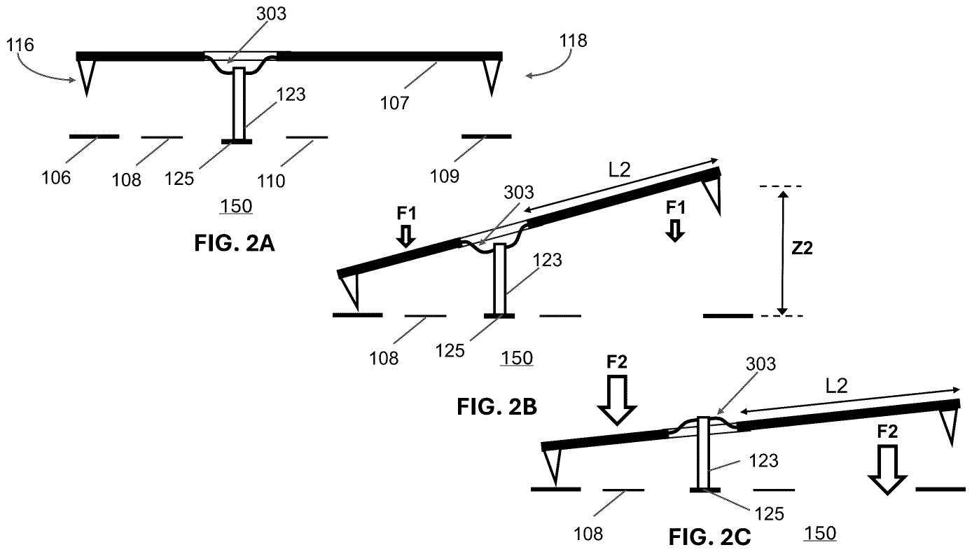

FIGS. 2A-2C schematically illustrate the asymmetric MEMS teeter-totter switch 150 in a neutral state (FIG. 2A), when the voltage difference between the control electrodes 108 and 110, and the beam 107 is substantially zero (FIG. 2A), and when first and second voltage differences, V1 and V2, are applied between the control electrode 108 and the beam 107 (FIGS. 2B and 2C, respectively), to actuate the teeter-totter switch into the OFF state (e.g., the state in which the first end 116 of the beam 107 is in contact with the first contact electrode 106). In some cases, V1 and V2 may be configured to counter electrostatic forces exerted between the second end 118 and the second contact electrode 109 (e.g., due to the voltage difference between the middle electrode 125 and the second contact electrode 109) and to maintain the OFF-state gap (e.g., Z2). In some cases, the voltage difference between the second end 118 of the beam 107 and the front contact electrode 109 can be larger in FIG. 2C compared to FIG. 2B. As such V2 may be greater than V1 to counter the larger attractive electrostatic force between the second end 118 and the front contact electrode 109 and maintain vertical distance Z2 between them. As shown in FIGS. 2A-2C, actuating and tilting the beam 107 can induce mechanical stress in the hinge 303 that connects the beam 107 to the post 123, and a larger electrostatic force (F2) applied closer to the first end 116 (via the control electrode 108), e.g., to counter the electrostatic force pulling the second end 118, may result in significant elastic deformation of the hinge 303 (as shown in FIG. 2C). In some examples, the elastic deformation of hinge 303 may reduce the vertical distance Z2 and reduce the corresponding breakdown voltage. In some embodiments, the mechanical stress and deformation induced in hinge 303, beam 107 may increase when length L2 is increased to increase the operational voltage of the teeter-totter switch.

The inventors have discovered that the mechanical stress and deformation induced in the hinge 303, post 123, and/or the beam 107 can be reduced by providing a mechanical stopper between beam 107 and the substrate on which the teeter-totter switch is formed, such that a major portion of the mechanical load resulting from the electrostatic forces applied on the teeter-totter switch structure is carried by the mechanical stopper and is transferred to the substrate. In some embodiments, the mechanical stopper may be formed at bottom surface of the beam 107 and extend towards the substrate. In some cases, the mechanical stopper may not be connected to the substrate and may freely move or rotate with respect to the substrate while being in contact with the substrate via a bottom surface (e.g., a curved surface). In some cases, upon actuation (e.g., activation or deactivation) of the MEMS switch, the mechanical stopper may contact the substrate to serve as a fulcrum and to substantially limit an elastic deformation of one or more of the beam 107, the post 123, or the hinge 303.

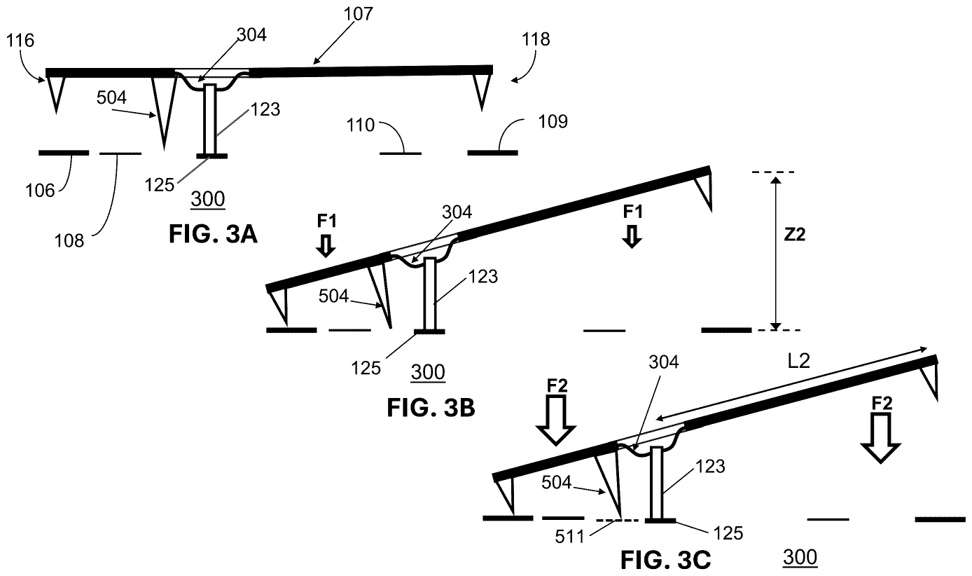

FIGS. 3A-3C schematically illustrate an asymmetric MEMS teeter-totter switch 300 having a mechanical stopper 504 in a neutral state (FIG. 3A), when the voltage difference between the control electrodes 108 and 110, and the beam 107, is substantially zero, and when first and second voltage differences, V1 and V2, are applied between the control electrode 108 and the beam 107 (FIGS. 3B and 3C, respectively) to actuate the teeter-totter switch into the OFF state (e.g., put the first end 116 of the beam 107 in contact with the first contact electrode 106). Similar to FIGS. 2A-2C, the voltage difference between the second end 118 of the beam 107 and the front contact electrode 109 can be larger in FIG. 3C compared to FIG. 3B. In some embodiments, the teeter-totter switch 300 shown in FIGS. 3A-3C may comprise one or more features described above with respect to the teeter-totter switch 150 shown in FIGS. 1B, and 2A-2C. In some embodiments, the mechanical stopper 504 may be formed at a bottom surface of the beam 107 and extend towards the substrate (not shown). In some cases, when the teeter-totter switch is in neutral state (FIG. 3A), the mechanical stopper 504 may not be in contact with the substrate. In some embodiments, when the teeter-totter switch is actuated and the beam 107 tilts (FIG. 3B), e.g., by applying a voltage difference between the first control electrode 108 and the beam 107, the mechanical stopper 504 may contact the substrate to limit (e.g., substantially limit) the stress an elastic deformation generated in the hinge 304, and in some cases, in the post 123 and/or beam 107. In some embodiments, when the MEMS teeter-totter switch 300 is actuated, the mechanical stopper 504 may serve as a mechanical pivot (or fulcrum) and the post 123 may serve as conductive path between the beam 107 and the middle electrode 125, and as an anchor that provides a mechanical connection between the beam 107 and the substrate (via the hinge 304). In some cases, the hinge 304 may be configured to provide mechanical connection between the post 123 and the beam 107 without significantly limiting the motion (e.g., rotational motion) of the beam 107 with respect to the post 123. For example, the hinge 304 can be thinner, narrower, or otherwise have smaller dimensions compared to the hinge 303 of the teeter-totter switch 150 that does not have a mechanical stopper. For example, the hinge 303 may comprise multiple segments connecting the post 123 to the beam 107 and the hinge 304 may comprise a single segment connecting the post 123 to the beam 107.

As shown in FIGS. 3A-3C, actuating and tilting the beam 107 can put the stopper 504 in contact with the substrate and once the stopper 504 contacts the substrate it may serve as a mechanical pivot to reduce mechanical stress in the hinge 304 such that the larger electrostatic force (F2) applied close to the first end 116 (via the control electrode 108), does not result in a significant deformation of the hinge 304 (as shown in FIG. 3C). In other words, the mechanical stopper 504 can significantly reduce or essentially eliminate the elastic deformation of the hinge 304 and can maintain the vertical distance Z2 at a desired value (or within a desired range) as the force exerted on the beam 107 increase (e.g., to switch a greater voltage). In some cases, the stopper 504 may allow for increasing of the length L2, and thereby the operating voltage (Vₘ) of the teeter-totter switch.

In some embodiments, the mechanical stopper 504 may comprise a conductive material. In some such embodiments, the mechanical stopper 504 may simultaneously serve as the mechanical pivot and as a conductive path or a supplemental conductive path between the beam 107 and the middle electrode 125. In some examples, an additional middle electrode 511 may be formed on the substrate below the stopper 504 such that when the teeter-totter switch 300 is actuated, the stopper 504 contacts the additional middle electrode 506 and establishes a conductive path between the beam 107 and the additional middle electrode 506. In some embodiments, the additional middle electrode may be electrically connected to the middle electrode 125. As such, in some implementation, the mechanically stopper 504 may provide conductive paths parallel to the conductive path provided by the post 123 to reduce a resistance between the beam 107 and the middle electrode 125 and thereby increase the current handling limit of the teeter-totter switch 300.

In various implementations, the mechanical stopper 504 can be positioned at the same or different longitudinal positions as the post 125 with respect to the beam 107. For example, the mechanical stopper can be closer to the first end 116, e.g., to provide a larger OFF-state gap (Z2) and/or support more mechanical load during the OFF state. It should be understood that in the OFF state, a larger actuating force may be applied on the beam 107 to counter the attractive force generated by the voltage between the beam 107 and the front contact electrode 109, compared to the ON state where the actuating force does not counter any opposing electrostatic force.

In addition to high voltage enabling features such as the asymmetrically positioned post and mechanical stoppers, the teeter-totter switches can further be configured for high current applications by dividing the current flow between the beam and multiple contact electrodes (e.g., multiple electrically connected contact electrodes distributed below an end of the beam).

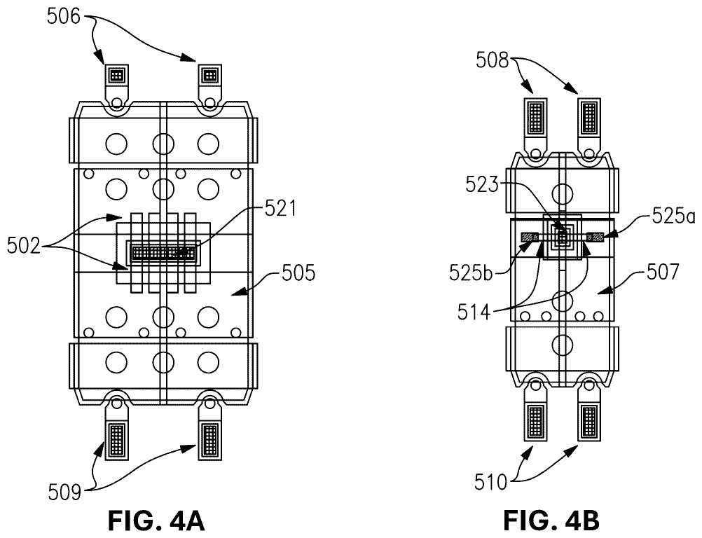

FIG. 4A is a schematic diagram illustrating top-view of a symmetric MEMS teeter-totter switch (similar to MEMS teeter-totter switch 100) comprising a conductive beam 505 connected to a rectangular post 521 by a multi-segment hinge 502 where the post 521 anchors the beam 107 to a substrate, via the multi-segment hinge 502, and serves as a mechanical pivot. In the example shown, the symmetric MEMS teeter-totter switch includes a first pair of contact electrodes 506 below a first longitudinal end (edge) of the beam 505 and a second pair of contact electrodes 509 below a second longitudinal end (edge) of the beam 505.

FIG. 4B is a schematic diagram illustrating top-view of an asymmetric MEMS teeter-totter switch comprising a conductive beam 507 connected to a square shape post 523 by a hinge 514, and two mechanical stoppers 525a, 525b, formed at opposite sides (e.g., opposite lateral sides) of the post 523 under the beam 507. In some cases, the hinge 514 can be a single segment hinge and/or can be thicker than the multi-segment hinge 502 in FIG. 4A. In some cases, the post 523 may have a smaller cross-sectional area compared to the rectangular post 521. In some embodiments, the post 523 may anchor the beam 507 to the substrate and may electrically connect the beam 507 to a middle electrode formed on the substrate (not shown). In some cases, the mechanical stoppers 525a, 525b, under the beam 507 may function as a mechanical pivot when the beam 507 rotates with respect to the post 523. In some such cases, the hinge 514 may stabilize the beam 507 by maintaining lateral and longitudinal positions of the beam 507 with respect to the post 523 as the beam 507 pivots. The asymmetric MEMS teeter-totter switch shown in FIG. 4B may include a first pair of contact electrodes 508 below a first longitudinal end (edge) of the beam 507 and a second pair of contact electrodes 510 below a second longitudinal end (edge) of the beam 507.

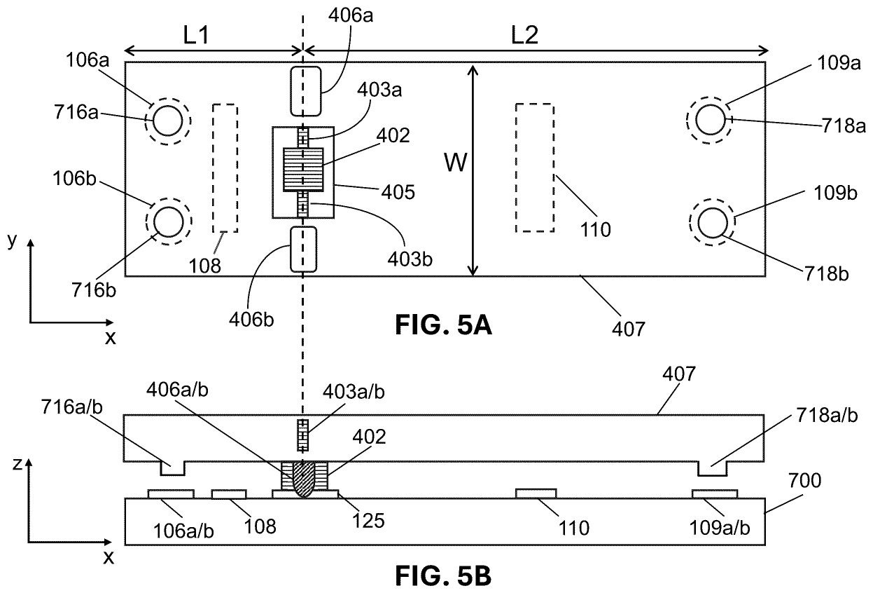

FIGS. 5A-5B are schematic diagrams illustrating a top-view (FIG. 5A) and a side cross-sectional view (FIG. 5B) of an example asymmetric MEMS teeter-totter switch according to some embodiments disclosed herein. In the example shown the teeter-totter switch shown in FIGS. 5A-5B may comprise a rectangular beam 407 mechanically connected to a substrate 700 via two hinges 403a, 403b, and a post (anchor) 402. In some cases, the post 402 may be formed on the substrate 700 and the two hinges 403a, 403b, may connect a region of the beam 407 closer to a first end of the beam 407 to the post 402. In some embodiments, the post 402 may be configured to electrically connect the beam 407 to the middle electrode 125. In some cases, the post 402 may be formed from a conductive material or at least comprise a conductive path extending from the hinges 403a, 403b, to the middle electrode 125 and electrically connection g the middle electrode 125 to the post 402, e.g., via the hinges 403a, 403b. In some examples the post 402 may comprise gold, doped gold, nickel, doped nickel, platinum, ruthenium, or an alloy formed by these materials or other conductive materials.

In some embodiments, the teeter-totter switch shown in FIGS. 5A-5B may comprise two mechanical stoppers 406a, 406b disposed at opposite lateral sides of the post 402 and configured to mechanically support the beam 407, e.g., when it is actuated and rotates with respect to the post 402 and the substrate 700. In some embodiments, the mechanical stoppers may be formed on a bottom surface of the beam 407 (facing the substrate 700) and can be vertically extended toward the substrate 700. In some cases, the stoppers 406, 406b may be configured to provide additional mechanical connection between the beam 407 and the substrate 700, allow the beam 407 to pivot around a contact point between the stopper 504 and the substrate 700, and reduce the mechanical stress on the hinges 403a/b and the post 402 when the teeter-totter switch is actuated. In some examples, bottom surfaces of one or both mechanical stoppers 406a, 406b, may be shaped to allow each mechanical stopper to pivot around a contact point between the mechanical stopper and the substrate 700. For example, the bottom surface of a mechanical stopper may comprise a round shape. In some examples the mechanical stoppers 406a, 406b, may comprise gold, doped gold, nickel, doped nickel, platinum, ruthenium, or an alloy formed by these materials or other conductive materials. In some cases, the hinges 403a, 403b, may be configured to allow the beam 407 tilt with respect to the substrate 700 while maintaining mechanical connection between the beam 407 and the post 402. In some examples, the region of the beam 407 connected to the post 402 may comprise an opening 405 configured to allow rotation of the beam 407 within a specified angular range without touching the post 402. In some embodiments, at least a portion of each of one the beam 407, the post 402, and the hinges 403a, 403b may comprise conductive material and may be configured to provide a conductive path between the end regions of beam 407, above the respective contact electrodes, and a contact electrode 125 formed on the substrate 700. In various implementations, the hinges 403a, 403b may comprise gold, doped gold, nickel, platinum, ruthenium, or other conductive materials. In some cases, the middle electrode 125 may be formed between the post 402 and the substrate 700. In some embodiments, the width (e.g., along x-axis) of the hinges 403a, 403b, can be from 1 to 3 microns, from 3 to 5 microns, from 5 to 10 microns or any ranges formed by these values or larger or smaller values. In some embodiments, the length (e.g., along y-axis) of the hinges 403a, 403b, can be from 1 to 5 microns, from 5 to 10 microns, from 10 to 15 microns, 15 to 20 microns or any ranges formed by these values or larger or smaller values.

In some embodiments, the post 402, the opening 405, and the mechanical stoppers 406a, 406b, can be closer to the first end or edge (e.g., back end) of the beam 407. For example, a longitudinal distance L1 (e.g., along the length of the beam 407) between the post 402 and the back end of the beam 407 can be greater than a longitudinal distance L2 between the post 402 and the front end of the beam 407. In some implementations, a ratio between L2 and L1 (L2/L1) can be larger than 1.05, larger than 1.1, larger than 1.2, larger than 1.3, larger than 1.5, larger than 1.7, larger than 2 or larger values. In some embodiments, L2 can be larger than L1 by at least 3%, at least 5%, at least 7%, at least 10%, at least 15%, or at least 20% of total length of the beam 407 (e.g., L1+L2). In some embodiments, the post 402 can be disposed closer to the first end relative to the second end of the beam 407 by at least 3%, at least 5%, at least 7%, at least 10%, at least 15%, or at least 20% of the length of the conductive beam 407 (e.g., L1+L2).

In various implementations, at least a portion of the beam 407 may comprise a conductive material. In some examples, the beam 407 may comprise a conductive region providing electrical connection between contact tips 716a, 716b, disposed ear the first edge of the beam 407, the hinges 403a, 403b, and thereby the post 402, and the contact tips 718a, 718b, disposed near the second edge of the beam 407. In various implementations, the beam 407 may comprise gold, doped gold, nickel, doped nickel, platinum, ruthenium, or an alloy comprising these materials or other conductive materials.

With continued reference to FIGS. 5A-5B, in some cases, the beam 107 may comprise a first pair of conductive contact tips 716a, 716b near a first end or end region (e.g., back end) of the beam 407 and a second pair of conductive contact tips 718a, 718b near a second end or end region (e.g., front end) of the beam 407 opposite to the first end. In some examples, the beam 107 and the contact tips 716a/716b or 718a/718b may comprise a conductive material. In some cases, the contact tips 716a/716b or 718a/718b, may be electrically connected to the post 402 via a conductive region of the beam 407 and the two hinges 403a, 403b.

In some cases, the first pair of the contact tips 716a/716b may be positioned above a first pair of contact electrodes 106a/106b formed on the substrate 700 and the second pair of the contact tips 718a/718b, may be positioned above a second pair of front contact electrodes 109a/109b to allow electrical contact between the first pair of the contact electrodes 106a/b and the first pair of contact tips 716a/b, or between the second pair of the contact electrodes 109a/b and the second pair of contact tips 718a/b, when the teeter-totter switch is actuated.

In some cases, first (front) and second (back) control electrodes 108, 110 formed on the substrate 700 may be configured to capacitively actuate the teeter-totter switch and pivot the beam 407 around the contact points between the stoppers 406a, 406b, and the substrate 700. In some cases, a bottom surface of the stoppers 406a, 406b, that become in contact with the substrate 700 may comprise a curved surface having a radius of curvature from 0.5 to 1 micron, from 1 to 5 microns, from 5 to 10 microns or any ranges formed by these values or larger or smaller values. In some cases, the width of the stoppers 406a, 406b (e.g., along x-axis) can be from 0.5 to 1 micron, from 1 to 5 microns, from 5 to 10 microns or any ranges formed by these values or larger or smaller values. In some embodiments, e.g., when the teeter-totter switch is configured as a two-port device, e.g., in a circuit breaker, the teeter-totter switch may be deactivated from the OFF state to the ON state by providing a voltage difference between the front control electrode 110 and the beam 407 to pull the front end of the beam 407 toward the substrate 700 to bring the contact tips 718a/718b, into contact with the respective front contact electrodes 109a/109b. In some such embodiments, the teeter-totter switch may be activated from the ON state to the OFF state by providing a voltage difference between the back control electrode 108 and the beam 407 to pull the back end of the beam 407 toward the substrate 700 to bring the contact tips 716a/716b, into contact with the respective back contact electrodes 106a/106b. It should be understood that in the contest of a circuit breaker circuitry activation (e.g., activation of the circuit breaker and the MEMS switch therein) may comprise breaking an electrical connection between two terminals and deactivation (may comprise an electrical connection between two terminals and deactivation may comprise establishing an electrical connection between the two terminals.

In some embodiments, the back contact electrodes 106a/106b may be electrically connected to the middle electrode 125 and the post 402, e.g., via one or more conductive lines formed over or in the substrate 700.

It should be understood that the embodiment shown in FIGS. 5A-5B is a non-limiting example of an asymmetric teeter-totter switch having a stopper and other configurations are possible. For example, the beam 407 may include one or more than two contact tips near each edge (end), number of contact tips near the two edges can be different, the contact tips of a pair of contact tips near the same edge may be positioned at two different distances from the post 402, the opening 405 may have different geometries, more than two hinges may secure the beam 407 to the post 402, multiple posts may be used to anchor the beam 107 to the substrate 700, the stopper 504 may have different geometries; other variations are possible, e.g., thickness of respective layers, shape of stopper, shape of the post, and the like, may vary in different examples.

In some embodiments, the width (W) of a teeter switch (e.g., teeter-totter switch shown in FIG. 5A) can be from 20 microns to 50 microns, from 50 to 70 microns, from 70 to 100 microns, from 100 to 150 microns, from 150 to 200 microns, or a value that is in a range defined by any of these values or larger or smaller. In some embodiments, the length (L=L1+L2) of a teeter switch (e.g., teeter-totter switch shown in FIG. 5A) can be from 30 to 60 microns, from 60 to 100 microns, from 100 to 150 microns, from 150 to 200 microns, from 200 to 250 microns, from 250 to 300 microns, a value that is in a range defined by any of these values or larger or smaller. In some embodiments, the width (e.g., along y-axis) of the opening 405 can be from 10 to 50 microns, from 50 to 100 microns, from 100 to 150 microns, or a value that is defined in a range defined by any of these values or larger or smaller. In some embodiments, the length (e.g., along x-axis) of the opening 405 can be from 10 to 50 microns, from 50 to 100 microns, from 100 to 150 microns, or a value that is in range defined by any of these values or larger or smaller.

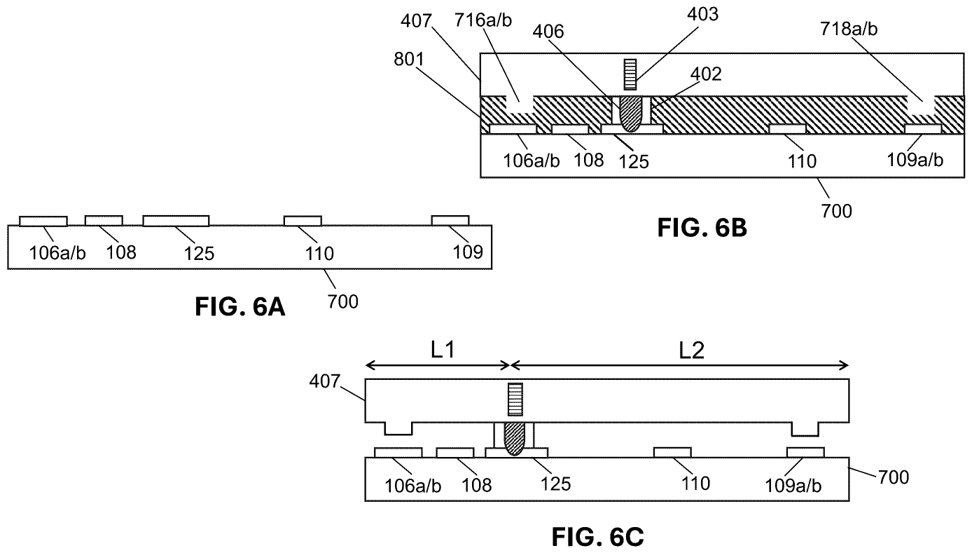

FIGS. 6A-6C illustrate side cross-sectional views of intermediate structures at various stages of fabricating of the asymmetric MEMS teeter-totter switch described above with respect to FIGS. 5A-5B.

Referring to FIG. 6A, the substrate 700 may be provided and back and front contact electrodes 106/a/b, 109a/b, middle electrode 125, and control electrodes 108 and 110, may be formed on a major top surface of the substrate 700, e.g., by forming (e.g., depositing) and patterning a conductive layer over the substrate 700. In some embodiments, the major top surface of the substrate 700 may comprise a layer of silicon dioxide (or another dielectric layer) and the electrodes 106, 109, 125, 108, 110 may be formed on the silicon dioxide layer. In some cases, the conductive layer may comprise a metallic layer and patterning the conductive layer may comprise photolithography patterning of a photoresist layer deposited on the contrive layer and etching the uncovered portions of the conductive layer. In some embodiments, the substrate 700 may comprise silicon, alumina, and/or silicon dioxide, or another other suitable material or combination of materials. In some embodiments, the metallic layer may comprise gold, aluminum, copper, or an alloy comprising these other metals.

Referring to FIG. 6B, a sacrificial layer 801 may be formed on the substrate 700 and the electrodes 106, 108, 125, 110 and 109, thereon and the beam 407 may be formed on the sacrificial layer 801, e.g., by depositing and patterning a structural material (e.g., a metal). In some implementations, the sacrificial layer 801 may comprise silicon dioxide, polymer, and/or a metal. In some examples, the thickness of the sacrificial layer 801 can be from 50 nm to 5 μm. In some cases, the thickness of the sacrificial layer 801 may define the vertical separation between the beam 407 and the top major surface of the substrate 700 when the teeter-totter switch is in the neutral state.

In some cases, the structural material of the beam 407 may comprise a conductive material (e.g., a metal). In some cases, forming the beam 407 may comprise patterning the sacrificial layer such that deposition of a metallic layer (or another structural material) over the patterned sacrificial layer results in formation of at least two conductive contact tips 716a/b, 718a/b, and a stopper 406 under the beam 407. For example, the sacrificial layer 801 may be patterned and/or fully etched to form one or more openings and a metal may be deposited in the openings to form the conductive contact tips 716a/b, 718a/b, the stopper 406 under beam 407. In some examples, the contact tips 716a/b, 718a/b, and the stopper 406 may be connected to the main bottom surface of the beam 407. Additionally, in some implementations, formation of the beam 407 may comprise formation of one or more posts 402 on the substrate 700 and one or more hinges 403 that mechanically connect the beam 407 to the post 402.

In some cases, the sacrificial layer 801 may be fully etched in a region where the post (anchor), which mechanically supports and connects the beam 407 to the substrate 700. In some embodiments, sacrificial layer 801 may be partially etched in regions corresponding to form conductive contact tips 716a/b, 718a/b and the stopper 406.

In some embodiments, the metal may be deposited as a blanket on the sacrificial layer 801, and the conductive contact tips 716a/b, 718a/b, stopper 406, or the post 402 may be formed by etching the metal outside the desired regions.

In some cases, at least the conductive beam 407, the contact tips 716a/b, 718a/b, and the stopper 406 can be different portions of a single structure formed over the sacrificial layer 801. In some embodiments, the two contact tips 716a/b, 718a/b may be formed above the back and front contact electrodes 106, 109, and the post 402, may be formed above the middle electrode 125. In some embodiments, a thin portion of sacrificial layer may exist between the stopper 406 and substrate 700. In some examples, the stopper 406 can be in contact with but not connected to the substrate 700 such that in the absence of the sacrificial layer it can move away from the substrate 700. In some embodiments, the middle electrode 125 may be formed under the post 402, where the post 402 mechanically connects the beam 407 to the substrate 700.

Referring to FIG. 6C, the sacrificial layer 801 may be removed to release the beam 407 and the stopper 406 connected to the beam 407 and to form a large gap between the beam 407 and, in some cases, a small gap between the stopper 504 and the substrate 700. In some embodiments, sacrificial layer 801 may be removed through a wet etch process.

It should be appreciated that FIGS. 6A-6C illustrate an example fabrication sequence for fabricating an asymmetric MEMS teeter-totter switch using a single sacrificial layer and two electroplating steps; however, asymmetric MEMS teeter-totter switches according to at least some aspects of the present application may be fabricated using a different number of sacrificial layers and/or electroplating steps and also combining structures and materials chosen depending on the specific requirements of the application.

### Circuit Breaker Circuitry Including MEMS Switch

In some embodiments, various MEMS switches disclosed herein, including e.g., the symmetric teeter-totter switch 100 (FIG. 1A) or the asymmetric teeter-totter switches 150 (FIG. 1B and FIGS. 2A-2C), 300 (FIGS. 3A-3C) may be used as part of a circuit breaker circuitry to electrically connect or disconnect two terminals thereof. In various implementations, the state of the teeter-totter switch may be controlled by a user or an electronic circuit configured to change the state of the teeter-totter switch from ON state to OFF state upon receiving a sensor signal indicative of a malfunction (e.g., excessive voltage or current) in the circuit.

In some embodiments, two terminals (e.g., input and output terminals) of a circuit (e.g., a circuit breaker circuitry) may be electrically connected to the middle electrode 120, 125 (and thereby to the post 121, 123) and one of the two contact electrodes of a teeter-totter switch (e.g., symmetric teeter-totter switch 100 or the asymmetric teeter-totter switches 150, 300). In some embodiments, a high voltage terminal (e.g., high voltage input terminal) may be electrically connected to the middle electrode 120, 125, and a low voltage terminal (e.g., a low voltage output terminal) may be connected to contact electrode. In some of these embodiments, the middle electrodes 120, 125 may be electrically connected to the other contact electrode of the teeter-totter switch and the teeter-totter switch may be configured as a two-port MEMS switch. Advantageously, in some cases, such teeter-totter switch configured as a two-port MEMS switch may be controlled using smaller actuation voltages, may be used to switch larger voltages, and may be less prone to mechanical failures, compared to a cantilever-based MEMS switch.

As described above, a first contact electrode 106 of the asymmetric teeter-totter switch 150 (or 300), herein referred to as the back contact electrode, can be closer to the post 123, and a second contact electrode 109 of the asymmetric teeter-totter switch 150 (or 300), herein referred to as the front contact electrode, can be farther from the post 123 (compared to the back contact electrode). In some embodiments, when an asymmetric teeter-totter switch is configured as a two-port switch, the middle electrode 125 (and thereby the post 123) can be electrically connected to a high voltage terminal of a circuit (e.g., a circuit breaker circuitry) and the front contact electrode 109 of the asymmetric switch may be electrically connected to a low voltage terminal of the circuit. However, the embodiments are not so limited and in some cases, when the asymmetric teeter-totter switch is configured as a two-port switch, the middle electrode 125 (and thereby the post 123) can be electrically connected to a low voltage terminal of the circuit and the front contact electrode 109 may be electrically connected to a high voltage terminal of the circuit. In some such embodiments, the back contact electrode 106 may be electrically shorted to the middle electrode 125 and the conductive post 123. Advantageously, using the front contact electrode 109 (instead of the back contact electrode 106) and the middle electrode 125 of an asymmetric teeter-totter switch 150 as the port, to control the electrical connection between the two terminals of a circuit, can increase the operating voltage for the teeter-totter switch since in the OFF state the voltage drops over the larger gap (Z2) between the second end 118 of the teeter-totter switch 150, 300 and the front contact electrode 109.

In some embodiments, multiple MEMS teeter-totter switches may be combined to form a MEMS switch network or circuit configured to switch voltages greater than the operating voltages of individual switches. In some implementations, the MEMS switch network or circuit may comprise any MEMS teeter-totter switch disclosed herein, e.g., the MEMS teeter-totter switches 100, 150, or 300. In some examples, a MEMS switch network or circuit may comprise at least one MEMS teeter-totter switch. In some examples, the at least one teeter-totter switch may be configured as a two-port device by electrically connecting its middle electrode 125 to one of its contact electrodes (e.g., the back contact electrode 106 for an asymmetric teeter-totter switch) as described above.

In some embodiments, two MEMS teeter-totter switches (e.g., symmetric or asymmetric teeter-totter switches) may be connected in series to control electric connection between two terminals of an electronic circuit, (e.g., two terminals of a circuit breaker) to increase the upper limit for the voltage difference between the two terminals. For example, when two teeter-totter switches (e.g., two identical teeter-totter switches) each can switch off voltages up to the corresponding operating voltage (Vₘ), they can be combined in series to switch off voltages up to 2Vₘ, where the voltage drop across each teeter-totter switch, does not exceed Vₘ. It will be appreciated that embodiments are not so limited, and in some implementations, the two teeter-totter switches, which are combined in series, may be different (e.g., may have different operating voltages), and/or more than two teeter-totter switches can be connected in series for even higher voltage applications.

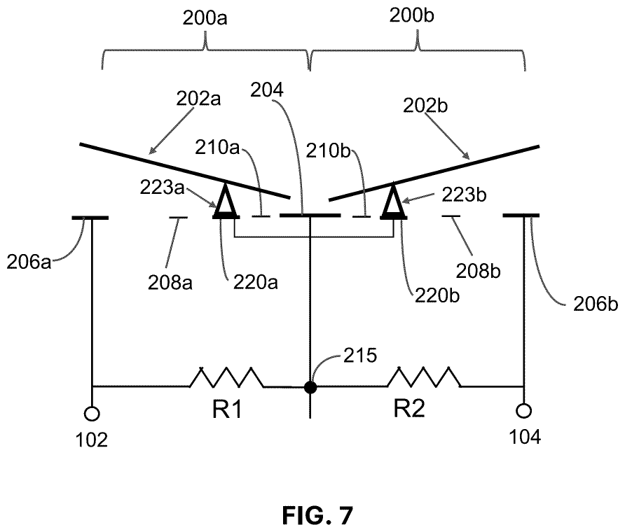

FIG. 7 is a schematic diagram illustrating an example MEMS switch circuit (e.g., a circuit breaker) comprising a MEMS switch network formed by connecting two teeter-totter switches in series. By way of example, in the illustrated embodiment, two asymmetric teeter-totter switches 200a, 200b (e.g., similar to teeter-totter switch 150 in FIG. 1B) are electrically in series between the first and second terminals 102, 104 (e.g., the two terminals of a circuit breaker). However, embodiments are not so limited, and in some implementations, one or both of the two teeter-totter switches may be symmetric teeter-totter switches connected in series. In some cases, the teeter-totter switches 200a, 200b may comprise one or more features described above with respect to the asymmetric teeter-totter switch 150, 300. In some examples, two resistors R1, R2, may be connected in series between the first and second terminals 102, 104, to divide a voltage V₁₂ between the two terminals 102, 104, to a first voltage V_{12,1} between the first terminal 102 and a middle node 215, and a second voltage V_{12,2} between the middle node 215 and the second terminal 104. In some embodiments R1 or R2 can be from 1 to 10 kΩ, 10 to 100 kΩ, 0.1 to 1 MΩ, from 1 to 50 MΩ, from 50 to 100 MΩ, from 100 to 500 MΩ2, from 500 MΩ to 1 GΩ, or have a value that is in any ranges formed by these values or larger or smaller.

In some embodiments, the first asymmetric teeter-totter switch 200a may be configured to electrically connect/disconnect the first terminal 102 and the middle node 215, and the second asymmetric teeter-totter switch 200b may be configured to connect/disconnect the second terminal 104 and the middle node 215. In various implementations, the first and second resistors R1, R2, can be substantially equal or different. Accordingly, the first and second teeter-totter switches 200a, 200b, may have the same or different operating voltages. In one example where R1=R2=R, V_{12,1}=V_{12,2}=V₁₂/2 and, in an OFF state, the voltage drop across each teeter-totter switch can be V₁₂/2.

In some embodiments, the first teeter-totter switch 200a may comprise a first front contact electrode 206a electrically connected to the first terminal 102 and a first post 223a electrically connecting a first conductive beam 202a to a first middle electrode 220a, where the first middle electrode 220a is electrically connected to the middle node 215. In some embodiments, the second teeter-totter switch 200b may comprise a second front contact electrode 206b electrically connected to the second terminal 104 and a second post 223b electrically connecting a second conductive beam 202b to a second middle electrode 220b, where the second middle electrode 220b is electrically connected to the middle node 215. As such, the first and second middle electrodes 220a, 220b, are electrically connected to each other and the middle node 215. In some cases, first and second back contact electrodes of the first and second teeter-totter switches 200a, 200b may be electrically connected to each other and to the middle node 215, and thereby to the first and second middle electrodes 220a, 220b. In some embodiments, the first and second teeter-totter switches 200a, 200b may share a common back contact electrode 204 where the common back contact electrode 204 can be electrically connected to the middle node 215 and the first and second middle electrodes 220a, 220b.

In some embodiments, a first pair of control electrodes 208a, 210a, may be configured to control the first beam 202a of the first teeter-totter switch 200a and thereby change the state of the first teeter-totter switch 200a, and a second pair of control electrodes 208b, 210b, may be configured to control the second first beam 202b of the second teeter-totter switch 200b and thereby change the state of the second teeter-totter switch 200b. In various implementations, the first and second teeter-totter switches 200a, 200b may be controlled by the same or different control signals and resulting actuation voltages.

In some embodiments, the front control electrodes 208a, 208b of the first and second teeter-totter switches 200a, 200b, may be electrically connected and receive a first common actuation voltage, and the back control electrodes 210a, 210b, of the first and second teeter-totter switches 200a, 200b, may be electrically connected and receive a second common actuation voltage. As such, in these embodiments, the first and second teeter-totter switches 200a, 200b, may simultaneously be in ON state or OFF state. In some cases, when both teeter-totter switches 200a, 200b, are in ON state an electrical path may be established between the first terminal 102 and the second terminal 104 through the first beam 202a, first post 223a, first middle electrode 220a, second middle electrode 220b, second post 223b, and the second beam 202b. In some embodiments, when both switches are in OFF state the electrical path between the first terminal 102 can be electrically disconnected from the second terminal 104. In some such cases the OFF state gaps between the first and second front contact electrodes 206a, 206b, and the respective front ends of the first and second beams 202a, 202b may be configured to maintain electric isolation under voltage drops substantially equal to V×R1/(R1+R2) and V×R2/(R1+R2), respectively, where V is the voltage difference between the first and second terminals 102, 104 and thereby between the first and second front contact electrodes 206a, 206b. As such, in some implementations, the L2/L1, L1, L2, L (=L1+L2), and the OFF state gap, can be different for the first and second teeter-totter switches 200a, 200b. Advantageously, by connecting the front contact electrodes 206a, 206b, of the two illustrated asymmetric teeter-totter switches 200a, 200b, to the first and second terminals 102, 104, a larger voltage may be isolated relative to analogous symmetric switches having the same beam length, since a gap (e.g., OFF state gap) formed above a front contact electrode, in the OFF state, is larger relative to that of a gap formed above a front contact electrode of a symmetric teeter-totter switch.

As disclosed herein, in a similar manner as discussed above, a MEMS switch such as an asymmetric teeter-totter switch, in the context of a MEMS switch circuit, may be referred to as being activated when the end of the conductive beam that is farther away from the conductive post is lifted and not in electrical contact with the respective contact electrode. For example, the asymmetric teeter-totter switch 200a, 200b as illustrated in FIG. 7 may be referred to as being in the activated state, with the front contact electrodes 206a, 206b and the second end of the beam 107 farther away from the post 223a, 223b are electrically disconnected from each other. Conversely, a MEMS switch such as an asymmetric teeter-totter switch, in the context of a MEMS switch circuit, may be referred to as being deactivated when the end of the conductive beam that is closer to the conductive post is lifted and not in electrical contact with the respective contact electrode. For example, the asymmetric teeter-totter switch 200a, 200b may be referred to as being in the deactivated state when the back contact electrode 204 and the first end of the beam 107 closer to the post 223a, 223b are electrically disconnected from each other.

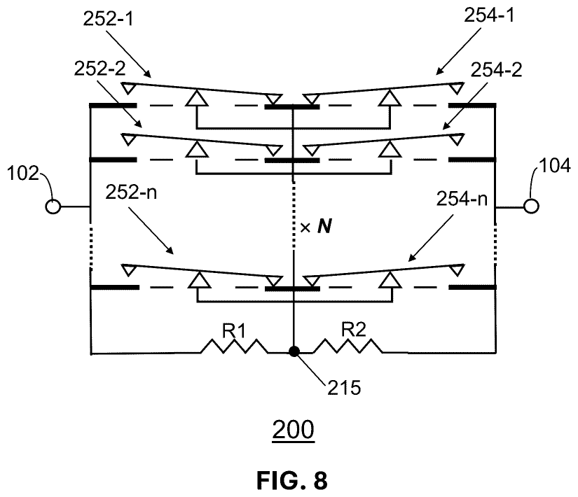

In some embodiments, two or more MEMS switch networks may be connected in parallel such that a larger current can be allowed to flow between the first and second terminals 102, 104. In some examples, at least one of the MEMS switch networks may comprise the configuration shown in FIG. 7. FIG. 8 schematically illustrates an example circuit breaker 200, or a MEMS switch network, comprising a plurality of MEMS teeter-totter switches configured to connect/disconnect the terminals 102, 104 and allow high current and high voltage connection between these terminals. The teeter-totter switches in this circuit breaker 200 may be symmetric or asymmetric as described above. In some cases, the circuit breaker 200 may comprise N pairs of teeter-totter switches connected in parallel, where an individual pair comprises two teeter-totter switches connected in series between the first and second terminals 102, 104 (e.g., the MEMS switch network shown in FIG. 7). Similar to the configuration show in FIG. 7, two resistors, R1, R2, connected in series between the first and second terminals 102, 104, may divide a voltage V₁₂ between the two terminals 102, 104, to a first voltage V_{12,1} between the first terminal 102 and a middle node 215, and a second voltage V_{12,2} between the middle node 215 and the second terminal 104. By way of one example, R1=R2=R, V_{12,1}=V_{12,2}=V₁₂/2 and, in an OFF state, the voltage drop across each teeter-totter switch can be V₁₂/2.

As such, in some cases, the operating voltage of a first teeter-totter switch 252-1, 252-2, . . . 252-n of each pair may be equal of smaller than V_{12,1} and the operating voltage of a second teeter-totter switch 254-1, 254-2, . . . 254-n of each pair may be equal of smaller than V_{12,21}.

In some examples, when the circuit breaker 200 is in an OFF state all teeter-totter switches 252-1, 252-2, . . . 252-n and 254-1, 254-2, . . . 254-n, can be in OFF state and the first terminal 102 can be electrically disconnected from the second terminal 104. In some examples, when the circuit breaker 200 is in an ON state all teeter-totter switches 252-1, 252-2, . . . 252-n and 254-1, 254-2, . . . 254-n, can be in ON state and the first terminal 102 can be electrically connected to the second terminal 104.

In various implementations, the two teeter-totter switches of a pair of switches (e.g., 252-1 and 254-1, 252-2 and 254-2, . . . ) in the circuit breaker 200 can be substantially identical or different. In various implementations, at least one the two teeter-totter switches of a pair of switches (e.g., 252-1 and 254-1, 252-2 and 254-2, . . . ) in the circuit breaker 200 can be an asymmetric teeter-totter switch (e.g., the teeter-totter switch 150 or 300). In various implementations, the at least two pairs of switches in the circuit breaker 200 can be substantially identical.

In some cases, all the teeter-totter switches 252-1, 252-2, . . . 252-n and 254-1, 254-2, . . . 254-n, of the circuit breaker 200 can be substantially identical. In some such cases, an upper limit for the voltage difference between the first and second terminals 102, 104, can be substantially equal to two times the operating voltage of an individual teeter-totter switch and upper limit for the electrical current flowing between the first and second terminals 102, 104, can be substantially equal to N times the operating current of an individual teeter-totter switch, where the operating current of an individual teeter-totter switch is the largest electric current that can pass through a teeter-totter switch in ON state without damaging the beam, post, hinge, the contacting end of the beam, and/or the front contact electrode of the teeter-totter switch.

In some embodiments, when the electric potential of the control electrodes and the middle electrodes of the teeter-totter switch are controlled with respect to a common reference voltage (e.g., a ground potential), the switching voltage (Vₛ) may vary based on a voltage applied between the middle electrode and the respective contact electrode (e.g., the operating voltage, Vₘ, of the teeter-totter switch). For example, when a teeter-totter switch is used to provide an electrical connection between two terminals having a potential difference of Vₘ, Vₛ may be substantially equal to Vₘ+V₀, where V₀ is switching voltage (or actuation voltage) for an isolated teeter-totter switch (e.g., when no voltage is applied between middle electrode and the one of the contact electrodes). As such, when a teeter-totter switch is used for high voltage switching (e.g., when Vₘ is larger than 100, 300, or 500 volts), a large Vₛ may be required to change the state of the teeter-totter switch (from ON to OFF state and vice versa). Moreover, as the voltage applied across the teeter-totter switch varies (e.g., the voltage provided to the first and second terminals 102, 104), the control voltage (e.g., the switching voltage Vₛ) provided to a control electrode to activate or deactivate the teeter-totter switch may vary with the applied voltage (e.g., proportionally).

In various implementations, V₀ can be from 20 to 40 volts, from 40 to 60 volts, from 60 to 80 volts, from 80 to 100 volts, or any ranges formed by these values or larger or smaller.

In various implementations, the number (N) of the pair of MEMS teeter-totter switches connected in parallel can be from 5 to 10, from 10 to 20, from 20 to 30, from 30 to 40, from 40 to 50, from 50 to 60, from 60 to 80, from 80 to 100, or a value in any of the ranges formed by these values or larger or smaller values.

In some cases, an individual MEMS teeter-totter switch (e.g., an asymmetric MEMS teeter-totter switches) may have an operating voltage Vₘ from 20 to 40 volts, from 40 to 60 volts, from 60 to 80 volts, from 80 to 100 volts, from 100 to 150 volts, from 150 volts to 200 volts, or a value in any of the ranges formed by these values or larger or smaller values.

In some cases, an upper limit for electric current passing through an individual MEMS teeter-totter switch can be from 10 to 40 milliamps, from 40 to 60 milliamps, from 60 to 80 milliamps, from 80 to 100 milliamps, from 100 to 150 milliamps, from 150 to 200 milliamps, or a value in any of the ranges formed by these values or larger or smaller values.

In some cases, the characteristics and the number of individual MEMS teeter-totter switches used in the circuit breaker 200 may be selected to allow a voltage difference between the first and second terminals 102, 103, to be greater than 100 volts, 200 volts, 300 volts, 400 volts, 500 volts, or larger values, and the a current passing through the circuit breaker 200 (when all MEMS switches are in ON state) to be greater than 0.5 amps, 1 amps, 2 amps, 3 amps, 4 amps, 5 amps, 8 amps, 10 amps, or larger values.

For example, when Vₘ and the upper current limit for an individual teeter-totter switches of the circuit breaker 200 are 65 milliamp and 200 volts, respectively, and N=60, the circuit breaker 200 may be used to switch voltages up to 400 volts and currents up to 4 amps.

In some embodiments, the circuit breaker 200 may be fabricated on single chip by forming N rows of MEMS switch pairs formed on a common substrate and connecting them using in parallel by two conductive lines formed on the common substrate. In some cases, in order to limit the voltage across each MEMS switch (e.g., each asymmetric MEMS teeter-totter switch) to the respective Vₘ, a grading network, e.g., a potential divider, may be formed on the substrate to divide the voltage applied between the first and second terminals. In other words, the resistors R1 and R2 in FIG. 200 may comprise a grading network (e.g., a plurality of resistors or resistive electric paths configured to distribute the applied voltage according to operating voltages of the individual MEMS switches).

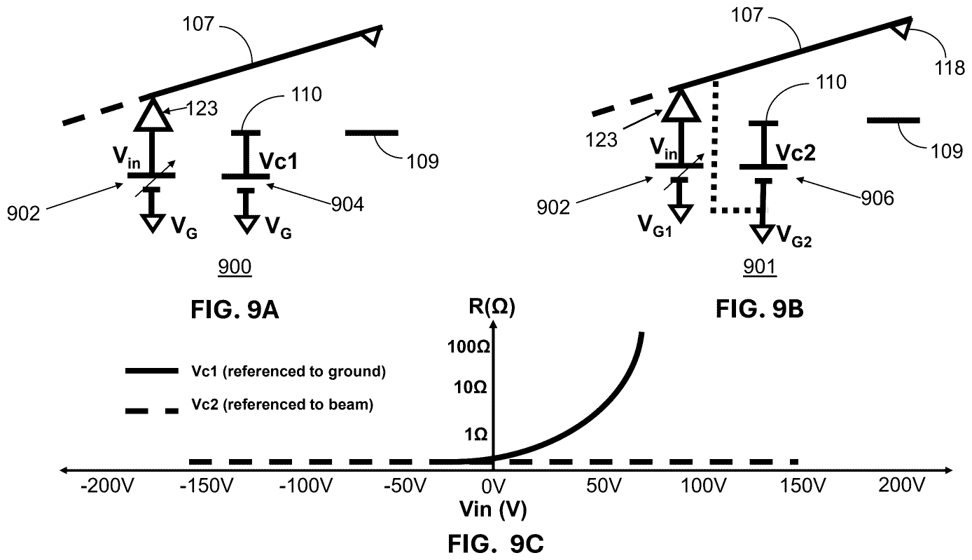

FIG. 9A schematically illustrates a teeter-totter switch 900 configured to electrically connect/disconnect a front contact electrode 109 to/from an input voltage source 902 that is configured to provide a voltage Vᵢₙ with respect to a reference voltage (V_{G}). In some cases, when the teeter-totter switch 900 is in the ON state, a conductive path between the input voltage source 902 and the front contact electrode 109 may be established via the post 123, the beam 107, an electrical connection between the post 123 and the front contact electrode 109. In some embodiments, to change the state of the teeter-totter switch 900 from OFF state to ON state, the front control electrode 110 may be connected to a control voltage source 904 that is configured to provide a first control voltage V_{C1} (e.g., greater than or equal to the switching voltage Vₛ) with respect to the same reference voltage (V_{G}) used by the input voltage source 902. In some such cases, when V_{C1} is constant, the resistance of the conductive path may vary as Vᵢₙ changes (e.g., when Vᵢₙ is time dependent). In some cases, as Vᵢₙ changes (e.g., when Vᵢₙ is time dependent) Vₛ may change as the potential difference between the beam 107 and the control electrode 110 depends on the voltage (e.g., Vᵢₙ) applied to the beam 107. In other words, in the configuration shown in FIG. 9A, Vₛ can be a function of Vᵢₙ. In some examples, such time varying resistance or time varying Vₛ may adversely affect the performance of an electronic circuit (e.g., a circuit breaker) that use the teeter-totter switch for voltage and/or current switching. In various implementations, an input voltage value provided by the input voltage source 902 can be from 10 to 100 volts, from 100 to 300 volts, from 300 to 500 volts, from 500 to 1000 volts, or have a voltage value that is in a range defined by any of these values or larger or smaller. In various implementations, an electric current value provided by the input voltage source 902 can be from 1 to 5 Amps, from 5 to 10 Amps, from 10 to 20 Amps, from 20 to 40 Amps, or have a current value that is in a range defined by any of these values or larger or smaller.

The inventors have discovered that by providing a control voltage with reference to the voltage of the beam (e.g., Vᵢₙ), the switching voltage (V_{S}) may remain substantially independent of the voltage, Vᵢₙ, applied between the terminals of a corresponding electronic circuit (e.g., a breaker circuitry) such that the control voltage can remain unchanged when Vᵢₙ varies.

FIG. 9B schematically illustrates a teeter-totter switch 901 configured to electrically connect/disconnect the front contact electrode 109 to/from an input voltage source 902 that is configured to provide a voltage Vᵢₙ with respect to a first reference voltage (V_{G1}). In some embodiments, to change the state of the teeter-totter switch 901 from OFF state to ON state, the front control electrode 110 may be connected to a control voltage source 906 configured to provide a second control voltage V_{C2} with respect to a second reference voltage (V_{G2}). In some cases, V_{G2} can be a voltage provided (e.g., Vᵢₙ) to the beam 107. For example, V_{G2} can be substantially equal to Vᵢₙ−V_{G1} and the control voltage source 906 may actuate the teeter-totter switch from the OFF state to ON state by providing V_{C2}=V_{S}=V₀ (where V₀ is the switching or actuation voltage for the isolated teeter-totter switch), substantially independent of Vᵢₙ. In some embodiments, the control voltage source 906 may comprise an electronic circuit configured to receive a control signal from a control circuit and provide the second control voltage V_{C2} substantially equal to Vₛ to the front control electrode 110. As described above, V_{S} can be a voltage that applies sufficient force between the second end 118 of the beam 107 to establish an electric contact between the front contact electrode 109 and the second end 118, having an electric resistance lower than a threshold value.

FIG. 9C is a plot schematically illustrating the resistance of a conductive path established between the post 123 and the front contact electrode 109 by the teeter-totter switch 900 (solid line) and the teeter-totter switch 901 (dashed line), as a function of the volage (Vᵢₙ) provided to the beam 107 for a constant V_{C1}=V_{C2}=V_{C} provided by voltage sources 902, 904 to teeter-totter switches 900, and 901, respectively. In some cases, when Vᵢₙ is near zero, a voltage difference between the beam 107 and the front control electrode 110 can be substantially equal to Vₛ for both teeter-totter switches 900, 901, resulting in a conductive path between the front contact electrode 109 and the post 123 having a sufficiently low resistance (e.g., less than 5 oms). In some cases, when Vᵢₙ increases, the voltage difference between the beam 107 and the front control electrode 110 of the teeter-totter switch 900 may decrease below Vₛ (since V_{C1} and Vᵢₙ are applied with respect to a common reference V_{G}) while the voltage difference between the beam 107 and the front control electrode 110 of the teeter-totter switch 901 may remain substantially equal to V_{S} (since V_{C2} and Vᵢₙ are applied with respect to different reference voltages V_{G1} and V_{G2}). In some cases, a resistance of the electrical connection between the second end 118 of the beam 107 the front contact electrode 109 can be proportional to the electrostatic force applied on the beam 107 and the electrostatic force applied on the beam 107 can be proportional to the square of the voltage difference between the beam 107 and the control electrode 110. As such, when Vᵢₙ increases, the resistance of the conductive path established between the front contact electrode 109 and the post 123 may increase above the desired value for the teeter-totter switch 900 (solid line in FIG. 9C) and stay constant for the teeter-totter switch 901 (dashed line in FIG. 9C).

Advantageously, the actuation configuration of the teeter-totter switch 901 may keep Vₛ substantially constant (e.g., close or equal to V₀) and may allow maintaining the resistance of conductive path between the post 123 and the front contact electrode 109, when the switch is in ON state, below a threshold value using a constant V_{C} close or substantially equal to V_{S}, substantially independent of magnitude and/or temporal variation of Vᵢₙ.

In should be understood that the electrical actuation configuration shown in FIG. 9B, which makes the switching voltage V_{S} applied provided to a control electrode substantially independent from Vᵢₙ, may be used for actuating both symmetric and asymmetric MEMS teeter-totter switches, and cantilever-based MEMS switches.

Circuit Breaker Circuitry with Isolation Circuit

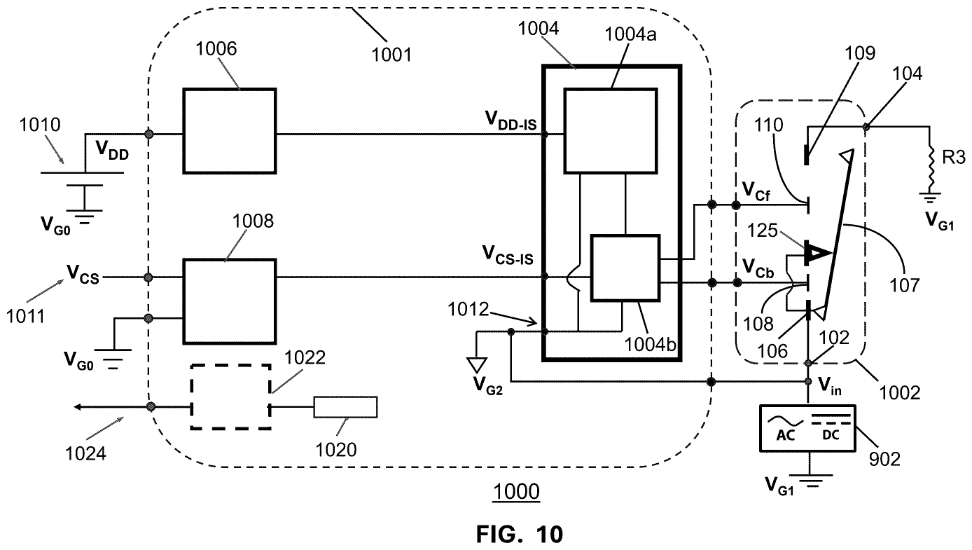

FIG. 10 schematically illustrates an example switching circuit 1000 (e.g., circuit breaker circuitry) comprising a MEMS switch 1002 and a control circuit 1001 configured to control the state of the MEMS switch 1002 based on a control signal 1011 and an input voltage Vᵢₙ provided to the MEMS switch 1002 by an input voltage source 902, according to the electrical configuration described above with respect to FIG. 9B. In some embodiments, the magnitude of the control voltage V_{C} provided to the MEMS switch 1002 can be substantially independent of Vᵢₙ. In some cases, control signal 1011 may comprise digital control data. In some examples, the control signal 1011 may comprise a deactivation signal indicative of ON state or an activation signal indicative of OFF state.

In various implementations, the MEMS switch 1002 may comprise a teeter-totter switch (e.g., the teeter-totter switch 100, 150, or 300) or a cantilever-based switch.

In the illustrated example, the MEMS switch 1002 comprises, without limitation, an asymmetric switch having a back contact electrode 106 electrically connected a first terminal 102 (e.g., an input terminal), a front contact electrode 110 electrically connected to a second terminal 104 (e.g., an output terminal), a middle electrode 125 electrically connected to the back contact electrode 106, and a beam 107, where the beam 107 is electrically connected to the middle electrode 125 by a conductive post that anchors the beam 107 to a substrate, as described herein. In some embodiments, the first terminal 102 may be electrically connected to an input voltage source 902 that provides an input voltage Vᵢₙ to the first terminal 102 with respect to a first reference voltage (V_{G1}), e.g., ground potential, and the second terminal 104 may be electrically connected the first reference voltage (or another reference voltage) via a resistor R3.

In some implementations, the teeter-totter switch 1002 may comprise a front control electrode 110 and a back control electrode 106 configured to control the position of the beam 107 (and thereby the state of the MEMS switch 1002) upon receiving front and back control voltages V_{Cf} and V_{Cb} from the control circuit 1001. In some examples, the control circuit 1001 may be configured to receive Vᵢₙ from the input voltage source 902, receive a control signal 1011 from an electronic circuit, and an actuation voltage V_{DD} from an actuation voltage source, and generate the front and back control voltages V_{Cf}, V_{Cb} using V_{DD}, and based on the control signal 1011 and Vᵢₙ. In some cases, the control circuit 1001 may generate an deactivation voltage for deactivating the MEMS switch 1002 from OFF state to ON state, or an activation voltage for activating the MEMS switch 1002 from ON state to OFF state. In some cases, activation and deactivation voltages may be collectively referred to as actuation voltages. In some examples, a deactivation voltage may comprise providing at least a front control voltage configured to electromechanically couple to the beam 107 to the front contact electrode 109 and decouple it from the back contact electrode 106. In some examples, an activation voltage may comprise providing front and back control voltages configured to electromechanically couple to the beam 107 to the back contact electrode 106 and decouple it from the front contact electrode 109. In some cases, a deactivation voltage may comprise a voltage provided to the front control electrode 110 and the activation voltage may comprise a voltage provided to the back control electrode 108.

In some cases, the control circuit 1001 may amplify V_{DD} (e.g., using a DC-to-DC converter) to the switching voltage V_{S} of the teeter-totter switch 1002 with respect to Vᵢₙ, and in response to receiving a control signal 1011 indicative of an ON state (or OFF state), generate V_{Cf} (or V_{Cb}) with a magnitude substantially equal to V_{S}+Vᵢₙ. In such cases, the control circuit 1001 may comprise at least a first isolator 1006 that electrically isolates V_{DD} provided by the actuation voltage source 1010 with respect to an initial reference signal V_{G0} from the electronic circuitry (e.g., a voltage converter) of control circuit 1001. In some examples, the isolator 1006 may allow amplifying V_{DD} to a fixed voltage (e.g., V_{S}) with respect to Vᵢₙ. In some embodiments, the control circuit 1001 may comprise a second isolator 1008 that electrically isolates the control signal 1011 from the electronic circuitry (e.g., a driver circuit) of the control circuit 1001. Advantageously, by isolating the voltage amplification and control circuitry from the actuation voltage source 1010 and a source of the control signal 1011, the control circuit 1001 can effectively bootstrap V_{Cf} and V_{Cb} to Vᵢₙ such that the voltage of the respective control electrode (e.g., the front control electrode 110 in ON state the back control electrode 108 in OFF state), is greater than a voltage applied on the beam 107 by Vₛ.

In some embodiments, the control circuit 1001 may comprise a actuation and control circuit 1004 and the first and second isolators 1006, 1008. In some embodiments, the actuation and control circuit 1004 may comprise a DC-to-DC converter 1004a and a driver 1004b. In some cases, the first isolator 1006 may be configured to receive the actuation voltage V_{DD} from the actuation source 1010 and provide an isolated actuation voltage V_{DD-IS} to the DC-to-DC converter 1004a. In some cases, the second isolator 1008 may be configured to receive the control signal 1011 comprising a control signal voltage V_{CS} and provide an isolated control signal voltage V_{CS-IS} to the driver 1004b. In some implementations, the DC-to-DC converter 1004a and the driver 1004b may be configured to receive the input voltage Vᵢₙ from the input voltage source 902 and use Vᵢₙ as an operating reference voltage provided to a reference voltage port/terminal 1012 of the actuation and control circuit 1004. In some cases, a voltage connected to the port/terminal 1012 may be referred to as the second reference voltage V_{G2}, with respect to which the DC-to-DC converter 1004a and the driver 1004b may operate. In some embodiments, the DC-to-DC converter 1004a may be configured to amplify the isolated actuation voltage V_{DD-IS} by a voltage amplification factor M to generate a control voltage substantially equal to M×V_{DD-IS} with respect to V_{G2} (=Vᵢₙ) and thereby substantially equal to M×V_{DD-IS}+Vᵢₙ with respect to V_{G1}. In some embodiments, M×V_{DD-IS} can be substantially equal to or greater than Vₛ=V₀. In some embodiments, the driver 1004b may be configured receive the amplified voltage from the DC-to-DC converter 1004a and provide the front control voltage V_{Cf} to the front control electrode 110 or to the back control electrode 108, based on the isolated control signal voltage V_{CS-IS} received from the second isolator 1008. For example, when V_{CS-IS} is indicative of an OFF state, the driver 1004b may provide the amplified voltage as V_{Cb} (=M×V_{DD-IS}+Vᵢₙ) to the back control electrode 108 to electrically disconnect the beam 107 from the front contact electrode 109. Analogously, when V_{CS-IS} is indicative of an ON state the driver 1004b may provide the amplified voltage as V_{Cf} (=M×V_{DD-IS}+Vᵢₙ) to the front control electrode 110 to electrically connect the beam 107 to the front contact electrode 109. In some embodiments, when V_{CS-IS} is indicative of OFF state, V_{Cf} can be substantially equal to Vᵢₙ with respect to V_{G1} (or zero with respect to V_{G2}) and when V_{CS-IS} is indicative of ON state, V_{Cb} can be substantially equal to Vᵢₙ with respect to V_{G1} (or zero with respect to V_{G2}). As such, using the first and second isolators 1006, 1008, and by setting the second reference voltage V_{G2} to Vᵢₙ, the control circuit 1001 can bootstrap V_{Cf}, V_{Cb}, to Vᵢₙ and control them based on V_{CS}.

In some embodiments, in addition to the first and second isolators 1006, 1008, the control circuit 1001 may comprise a third isolator 1022 configured to receive a sensor signal from a sensor 1020 and output an isolated sensor signal 1024. In some implementations, the sensor 1020 may comprise a temperature sensor, a current sensor, or other types of sensors that may generate sensor signals indicative of an operating condition or parameter of the teeter-totter switch 1002 or the electric circuitry (e.g., a circuit breaker) controlled by the teeter-totter switch 1002. In some cases, the isolated sensor signals 1024 output by the control circuit 1001, may be used by signal processing circuit to control the control signal 1011 and/or the actuation voltage source 1010. In some embodiments, the control circuit 1001 may comprise a readout circuit (not shown) configured to receive sensor signals from the senor 1020 and provide processed sensor signals to the third isolator 1022. In some examples, the sensor signal may comprise an analog signal, the readout circuit may comprise an analog-to-digital converter (ADC), and the processed sensor signal may comprise a digital signal.

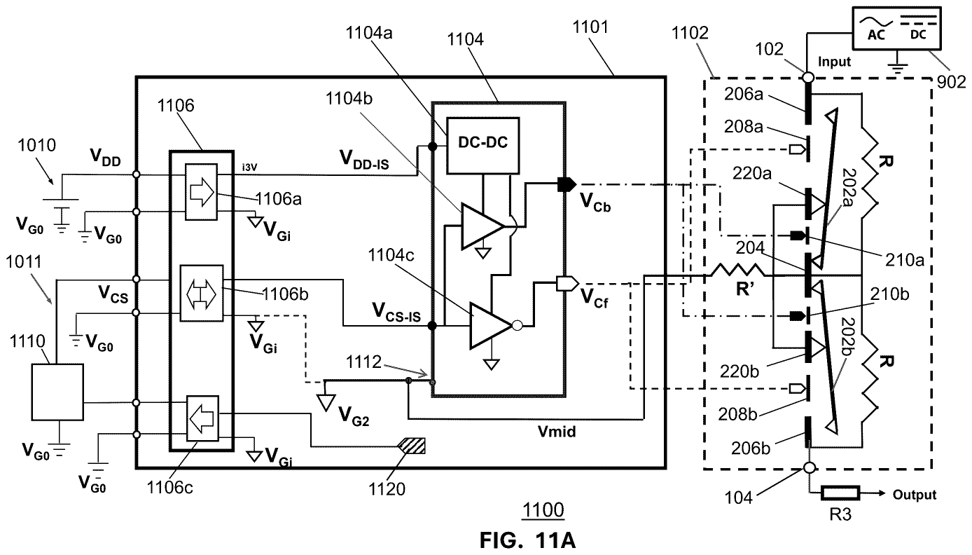

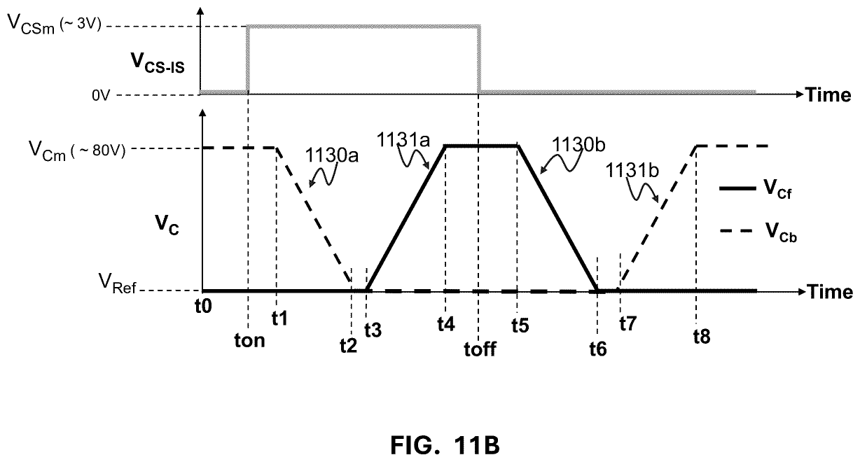

FIG. 11A schematically illustrates another example switching circuit 1100 (e.g., a circuit breaker circuitry) comprising a control circuit 1101 and a MEMS switch network 1102 comprising two or more MEMS switches. In various implementations, the MEMS switch network 1102 may comprise any one of the teeter-totter switch 100, 150, 300, a cantilever-based switch, or combination thereof. For illustrative purposes, the MEMS switch network 1102 includes two teeter-totter switches (e.g., each similar to the teeter-totter switch 100, 150, or 300) connected in series between the input and output terminals 102, 104 of an electronic circuit (e.g., an electronic circuit protected/controlled by switching circuit 1100 formed by the control circuit 1101 and the MEM switch network 1102). In some embodiments, the MEMS switch network 1102 may comprise one or more features described above with respect to MEMS switch circuit shown in FIG. 7. In some embodiments, the control circuit 1101 may comprise one or more features analogous to those described above with respect to control circuit 1001 (FIG. 10), the details of which may not be repeated herein for brevity.

In some embodiments, the control circuit 1101 may be configured to provide a front control voltage V_{Cf} to the first and second front control electrodes 208a, 208b of the first and second teeter-totter switches of the switch network 1102, and a back control voltage V_{Cb} to the first and second back control electrodes 210a, 210b of the first and second teeter-totter switches of the switch network 1102. In some embodiments, the control circuit 1101 may be configured to receive a midpoint voltage V_{mid} from a common back contact electrode 204 shared between the two teeter-totter switches of the MEMS switch network 1102. In some embodiments, the input terminal 102 may be connected to the input voltage source 902, and the output terminal 104 may be connected to a first reference voltage V_{G1}, e.g., a ground voltage, via a resistor R3. In some embodiments, the first front contact electrode 206a of the first teeter-totter switch may be connected to the input terminal 102, the second front contact electrode 206b of the second teeter-totter switch may be connected to the output terminal 104, and the two teeter-totter switches may share the common back contact electrode 204. In some examples, a first resistor may be connected in parallel with the first teeter-totter switch between the first front contact electrode 206a and the common back contact electrode 204 and a second resistor may be connected in parallel with the second teeter-totter switch between the common back contact electrode 204 and the second front contact electrode 206b. In some implementations, the first and second resistors may have substantially equal resistances and thereby equally dividing the input voltage Vᵢₙ between the first and second teeter-totter switches. In some such implementations, the midpoint voltage V_{mid} of the common back contact electrode 204 can be substantially equal to (Vᵢₙ−V_{G1})/2. In some embodiments, the common back contact electrode 204 and first and second middle electrodes 220a, 220b, of the first and second teeter-totter switches can be electrically connected (e.g., shorted). In some embodiments, the first and second resistors may be different and the midpoint voltage V_{mid} of the common back contact electrode 204 can be different from (Vᵢₙ−V_{G1})/2. In some embodiments, the MEMS switches of the MEMS switch network 1102 can be different (e.g., have different switching voltages, different OFF state gaps, operating voltages and the like).

In some embodiments, the control circuit 1101 may comprise an isolator circuit 1106 and an actuation and control circuit 1104, where isolator circuit 1106 is configured to receive one or more voltages from external circuits and provide isolated voltages to the actuation and control circuit 1104. In some embodiments, the actuation and control circuit 1104 may be configured to receive the midpoint voltage V_{mid} from the common back contact electrode 204 and generate the front and back control voltages V_{Cf}, V_{Cb} using V_{mid} and the isolated voltage received from the isolator circuit 1106, such that V_{Cf}, V_{Cb} are generated with respect to V_{mid} and thereby with respect to the voltage of the beams of the first and second teeter-totter switches that are connected to the respective first and second middle electrodes 220a, 220b.

In some embodiments, the isolator circuit 1106 may comprise a first isolator 1106a configured to receive an actuation voltage V_{DD} from the actuation source 1010 with respect to an initial reference signal V_{G0} and provide an isolated actuation voltage V_{DD-IS} and an isolated reference signal V_{G-IS} with respect to an isolated reference voltage V_{G-IS} to a DC-to-DC converter 1104a of the actuation and control circuit 1104. In some embodiments, the control circuit 1104 may be configured to use the isolated actuation voltage V_{DD-IS} to provide activation or deactivation voltages to the control electrodes of the MEMS switch network 1102 to electrically connect to disconnect the input and the output terminals 102, 104.

In some embodiments, the isolator circuit 1106 may comprise a second isolator 1106b configured to receive a control signal 1011 from a microcontroller 1110 and provide an isolated control signal voltage V_{CS-IS} with respect to an isolated reference voltage V_{G-IS} to first and second drivers 1104b, 1104c, of the actuation and control circuit 1104.

In some embodiments, the DC-to-DC converter 1104a, the first driver 1104b, and the second driver 1104c may be configured to use V_{DD-IS} and V_{CS-IS} to generate V_{Cf} and V_{Cb} with respect to V_{mid} that may be provided to the actuation and control circuit 1104 as the reference operating voltage, e.g., by electrically connecting the common back contact electrode 204 to a reference voltage port/terminal 1112 of the actuation and control circuit 1104.

In some embodiments, the DC-to-DC converter 1104a may be configured to amplify the isolated control voltage V_{DD-IS} by a voltage amplification factor M to generate a control voltage substantially equal to M×V_{DD-IS} with respect to V_{G2} (=Vᵢₙ) (or equal to M×V_{DD-IS}+Vᵢₙ with respect to V_{G1}), where M×V_{DD-IS} can be substantially equal to V₀. In some embodiments, the first and second drivers 1104b, 1104c may be configured receive the amplified voltage from the DC-to-DC converter 1104a and provide the control voltage V_{Cf} to the first and second front control electrodes 208a, 208b, or the control voltage V_{Cb} to the first and second back control electrodes 210a, 210b, based on the isolated control signal voltage V_{CS-IS} received from the second isolator 1106b. For example, when V_{CS-IS} is indicative of an OFF state the first driver 1104b may provide the amplified voltage as V_{Cb} (=M×V_{DD-IS}+Vᵢₙ) to the back control electrode first and second back control electrodes 210a, 210b to electrically disconnect the respective beams from the first and second front contact electrodes 206a, 206b. Analogously, when V_{CS-IS} is indicative of an ON state the second driver 1104c may provide the amplified voltage as V_{Cf} (=M×V_{DD-IS}+Vᵢₙ) to the first and second front control electrodes 208a, 208b to electrically connect the respective beam to the first and second front contact electrodes 206a, 206b.

In some embodiments, in addition to the first and second isolators 1106a, 1106b, the control circuit 1101 may comprise a third isolator 1106c configured to receive a sensor signal from a sensor 1120 and output an isolated sensor signal. In some implementations, the sensor 1120 may comprise a temperature sensor, a current sensor, or other types of sensors that may generate sensor signals indicative of an operating condition of the teeter-totter switch network 1102. In some cases, the isolated sensor signals output by the control circuit 1101 may be used by the microcontroller 1110 to control the control signal 1011 and/or the actuation voltage source 1010. Additionally, or alternatively, the third isolator 1106c may be configured to receive a data signal (e.g., from the microcontroller 1110 and provide an isolated data signal to one or the sensor, the control circuit 1104, or to another circuit that is directly or indirectly connected to MEMS switch network.

In various implementations, the first, second, and third isolators 1006, 1008, 1022 of the switching circuit 1000 (FIG. 10), or the first, second, and third isolators 1106a, 1106b, 1106c of the switching circuit 1100 (FIG. 11), may comprise galvanic isolators (e.g., capacitive, inductive, radiative, optical, acoustic). In some cases, at least one of the first, second, and third isolators 1006, 1008, 1022 (FIG. 10) or the first, second, and third isolators 1106a, 1106b, 1106c may comprise a transformer (e.g., an inductive isolator comprising magnetically coupled coils). In some examples, the transformer may comprise an integrated circuit comprising two coils (e.g., spiral coils) formed (e.g., monolithically formed) on opposite sides of a core layer through which the two coils are magnetically coupled. In some examples, the transformer may comprise an integrated circuit comprising laterally isolated primary and secondary coils wound around a winding axis parallel to a main surface of a core layer formed over substrate. In some cases, at least one of the first, second, and third isolators 1006, 1008, 1022 (FIG. 10) or the first, second, and third isolators 1106a, 1106b, 1106c may not comprise a transformer. In some such cases, one of the isolators may comprise a coupler (isolation) circuit configured to provide a two-way isolated electrical connection.

FIG. 11B schematically illustrates temporal variation of example control signal voltage (e.g., isolated control signal voltage V_{CS-IS}) and the front and back control voltages V_{Cf} and V_{Cb} provided to the teeter-totter switch or teeter-totter switch network shown in FIG. 10 and FIG. 11A depicting the temporal alignment between V_{CS-IS} and V_{Cf} and V_{Cb}. In some embodiments, at time to, V_{CS-IS} can be zero or near zero (e.g., a logic level of 0), V_{Cf} can be close or substantially equal to Vᵢₙ (or V_{mid}), V_{Cb} can be close or substantially equal to Vᵢₙ+V₀ (or V_{mid}+V₀), and the teeter-totter switch (or switch network) can be in the OFF state. At time tₒₙ, V_{CS-IS} transitions to maximum value V_{CSm} (e.g., logic level of 1) and triggers the control circuits 1004 (or 1104) to generate front and back control voltages V_{Cf} and V_{Cb} for changing the state of the teeter-totter switch (or switch network) from the OFF state to the ON state. In some embodiments, to change the state of the teeter-totter switch (or switch network) from the OFF state to the ON state, the control circuits 1004 (or 1104) may decrease V_{Cb} and increase V_{Cf} to disconnect the beam 107 (or beams 202a, 202b) from the back contact pad (or contact pads) and connect it to the back contact pad (front contact pads). In some such embodiment, in order to change the state of the teeter-totter switch (or switch network) between the ON and OFF states, V_{Cb} and V_{Cf} may be changed in opposite directions with the same slope (or two different slopes). Further, in some cases, V_{Cb} or V_{C} may not be increased from V_{Ref} (e.g., Vᵢₙ or V_{mid}), until the other one of V_{Cb} and V_{Cf} is decreased to V_{Ref}.

In the example shown in FIG. 11B, to activate (transition to ON state) the teeter-totter switch (or switch network) in response to the transition of V_{CS-IS}, at a time t1 (that can be delayed with respect to tₒₙ) V_{Cb} is decreased with a slope 1130a until reaches (or close to) V_{Ref} at time t2 and at time t3 (that may be delayed with respect to t2) V_{Cf} is increased with a slope 1131a until it reaches (or close to) V_{Cm}=V_{Ref}+V₀ at time t4. Similarly, as shown in FIG. 11B, to activate (transition to ON state) the teeter-totter switch (or switch network) in response to the transition of V_{CS-IS} from V_{CSm} to zero (or near zero) at time t_{off}, at a time t5 (that can be delayed with respect to t_{off}) V_{Cf} is decreased from V_{Cm} with a slope 1130b until reaches (or close to) V_{Ref} at time t6 and at time t7 (that may be delayed with respect to t6) V_{Cb} is increased from V_{Ref} with a slope 1131b until it reaches (or close to) V_{Cm}=V_{Ref}+V₀ at time t8. In some embodiments, the slopes 1130a, 1131a, 1130b, and 1131b can be substantially equal. In some embodiments, the difference between t2 and t1, t4 and t3, t6 and t5, and/or t8 and t7 can be from 10 to 30 microseconds, from 30 to 50 microseconds, from 50 to 80 microseconds, from 80 to 100 microseconds, or any ranges formed by these values or larger or smaller values. In some examples, V_{CSm} can be substantially equal to 3 volts. In some examples, V₀ (=V_{Cm}−V_{Ref}) can be substantially equal to 80 volts.

In some examples, when the teeter-totter switch is activated from the OFF state to the ON state a current flow through the teeter-totter switch may decrease over a time period from 0.1 to 1 microseconds, from 1 to 10 microseconds, from 10 to 20 microseconds, from 20 to 30 microseconds, from 30 to 40 microseconds, from 40 to 50 microseconds, from 50 to 60 microseconds, from 60 to 80 microseconds or any ranges formed by these values, ore larger or smaller values.

In some examples, when the teeter-totter switch is deactivated from the ON state to the OFF state a current flow through the teeter-totter switch may increase over a time period from 1 to 5 microseconds, from 5 to 10 microseconds, from 10 to 30 microseconds, from 30 to 50 microseconds, from 50 to 70 microseconds, from 70 to 90 microseconds, from 90 to 100 microseconds, from 100 to 150 microseconds, from 150 to 200 microseconds or any ranges formed by these values, ore larger or smaller values.

In various implementations, the first, second, and third isolators 1006, 1008, 1022 of the switching circuit 1000 (FIG. 10), or the first, second, and third isolators 1106a, 1106b, 1106c of the switching circuit 1100 (FIG. 11), may be comprise magnetic isolators or other types of isolators. In some cases, a magnetic isolator may comprise two magnetically coupled coils, and in some cases, an electronic circuit configured to convert DC voltage to an AC voltage and/or AC voltage to an DC voltage, regulate the output voltage). In some embodiments, the first, second, and third isolators 1006, 1008, 1022 of the switching circuit 1000 (FIG. 10), or the first, second, and third isolators 1106a, 1106b, 1106c of the switching circuit 1100 (FIG. 11), may include other types of isolators such as E-field based isolators such as capacitive isolators including discreet DC high voltage capacitors.

In various implementations, the first, second, and third isolators 1006, 1008, 1022 of the switching circuit 1000 (FIG. 10), or the first, second, and third isolators 1106a, 1106b, 1106c of the switching circuit 1100 (FIG. 11), may be fabricated on separate substrates. In some examples, at least two isolators of the first, second, and third isolators 1006, 1008, 1022 of the switching circuit 1000 (FIG. 10), or the first, second, and third isolators 1106a, 1106b, 1106c of the switching circuit 1100 (FIG. 11), may fabricated on a common substrate.

In some embodiments, the isolator circuit 1106 may comprise an integrated circuit enclosed in a single package.

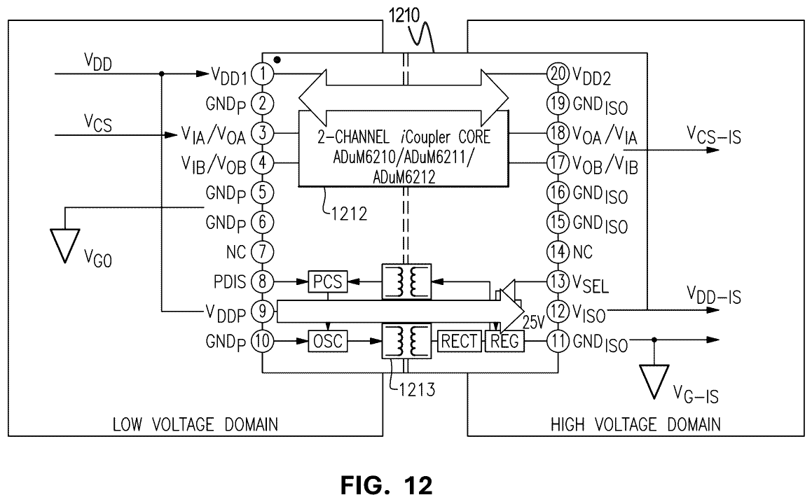

FIG. 12 schematically illustrates the internal circuitry of the integrated isolator circuit 1210 comprising a coupler (isolation) circuit 1212 configured to provide a two-way isolated electrical connection for transmitting control signals Ves and a transformer 1213 and corresponding circuitry (described above) configured to receive the actuation voltage V_{DD} and the initial reference voltage V_{G0} and to generate the isolated actuation voltage V_{DD-IS} and the isolated reference voltage V_{G-IS}. In some examples, the coupler (isolation) circuit 1212 may be configured for isolated signalling and may comprise a signal conditioning circuitry. In some examples, the transformer 1213 may comprise a power transformer that uses a voltage regulation circuitry combined with a transformer.

In some embodiments, the isolator circuit 1106 may comprise one or more optical isolators configured to generate isolated control, actuation, and reference voltages by converting input voltages to optical beams and detecting the optical beams to generate the isolated voltages.

Circuit Breaker Circuitry with Optical Isolation

In some implementations, one or more of the first, second, and third isolators 1006, 1008, 1022 of the control circuit 1000 (FIG. 10), or one or more of the first, second, and third isolators 1106a, 1106b, 1106c of the control circuit 1101 (FIG. 11), may comprise an optical isolator.

In some embodiments, the optical isolator may comprise at least one optical source or photon generation source (e.g., a semiconductor optical source such as a light emitting or laser diode) optically coupled to at least one opto-sensitive or photon detection device (e.g., a semiconductor photoconductive or photovoltaic device). In some cases, the optical source may be configured to receive an input voltage or signal (e.g., V_{DD} or V_{CS}) and generate a light beam having optical power or intensity proportional to the magnitude of the input voltage or signal. As such, the optical isolator may electrically isolate external circuits and devices that generate or provide control signals and actuation voltages for a control circuit of a MEMS switch from the internal circuitry of the control circuit. Similar to transformer-based (magnetic) isolation described above, optical isolation may allow the control voltages provided to the control electrode of a MEMS switch (e.g., a teeter-totter switch) to be referenced to the input voltage switched by the MEMS switch.

Advantageously, replacing one or more magnetic isolators (transformers) of a control circuit with optical isolators may allow reducing the cost and size of the control circuit. Since an optical isolator can be smaller than a transformer, in some cases a large number of optical isolators may be integrated on a single chip to provide optical isolation for multiple control circuits, or for a multichannel control circuit that controls multiple MEMS switches.

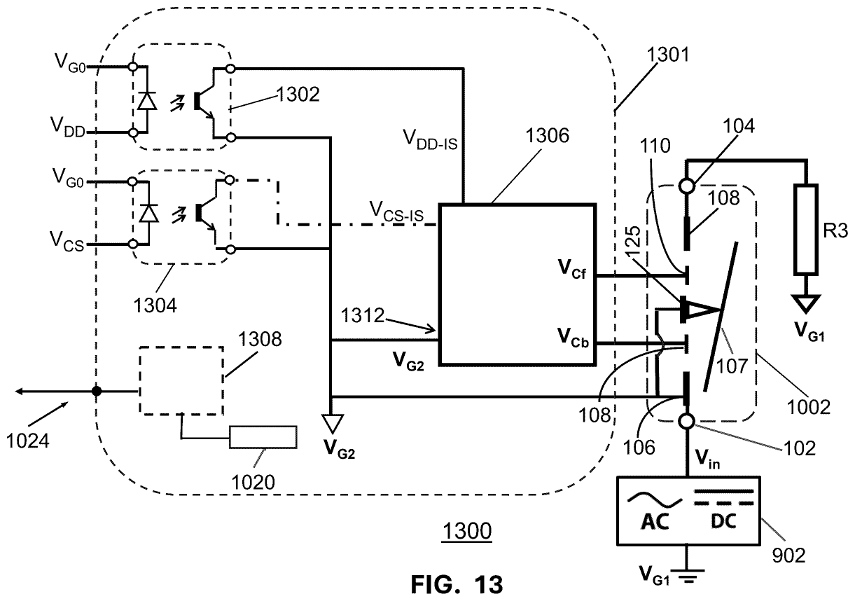

FIG. 13 schematically illustrates an example switching circuit 1300 (e.g., circuit breaker circuitry) comprising a MEMS switch 1002 and a control circuit 1301 configured to control the state of the MEMS switch 1002 based on a control signal voltage V_{CS} and an input voltage Vᵢₙ provided to the MEMS switch 1002 by an input voltage source 902, e.g., analogous the electrical configuration described above with respect to FIG. 9B. The control circuit 1301 may include some features that may have been described above with respect to the control circuit 1001 (FIG. 10) or 1101 (FIG. 11), the details of which may be omitted herein for brevity. Unlike the control circuits 1001, 1101, the control circuit 1301 may provide at least one of isolated actuation or control voltages (V_{DD-IS} or V_{CS-IS}) from the respective actuation or control voltages (V_{DD} or V_{CS}) using an optical isolator (c.f., a transformer). In some implementations, the control circuit 1301 may comprise a actuation and control circuit 1306 and first and second optical isolators 1302, 1304 configured to provide isolated actuation and control voltages (V_{DD-IS} and V_{CS-IS}) to the actuation and control circuit 1306. In some embodiments, the control circuit 1301 may be configured to provide control voltages V_{Cf} or V_{Cb} to the front and back control electrodes 110, 108 of the MEMS switch 1002, with respect to the voltage of the middle electrode 125 (thereby with respect to the voltage of the beam 107), and substantially independent of the input voltage Vᵢₙ of the input voltage source 902.

In various implementations, the MEMS switch 1002 may comprise a teeter-totter switch (e.g., the teeter-totter switch 100, 150, or 300) or a cantilever-based switch. In the illustrated example, the MEMS switch 1002 comprises, without limitation, an asymmetric switch having a back contact electrode 106 electrically connected a first terminal 102 (e.g., an input terminal), a front contact electrode 110 electrically connected to a second terminal 104 (e.g., an output terminal), a middle electrode 125 electrically connected to a back contact electrode 106, and a beam 107, where the beam 107 is electrically connected to the middle electrode 125 by a conductive post that anchors the beam 107 to a substrate, as described herein. In some embodiments, the first terminal 102 may be electrically connected to an input voltage source 902 that provides an input voltage Vᵢₙ to the first terminal 102 with respect to a first reference voltage (V_{G1}), e.g., ground, and the second terminal 104 may be electrically connected the first reference voltage via a resistor R3. In some implementations, the teeter-totter switch 1002 may comprise a front control electrode 110 and a back control electrode 108 configured to control the position of the beam 107 (and thereby the state of the MEMS switch 1002) upon receiving front and back control voltages V_{Cf} and V_{Cb} from the control circuit 1001.

In some embodiments, the actuation and control circuit 1306 may comprise one or more features analogous to those described above with respect to the actuation and control circuits 1004 (FIG. 10) and 1104 (FIG. 11) of the control circuits 1001 and 1101, respectively, the details of which may be omitted herein for brevity. For example, the control circuit 1306 may be configured to receive the isolated actuation voltage V_{DD-IS}, an isolated control voltage V_{CS-IS}, and a reference voltage V_{G2}, and generate two control voltages V_{Cf} and V_{Cf} with respect to V_{G2} using V_{DD-IS} and based on V_{CS-IS}. For example, when V_{CS-IS} indicates an ON state, V_{Cf} can be substantially equal to V₀ and V_{Cb} can substantially equal to zero (e.g., with respect to V_{G2}) and when V_{CS-IS} indicates an OFF state, V_{Cb} can be substantially equal to V₀ and V_{Cf} can be substantially equal to zero. In some examples, the reference voltage port 1312 of the actuation and control circuit 1306 can be electrically connected (e.g., shorted) to the output of the input voltage source 902 and thereby to the back contact electrode 106, the middle electrode 125, and the beam 107, of the MEMS switch 1002. In these examples, V_{G2} can be substantially equal to Vᵢₙ.

In some embodiments, the first optical isolator 1302 may be configured to receive the actuation voltage V_{DD}, with respect to an initial reference voltage, V_{G0} from a voltage source external to the control circuit 1301 and provide the isolated actuation V_{DD-IS} with respect to a first isolated reference voltage (e.g., an isolated ground), to the actuation and control circuit 1306.

In some embodiments, the second optical isolator 1304 may be configured to receive the control voltage V_{CS}, with respect to the initial reference voltage V_{G0}, from a signal source external to the control circuit 1301 and provide the isolated control voltage V_{CS-IS}, with respect to a second isolated reference voltage, to the actuation and control circuit 1306.

In some embodiments, isolated reference voltage ports (e.g., local output ground ports) of the first and second optical isolators 1302, 1304, can be electrically connected (e.g., shorted) to the reference voltage port 1312 of the actuation and control circuit 1306, such that the first and second isolated reference voltages are substantially equal to the reference voltage V_{G2} of the actuation and control circuit 1306. In some such embodiments, the reference voltage port 1312 can be electrically connected (e.g., shorted) to the input voltage source 902 and the first and second isolated reference voltages of the first and second isolators, and V_{G2} can be substantially equal to Vᵢₙ. In these embodiments, the actuation and control circuit 1306 may be configured to amplify V_{DD-IS} such that V_{Cf} is greater than the voltage of the beam 107 (Vᵢₙ) by V₀, which is the switching voltage for an isolated teeter-totter switch (e.g., when no voltage is applied between the middle electrode 125 and the one of the contact electrodes 106, 110, and V_{Cb} is substantially equal to the voltage of the beam 107, when V_{CS-IS} indicates an ON state, and that V_{Cb} is greater than the voltage of the beam 107 (Vᵢₙ) by V₀ and V_{Cf} is substantially equal to the voltage of the beam 107, when V_{CS-IS} indicates an OFF state.

In some embodiments, the actuation and control circuit 1306 may comprise a DC-to-DC converter configured to amplify V_{DD-IS} and a driver configured to provide the amplified V_{DD-IS} or V_{G2} as control voltage to front or back control electrodes 108, 106, based on a switch state indicated by V_{CS-IS}.

In some implementations, at least one of the first and second optical isolators 1302, 1304, may comprise an optical source and an externally un-biased optical-to-electrical power converter configured to use light received from the optical source to generate a photovoltage and/or photocurrent proportional to received light and isolated from the electronic circuitry that drives the optical source. In some examples, the optical-to-electrical power converter may comprise an unbiased semiconductor diode and/or transistor (e.g., a photodiode and/or phototransistor) comprising a semiconductor junction such as a PN-junction and configured to operate in photovoltaic mode. In some embodiments, optical-to-electrical power converter may comprise a plurality of photodiodes connected in series and configured to generate an isolated voltage with respect to a reference voltage (e.g., V_{G2}) upon receiving light generated by the optical source. In some such embodiments, the isolated voltage may comprise a plurality of photovoltages generated along individual photodiodes and summed up in series to provide a large photovoltage proportional to the received light.

In some implementations, at least one of the first and second optical isolators 1302, 1304, may comprise an optical source and an externally biased opto-sensitive device (e.g., an optical detector such as a semiconductor photodiode or phototransistor) configured to use light received from the optical source and bias voltage to generate photovoltage and/or photocurrent proportional to received light and isolated from the electronic circuitry that drives the optical source. In some examples, the semiconductor photodiode may be configured to operate in photoconductive mode, generate a photocurrent and generate a photovoltage by passing the photocurrent through a resistor. In some embodiments, the optical detector may be biased by a voltage source of the control circuit 1301 isolated from electronic circuits that generate V_{DD} and V_{CS} to drive the optical sources of the first and second optical isolators 1302, 1304.

In some embodiments, in addition to the first and second optical isolators 1302, 1304, the control circuit 1301 may comprise a third isolator 1308 configured to receive a sensor signal from a sensor 1020 and output an isolated sensor signal 1024. In some implementations, the sensor 1020 may comprise a temperature sensor, a current sensor, or other types of sensors that may generate sensor signals indicative of an operating condition of the teeter-totter switch 1002. In some cases, the isolated sensor signal 1024 output by the control circuit 1301 may be used by a signal processing circuit to control the V_{DD} and V_{CS} provided to the control circuit 1301. In some embodiments, the third isolator 1308 of the control circuit 1301 can be an optical isolator comprising an optical source optically coupled to the optical detector or the optical-to-electrical converter. In some cases, the optical source may be configured to receive an electric signal from the sensor 1020 and generate light having optical intensity or power proportional to the electric signal, and the optical detector (or optical-to-electrical converter) may be configured to receive the light generated by the optical source and generate the isolated sensor signal 1024.

In some embodiments, at least one of the second and third isolators 1304, 1308 may comprise two pairs of optical source and optical detector, where the first pair electrically isolates incoming signals and data provided to the control circuit 1301 and a second pair electrically isolates outgoing signals and data output by the control circuit 1301.

In some embodiments, at least the first and second optical isolators 1302, 1304 may be fabricated or disposed on a common substrate and/or be included in a common package.

In some examples, at least one of the first, second, and third optical isolators 1302, 1304, 1308 may comprise an optocoupler, or an opto-isolator. In some such examples, the optocoupler may comprise a photo-transistor, a pair of photo-transistors (e.g., a photodarlington circuit), a photo-SCR, a photo-TRIAC, or a combination thereof. However, the embodiments are not so limited and other opto-sensitive devices may be used to form an opto-coupler to provide optical isolation between external circuits and the circuitry of the control circuit 1301.

In some embodiments, the control circuit 1301 may be configured to control the MEMS switch network 1102 similar to that described above with respect to FIG. 11A by providing the front control voltage V_{Cf} to both front control electrodes 208a, 208b, and the back control voltage V_{Cb} to both back control electrodes 208a, 208b.

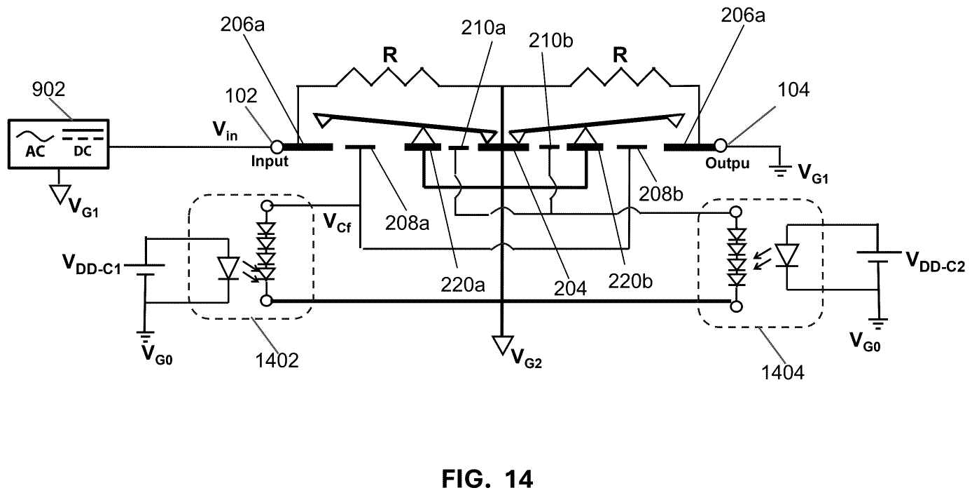

FIG. 14 is a schematic diagram illustrating a MEMS switch network comprising two MEMS switches connected in series and actuated by optically isolated control voltages provided by two optical isolators 1402, 1404. In various implementations, an individual MEMS switch of the MEMS switch network may comprise any one of the teeter-totter switches 100, 150, 300 described herein or a cantilever-based switch, or combination thereof. For illustrative purposes, the MEMS switch network in FIG. 14 includes two teeter-totter switches (e.g., each similar to the teeter-totter switch 100, 150, or 300) connected in series between the input and output terminals 102, 104 of an electronic circuit (e.g., an electronic circuit protected by the two MEMS switches). In some embodiments, the MEMS switch network shown in FIG. 14 may comprise one or more features described above with respect to the MEMS switch circuit shown, e.g., in FIG. 7 and the MEMS switch network 1102 shown in FIG. 11A. In some embodiments, the MEMS switch network may be configured to receive an input voltage Vᵢₙ from a voltage source 902 with respect to a first reference voltage V_{G1} via the input terminal 102 and controllably provide Vᵢₙ to the output terminal 104. In some cases, the beams of the MEMS switch network shown in FIG. 14 may be controlled by an optically isolated front control voltage V_{Cf} provided to the front control electrodes 208a, 208b, and an optically isolated back control voltage V_{Cb} provided to the back control electrodes 210a, 210b. In some examples, the front control voltage Ver may be received from a first optical isolator 1402 and the back control voltage V_{Cb} may be received from a second optical isolator 1404. In some embodiments, each of the first and second optical isolators 1402, 1404, may comprise an optical source and a high-voltage optical-to-electrical converter. In some embodiments, the high-voltage optical-to-electrical converter may be implemented as an array of photodiodes. In some embodiments, other types of optical-to-electrical converter may be used. In some embodiments, the first and second optical isolators 1402, 1404, may comprise multiple optical sources. In some examples, the number of optical sources and the number of optical-to-electrical converters in each one of the first and second optical isolators 1402, 1404, may be selected based on the switching voltage V₀ of the optical switches of the optical switch network. In some embodiments, the optical-to-electrical converter of the first optical isolator 1402 may be electrically connected between the first and second front control electrodes 208a, 208b, and a common back contact electrode 204 shared between the two switches of the MEMS switch network, which is electrically connected (e.g., shorted) to the first and second middle electrodes 220a, 220b. As such, the first optical isolator 1402 may provide the front control voltage V_{Cf} with respect to the voltage of the common back contact electrode 204 that serves as a second reference V_{G2}, which is different from V_{G1} and can be substantially equal to (Vᵢₙ−V_{G1})/2. Similarly, the second optical isolator 1404 may provide the back control voltage V_{Cf} with respect to the second reference voltage V_{G2}.

In some embodiments, the optical switch network may be deactivated from the OFF state to the ON state by providing an actuation voltage V_{DD-C2} of substantially zero to the optical source of the second optical isolator 1404 and an actuation voltage V_{DD-C1} to the optical source of the first optical isolator 1402, where magnitude of V_{DD-C1} is configured to cause the first optical isolator 1402 to output a front control voltage V_{Cf} substantially equal or larger than Vₛ that can be substantially equal to V₀ (e.g., 80 volts) for an individual MEMS switch of the MEMS switch network, where V₀ is the switching voltage of the an isolated individual MEMS switch.

In some embodiments, the optical switch network may be activated from ON state to OFF state by providing an actuation voltage V_{DD-C1} of substantially zero to the optical source of the first optical isolator 1402 and an actuation voltage V_{DD-C2} to the optical source of the second optical isolator 1404, where magnitude of V_{DD-C2} is configured to cause the second optical isolator 1404 to output a back control voltage V_{Cb} substantially equal or larger than V₀.

In some embodiments, the control voltages V_{Cf} (or V_{Cb}) provided by the optical-to-electrical converters of the first and second optical isolators 1402, 1404, can be larger than the V_{DD-C1} (or V_{DD-C2}). For example, by illuminating the optical-to-electrical converter over an extended period optically generated charges accumulated on a control electrode may build up to generate a voltage difference larger than V_{DD-C1} (or V_{DD-C2}) between the control electrode and the respective beam. As such, in some embodiments, the first and second optical isolators 1402, 1404 may be used to generate the voltages needed for actuating the beams of the two MEMS switches, and the corresponding MEMS switching system may not need additional electronic circuitry (e.g., DC-to-DC converters and drivers) and separate control signals for actuation. In some cases, MEMS switching systems of the types described with respect to FIG. 14 may lack high-voltage generators such as high-voltage power supplies (e.g., supplying more than 20V) and charge pumps. Removing charge pumps and/or high-voltage power supplies may provide significant noise reduction. In some examples, certain circuits having charge pumps and/or high-voltage power supplies can exhibit noise of up to 115 dBm. Removing the charge pumps and/or high-voltage power supplies may reduce the noise to less than −135 dBm or less than −157 dBm, for example.

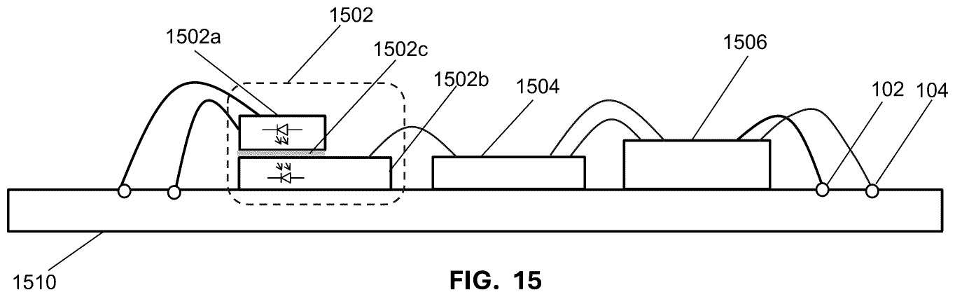

In some embodiments, an optical isolator (or at least a portion of the optical isolator) and actuation and control circuit of a MEMS control circuit MEMS switch may be integrated on a common substrate and/or be co-packaged, e.g., to reduce manufacturing costs and form factor. Additionally, in some implementations, a MEMS switch controlled by a control circuit may be integrated on a common substrate and/or be co-packaged with the control circuit or a portion of the control circuit (e.g., the optical isolators and/or the actuation and control circuit). FIG. 15 illustrates an example integrated MEMS switch system including a MEMS switch device 1506, a voltage supply and a control circuit 1504 configured to control the MEMS switch device 1506, and an optical isolator 1502 configured to electrically isolate the actuation and control circuit 1504 from another circuitry that provides V_{DD} and V_{CS} to the actuation and control circuit 1504. In various implementations, the MEMS switch device 1506 may comprise a teeter-totter switch (e.g., the teeter-totter switch 100, 150, or 300), a MEMS switch network (e.g., the MEMS Switch network 1102 or the MEMS Switch network show in FIG. 7), or another type of MEMS switch. In some embodiments, two or more of the MEMS switch devices 1506, the actuation and control circuit 1504, and the optical isolator 1502 may be fabricated and/or disposed on a common substrate. In some embodiments, the MEMS switch device 1506, the actuation and control circuit 1504, and the optical isolator 1502 may fabricated on separate chips which are disposed and/or mounted on the common substrate 1510 after fabrication. In some cases, the MEMS switch device 1506 may be configured to control the electrical connection between an input terminal 102 and an output terminal 104 of an electronic circuit (e.g., an electronic circuit formed on the substrate 1510).

In some embodiments, the optical isolator 1502 may comprise an optical source and optical-to-electrical converter configured to receive light generated by the optical source. In some examples, the optical isolator 1502 may comprise a first layer 1502a comprising the optical source disposed over a second layer 1502b comprising the optical-to-electrical converter, and a middle layer 1502c (e.g., an optically transparent layer) configured to allow light generated by the optical source to be received by the optical-to-electrical converter or configured to redirect or guide light generated by the optical source to the optical-to-electrical converter. The optical source may comprise one or more light emitting diodes or laser diodes and the optical-to-electrical converter may comprise one or more photodiodes, phototransistors, or other photosensitive devices (e.g., photosensitive semiconductor devices). In some embodiments, the optical isolator 1502 may comprise multiple pairs of optical sources and optical-to-electrical converters each configured to isolate one of the signals or voltages provided to the actuation and control circuit 1504. In some cases, at least one pair of optical source and optical-to-electrical converter may use different wavelength compared other pairs. In some cases, the optical isolator 1502 may comprise a single optical source and a plurality of optical-to-electrical converters configured to receive light from the single optical source.

In various implementations, the middle layer 1502c may comprise an optically transparent medium such a clear adhesive, a paste, a film, having high optical transmission within wavelength range comprising the wavelengths generated by the optical source. In some cases, the middle layer 1502c may comprise an optical interposer configured to direct light generated by the optical source in the first layer 1502a to the optical-to-electrical converter (e.g., a photodetector) in the first layer 1502b. In some examples, the interposer may comprise a Fresnel lens (e.g., a planar Fresnel lens), a composite structure comprising a waveguide, a structure comprising an optical filter (e.g., a planar optical filter, such as, grating or multilayer coating), an optical waveguide, or combination thereof. Accordingly, in various embodiments, the middle layer 1502c may be fabricated (or integrated within the package/SIP construction) using different methods (e.g., layer deposition, photolithographic patterning, hybrid integration, bonding, and the like) and using different materials depending on a selected structure and requirements of an application.

In some embodiments, the optical isolator 1502 may comprise an optical source and an optical-to-electrical converter fabricated side-by-side over on a common surface (e.g., top surface of the substrate 1510) such that the optical-to-electrical converter can receive at least a portion of light generated by the optical source via an optical path extended substantially in a lateral direction over the common surface. In some examples, the optical path may be established by an intervening layer formed on or over the common surface between the laterally separated optical source and optical-to-electrical converter. The intervening layer may be configured to facilitate transmission of light from the optical source to the optical-to-electrical converter. In various implementations, the intervening layer may comprise a clear adhesive, a paste, a film, having high optical transmission within wavelength range comprising the wavelength of the optical source. In some cases, the intervening layer may comprise an optical interposer configured to direct or guide light generated by the optical source to the optical-to-electrical converter (e.g., a photodetector) via the optical path. In some examples, the interposer may comprise a Fresnel lens, a composite structure comprising a waveguide, a structure comprising an optical filter (e.g., a planar optical filter, such as, grating or multilayer coating), or combination thereof. Accordingly, in various embodiments, the intervening layer may be fabricated (or integrated within the package/SIP construction) using different methods (e.g., layer deposition, photolithographic patterning, hybrid integration, bonding, and the like) and using different materials depending on a selected structure and requirements of an application.

In some embodiments, the MEMS switch device 1506, the actuation and control circuit 1504, and the optical isolator 1502 may be electrically coupled to each other by wire bonds. In some embodiments, two or more of the MEMS switch device 1506, the actuation and control circuit 1504, and the optical isolator 1502 may be electrically coupled by conductive lines formed over or on the substrate 1510.

In some cases, the integrated MEMS switch system shown in FIG. 15 may comprise the switching circuit 1300.

In some cases, the MEMS switches of the MEMS switch network shown in FIG. 14 may be fabricated on a first chip and the first and second optical isolators 1402 and 1404 may be fabricated on a second chip, and corresponding MEMS system may be formed by disposing the first and second chips on a common substrate and electrically connecting them. For example, the MEMS device 1506 in FIG. 15 may comprise the first chip, the optical isolator 1502 may comprise the second chip and the voltage supply and the actuation and control circuit 1504 may be removed to directly electrically connect the optical isolator 1502 the MEMS device 1506.

MEMS Switch Protection with Transistor

As described above, the behavior of the resistance of the conductive path established by a teeter-totter switch (or in general a MEMS switch) may change as a function of a voltage difference between the front control electrode (e.g., control electrode 110) and the conductive beam (e.g. the conductive beam 107). It has been observed that the electrical path between the front contact electrode (e.g. the front contact electrode 109) and the conductive beam may change between an ON-state resistance and an open circuit in a gradual manner (e.g., in a stepwise manner). Without being bound to any theory, such behavior can be attributed to a physical arrangement where the number of contact regions or points between the front contact electrode and the conductive beam gradually decreases. This may be due to, e.g., asperities or uneven contact surfaces between the contact electrodes and the beam. In addition, similar effects may be observed when the contact area depends on, e.g., proportional to, the amount of force applied between the contact electrodes and the beam. The inventors have discovered that such behavior may be understood by modeling the teeter-totter switch (or in general a MEMS switch), as a plurality of MEMS switch elements electrically connected in parallel where the electrical path established by an individual MEMS switch element can either have a very large resistance (e.g., resembling and open circuit) or an ON resistance (e.g., a low resistance between 5 to 10 Ohms). As such, when the voltage between the front control electrode and the conductive beam is increased to transition from the OFF state to the ON state, the number of MEMS switch elements that provide the ON resistance gradually increase and thereby the resistance of the conductive junction established by the MEMS switch gradually decreases. Similarly, when the voltage between the front control electrode and the conductive beam is decreased to transition from the ON state to the OFF state, the number of MEMS switch elements that provide the ON resistance gradually decrease and thereby the resistance of the remaining conductive junctions established by the MEMS switch gradually increases. In some cases, during such switching events, a very large amount of current may pass through the last one or few MEMS switch elements that transition from the ON resistance to an open circuit, and similarly a very large voltage drop may be generated across the first one or few MEMS switch elements that transition from an open circuit to the ON resistance. In some cases, when the MEMS switch (e.g., teeter-totter switch) is used in a circuit breaker to switch a large voltage (e.g., larger than 100, 200, or 300 volts), an electric discharge and/or a high current through few MEMS switch elements (each having ON resistance of few Ohms) during such transitions may cause severe damage to MEMS switch elements and, equivalently, to the contact regions of the conductive beam and front contact electrode of the MEMS switch, resulting in a high resistance ON state or, in some cases, a dysfunctional MEMS switch.

In some embodiments, to avoid the extreme voltage and current conditions that may occur at small and localized regions of contact surfaces of the front contact electrode and the conductive beam (equivalent to few MEMS switch elements of the plurality of MEMS switch elements), a protective switch (e.g., a transistor such as field-effect transistor), which may referred to herein as a hot switch or protective switch, may be electrically connected in parallel with the teeter-totter switch to reduce the electric current flowing through the teeter-totter switch during transition from OFF state to ON state and reduce the voltage between the conductive beam and front contact electrode of the teeter-totter switch during transition from ON state to OFF state. In some such embodiments, a control voltage (e.g. gate voltage, Vg) provided to the transistor may be configured to turn on the protective switch before providing an activation or deactivation voltage to the teeter-totter switch and to turn off the protective switch when the teeter-totter switch completes the transition to ON or OFF state. In some cases, given that the transition period is relatively short, the current handled by the transistor may not impose extreme current/voltage handling requirements on the transistor allowing usage of transistors with reasonable size and cost.

It will also be appreciated that while the hot switching condition is described herein in reference to a model equivalent circuit with a plurality of MEMS elements electrically connected in parallel, the inventors have discovered that protective switches to protect against hot switching conditions are of particular utility in the context of high current applications of circuit breakers that may employ a plurality of MEMS switches in parallel to handle high currents. Thus, as disclosed herein, multiple MEMS elements depicted as being electrically in parallel may represent actual multiple MEMS switches or an equivalent circuit of a single MEMS switch.

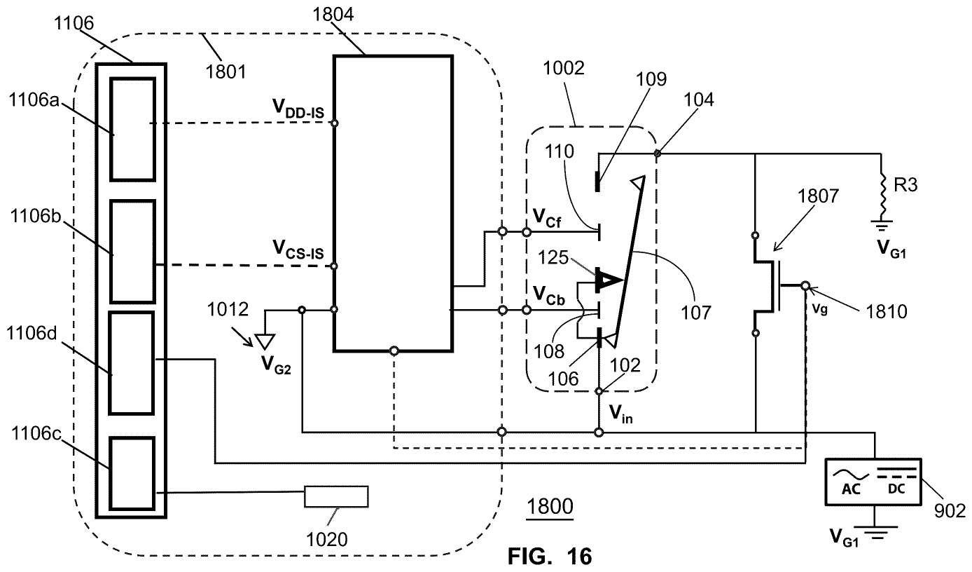

FIG. 16 schematically illustrates an example switching circuit 1800 comprising a MEMS switch 1002 (described above with respect to FIG. 10) and a control circuit 1801 configured to control the state of the MEMS switch 1002 by providing front and back control voltages V_{Cf} and V_{Cb} to the front and back control electrodes, 110, 108, of the MEMS switch 1002, respectively. In some examples, the control circuit 1801 may comprise an actuation and control circuit 1804 configured to generate the front and back control voltages V_{Cf} and V_{Cb}. The MEMS switch 1002 may be connected between the input terminal 102 connected to a voltage source 902 and the output terminal 104 connected to an electrical ground or another reference voltage (V_{G1}), e.g., via a resistor R3. In some cases, control circuit 1802 may comprise one or more features described above, e.g., with respect to control circuit 1001 (FIG. 10), the details of which are omitted herein for brevity. For example, the control circuit 1801 may be configured to provide the front and back control voltages V_{Cf} and V_{Cb} with respect to an input voltage (Vᵢₙ) provided by the voltage source 902 to the conductive beam 107 via the input terminal 102, the back contact electrode 106 and the middle electrode 125, which can be electrically connected to the back contact electrode 106.

It will be appreciated that as described above the MEMS switch 1002 may include multiple MEMS switch elements or behave similar to multiple parallel MEMS elements.

In some embodiments, a protective switch 1807 (e.g., a FET such as MOSFET) may be connected in parallel with the MEMS switch 1002 of the switching circuit 1800 to protect the contact surfaces of the conductive beam 107 and the front contact pad 109 during transitions between ON and OFF states. In some embodiments, the protective switch 1807 may be switched ON e.g., by a gate voltage Vg provided to the gate 1810 of the protective switch 1807, to establish a low resistance electrical path parallel to the MEMS switch 1002 to reduce an amount of current that passing through the conductive junction formed between conductive beam 107 and the front contact electrode 109 when transitioning from the ON state to the OFF state, or to reduce voltage difference between conductive beam 107 and the front contact electrode 109 when transitioning from OFF to ON state.

In some various implementations, the state of the protective switch 1807 may be controlled by the gate voltage (V_{g}) generated by the control circuit 1801 or a separate hot switch control circuit (not shown) different from the control circuit 1801. In some cases, the hot switch control circuit may be included in the control circuit 1801 or can be an external circuit connected to the control circuit 1801.

In some embodiments, the gate voltage V_{g} may comprise an isolated gate voltage signal generated by the isolator circuit 1106 in response to receiving an external gate control voltage from the external hot switch control circuit. In some such embodiments, the isolator circuit 1106 may comprise a fourth isolator configured to receive the external gate control voltage and generate the isolated gate voltage. In some examples, the fourth isolator 1106d can be separated from the first, second, and the third isolators 1106a, 1106b, 1106c. In some such embodiments, the external hot switch control circuit may generate and/or control the gate voltage V_{g} based at least in part on the V_{CS} or V_{CS-IS}. For example, the external hot switch control circuit may temporally align the external gate control voltage with V_{CS} or V_{CS-IS} such that the protective switch 1807 is turned ON prior to activation or deactivation of the MEMS switch 1002 and is turned of after the MEMS switch 1002 is activated or deactivated.

In some embodiments, the actuation and control circuit 1804 of the control circuit 1801 may be configured to generate and/or control the gate voltage V_{g} based at least in part on V_{CS} or V_{CS-IS}. In some such embodiments, the actuation and control circuit 1804 or the hot switch control circuit may use the isolated control signal V_{CS-IS} (e.g., received from an isolator of the control circuit 1801) and/or V_{Cf} and V_{Cb}, and generate and/or control the gate voltage V_{g} based at least in part on the V_{Cf} and V_{Cb} and/or V_{CS-IS}. For example, the actuation and control circuit 1804 may temporally align V_{g} with V_{CS-IS} and/or such that the protective switch 1807 is turned on prior to activation or deactivation of the MEMS switch 1002.

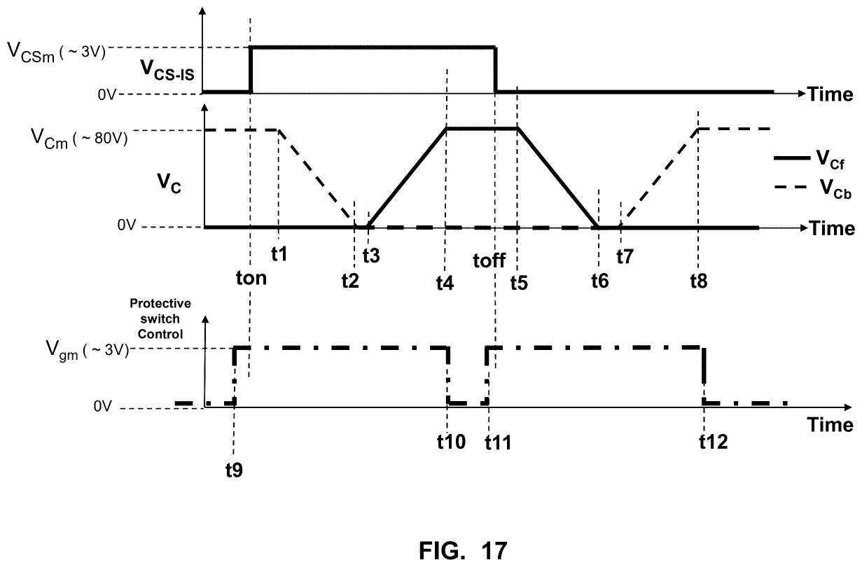

FIG. 17 schematically illustrates example temporal variations of the control signal voltage (top panel), e.g., isolated control signal voltage V_{CS-IS}, and the front and back control voltages V_{Cf} and V_{Cb} provided to the MEMS switch 1002, and the gate voltage, V_{g}, (bottom panel) provided to the protective switch 1807 during the transition from the OFF state to the ON state and vice versa.

In the example shown, at time tₒₙ, V_{CS-IS} can be switched from 0 to V_{CSm} to change the state of the MEMS switch 1002 from OFF state to ON state and at time to the gate voltage (V_{g}) may be switched from 0 to an on voltage (V_{gm}) of the protective switch 1807 to turn on the protective switch 1807 to protect the MEMS switch 1002. In some cases, once the transition to the ON state is complete (e.g., at time t₄), V_{g} can be switched from V_{gm} back to 0 to to turn on the protective switch 1807. Further, in the example shown, at time t_{off}, V_{CS-IS} can be switched from V_{Cm} to 0 to change the state of the MEMS switch 1002 from the ON state to the OFF state and at time t₁₁ the gate voltage (V_{g}) may be switched from 0 to an ON voltage (V_{gm}) of the protective switch 1807 to turn on the protective switch 1807 to protect the MEMS switch 1002. In some cases, once the transition to OFF state is complete (e.g., at time t₈), V_{g} can be switched from V_{gm} back to 0 to to turn off the protective switch F1807.

As described above with respect to FIG. 11B, to change the state of the MEMS switch 1002 from the OFF state to the ON state, from time t₁ after tₒₙ to time t₂, V_{Cb} may be decreased from V_{Cm} to 0 and from time t₃ (than can be after t₂) to time t₄, V_{Cf} may be increased from 0 to V_{Cm}. In some cases, to can be earlier than t₁ such that when the reduction of V_{Cb} starts, the FET 1807 is already on. In some such cases, depending on the delay between tₒₙ and t₁, t₉ can be earlier, coinciding, or later than tₒₙ. In some cases, the delay between tₒₙ and t₁ can be a predetermined value (e.g., a set parameter of the actuation and control circuit 1804) and the actuation and control circuit 1804 or the hot switch control circuit may be configured to temporally align ty with respect to tₒₙ such that t₉<t₁. Similarly, to change the state of the MEMS switch 1002 from ON to OFF state, from time t₅ after t_{off} to time t₂ V_{Cf} may be decreased from V_{Cm} to 0, and from time t₇ (that can be after t₆) V_{Cb} may be increased from 0 to V_{Cm}. In some cases, t₁₁ can be smaller than t₅ such that when the reduction of V_{Cf} starts, the protective switch 1807 is already on. In some such cases, depending on the delay between t_{off} and t₅, t₁₁ can be smaller, equal, or larger than t_{off}. In some cases, the delay between t_{off} and t₅ can be a predetermined value (e.g., a set parameter of the actuation and control circuit 1804) and the actuation and control circuit 1804 or the hot switch control circuit may be configured to temporally align t₁₁ with respect to t_{off} such that t₁₁<t₅. In some cases, once the transition to ON state is complete (e.g., at time t₈), V_{g} can be switched from Vem back to 0 to turn off the protective switch 1807. In some examples, tₒₙ (the edge of the MEMS control signal) may be delayed with respect to ty (the edge of the protective switch control signal) by a duration from 0.1 to 1 microsecond, from 1 to 100 microseconds, from 100 microseconds to 1 millisecond, from 1 to 100 milliseconds, or a time value that is in a range defined by any of these values or larger or smaller. In some examples, t₁ (the time at which the MEMS control voltage begins to change) may be delayed with respect to tₒₙ by a duration from 0.1 to 1 microsecond, from 1 to 100 microseconds, from 100 microseconds to 1 millisecond, from 1 millisecond to 100 milliseconds, or a time value that is in a range defined by any of these values or larger or smaller.

In some embodiments, protective switch 1807 may be replaced by two or more protective switches connected in parallel with the MEMS switch 1002 between the input and output terminals 102, 104.

In some embodiments, one or more protective switches may be connected in parallel between the input and output terminals 102, 104, of the MEMS switch network 1102 of the switching circuit 1100, or the MEMS switch 1002 of the switching circuit 1300, for protection against damage during transitions between ON and OFF states. In some cases, these protective switches may be controlled by the control circuits the switching circuits 1100 and 1300, or separate hot switch control circuit, e.g., based on temporal signal alignments described above with respect to FIG. 16, the details of which may not be repeated herein for brevity.

In some embodiments, two or more protective switches may be connected in parallel with a MEMS switch or MEMS switch network to provide protection during an activation or deactivation process. In some examples, two or more protective switches may be connected together in series between the input terminal 102 and 104 to protect a MEMS switch or MEMS switch network having an operating voltage greater than the operating voltage of an individual protective switch. In some examples, two or more protective switches may be connected together in parallel between the input terminal 102 and 104 to protect a MEMS switch or MEMS switch network having an operating current greater than the operating current of an individual protective switch. In some examples, three or more protective switches may be connected together in parallel and series between the input terminal 102 and 104 to protect a MEMS switch or MEMS switch network having operating voltage and current greater than the operating voltage and current of an individual protective switch. For example, two pairs of serially connected protective switches may be connected in parallel with the MEMS switch or MEMS switch network. In some embodiments, the two or more protective switches may be controlled by a single gate voltage distributed among the protective switches or by individual gate voltages synchronized to control the protective switches.

Circuit Breaker with MEMS Switch and Electrical Overstress (EOS) Protection

In some cases, a MEMS switch can be exposed to electrical overstress (EOS) events that may damage the switch by generating a high voltage, e.g., between a conductive beam and a contact electrode and generating a high current beyond the specified limits of the MEMS switch (e.g., exceeding one or both the operating voltage and operating current of the MEMS switch). For example, a MEMS switch (e.g., a teeter-totter switch) may experience a transient signal event, or an electrical signal lasting a short duration and having rapidly changing voltage and/or current and having high power. Transient signal events can include, for example, electrostatic discharge (ESD) events arising from an abrupt release of charge (e.g., voltage/current spike) from a device or system electrically connected to the MEMS. In some cases, an EOS event can occur when the MEMS switch is in the ON or OFF state. The EOS event can cause high current to flow through contacting regions of the MEMS switches (e.g., the end of the conductive beam contacting the corresponding contact electrode), and can even cause arcing to occur between non-contacting regions of the MEMS switches (e.g., the end of the conductive beam separated from the corresponding contact electrode). Such high current or arcing events can damage the MEMS switches. To prevent such EOS events from damaging the MEMS switches, according to various embodiments, an EOS protection device may be integrated with the MEMS switches and configured to shunt discharge current caused by the EOS events. In particular, a spark gap may be configured to arc in response to an overvoltage applied on the MEMS switch to protect the MEMS switch from being damaged, e.g., when the switch is in the ON or OFF state. In some such embodiments, the EOS or protection device may be electrically connected with the MEMS switch in parallel, between an input and output terminals (e.g., input and output terminals of the MEMS switch). In some embodiments, the EOS device may be electrically connected between an input terminal (or an output terminal) and a ground voltage or a reference voltage (e.g., the isolated reference voltage V_{G-IS} in FIG. 11A). The EOS protection device can have an activation voltage (e.g., arcing voltage) lower than voltage that would cause damage to the MEMS switch. For example, in the OFF state, the EOS protection device can have an activation voltage lower than a breakdown voltage between the conductive beam and an open circuited one of the contact electrodes. In the ON state, the EOS protection device can have an activation voltage lower than a voltage that would cause excessive current flowing between the conductive beam and the contacting one of the contact electrodes to cause damage to the MEMS switch.

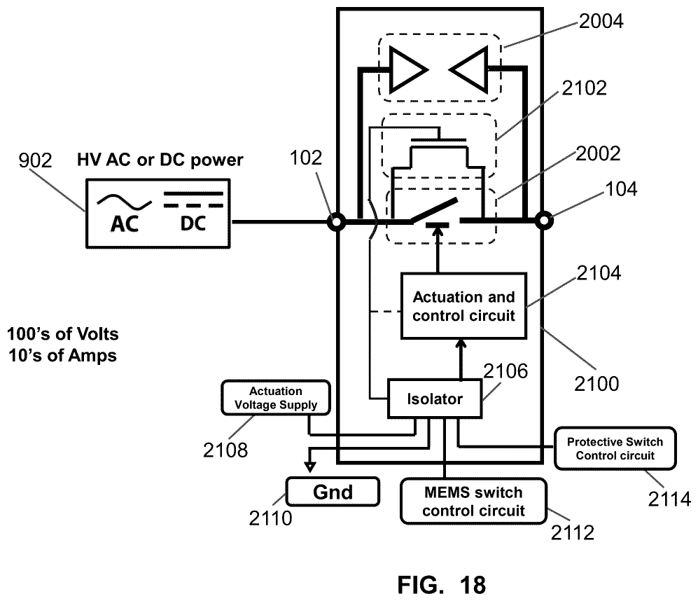

FIG. 18 schematically illustrates an example circuit breaker 2100 comprising the MEMS switch 2002 and the EOS protection device 2004 configured to protect the MEMS switch 2002 against unexpected external transient signals (e.g., when the MEMS switch 2002 is in the OFF state). The EOS protection device 2004 is additionally configured to protect a protective switch 2102, e.g., a transistor, configured to protect the MEMS switch 2002 against formation of high current and/or high voltage between a contact electrode and the conductive beam of the MEMS switch 2002 during a transition between the ON and OFF states (as described above with respect to 18). In some embodiments, the MEMS switch 2002, the EOS protection device 2004, and the protective switch 2102 can be connected in parallel between the input and output terminals 102, 104 of the circuit breaker 2100. In some embodiments, the protective switch 2102 may comprise one or more features described above with respect to the protective switch 1807.

In some embodiments, the circuit breaker 2100 may be configured to provide electric power from an electric source 902 connected to the input terminal 102 to a device or system connected to the output terminal 104 and allow a system or user to control the connection between electric source and the device or system using MEMS switch 2002.

In some embodiments, the circuit breaker 2100 may comprise one or more features described above with respect to the switching circuit 1000, the switching circuit 1100, the switching circuit 1300, described above with respect to FIGS. 10, 11A, and 13, respectively, the details of which may not be repeated herein for brevity.

In some embodiments, the circuit breaker 2100 may comprise an isolator module 2106 comprising one or more isolators (e.g., optical isolators, magnetic isolators, and the like) configured to provide electric isolation between the circuits and elements within the circuit breaker 2100 and one or more external systems and devices. In some implementations, the isolator module 2106 may comprise one or more features described above with respect to the isolator circuit 1106 in FIGS. 11A and 18. The external systems and devices may provide signals or supply voltages to the circuit breaker 2100 and/or receive signals from the circuit breaker 2100. In some embodiments, the circuit breaker 2100 may comprise a voltage control and supply circuit 2104 configured to receive signals from the isolator module 2106 and provide control signals to the MEMS switch 2002 and the protective switch 2102. For example, the isolator module 2106 may receive a supply voltage from an actuation voltage supply 2108, a switch control signal from a switch control circuit 2112 and a protective switch control signal from a protective switch control circuit 2114 and may be configured to provide corresponding isolated voltages and signals to the voltage control and supply circuit 2104. In some cases, the supply voltage received from the actuation voltage supply 2108, the switch control signal received from the switch control circuit 2112, and the protective switch control signal received from the protective switch control circuit 2114 may be generated with respect to a first common reference voltage 2110 (e.g., a common ground) that is electrically isolated from a second common reference signal with respect to which the corresponding the isolated supply voltage, isolated switch control signal, and isolated protective switch control signal are generated. In some cases, the second common reference may be substantially equal to the electrical potential of one or more conductive beams of the MEMS switch 2303. In some embodiments, the protective switch 2102 may receive an isolated protective switch control signal corresponding to the protective switch control signal generated by the protective switch control circuit 2114 directly from the isolator 2106. In some embodiments, the voltage control and supply circuit 2104 may generate the protective switch control signal using switch control signal received from the switch control circuit 2112 (via the isolator module 2106). In some such embodiments, the circuit breaker 2100 may not receive the protective switch control signal from the protective switch control circuit 2114.

In some embodiments, the actuation voltage provided by the actuation voltage supply 2108 can be from 1 to 2 volts, from 2 to 3 volts from 3 to 4 volts from 4 to 5 volts, or any ranges formed by these values or larger or smaller values.

In some embodiments, the MEMS control signal provided by the MEMS switch control circuit 2112 can be from 1 to 2 volts, from 2 to 3 volts, from 3 to 4 volts, from 4 to 5 volts, or have a voltage value that is in a range defined by any of these values or larger or smaller.

In some embodiments, the protective control signal provided by the protective switch control circuit 2114 can be from 1 to 5 volts, from 5 to 10 volts from 10 to 20 volts from 20 to 30 volts, or any ranges formed by these values or larger or smaller values.

In some embodiments, a circuit breaker may comprise an EOS protection device connected between the input terminal 102 or the output terminal 104 and an internal isolated reference voltage or an external reference voltage.

In some embodiments, the MEMS switch device may be integrated and/or co-fabricated with the electrical overstress (EOS) protection device configured to protect the MEMS switch. In some examples, the EOS protection device may be co-fabricated with the MEMS switch on a common substrate. In some such examples, the EOS protection device can be electrically connected to the MEMS switch via conductive lines formed on or over the common substrate. Advantageously, the MEMS switch and the EOS protection device may have corresponding structures that can be co-fabricated from a common layer formed over the substrate. In various implementations, the EOS protection device may comprise a vertical or lateral spark gap device. In various implementations, at least a portion of the EOS protection device may be co-fabricated with a portion of the MEMS switch. As described herein, co-fabrication refers to a fabrication process in which two or more structures are at least partly formed from a common process step, such as a deposition step or a patterning step. In these implementations, corresponding features resulting from the co-fabrication can have characteristic signatures. For example, structures of the EOS protection device 2004 that are co-fabricated with the MEMS switch can have substantially the same physical dimensions as the corresponding structures of the MEMS switch.

Circuit Breaker Circuitry with Sensors

In some embodiments, a system comprising a MEMS switch may include one or more sensors configured to monitor various parameters of the MEMS switch or MEMS switch network and, in some cases, a circuitry (e.g., a circuit breaker) connected to or comprising the MEMS switch or MEMS switch network. For example, the one or more sensors may include sensors to measure electric current passing through the MEMS switch, the temperature of the MEMS switch, or other parameters that may be used to determine an operational condition of the MEMS switch or to determine that the state of the MEMS switch should be changed (e.g., from ON to OFF state). For example, a temperature sensor may be used to measure and/or estimate the temperature of the MEMS switch in the ON state. In response to determining that the temperature is above a threshold value, a microcontroller (e.g., microcontroller 1110 in FIG. 11A) may provide an actuation control signal to a control circuit (e.g., control circuit 1101 in FIG. 11A) to change the state of the MEMS switch to OFF state, e.g., to protect a core circuitry protected by the circuit breaker circuitry. As another example, a current sensor may be used to measure and/or estimate electric current conducted by the MEMS switch in the ON state. In response to determining that the electric current is above a threshold value (e.g., an operating current of the MEMS switch), a microcontroller (e.g., microcontroller 1110 in FIG. 11A) may provide an activation control signal to the control circuit to change the state of the MEMS switch to OFF state. In various implementations, at least a portion of a sensor may be integrated and/or co-fabricated with the MEMS switch on a common substrate. In some embodiments, the system comprising the MEMS switch (e.g., a control circuit of the system) may comprise a sensor block configured to receive a sensor signal (e.g., an analog signal) from the sensor or a sensor element and generate a processed sensor signal or measured value (e.g., digitized sensor signal or digitized measure value) usable by the microcontroller. In some examples, the sensor block (e.g., a sensor readout circuit) may comprise an analog-to-digital converter (ADC) configured to receive an analog senor signal from the sensor element and generate a digital sensor signal that can be processed by the microcontroller.

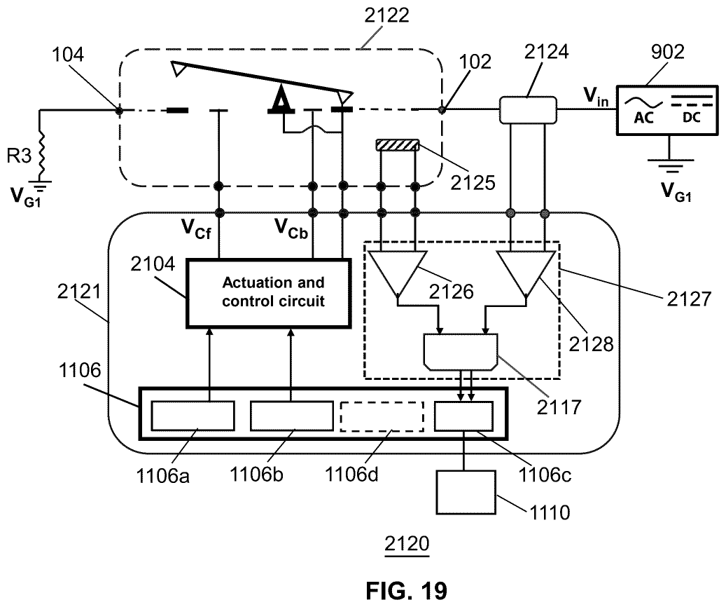

FIG. 19 schematically illustrates an electric (or electronic) system 2120 or a portion of an electric system comprising a MEMS switch module 2122 (e.g., a single MEMS switch or a MEMS switch network) and a control circuit 2121 configured to control the MEMS switch module 2122. In some embodiments, the MEMS switch module 2122 or may comprise one or more features described above with respect to various circuit breakers described above. For example, the MEMS switch 2122 may be arranged similarly to the teeter-totter switch 150 (FIGS. 2A-2C) or the teeter-totter switch 300 (FIGS. 3A-3C). The control circuit 2121 may comprise one or more features similar to those described above with respect to control circuits 1101 (FIGS. 10, 11A), 1301 (FIG. 13), or 1801 (FIG. 18), the details of which may not be repeated herein for brevity.

In some embodiments, the electric system 2120 can be a circuit breaker configured to control electric connection between an electric power source 902 and a load (e.g., a resistive load having a resistance R3) via an input terminal 102 and an output terminal 104. In some examples, the MEMS switch module 2122 may comprise one or more teeter-totter switches connected in parallel and/or in series. In some embodiments, the electric system 2120 may comprise one or both of a temperature sensor 2125 configured to monitor and measure temperature of the MEMS switch 1002 and a current sensor 2124 configured to monitor and measure electric current conducted between the input terminal 102 to the output terminal 104 by the MEMS switch module 2122. In some embodiments, the temperature sensor 2125 and/or the current sensor 2124 may comprise one or more sensor elements, configured to generate one or more analog sensor signals indicative of the temperature of the MEMS switch module 2122 and/or current conducted through the MEMS switch module 2122, respectively.

In some embodiments, the control circuit 2121 may comprise a sensor block or sensor readout circuit 2127 configured to receive sensor signals (e.g., an analog sensor signal) from the temperature sensor 2125 and/or the current sensor 2124 and generate a processed sensor signal usable by the microcontroller 1110, e.g., to generate a control signal that can cause the microcontroller to change the state of the MEMS switch module 2122. In some examples, the processed signal may comprise a digital signal (e.g., a digitalized sensor signal).

In some embodiments, the temperature sensor 2125 may comprise a first resistor. The change in resistance of a resistor with temperature or temperature coefficient of resistance (TCR). A positive TCR indicates that a resistor's resistance increases with increasing temperature, as in the case of a metallic material. On the other hand, a negative TCR indicates that a resistor's resistance decreases with increasing temperature, as in the case of a semiconductor material. The resistor of the temperature sensor 2125 may be formed as a thin film resistor having either a positive or positive TCR. The temperature sensor is disposed close to the MEMS switch module 2122, e.g., on the same substrate. In some such examples, the sensor block 2127 may comprise a first amplifier 2126 (e.g. a differential amplifier) configured to generate a sensor signal proportional to resistance of the first resistor. In some embodiments, the temperature sensor 2125 may comprise a thermo-electric element configured to generate a temperature dependent signal (e.g., a current or a voltage) indicative or the temperature of the MEMS switch.

In some embodiments, the current sensor 2124 may comprise a second resistor connecting the electric power source 902 to the MEMS switch module 2122. In some such examples, the sensor block 2127 may comprise a second amplifier 2128 (e.g. a differential amplifier) configured to generate a sensor signal proportional to a voltage drop across the second resistor and thereby a current transmitted via the current sensor 2124 and thereby through the MEMS switch module 2122 when the MEMS switch module is in ON state. In some embodiments, the current sensor 2124 may comprise a Hall sensor configured to generate a sensor signal indicative of the current transmitted between the electric power source 902 and the MEMS switch module 2122. In some implementations, the current sensor 2124 can be part of a Delta-Sigma measurement system configured to measure the current transmitted between the electric power source 902 and the MEMS switch module 2122. In some embodiments, the sensor block 2127 may comprise an analog-to-digital converter (ADC) 2117 configured to receive one or both the sensor signals indicative of the temperature of the MEMS switch and the current passing through the MEMS switch, generate respective digital sensor signals, and transmit the digital sensor signals to the microcontroller 1110 via the third isolator 1106c such that the microcontroller 1110 receives isolated digital sensor signals.

In some embodiments, the microcontroller 1110 may compare a sensor signal (e.g., an isolated digital sensor signal) received from the control circuit 2121, to determine whether the one or both temperature of the MEMS switch module 2122 and the current passing through the MEMS switch, as indicated by the respective signals, exceed respective predetermined threshold values. In some cases, the predetermined threshold values (e.g., threshold current and/or threshold temperature) may be stored in a non-transitory memory of microcontroller 1110. For example, upon the microcontroller 1110 determining that a temperature sensed from the temperature sensor 2125 (e.g., indicated the sensor signal) exceeds a predetermined threshold temperature, the microcontroller 1110 may activate the MEMS switch module 2122 by changing the state of a MEMS switch from ON to OFF state), e.g., by tiling the beam of the teeter-totter switch 1002 to connect the first end of the beam 107 to the back contact electrode 106 and disconnect the second end of the beam 107 from the front contact electrode 109. As another example, upon the microcontroller 1110 determining that a current sensed from the current sensor 2124 (e.g., indicated the sensor signal) exceeds a predetermined threshold current, the microcontroller 1110 may activate the MEMS switch module 2122, by changing the state of a MEMS switch from ON to OFF state).

In some implementations, one or both the temperature sensor 2125 and the current sensor 2124 may be fabricated or disposed on a substrate on which at least a portion of the MEMS switch module 2122 (e.g., at least one MEMS switch of a plurality of MEMS switches) is formed. In some such implementations, one or both the temperature sensor 2125 and the current sensor 2124 may be co-fabricated with least a portion of the MEMS switch module 2122 (e.g., a portion of a MEMS switch therein). In some examples, one or more thin film-based sensors may comprise a thin film resistor patterned from a same layer as one or more of the first and second contact electrodes 106, 109, or one or more of the first and second control electrodes 108, 110. In some such examples, the thin film resistor may have the same thickness as the one or more of the first and second contact electrodes 106, 109 or the one or more of the first and second control electrodes 108, 110.

In some embodiments, the sensor block 2127 may provide the processed sensor signals generated using the sensor signals received from the temperature and current sensors 2125, 2124, to an isolator configured to provide an isolated processed sensor signal to the microcontroller 1110. In some examples, the isolator can be, e.g., the third isolator 1106c of the isolator circuit 1106 (described above with respect to FIGS. 11A and 18), which additionally comprises the first, second, and fourth isolators 1106a, 1106b, 1106d, configured to isolate the supply voltage, MEMS switch control signals, and the protective switch control signals, respectively.

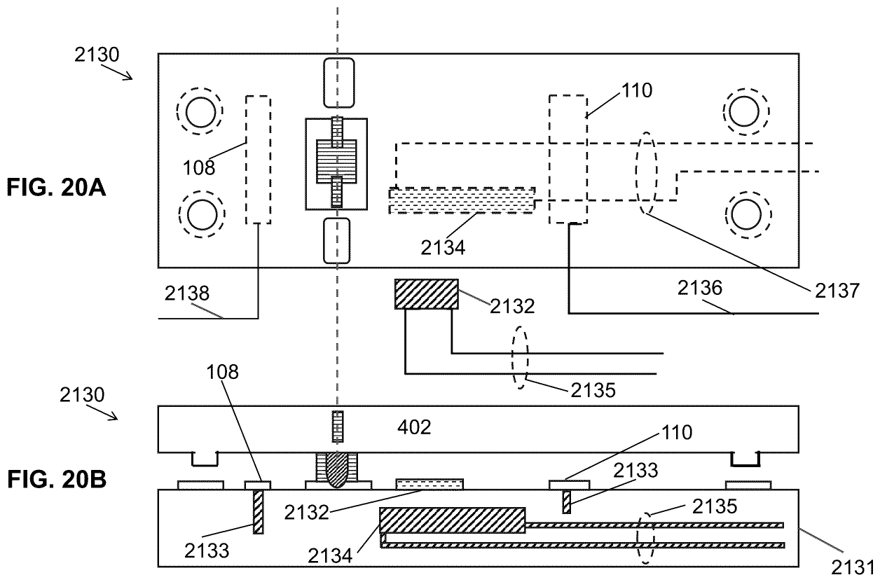

FIGS. 20A-20B schematically illustrate a top view (FIG. 20A) and a side cross-sectional view (FIG. 20B) of an example MEMS switch 2130 (e.g., a MEMS switch in the MEMS switch module 2122) comprising one or more integrated sensors. In some cases, the MEMS switch 2130 can be a teeter-totter switch comprising one or more features described above with respect to the teeter-totter switch shown in FIGS. 6A-6C. In some cases, the MEMS switch 2130 may be formed on a top layer 2131 of a substrate (e.g., a chip or a wafer). In some such cases, the integrated sensor may be formed or disposed on a top surface of the top layer 2131 or within the top layer 2131. In some cases, the integrated sensor may comprise a resistor 2132 formed on or above the top layer 2131 where the resistor 2132 can be connected to a readout circuit (e.g., the sensor block 2127) via conductive lines 2135. In various implementations, the conductive lines 2135 may be formed on, above, or within the top layer 2131. In examples, at least a portion of the conductive lines 2137 may be formed within the top layer 2131. In some cases, the integrated sensor may comprise a resistor 2134 formed within the top layer 2131 (below the top surface) and the resistor 2134 can be connected to a readout circuit (e.g., the sensor block 2127) via conductive lines 2137 at least partially formed within the top layer 2131. In examples, the resistor 2134 and, in some cases, the conductive lines 2137, may be co-fabricated with another conductive line or a conductive via (e.g., conductive via 2133) connected to a control electrode of the MEMS switch 2130 (e.g., front or back control electrodes 110, 108 of the teeter-totter switch). In some examples, the resistors 2134 may comprise polysilicon. In some other examples, the resistor 2134 may comprise a metal. In some examples, the resistor 2134 may be co-fabricated with the via 2133 by depositing and patterning a polysilicon layer during formation of the top layer 2131. In some examples, the conductive lines 2135 may comprise polysilicon or a metal.

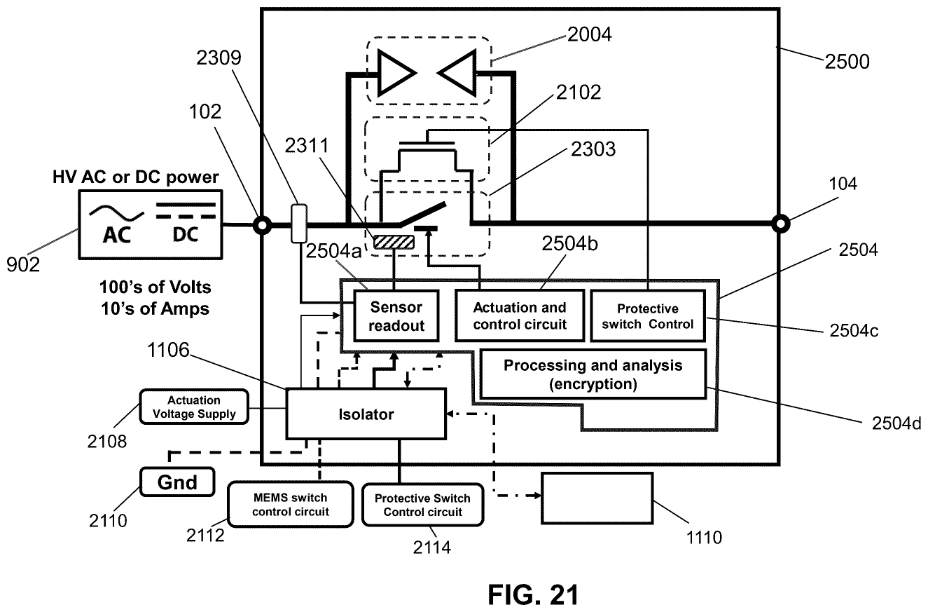

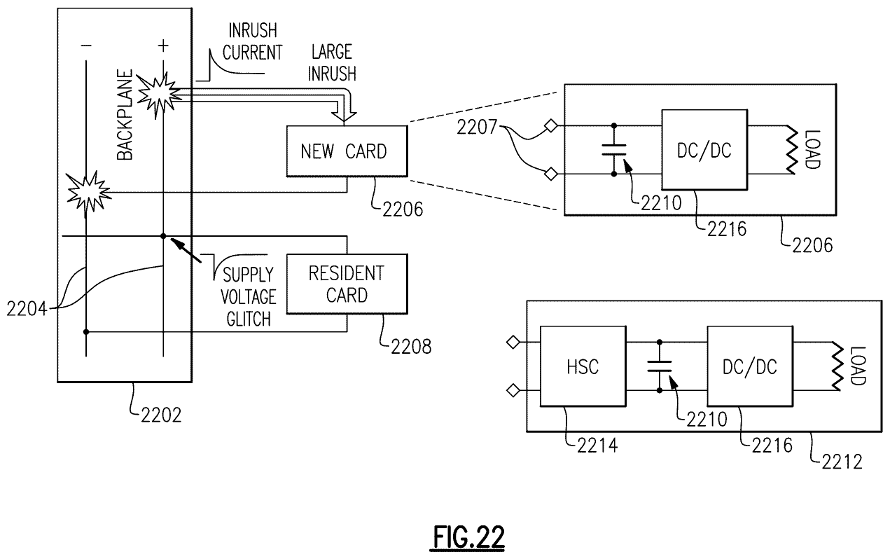

FIG. 21 is a block diagram illustrating an example circuit breaker 2500 comprising the MEMS switch module 2303, the protective switch 2102, the EOS protection device 2004 (described above with respect to FIG. 18), the temperature sensor 2311, and the current sensor 2309. In some embodiments, the circuit breaker 2500 may comprise a signal control and processing circuit 2504 and an isolator circuit 1106. In some embodiments, the signal control and processing circuit 2504 may be configured to generate control voltages using isolated signals received from the isolator circuit 1106 and process sensor signals received from the temperature and current sensors 2311, 2309. In some embodiments, the isolator circuit 1106 may receive one or more of an actuation supply voltage 2108, MEMS control signals, and protective switch control signals, and provide one or more of an isolated supply voltage, isolated MEMS control signals, and isolated protective switch control signals to the signal control and processing circuit 2504. In some examples, the isolator circuit 1106 may be connected to a microcontroller 1110 and an external reference voltage 2110.

Additionally, in some cases, the signal control and processing circuit 2504 may be configured to encrypt a sensor signal or an isolated control signal. In some embodiments, the signal control and processing circuit 2504 may comprise one or more of a sensor readout module 2504a, an actuation and control circuit, herein referred to as MEMS actuation and control module 2504b, a protective switch control module 2504c, a processing and analysis module 2504d. In some cases, the MEMS actuation and control module 2504b may comprise the voltage control and supply circuit 1004, 1104, 1804, and 2104.

### Current Regulation Apparatus Based on MEMS Switch: Hot Swap Controllers

In various electric and electronic systems (e.g., a data center, a server, a switch system, a base station and the like), it may be desirable to replace, add, or remove a module, card (e.g., a server card or server shelf), circuit board, modular circuit card, server blade, and the like without shutting down the system. In some cases, a device or circuit (e.g., a switch) may be used to manage or prevent an inrush current, an electric discharge, or other transient electric events that may damage the component or the system, or cause operational faults when the component is added, removed, or replaced. This allows the module to be added to or removed from a large rack running multiple of the modular circuits in parallel (e.g., backplane of a system), for reasons such as repair or upgrading, without the need to shut down the entire rack. In some cases, the process of swapping a module connected to a system while the system, and/or a backplane or an interface of the system to which the module is removably connected, may be referred to as hot swapping and a device or circuit used to manage or prevent an inrush current, an electric discharge, and/or a voltage drop during the hot swap may be referred to as hot swap controller (HSC). In various applications, an HSC may be used to protect a module, card, circuit board or the like during a swapping process and additionally, in some cases, during an operational period when the module, card, or circuit board is connected to and powered by a system. In various embodiments, the MEMS-based HCs described below may be used for switching and/or regulating current flow between a modular circuit and a powered main circuit. In some cases, the modular circuit may comprise a circuit card (e.g., a server card or shelf) and the powered main circuit may comprise a backplane or a motherboard.

FIG. 22 schematically illustrates a backplane 2202 of a server system comprising two power lines 2204 electrically connected to a plurality of server shelves including two illustrated server shelves or server cards 2206, 2208, that may be configured to be powered by the system through the backplane 2202 and to communicate with the system. In some cases, the server system (e.g., a server rack) may comprise a main circuit (e.g., the backplane 2202) electrically coupled to a plurality of modular circuits or circuit modules (e.g., server cards or shelves). In some examples, the server rack may comprise a plurality of coupling slots and the server shelves 2206, 2208, may be inserted into respective coupling slots.

In some embodiments, the two power lines 2204 may provide direct current (DC) voltage to the server shelves 2206, 2208. In some cases, the DC voltage can be from 48 to 50 volts. In some embodiments, the backplane 2202 may include a power supply unit (not shown) configured to receive alternating current (AC) voltage and provide DC voltage to the power lines 2204. In some such embodiments, the server system shown in FIG. 22 may comprise a rack level AC power distribution where the power supply unit is located inside the server rack. In some such embodiments, the AC voltage received by the power supply unit can be about 400 Volts. For example, the AC voltage received by the power supply unit may comprise 3-phase 400 Volts input electric supply.

In some embodiments, each one of the two power lines 2204 may supply a voltage magnitude of about 400V with respect to a reference voltage (e.g., ground potential) and with different polarities. For example, one of the power lines may supply +400 Volts and the other ones −400 Volts to each of the server shelves 2206, 2208. In some such embodiments, the two power lines 2204 may receive DC voltages of +400 Volts from a power rack separate from the server rack that houses the back plane and the server shelves. For example, the server system shown in FIG. 22 may comprise a server rack of a high voltage DC server system. In some such embodiments, the power rack may receive an AC voltage of about 400 Volts (e.g., from a 3-phase 400 Volts input electric supply) and provide DC voltages of ±400 Volts to server rack shown in FIG. 22.

In some embodiments, one of the server shelves (e.g., a damaged, or outdated card) may be swapped with a new card 2206. In some embodiments, an individual card may comprise two pins or terminals 2207 through which the card can be electrically connected to the power lines 2204 of the backplane 2202 to receive electric power, and in some cases, establish a communication link. In some such embodiments, the card may comprise a bypass (or reservoir) capacitor 2210 connected between the two terminals 2207 of the new card 2206. In some cases, where the bypass capacitor 2210 of the new card 2206 is discharged prior to connection to the backplane 2202, a large and uncontrolled electric current may flow through and charge the bypass capacitor 2210. In some such cases, such an inrush current may pull down a backplane supply voltage and/or trigger an electric discharge between a pin/terminal of the new card 2206 and a corresponding power line of the backplane 2202. Additionally, the inrush current can cause damage to the connectors due to electric arching, and tripping of the protection circuit such as a breaker or fuse. In some examples, voltage drop in the backplane 2202 may reset a resident card 2208 connected to the backplane 2202 and the electric discharge may damage a connector, a transmission line, and/or an electronic circuit of the system, the backplane 2202, and/or the new card 2206. In some embodiments, the new card 2206 can be a server shelf 2212. Comprising an HSC 2214 configured to prevent the current inrush and thereby the electric discharge and/or voltage drop during an insertion/connection or booting procedure of the server shelf 2212. In some cases, the HSC 2214 may be connected between the pins/terminals 2207 and a circuit 2216 (e.g., a DC-to-DC converter) of the server shelf 2212. In some cases, the HSC 2214 may comprise an HSC switch configured to control an electric connection between a pin/terminal and the circuit 2216. In various implementations, the HSC switch may comprise a transistor an electro-mechanical switch, or another type of switch configured to provide a controlled electric connection between a pin/terminal of the module. In some cases, during a power up period (e.g., during connection process and/or immediately after connecting the module 2212 to the backplane 2202), the HSC 2214 may ramp and regulate the current flow to slowly charge up the bypass capacitor 2210. Once the HSC 2214 (e.g., a controller of the HSC 2214) determines that the current flow is reduced (e.g., when the bypass capacitor 2210 is fully charged), the HSC switch may stop restricting the current to a load (e.g., a load in the server shelf 2212). Further, in some cases, during a power down period (e.g., prior to physically disconnecting and/or during disconnection process, module 2212) HSC 2214 may electrically disconnect the module 2212 from the backplane 2202 and, some cases, discharge the capacitor 2210 to prevent electric arcing when the module 2212 is removed from a rack. In some embodiments, in addition to regulating and/or controlling the in-rush current to the server shelf 2212 during a hot swap procedure, the HSC 2214 may be configured to perform inline current sensing and monitor current flow between the server shelf 2212 and the backplane 2202 during or after connecting the server shelf 2212 to the backplane 2202. For example, the HSC 2214 may function as a power/energy monitor, to allow the user to better understand the power and energy consumption of a card or module. In some such embodiments, the HSC 2214 may function as a circuit breaker configured to disconnect the server shelf 2212 from the backplane 2202 in response to detecting an electric over stress (EOS) event. For example, an over current or short circuit event can be detected through a current sensing element with a high dl/dt profile, and the HSC may open the HSC switch to prevent damage. In some cases, an HSC 2214 may perform inline current sensing and use the HSC switch therein to regulate and control the current.

In some cases, the operational current and voltage of the HSC (e.g., the maximum current and/or voltage that can be safely handled by the HSC) may be limited by the electrical characteristics of the HSC switch. For example, when metal-oxide-semiconductor (MOS) field-effect transistor (FET) is used as the HSC switch, the performance of the HSC may be limited by the damage threshold, drain-source ON-resistance (RDS_on), or other characteristics of the MOSFET.

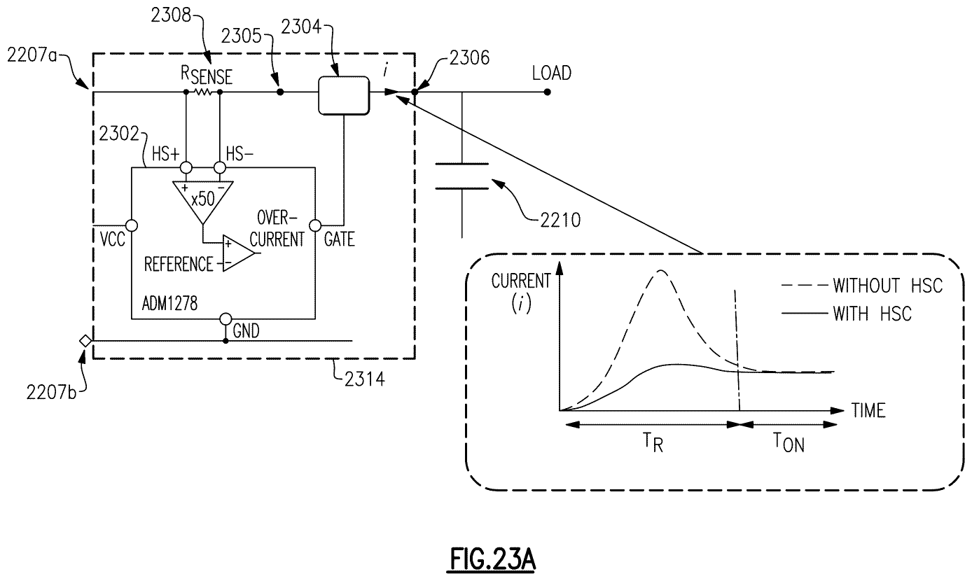

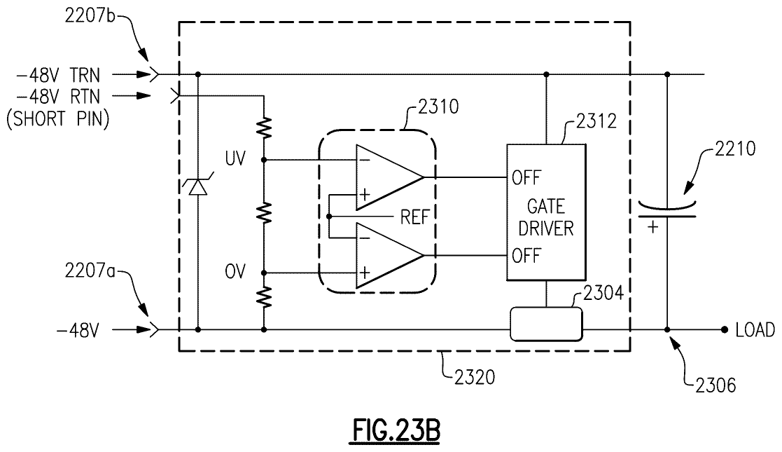

FIG. 23A schematically illustrates an example HSC 2314 comprising a current sensing element 2308 (e.g., a resistor) and a control circuit 2302, and an HSC switch 2304 (e.g., MEMS switch, an electronic switch, as a MOSFET, or a combination thereof) controlled by the control circuit 2302. In some cases, the HSC 2314 may be configured to control electric connection between an input terminal 2207a of a card (or a circuit board) and a load. In some cases, the current sensing element 2308 may be connected between the input terminal 2207a and a first switch terminal/port 2305, and the HSC switch 024 may be connected between the first switch terminal/port 2305 and a second switch terminal/port 2306 electrically connected to the load. In some embodiments, during an inrush current period (TR), when the card is being connected to a backplane and the bypass capacitor 2210 is charged, the control circuit 2302 may measure an inrush current using the current sensing element 2308 and control an electrical connection and/or resistance within the HSC switch 2304 to prevent a current overshoot exceeding a specified limit (e.g., a damage threshold). Once the bypass capacitor 2210 is charged, during an operational period (T_{ON}), in response to measuring a stable current using the current sensing element 2308, the control circuit 2302 may establish an electric connection and/or minimize a resistance within the HSC switch 2304 (e.g., down to an ON resistance) to establish a low resistance electric path between the input terminal 2207a and the load. The inset in FIG. 23A schematically illustrates example variation of current provided from the input terminal 107a to the load and the bypass capacitor 2210 during T_{R} and T_{ON}, in the presence and absence of HSC 2314 indicating that HSC 2314 can eliminate a current overshoot during T_{R} and provide a low-slope transition from 0 to a stable current (e.g., the normal operation current of the corresponding card). As such, in some embodiments, the operation of an HSC may comprise an inrush current regulation mode during TR and a steady state (or ON state) mode during T_{ON}. In some cases, if the T_{R} becomes longer than a specified period, the HSC 2314 may turn off the HSC switch 2304 to prevent damage to the HSC switch 2304. In some cases, the specified time may be determined by the HSC circuit based on a measured current flowing through the HSC switch 2304 and characteristics of the HSC switch 2304. In some embodiments,

In various implementations, the current sensing element may comprise a resistor, a Hall sensor, an anisotropic magneto-resistive (AMR) sensor, a tunnel magnetoresistance sensor (TMR) or another solid state sensor that can generate a signal indicative of electric current transmitted between two voltage nodes (e.g., the first terminal 2207a of a card and an input switch port 2305 of an HSC switch 2304). In some embodiments, the current sensing element may be formed (e.g., co-fabricated) on a common substrate with a portion of the HSC (e.g., the corresponding HSC switch). In some embodiments, the current sensing element may be an external element connected to the control circuit 2302 of the HSC via two conductive lines.

In some embodiments, the HSC switch and the control circuit off of an HSC may be fabricated on a common or different substrates or chips.

FIG. 23B is block diagram of another HSC 2320 configured to control an electric current flowing from a first terminal 2207a of a card to a load based on a voltage provided to the load to ensure valid operation voltage and to protect the load. In some cases, the HSC 2320 may comprise one or more comparators 2310 (e.g., operational amplifiers), and a gate driver 2312 connected to the comparators 2310, and an HSC switch 204 controlled by the gate driver 2312. In some cases, the comparators 2310 (e.g., operational amplifiers), and the gate driver 2312 may be configured to validates input voltage against under voltage (UV) and over voltage (OV) thresholds and control the HSC switch 2304 such to protect the load when the input voltage and thereby the voltage provided to load drops below a minimum operating voltage or rises above a maximum operating voltage of the load.

In some embodiments, using an electronic switch (e.g., a transistor) as an HSC switch may limit the operation of the HSC due to current, voltage, and/or power handling limitation of transistors. As more complex computing, processing, and/or communication system are employed to address rising demand for more computational power, faster communication links, high-capacity storage systems, among other applications, the corresponding server shelves and circuit boards may consume more power and operate at higher currents and/or voltages. As such there is a need for HSC switches that can switch larger currents and voltages compared to electronic transistors and establish a high current conductive path, while providing fast and reliable control over an electric connection between a system and a card.

In various applications, the desired characteristics of an HSC switch (e.g., a current control switch) may include, among other characteristics:
Low ON-resistance (e.g., to reduce insertion loss and heat dissipation when fully on).
Ability to regulate current.
Ability to withstand/dissipate high power during a regulation mode (e.g., inrush current regulation mode).
Fast shutdown for short circuit protection.
Ability to withstand high-voltage surge events.
Small form factor and package size.

In some cases, a MEMS switch may comprise one or more of the above-mentioned desired characteristics. For example, a MEMS switch can have a switching speed in the micro-second range, an operating voltage of 200V or greater, a continuous operating current of 65 mA, continuous per beam-cell, an ON-resistance of 3Ω or smaller, a drive current in nano-Ampere range, a direct current (DC) activation (or deactivation voltage) of 80 V or lower.

In some cases, the several MEMS switches may be combined in parallel or series to form a MEMS switch network having a larger operating voltage and/or current compared to an individual MEMS switch. In some such cases, the design, structure, and/or fabrication process of a MEMS switch may allow fabrication of a plurality of MEMS switches on small a small an area of chip. For example, more than fifty MEMS switches may be fabricated on area equal to less than 1 mm² and connected in parallel to provide an operating current of 3 Amps. As such, operating current of a MEMS-based switch can be scaled at a rate of 3 Amps/mm². In some cases, two or more MEMS switches may be connected in series to provide an operating voltage exceeding that of an individual MEMS switch. For example, five MEMS switches may be fabricated on a single chip to provide an operating voltage equal to greater than 1000 V.

In some embodiments, a MEMS switch or a MEMS switch network may serve as an HSC switch to provide a high-voltage and/or high-current MEMS-based HSC having a first or input switch port/terminal and a second or switch output port/terminal. In some such embodiments, at least one of the MEMS switches of the MEMS-based HSC may comprise a teeter-totter switch comprising one or more features described above with respect to FIGS. 1A to 6C. In some embodiments, electrical connection between the input and output switch port/terminals of the MEMS-based HSC may be controlled by one or more control signal(s) generated by a control circuit of the MEMS-based HSC provided to the MEMS switch or the MEMS switch network. In some embodiments, MEMS-based HSC may be configured to electrically connect the input switch port and output switch port of the MEMS-based HSC during normal operation. In some embodiments, MEMS-based HSC may be configured to electrically isolate the input switch port and an output switch port of the MEMS-based HSC during normal operation. In some embodiments, the MEMS-based HSC may comprise an integrated or external sensor configured to generate a sensor signal indicative of electric current flowing between the input and output ports of the MEMS-based HSC, a voltage difference between the input and output ports of the MEMS-based HSC, and/or a temperature of one or mor MEMS switched on the MEMS-based HSC. In some such embodiments, the control circuit of the MEMS-based HSC may be configured to generate the one or more control signal(s) based at least on part of a sensor signal, which can indicate measure voltage, current, or temperature. In some examples, in response to receiving a sensor signal from a current sensor indicative of a severe over current fault the control system may generate one or more control signals to electrically disconnect the input and output ports of the MEMS-based HSC by opening one or more MEMS switches of the MEMS-based HSC.

In some examples, in response to receiving a sensor signal from a voltage sensor indicative of a severe under or over voltage fault the control system may generate one or more control signals to electrically disconnect the input and output ports of the MEMS-based HSC by opening one or more MEMS switches of the MEMS-based HSC.

In some examples, the sensor or sensing element may be fabricated with the MEMS switch(es) on a common chip.

In some embodiments, a MEMS-based HSC may be configured to limit and/or regulate flow of electric current between the input switch port/terminal and the output switch port/terminal of the MEMS-based HSC during a hot swap event.

In some cases, a MEMS-based HSC may establish, during an ON mode, an electric path between the input and output switch ports having a resistance lower than that of ON-resistance of a Metal-Oxide-Semiconductor (MOS) field-effect transistor (FET).

In some embodiments, a MEMS-based HSC may provide an electric path between the input and output switch ports having a resistance that can be controlled by controlling an activation (or deactivation) voltage provided between a conductive beam and a contact electrode of a MEMS switch (e.g., a teeter-totter switch) used as HSC.

In some embodiments, a MEMS-based HSC may comprise a plurality of MEMS switches each configured to provide an electric path with a resistance different than those provided by other MEMS switches, between two switch ports of the HSC. In some such embodiments, a control circuit of the MEMS-based HSC may control an electric current during TR or regulate a current during TON by providing currents to different ones of the plurality of MEMS switches or to different combinations of the plurality of MEMS switches.

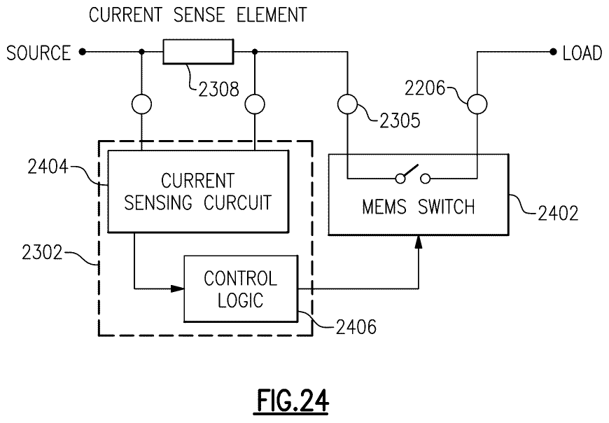

FIG. 24 schematically illustrates a MEMS-based HSC comprising a current sensing element 2308, a MEMS switch 2402 and a control circuit 2302 configured to control the MEMS switch 2402 based at least in part on a signal received from the current sensing element 2308 or a voltage drop along the current sensing element 2308. In some cases, the control circuit 2302 may comprise a current sensing circuit 2404 configured to generate a sensor signal indicative of current measured by or flowing through the sensing element 2308 and a control logic 2406 configured to receive the temperature signal, generate a drive signal based at least in part on the sensor signal, and provide the drive signal to the MEMS switch 2402 to control a state of the MEMS switch 2402. In some cases, the sensor signal may comprise a temperature-based signal, e.g., the current sensing element 2308 may comprise a thermistor in thermal communication with a resistor conducting the current between the source and the MEMS switch 2303. In some embodiments, the MEMS-based HSC shown in FIG. 24 may comprise one or more features described above with respect to HSC 2214 or HSC 2314. For example, a control operation of the control circuit 2302 of the MEMS-based HSC may comprise one or more features of control operation of the control circuit 2302 of HSC 2314 (e.g., with respect to inrush current regulation mode during T_{R} and/or ON mode during T_{ON}).

In some embodiments, the MEMS switch 302 may comprise one or more of the teeter-totter MEMS switches described above with respect to FIGS. 1A-1B, 3A-3C, 4A-4B, 5A-5B, and 6A-6C. In some such embodiments, the MEMS switch 2402 may be configured to disconnect and/or establish a conductive path (e.g., via conductive beam and a contact electrode) between the input switch port 2305 and output switch port 2306 to allow adding, removing, or replacing a component, module, card, or circuit board. In some cases, the state of the MEMS switch may be controlled by applying an activation (or deactivation) voltage between the conductive beam and a control electrode of the MEMS switch.

In some examples, a hot-swap controller that uses a MEMS switch may provide a better performance within a smaller form factor compared to a hot-swap controller that uses a MOSFET switch.

In some cases, the MEMS switch 2402 may comprise a MEMS switch network, or a circuit breaker (e.g., a circuit breaker comprising a MEMS switch or MEMS switch network and an internal control circuit). In some embodiments, the MEMS switch (or the MEMS-based circuit breaker) may be controlled by the control logic 2406 based on one or more sensor signals (e.g., received from the current sensing element 2308, or another sensor). For example, when a magnitude and/or temporal behavior of a current indicated by the sensor signal satisfies a swap condition, e.g., a large current when the card/module protected by the HSC is being connected to a power supply (e.g., back panel), the control logic 2406 may provide a control signal to the MEMS switch 2402 (e.g., to a control electrode of the MEMS switch) to prevent or reduce current rush during the swap process by controlling the resistance between input switch port 2305 and output switch port 2306 (the resistance between a contact electrode and the conductive beam of the MEMS switch 2402). For example, with reference to FIG. 23A, during the transition period TR, control logic 2406 may gradually decrease the resistance between the source and the load from a high value to a low value to provide a smooth transition of current from near zero to a steady state current. In some cases, when the magnitude and/or temporal behavior of a current indicates completion of a swap the controller may reduce the resistance of the MEMS switch 2402 to a minimum value to establish the conductive path between the source and load.

In some embodiments, where the MEMS switch 2402 comprises a single MEMS switch (e.g., a teeter-totter switch), the control logic may control the resistance between a front end of the conductive beam and a front contact electrode of the MEMS switch 2402 by controlling the control voltage (deactivation voltage in this case), which in turn controllably varies the electrostatic force applied on the conductive beam of the MEMS switch. In some of these embodiments, the control logic 2406 may control an ON resistance of the electric path established through the MEMS switch during T_{R} and T_{ON} to provide inrush current regulation (e.g., a low-slope transition from zero or near zero to a stable electric current flow and) steady state protection (e.g., disconnecting the electric path when an EOS is detected). With reference to FIG. 9C, the resistance of a conductive path established between the post 123 (or the conductive beam 107) and the front contact electrode 109 by the teeter-totter switch 900 can be controlled by controlling the volage (Vin) provided to the conductive beam 107. In some cases, a resistance of the electrical connection between the second end 118 the conductive beam 107 and the front contact electrode 109 can be proportional to the electrostatic force applied on the conductive beam 107. The electrostatic force applied on the conductive beam 107 can be proportional to the square of the voltage difference between the beam 107 and the control electrode 110. As shown in FIG. 9C, decreasing the control voltage (e.g., the deactivation voltage or the difference between Vᵢₙ and V_{c1}) may increase the resistance (ON resistance). For example, when Vᵢₙ is substantially zero, the control voltage between the conductive beam 107 and the front control electrode 110 can be larger than a threshold deactivation voltage causing the resistance (R) of the conductive electric path established through the MEMS switch to be very small (e.g., less than 10 ohms or less than 5 ohms, or smaller values). Increasing Vᵢₙ above zero decreases the control voltage between the conductive beam 107 and the front control electrode 110, which may in turn increase (e.g., nonlinearly increase) the R. Thus, FIG. 9C shows that the resistance of an electric path established via a MEMS switch (e.g., MEMS switch 2402) can be controlled by controlling the deactivation voltage provided to the MEMS switch (e.g., between the conductive beam and from control electrode).

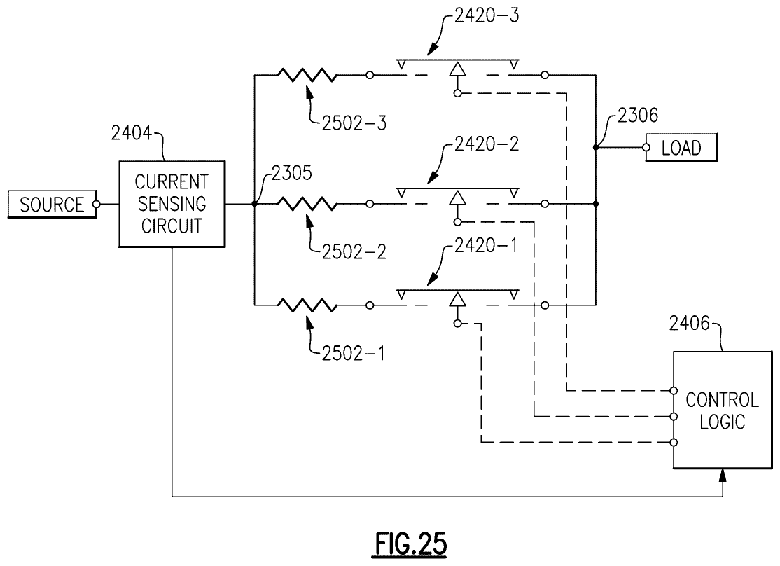

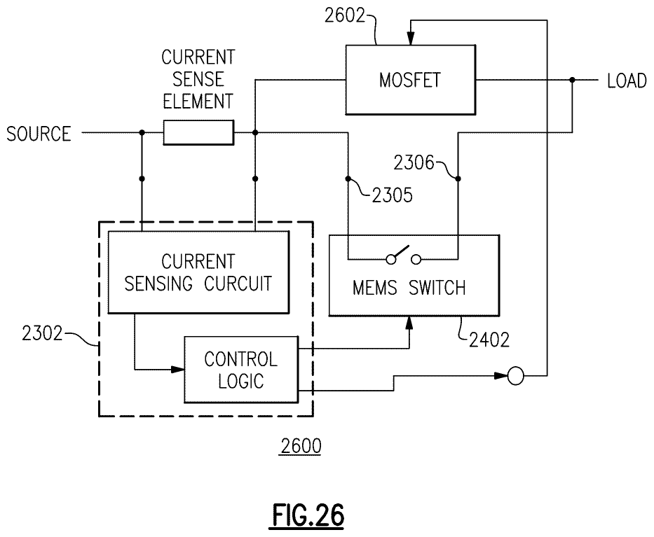

FIG. 25 schematically illustrates a MEMS-based HSC having three MEMS switches 2420-1, 2420-2, 2420-3, connected in parallel between the input and output switch ports 2305, 2306, of the MSC and configured to provide variable resistance. In some cases, each MEMS switch may be connected to the input switch port 2305 via a different resistor. For example, the first resistor 2502-1 connecting the first MEMS switch 2420-1 to the input switch port 2305 can be greater than the second resistor 2502-2 connecting the second MEMS switch 2420-2 to the input switch port 2305, and the second resistor 2502-2 connecting the second MEMS switch 2420-2 to the input switch port 2305 can be greater than the third resistor 2502-3 connecting the third MEMS switch 2420-3 to the input switch port 2305. As such, the resistance of the conductive path between the input and output switch ports 2305, 2306, can be changed depending on which MEMS switch or which combination of the MEMS switches are turned ON.

In some cases, the resistance of the conductive path between the input and output switch ports 2305, 2306, can be binary weighted and combined with a decoder in the control logic 2406 to create a digitally programmable resistance value.

In some embodiments, a solid-state switch (e.g., a MOSFET switch) may be connected in parallel with a MEMS switch in an HSC. In some such embodiments, the solid-state switch may be used during a T_{R} and the MEMS switch may be used during T_{ON}. In other words, during a current regulation period (during the T_{R}), the corresponding control circuit may activate the MEMS (put the MEMS switch in the OFF state) switch and turn on the solid-state switch, and during a steady state period (during T_{ON}) the corresponding circuit may turn off the solid-state switch and deactivate the MEMS switch (put the MEMS switch in ON state) to establish the conduction path through the MEMS switch (e.g., to reduce power loss by using the MEMS-based conduction path that can have lower resistance compared to a transistor-based conduction path). In some embodiments, the control circuit (e.g., control logic 2406) may keep the solid-state switch on during both the regulation period and the steady state period. In some such embodiments, the solid-state switch may regulate the current during the T_{R} and stay on during a steady state (during T_{ON}) to further reduce the resistance between the source and the load by providing an additional conduction path parallel with the conduction path established via the MEMS switch.

FIG. 26 Schematically illustrates an HSC that comprises a MEMS switch 2402 (or MEMS switch network) connected in parallel with a solid-state switch (e.g., a transistor such as MOSFET) 2602 between the input and output switch ports 2305, 2306 of the HSC. In some cases, the transistor switch 2602 may be controlled by the same control circuit 2302 that controls the MEMS switch 2304 such that the operation of the solid-state switch 2602 and the MEMS switch 2402 can be temporally aligned to allow a smooth transition between conductive paths established by the solid-state switch 2602 and the MEMS switch 2402. In some embodiments, when the HSC 2600 is protecting a card (module) during a swapping process, e.g., connecting the card (module) to a back panel, the control circuit 2302 may control the solid-state switch 2602 to regulate current flow during the inrush current period (T_{R}) while keeping the MEMS switch 2402 in OFF state. Once a steady current is established, during the state period, the MEMS switch 2402 may deactivate the MEMS switch 2402 to establish a low resistance electric connection between the back plane and the card (module). In some cases, the control circuit 2302 may maintain the solid-state switch 2602 in ON state (conductive or low resistance state) during the steady state period such that the steady current is conducted through both the MEMS switch 2402 and the solid-state switch 2602. Advantageously, maintaining the solid-state switch 2602 in ON states, along with the MEMS switch 2402, during the steady state period, not only reduces the total resistance of the electric path established between back panel and the module/card, but also allows the solid-state switch 2602 to control the current when the MEMS switch has to be activated (transition from ON to OFF state) to avoid formation of an arc between the contact pads of the MEMS switch when the contact pads are disconnected.

In some embodiments, the HSC 2600 may comprise one or more features described above with respect to circuit breakers 2100, 2121, and 2500 in FIGS. 18, 19 and 21, respectively. For example, the HSC 2600 may comprise at least a portion of the circuit breaker 2500 including but not limited to the MEMS switch 2303, the protective switch 2102, the actuation control circuit 2504b, protective switch control 2504c, and the current sensor 2309. The MEMS switch 2303, the protective switch 2102, and the current sensor 2309, may serve as the MEMS switch 2402, solid-state switch 2602, and the current sense element.

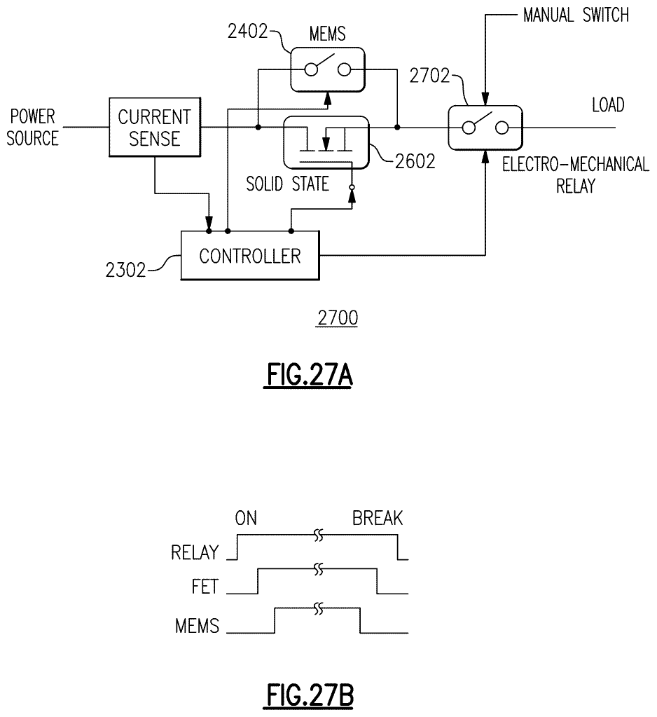

In some embodiments, an electro-mechanical relay may be included in the HSC 2600 to provide additional protection in particular to handle emergency scenarios where the card (module) has to be disconnected from a high voltage supply in the back panel and the MEMS switch 2402 and/or the solid-state switch 2602 are not capable to break the circuit. FIG. 27A schematically illustrates an HSC 2700 that in addition to the controller, 2302, MEMS switch 2402, the solid-state switch 2602, and the current sense, includes an electro-mechanical relay 2702 configured to open an electrical path between the power source (e.g., back panel) and the load (e.g., the main circuitry of the card or module protected by the HSC 2700). In various implementations, the electro-mechanical relay 2702 may be controlled by one or both of a manual switch and the controller 2302.

FIG. 27B schematically illustrates non-limiting examples of the control pulses that may be provided by the control circuit or controller 2302 to the MEMS switch 2402, the solid-state switch 2602, and the electro-mechanical relay 2702, depicting temporal variation of the corresponding control signals (e.g., voltages) between ON and OFF levels. In some embodiments, the controller 2302 may be configured to turn on the solid-state switch 2602 upon connecting a card (module) protected by the HSC 2700 to the power source to regulate the rush current until a steady state is established and maintain the solid-state switch 2602 in ON state until MEMS switch 2402 is activated. In some cases, after the steady state current is established the MEMS switch may contribute to reducing the resistance of the electric path between the power sources and during the activation of the MEMS switch 2402 (when MEMS switch is in OFF state), the solid-state switch may control the current to prevent arcing between the contact pads of the MEMS switch 2402 as they are being separated. In some embodiments, the controller 2302 may be configured to deactivate the MEMS switch 2402 when a steady state current is established and maintain the MEMS switch 2402 in ON state during an operational period of the card (module). In some embodiments, the controller 2302 may be configured to turn on the electro-mechanical relay 2702 prior to turning on the solid-state switch 2602 and maintain the electro-mechanical relay 2702 in ON state during connection/disconnection of the card (module) to/from the power source.

### Protection Device for High Voltage Systems Based on MEMS Switch

Various high voltage systems such as data centers, grid energy storage systems and plasma systems (e.g., plasma-based processing systems such as plasma cleaning systems, plasma etching chambers, corona systems, and the like), may function by forming and sustaining a plasma, e.g., between two plasma electrodes during an operational period and exposing a target region (e.g., surface of an object) to be processed. Various plasma processing procedures may be performed by exposing the target regions, without limitation, to etch or clean the target region, deposit charge on the target regions, and stimulate a reaction in the target region, among other processes. In some embodiments, the plasma system, e.g., an alternating current (AC), may comprise a plasma power supply (PPS) configured to provide electric power (e.g., in the form of a radio frequency electric field) to a region or volume (e.g., a plasma chamber) to ignite the plasma and sustain the plasma during the operational period. In some examples, the PPS may apply a high voltage (e.g., a large constant and/or alternating electric field) between the two plasma electrodes and provide sufficient ions and electrons to sustain the resulting plasma. In some examples, the electric power provided by the PPS to the plasma can be from 1 kilowatt (kW) to 1 Megawatt (MW), or larger or smaller values. As described herein, one of the two electrodes of a plasma system, e.g., an alternating current (AC) plasma system, may be grounded.

In some cases, during the operational period of the plasma system, when the plasma is sustained between the two plasma electrodes, an electric arc may be formed through the plasma, e.g., between the two plasma electrodes. In some cases, the electric arc may comprise a low resistance electric path that may be initiated by a perturbation (e.g., a sudden local change in plasma charge density) and may be sustained by a large electric current drawn from the PPS. In some cases, such electric charge can damage the sample processed by the plasma system and, in some cases, the PPS. In some cases, a PPS may comprise an arc detection and extinguishing circuit configured to detect an electric arc within a short period after the arc is initiated and disconnect an electric link through which the arcing electric current transmitted through the plasma is established. In some cases, the electric link can be an electrical connection/line between a plasma electrode of the plasma system and the PPS or an electric path between one of the electrodes of the plasma system and an electric ground. In some embodiments, the plasma system may comprise a safety or arc switch that provides a controllable electric link between one of the electrodes and the PPS or electric ground. In some such embodiments, upon detection of an arcing event, the arc detection and extinguishing circuit may be configured to generate and transmit a control signal to the arc switch to turn the arc switch OFF and thereby disconnect the electric link through which the spark current flows. According to various embodiments disclosed herein, the arc detection and extinguishing circuit includes a protection device configured to be electrically connected between a plasma chamber and a power supply for delivering power to the plasma chamber. In some embodiments, the protection device includes a micro-electro-mechanical systems (MEMS) switch module. The arc detection and extinguishing circuit additionally may include an electrical over-stress (EOS) sense device electrically connected to the plasma chamber and configured to detect an EOS event in the plasma chamber. A controller can be communicatively coupled to the protection device and the EOS sense device is configured such that upon sensing or detecting the EOS or arcing event in the plasma chamber, the controller causes the MEMS switch module to form an open circuit to interrupt power from the power supply to the plasma chamber. In some cases, the EOS sense device mat be configured to detect an early indication of formation of an electric arc (e.g., a current change) and the controller may cause the MEMS switch module to form an open circuit to prevent formation of an arc withing the chamber. In some cases, after a specified wait period, the plasma system may be configured to reestablish the electric link and re-ignite/sustain the plasma, by turning the arc switch ON. In some cases, controller may detect the arcing event in less than 2 microseconds, less than 5 microseconds, or less than 10 microseconds. Upon detection of the arcing event the controller may use the MEMS switch module to extinguish the electric arc in less than 2 microseconds, less than 5 microseconds, or less than 10 microseconds.

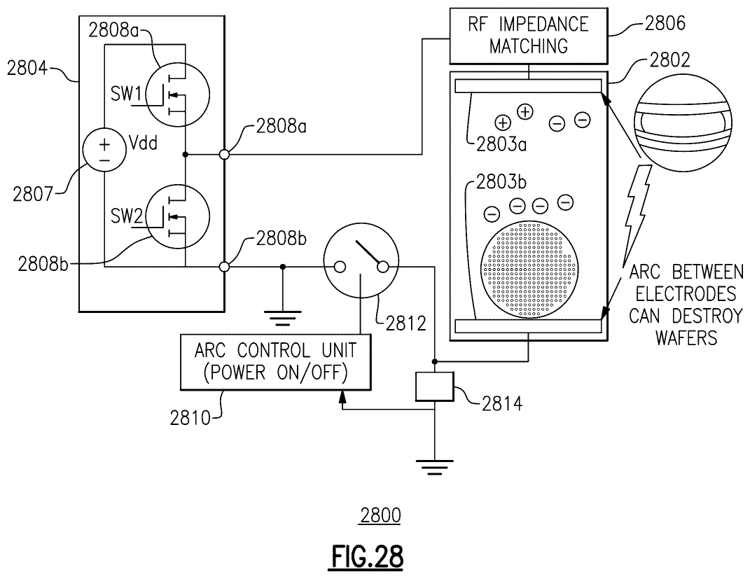

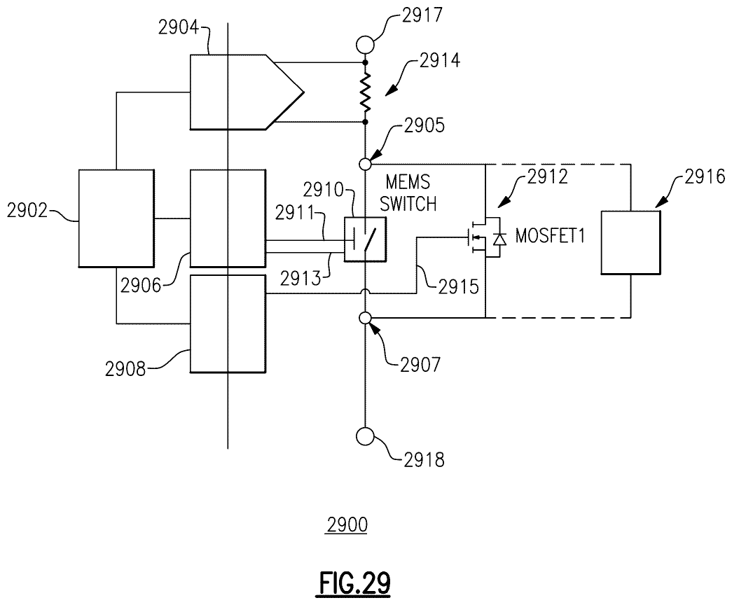

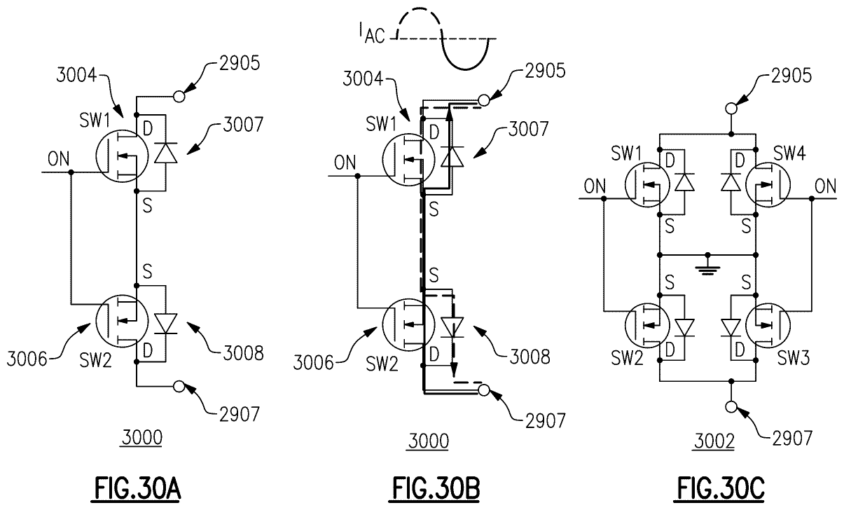

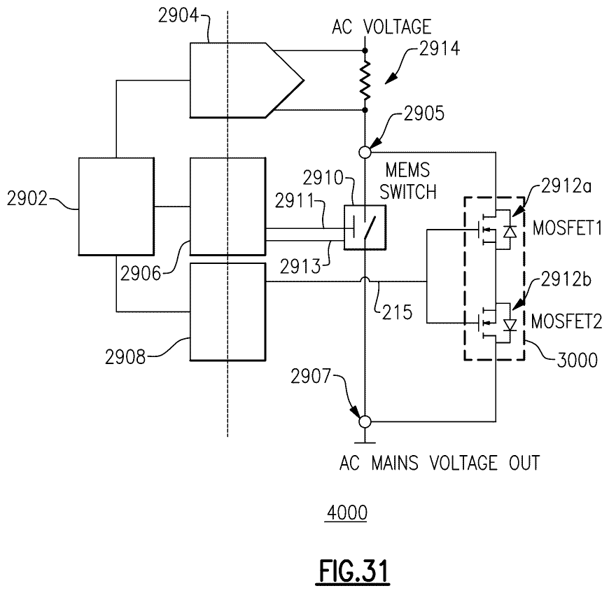

FIG. 28 schematically illustrates an example plasma system 2800 comprising a PPS 2804, a plasma chamber 2802, an arc detection and extinguishing circuit 2810, and an arc switch 2812. In some embodiments, a first terminal (or port) 2809a of the PPS 2804 may be electrically connected to first plasma electrode 2803a in the plasma chamber 2802 and a second terminal (or port) 2809b of the PPS 2804 may be electrically connected to a second plasma electrode 2803b in the plasma chamber 2802 via a controllable electrical connection provided by the arc switch 2812. In some such embodiments, the second terminal 2809b of the PPS 2804 may be electrically connected to an electric ground and the arc switch 2812 may be connected to the second plasma electrode 2803b and the electric ground (and thereby the second terminal 2809b). In some embodiments, the arc detection and extinguishing circuit 2810, also referred to as arc control unit, may be configured to control the arc switch 2812 and thereby the electric connection between the second terminal 2809b of the PPS 104. In some cases, the arc detection and extinguishing circuit 2810 may be configured to control the arc switch 2812 based on a sensor signal received from an EOS sense device configured to detect formation an electric arc, or an early indication of formation of an electric arc, in the plasma chamber 2802. In some embodiments, the EOS sense device can be electrically or electromagnetically coupled to the plasma chamber 2802 or a plasma formed therein. In some embodiments, the EOS sense device may comprise a current or voltage measurement device 2814 electrically connected to the second plasma electrode 2803b, e.g., between the second plasma electrode 2803b and the electric ground. In some cases, the current or voltage measurement device 2814 may be configured to provide a sensor signal indicative of a current received by the second plasma electrode 2803b or a voltage of the second plasma electrode 2803b with respect to electric ground or another reference potential.

In various implementations, PPS may comprise one or more of a direct current (DC) source, a pulsed DC source, a medium frequency source (MF) source, a bipolar source, a radio frequency (RF) source and a very-high frequency (VHF) source.

In some embodiments, when the arc detection and extinguishing circuit 2810 detects an EOS event such as an arcing event in the plasma chamber 2802, via the EOS sense device, it may generate and transmit a switch control signal to the arc switch 2812 to disconnect the second plasma electrode 2803b from the second terminal 2809b and/or electric ground and thereby interrupt power from the PPS 2804 to the plasma chamber 2802 to extinguish the plasma.

In some embodiments, the PPS 2804 may comprise a voltage supply 2807 and an internal electronic switching circuit configured to provide a controllable connection between the voltage supply 2807 and one or both the first and second terminals 2809a, 2809b. In some cases, the voltage provided by the voltage supply 2807 can be from 1000 to 1500 V, from 1500 to 2000 V, from 2000 V to 3000 V, or a value in a range defined by any of these values or larger values.

In some such embodiments, the electronic switching circuit of the PPS 2804 may comprise one or more electronic switches, each controlled by a gate control signal received from a controlled circuit of the PPS 2804. In the example shown, the PPS 2804 includes two electronic switches 2808a, 2808b configured to control electric connection between the voltage source 2807 and the PPS 2804. In some examples, an electronic switch of the PPS 2804 may comprise a transistor (e.g., a field-effect transistor).

In some cases, the arc switch 2812 may and/or the electronic switches 2808a, 2808b may comprise a wide bandgap switch such as a silicon carbide (SiC)-based switch (e.g., a SiC FET).

In some cases, the electronic switching circuit may comprise an internal arc detection mechanism or can be connected to the detection and extinguishing circuit 2810, and configured to receive a signal indicative of an arcing event in the plasma chamber 2802, and in response to receiving the signal, to disconnect the voltage supply 2807 from one or both of first and second plasma electrodes 2803a, 2803b.

In some embodiments, the arc detection and extinguishing circuit 2810 may use a current sensing element 2814 to measure a current transmitted through the plasma chamber 2802 and in response to determining that the measured current exceeds a specified threshold value, generate a signal (e.g., a control signal) indicative of detection of an arcing event. In some embodiments, the arc detection and extinguishing circuit 2810 may additionally use a voltage sensing element to measure an electric potential difference between the first and second plasma electrodes 2803a, 2830b, and generate a signal (e.g., a control signal) indicative of detection of an arcing event based on the measured current and voltage (e.g., by comparing the measured voltage and current or determining that a ratio between the current and voltage, e.g., conductance of the plasma, exceeds a specified threshold).

In some cases, the arc detection and extinguishing circuit 2810 may use one or both of measured voltage and current to predict the occurrence of an arcing event and generate a signal (e.g., a control signal) indicative of a predicted arcing event.

In some cases, upon detection of an arcing event or predicting an arcing even the arc detection and extinguishing circuit 2810 may transmit a control signal to the arc switch 2812 to turn off the arc switch 2812.

In some cases, upon detection of an arcing event or predicting an arcing even the arc detection and extinguishing circuit 2810 may transmit a first control signal to the arc switch 2812 to turn off the arc switch 2812 (disconnect the second plasma electrode 2803b from the electric ground and the second terminal 2809b) and a second control signal to the internal electronic switching circuit to disconnect the voltage source 2807 from the first and second terminals 2809a, 2809b.

In some embodiments, when the PPS is a DC supply, upon detecting an arcing even the arc detection and extinguishing circuit 2810, may reverse the voltage between the first and second terminal 2809a, 2809b.

In some embodiments, it is desired to reduce time between detection of an arcing event and disconnecting the second electrode 2803b from the second terminal 2809b and/or the electric ground and additionally reduce the chamber down time by quickly re-connecting the plasma second electrode 2803b to reestablish the plasma. For example, in some cases, the down time can be less than 20 us for a 6 kHz pulsed DC PPS.

In some cases, the arc switch 2812 may be configured to extinguish a plasma in the plasma chamber 2802 by disconnecting the plasma chamber 2802 (e.g., the second plasma electrode 2803b of the plasma chamber 2802) from the PPS 2804 and/or electric ground in less than 5 μs, than 3 μs, than 1 μs, than 0.5 μs, than 0.01 μs, or a value in a range defined by any of these values, or faster. In some such cases, the voltage provided by the PPA 104, and thereby switched by the arc switch 2812 can be 1500V-1700V or a larger value. In some such cases, during a normal operation period the electric current flowing through the plasma chamber 2802 can be greater than 20 Amps, greater than 40 Amps, greater than 50 Amps, greater than 60 Amps or a value in range defined by any of these values or a larger value.

As such, in some cases, to effectively protecting the PPS 2804 and//or a sample processed by or exposed to the plasma, the switching circuit of the PPS 2804 and/or arc switch 2812 should be configured to transmit a large electric current during an operational period of the plasma system 2800, with minimal dissipation, and to switch off a high voltage within a short period (e.g., 1 microsecond or shorter) after receiving a signal indicative of an ongoing or predicted arcing event from the arc detection and extinguishing circuit 2810.

In some embodiments, the arc switch 2812 may comprise a MEMS switch (e.g., a high voltage MEMS switch) configured to conduct high current levels associated with an operational period of the plasma system 2800 and disrupt an electric connection between the second plasma electrode 2803b and the PPS 2804 and/or electric ground, in response to detection of current larger than a threshold level (e.g., by a current sensor 2814), which may indicative of an occurrence of an electric arc in the plasma chamber 2802. In some cases, when deactivated, the MEMS switch may be configured to establish a low resistance electric connection to transmit an electric current greater than 20 Amps, greater than 40 Amps, greater than 50 Amps, greater than 60 Amps or larger values. In some cases, the resistance of the electric connection provided by the MEMS switch can be lower than that of an electronic switch (e.g., a SiC transistor) by factors ranging from 3 to 5, from 5 to 7, from 7 to 10, from 10 to 15, or any ranges formed by these values or larger or smaller values. As such, in some cases, electric power loss during an operational period of the plasma system 2800 can be smaller (e.g., by a factor 5, 20, 15, or greater) when a MEMS switch is used to control electric connection of the plasma chamber 2802 instead of an electronic switch. In some examples, the ON resistance of a SiC FET can be 45 mΩ compared to ON resistance of MEMS switch 4 mΩ. Additionally, the capacitance of MEMS switch can be smaller than capacitance of an electronic switch (e.g., a SiC FET) by factors ranging from 50 to 100, from 100 to 200, from 200 to 1300 or any ranges formed by these values or larger or smaller values. As such, in some cases, the MEMS switch may support a faster switching time.

TABLE 1 illustrates typical ranges for parameters relevant to the operation of the arc switch 2812 for a MEMS switch, a solid-state relay (e.g., a transistor-based relay), and an electromagnetic relay, further highlighting the super performance of the MEMS switch for serving as the arc switch 2812.

TABLE 1

| | EM Relay | | Solid State | | HV MEMS | |
|---|---|---|---|---|---|---|
| Parameter | (EMR) | | Relay | | Switch | |
| On-Resistance | <100 | mΩ | <230 | mΩ | <1 | mΩ |
| switching time | >20 | ms | >1 | ms | <10 | μs |
| Leakage current | 75pA@200V | | 0.4mA@200V | | 75pA@200V | |
| Switching | <30 | million | <100 | million | >3 | billion |
| operations | | | | | | |

In some cases, the arc switch 2812 may comprise one of the MEMS switches (e.g., a teeter-totter switch) described above with respect to FIGS. 1-21. For example, the arc switch 2812 may comprise the teeter-totter switches described with respect to FIGS. 1B, 4A-4B, 5A-5B. In some embodiments, the arc switch 2812 may comprise one or more MEMS switches connected in series, to switch higher voltages, connected in parallel, to transmit lager currents, or forming a switch network comprising a plurality of MEMS switches connected in parallel and series to switch higher voltages and transmit lager currents. For example, the arc switch 2812 may comprise the switch configurations described with respect to FIGS. 7 and 8.

In some embodiments, a MEMS switch (e.g., a teeter-totter MEMS switch) may rapidly switch electric power delivery from the PPS 2804 to the plasma chamber 2802, by switching 1000's of volts. In some examples, a MEMS switch can be more compact and occupy a smaller area on a chip compared to a solid-state switch.

In some cases, a spark gap, e.g., a MEMS-based spark gap, may be used, in addition to the MEMS switch to shunt the electric current to ground when an electric arc is formed in the plasma chamber 2802. In some examples, the MEMS switch and the MEMS-based spark gap may be at least partially co-fabricated (e.g., on a common substrate) and/or co-packaged. In some cases, the MEMS-based spark gap may comprise a structure for example a microstructure fabricated (e.g., micro fricated) on a substrate (e.g., a silicon substrate).

In some embodiments, the spark gap may be additionally used to log arcing events in a memory and later use the stored arcing events for predictive maintenance and, in some cases, adjusting a parameter of the plasma system 2800 to reduce future arcing events.

In some embodiments, when the arc switch 2812 comprises a MEMS switch, the plasma system 2800 may comprise a MEMS control circuit configured to control the MEMS switch based at least in part signal received from the arc monitoring and extinguishing circuit 2810. In some cases, arc monitoring and extinguishing circuit 2810 may comprise the MEMS control circuit. In some such embodiments, the MEMS control circuit may comprise one or more features described above with respect to MEMS control circuit 1801 in FIG. 18, MEMS control circuit 1301 in FIG. 13, and MEMS control circuit 1101 in FIG. 11A and MEMS control circuit 1001 in FIG. 10. In some cases, the MEMS control circuit may comprise one or more isolator circuits configured to electrically isolate the MEMS switch (the arc switch 2812) from the arc monitoring and extinguishing circuit 2810 and other circuits and modules that may be electrically connected to the MEMS switch to monitor the MEMS switch, a current transmitted through the switch, and/or a voltage across the MEMS switch. In some cases, the arc switch 2812 may comprise a current sensing element configured to measure a current passing through the MEMS switch therein and the MEMS. In some cases, the current sensing element may be electrically connected to one or both the MEMS control circuit and the arc monitoring and extinguishing circuit 2810. As described above with respect to FIGS. 20 and 21, in some cases, one or more electronic switches (e.g., FET transistors) may be connected in parallel with the arc switch h (e.g., MEMS switch) 2812 to protect the contact surfaces of the MEMS switch 2812 during transitions between ON and OFF states (similar to protective switch 2102 in FIGS. 20 and 21).

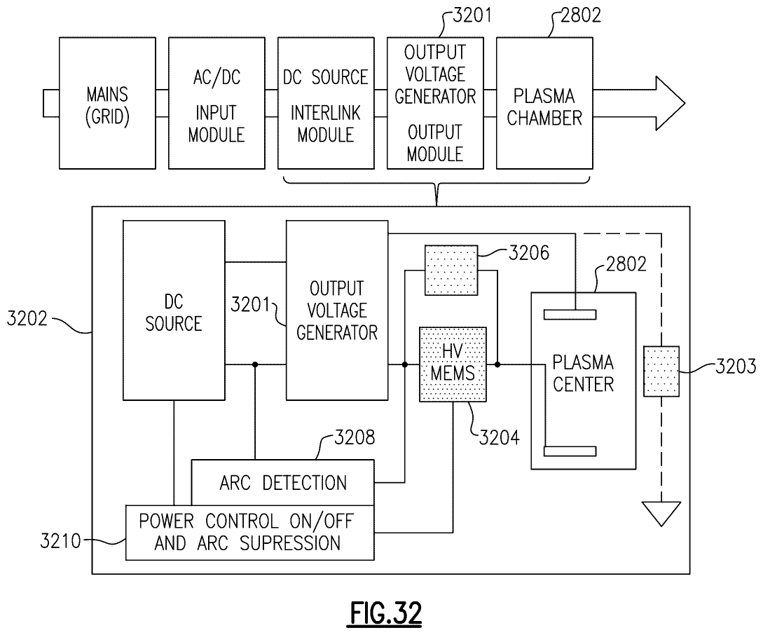

FIG. 29 schematically illustrates an example MEMS-based circuit breaker 2900 that may be used in the plasma system 2800 to protect the plasma system 2800 against arcing events using a MEMS switch 2910 serving as the arc switch 2812. In some cases, the MEMS-based circuit breaker 2009 may be configured to control a connection between a first voltage node 2917 (e.g., the second plasma electrode 2803b of the plasma chamber 2802) and a second voltage node 2918, e.g., the PPS 2804 (e.g., the second terminal 2809b of the PPS 2804) and/or electric ground. In some embodiments, the MEMS-based circuit breaker 2900 may comprise a system controller 2902 configured to send control signals and receive sensor signals, a supply circuitry 2906 configured to generate and provide an isolated drive signal 2911 to the MEMS switch 2910, an isolated analog-to-digital converter (ADC) 2904 configured to convert a current/voltage measurement across a current sensing element 2914 to a digital signal and transmit the digital signal to the system controller 2902.

In some embodiments, the MEMS-based circuit breaker 2900 may further comprise a protective electronic switch 2912 (e.g., a field-effect transistor, FET) connected in parallel with the MEMS switch 2910 and an isolated gate driver 2908 configured to generate and provide a gate signal to protective electronic switch 2912. In some embodiments, the protective electronic switch 2912 may be switched ON e.g., by a gate signal 2915 provided to the gate of the protective switch 2912, to establish a low resistance electrical path parallel to the MEMS switch 2910 to reduce an amount of current passing through a conductive junction of the MEMS switch 2910 when transitioning from the ON state to the OFF state, or to reduce voltage across a contact gap when transitioning from OFF to ON state. As such, in some embodiments, the isolated gate driver 2908 may be configured to turn on the protective electronic switch 2912 during activation and deactivation periods of the MEMS switch 2910 when the electric current transmitted through the MEMS switch 2910 is changing from zero or near zero to a steady state value or vice versa. In some embodiments, a diode may be connected in parallel with the FET 2912 (e.g., to improve circuit performance and protect the corresponding FETs. In some cases, this diode may reduce switching losses, enhance reverse recovery performance, and/or protect against overvoltage). The diode may be separately provided or may be built-in by a PN junction formed by a drain/channel junction or a source/drain junction of the FET 2912.

In some embodiments, the current sensing element 2914 may comprise a resistor connected in series with the MEMS switch 2910 and the system controller 2902 may process a digital signal received from the isolated analog-to-digital converter 2904 to determine the magnitude of the current passing through the MEMS switch 2910.

In some embodiments, the supply circuitry 2906 may be configured to receive a temperature signal 2913 near the MEMS switch 2910 (e.g., integrated with the MEMS switch) and transmit an isolated temperature signal to the system controller 2902.

In some embodiments, the MEMS-based circuit breaker 2900 may include a spark gap 2916 (e.g., a MEMS-based spark gap) connected in parallel between input and output switch ports 2905, 2907 and configured to protect the MEMS switch 2910 from an EOS event.

In some embodiments, the MEMS switch 2910 may comprise any one of the teeter-totter switches described above with respect to FIGS. 1A-1B, 2A-2C, 3A-3C, 4A-4B, 5A-5B, and 6A-6C.

In some embodiments, the MEMS-based circuit breaker 2900 may serve as the arc switch 2812, the arc detection and extinguishing circuit 2810, and the EOS sense device (e.g., the current or voltage measurement device 2840 of the plasma system 2800). For example, the current sensing element 2914 may serve as EOS sense device and the system controller 2902 may generate and transmit activation and deactivation signals to the supply circuitry 2906 to turn on (deactivate) or turn off (activate) the MEMS switch. In some cases, the system controller 2902 may use a signal received from the current sensing element 2914 (via the isolated ADS) to determine that a current passing through the sensing element 2914, thereby trough the MEMS switch 2910 and the plasma chamber 2802, exceeds a specified threshold, and in response to such determination generate an activation signal to turn on (open) the MEMS switch 2910 and electrically disconnect one of the plasma electrodes. In some examples, in response to determining that a current passing through the sensing element 2914 exceeds a specified threshold, to electrically disconnect one of the plasma electrodes, the system controller 2902 may first generate a first gate signal 2915 to turn on the protective electronic switch 2912, then generate an activation signal to open the MEMS switch 2910, and finally generate a second gate signal 2915 to turn off the protective electronic switch 2912.

In some embodiments, when the voltage supply source 2807 comprises an alternating current (AC) voltage source (instead of a DC or pulsed source), the single protective electronic switch 2912 may not provide electric connection between input and output switch ports 2905, 2907, during the entire voltage cycle, during which the potential difference between input and output switch ports, 2905, 2907, is reversed. As such, during a transition period (e.g., form ON to OFF state or form OFF to ON state), the MEMS switch 2910 may not be protected by an auxiliary conductive path between the input and output switch ports, 2905, 2907.

In some embodiments, to protect the MEMS switch 2910 when connecting or disconnecting an AC voltage supply and the plasma chamber 2802, the MEMS control circuit may comprise two protective electronic switches connected in series between input and output switch ports, 2905, 2907. In some cases, the two protective electronic switches may comprise two FETs connected in series in a back-to-back arrangement such that body diodes of the FET and the second FET have opposite polarities.

FIG. 30A schematically illustrates a dual FET switch 3000 comprising two FETs 3004, 3006 that may be connected in series between the input and output switch ports, 2905, 2907, of the MEMS switch 2910 (FIG. 2900). In some cases, the gates of the two FETs 3004, 3006, may be electrically connected to a common output of the isolated gate driver 2908 to receive a common gate signal 2915 configured to turn on both FETs 3004, 3006, during activation and/or deactivation period of the MEMS switch 2910 and turn off both FETs 3004, 3006, after a specified period after the MEMS switch 2910 is opened or closed.

In some cases, a diode may be connected in parallel with each one of the FET 3004 and FET 3006 and may be configured to conduct a current in a direction opposite to a current direction in the corresponding FET when the FET is turned on. The diode may be separately provided or may be built-in by a PN junction formed by a drain/channel junction or a source/drain junction of the FETs 3004, 3006.

FIG. 30B schematically illustrates conductive paths and current follows established by the FETs 3004, 3006, in the dual FET switch 3000, when both FETs 3004, 3006, are turned on. As shown, during a first period, the conductive path between the input and output switch ports, 2905, 2907 is established by the first FET 3004 and the second diode 3008 in the forward direction and during a second period, the conductive path between the input and output switch ports, 2905, 2907 is established by the first diode 3007 in the forward direction and the second FET 3006.

In some cases, a FET quartet 3002 (shown in FIG. 30C) may be used to protect the MEMS switch 2910. In some cases, the FET quartet 3002 may comprise two pairs of FETs and diodes, where each pair comprises the arrangement shown in FIG. 30A and features described with respect to FIG. 30B. The two pairs may be connected in parallel between the input and output switch ports, 2905, 2907, to establish conductive paths with lower resistivity and to support larger electric current flow between the input and output switch ports, 2905, 2907, to allow the MEMS switch 2910 change its state without being damaged.

FIG. 31 schematically illustrates, a MEMS-based control circuit 4000 configured to control connection between an AC voltage node (e.g., the second plasma electrode 2803b of the plasma chamber 2802) and the PPS 2804 and/or electric ground, using a protection device comprising the MEMS switch 2910. In some cases, the MEMS-based control circuit 4000 may comprise one or more features described above with respect to the MEMS control circuit 2900. However, since the MEMS-based control circuit 4000 is connected to an AC voltage node, it comprises two protective electronic switches 2912a, 2912b configured to protect the MEMS switch 2910. In some cases, the configuration of the two protective electronic switches 2912a, 2912b corresponding diodes, and their connection to the two protective electronic switches 2912a, 2912b may comprise one or more features described above with respect to the FET pair 3000 (FIGS. 3A, 3B). In some cases, the FET quartet 3002 (FIG. 3C) may be used to protect the MEMS switch 2910 in the MEMS-based control circuit 4000.

FIG. 32 schematically illustrates an example plasma system 3202 comprising a plasma power supply system. In some embodiments, the plasma power supply system may comprise a DC source and an output voltage generator configured to provide electric power to a plasma chamber to generate and sustain in the plasma chamber. In some cases, the plasma chamber 2802 may be configured to process (e.g., etch) wafers, substrates (e.g., electronic substrates), or other samples. In some cases, the plasma chamber may be electrically connected to the output voltage generator 3201 (e.g., a DC, a pulsed or an AC voltage generator such as an RF voltage generator) by a high voltage MEMS switch 3204 configured to disconnect the plasma chamber 2802 from the output voltage generator 3201 to protect the output voltage generator 3201 and a sample being processed in the plasma chamber 2802 from damage in the event that an arc is initiated or formed in the chamber. In some embodiments, the plasma system 3202 may comprise an arc detection module 3208 and a power control module 3210 in communication with the arc detection module 3208. In some embodiments, the arc detection module 3208 may be configured to detect and/or predict an arcing event, e.g., by measuring a current passing through the plasma chamber 2802 and, in some cases, through the MEMS switch, and generate an arcing event signal indicative of formation or initiation of an electric arc in the plasma chamber 2802. In some such embodiments the power control module 3210 may be connected to the MEMS switch 3204 and the DC power source and can be configured to activate the MEMS switch 3204, to disconnect the plasma chamber 2802 from the voltage generator and turn off the DC source in response to receiving the event signal.

In some embodiments, the plasma system 3202 may comprise a first spark gap 3206 (e.g., a MEMS-based spark gap) connected in parallel with the MEMS switch 3204 between the voltage generator and the plasma chamber 2802. The first spark gap 3206 may be configured to establish a conductive path to protect the MEMS switch 3204. In some embodiments, the plasma system 3202 may further comprise a shunt device 3203 (e.g., a spark gap such as MEMS-based spark gap) electrically connected to the plasma chamber 2802 and configured to conduct current caused by an EOS event originated in output voltage generator to avoid formation of an electric arc in the plasma chamber due to the EOS event.

MEMS Switch System Configured with Self-Evaluation Capability

In various applications, a MEMS switch system may comprise one or more MEMS switches configured to provide switching functionality to a main circuit, e.g., provide protection functionality to a system from an over electrical overstress (EOS) event, or provide a control functionality to the system. Because proper operation or protection of the system, e.g., protection from an EOS event, may rely on the MEMS switches, it may be desired to periodically test the functionality or performance of these MEMS switches without interrupting normal operation of the system.

Some of the MEMS switch systems disclosed herein may be configured for self-evaluation or self-testing. In some embodiments, a MEMS switch system may comprise a network and/or circuit disclosed that enables testing the switching performance of one or more MEMS switches therein without interrupting the normal operation of a circuit that uses the one or more MEMS switches to provide controlled electric connection between two terminals of the circuit.

In various embodiments disclosed herein, a MEMS switch system configured with self-testing capability includes a first and second MEMS switches electrically connected in parallel between two terminals. The switch system additionally includes a sensor in communication with one or both of the first and second MEMS switches. The switch system additionally includes a control logic communicatively coupled to the first and second MEMS switches and the sensor. The control logic is configured to sequentially transmit an activation signal and a deactivation signal to the first MEMS switch while the second MEMS switch is in a deactivated state, and to receive or detect changes in the sensor signal caused by the activation signal and/or the deactivation signal and determine therefrom a functionality of the first MEMS switch. In some cases, a change of the sensor signal may comprise temporal variation or change caused by activating or deactivating the MEMS switch. In some cases, receiving changes in the sensor signal may comprise comparing a value (e.g., a present value) of the sensor with a reference value stored in a non-transitory memory of the system or determined based on a mission profile or operational condition of the system. For example, when the MEMS switch is deactivated magnitude of electric current can be smaller than a reference or expected value and such change in the ON-state current may indicate that the ON-resistance of the MEMS switch has been increased. The sensor can be a current sensor electrically connected in series with the first MEMS switch, a temperature sensor in thermal communication with one or both of the first and second MEMS switches, or a voltage sensor connected between the two terminals.

In various implementations, determine the functionality of the first MEMS switch may comprise determining that the first MEMS switch can successfully perform one or more of: electrically disconnecting the two terminals upon receiving a deactivation signal, establishing an electrical connection between two terminals with a resistance lower than a threshold resistance, activating with a delay less than a threshold delay time value between receiving an activation signal and electrically disconnecting the two terminals, deactivating with a delay less than a threshold delay time value between receiving a deactivation signal and establishing an electrical connection between two terminals, and the like.

In some embodiments, where the one or more MEMS switches are configured to serve as a circuit breaker, during the normal operation of the circuit, the MEMS switches may electrically connect the two terminals to provide, e.g., uninterrupted signal therebetween. The one or more MEMS switches may be configured to electrically disconnect the two terminals upon detection of an EOS event by at least one sensor (e.g., a current sensor) of the MEMS switch system that monitors, e.g., continuously monitors, at least the current transmitted through the one or more MEMS switches.

In some such embodiments, the MEMS switch circuit may be configured to allow at least one of the MEMS switches to transition from ON state (connected state) to OFF state (disconnected state), during a testing period, while maintaining the electric connection between the two terminals, e.g., using another switch. In various embodiments, the other switch can be an auxiliary switch (e.g., MEMS switches or electronic switches), which is turned on during a testing process and stays in off otherwise, or a MEMS switch that can be intermittently activated during the testing process and stay ON otherwise. Advantageously, keeping the auxiliary switch in ON state during a normal operation of the MEMS switch may reduce the resistance of the electric path between the two terminals by providing an addition electric path between the two terminals parallel to eth electric path through the MEMS switch.

In some embodiments, where the one or more MEMS switches are configured to serve as a controlled electric connector between two terminals, during the normal operation of the circuit the MEMS switches may be in OFF state (disconnected). In some such embodiments, the MEMS switch circuit may be configured to allow at least one of the MEMS switches to transition from the OFF state to ON state, during a testing period, without electrically connecting the two terminals, e.g., by keeping another switch (e.g., another MEMS switch), connected in series with the MEMS switch in an open or disconnected state.

In some embodiments, the one or more MEMS switches that provide a controllable electric connection between two terminals may be referred to as a MEMS switch module. In some examples, the MEMS switch module may comprise a plurality of MEMS switches connected in series and/or in parallel to allow a larger electric current to be transmitted and/or a larger electric voltage to be applied, between two ports of the MEMS switch module. In some cases, all switches within a MEMS switch module may be configured to be activated or deactivated concurrently to electrically connect or disconnect the two ports of the MEMS switch module.

In some embodiments, a MEMS switch circuit or network that supports in situ or on-the-fly testing may comprise a control system (herein referred to as control logic) configured to control a first MEMS switch module and a second MEMS switch module such that during a testing period, the electric connection or electric isolation between two terminal can be maintained while state of some or all the MEMS switches within the first or the second MEMS switch modules is changed (e.g., from ON to OFF or vice versa).

In some embodiments, the MEMS switch circuit or network that supports in situ or on-the-fly testing may comprise a fault detection system (herein referred to as fault detection logic) configured to trigger the control logic to initiate a testing process for MEMS switch module, receive a sensor signal indicating a current transmitted or a voltage applied between two terminals that are electrically connected or can be electrically connected by the MEMS switch module, and determine a health of the MEMS switch module based on the received sensor signal.

In some embodiments, the MEMS switch circuit or network may be configured to predict potential failure or malfunction of a MEMS switch module in future. In some such embodiments, the MEMS switch circuit or network may comprise a prognosis system (herein referred to as prognosis logic) configured to, during a testing period, trigger the control logic to initiate a testing process for MEMS switch module, receive a sensor signal indicating a current transmitted or a voltage applied between two terminals that are electrically connected or can be electrically connected by the MEMS switch module, and predict a potential failure or malfunction of the MEMS switch module during a future period, based on the received sensor signal. In some cases, a sensor signal may indicate temperature of the MEMS switch module or temperature of the chip or die on which the MEMS switch module is fabricated.

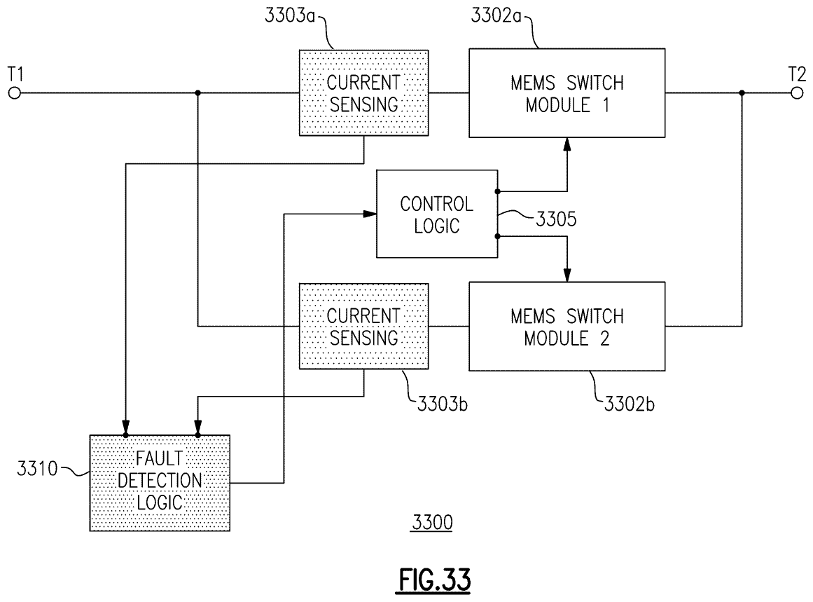

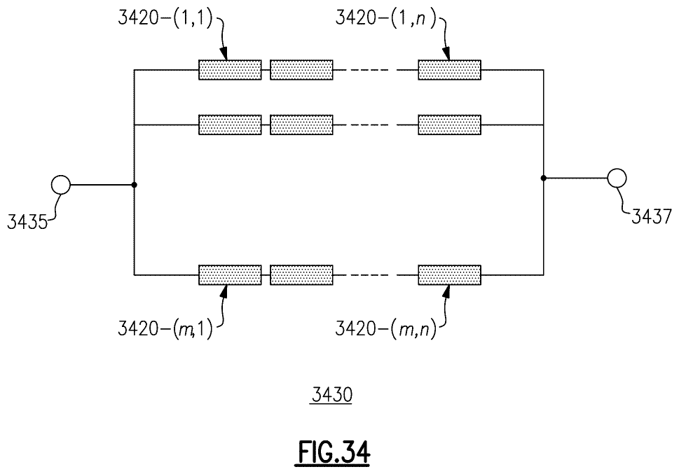

FIG. 33 schematically illustrates an example MEMS switch circuit 3300 configured to test the performance of a first MEMS switch module 3302a that provides a controllable electrical connection between a first electric terminal (T1) and a second electric terminal (T2) without interrupting electrical connection between the T1 and the T2. In some embodiments, the T1 and the T2 can be electric terminals of one or more electric or electronic circuits and the MEMS switch circuit 3300 may be configured to test the performance of the first MEMS switch module 3302a without interrupting the operation of the one or more electric or electronic circuits during a normal operation period. In some embodiments, the first MEMS switch module 3302a may be configured to serve as a circuit breaker that electrically connects the T1 and the T2 during the normal operation period and disconnects T1 from T2 in response to detection of an anomaly, e.g., an EOS event, to protect the one or more electric or electronic circuits. In some examples, the EOS event may be detected by an EOS detection circuit that generates and provides a control signal to the first MEMS switch module 3302a causing the first MEMS switch module 3302a to electrically disconnect the T1 from the T2. In some embodiments, the EOS event may be determined to have occurred based on sensor signals generated by one or more sensors (e.g., current sensors, voltage sensors, temperatures sensors, and the like) connected to or otherwise in communication with the first MEMS switch.

In some embodiments, the MEMS switch circuit 3300 may comprise one or more MEMS switches, where an individual MEMS switch of the one or more MEMS switches is configured to provide a controllable electrical connection between two contact electrodes of the MEMS switch using a conductive beam that is electromechanically controlled by providing a control signal to a control electrode of the MEMS switch, as described elsewhere herein.

In some embodiments, the MEMS switch circuit 3300 may comprise a second MEMS switch module 3302b connected between the T1 and the T2, a control logic 3305 electrically connected to the first and second MEMS switch modules 3302a, 3302b, configured to control the first and second MEMS switch modules during a testing process. In some such embodiments, the MEMS switch circuit 3300 may comprise a first current sensing module 3303a connected in series with the first MEMS switch module 3302a between the T1 and the T2. In some cases, the MEMS switch circuit 3300 may further comprise, a second current sensing module 103b connected in series with the first MEMS switch module 3302a between the T1 and the T2. In some cases, the first MEMS switch module 3302a and the first current sensing module 3303a may be connected in parallel with the second MEMS switch module 3302b and the second current sensing module 3303b. The first and second current sensing modules 3303a, 3303b may be configured to generate first and second current sensor signals indicative of magnitudes of the first and second electric current passing through the first and second MEMS switch modules 3302a, 3302b respectively. In some cases, the first and/or second current sensing modules 3303a, 3303b may comprise a resistor, a Hall sensor or another device that can measure a current transmitted between the T1 and the T2 and generate a current sensor signal.

In some embodiments, the control logic 3305 may be configured to activate (e.g., open) the second MEMS switch module 3302b and deactivate the first MEMS switch module 3302a during a normal operation of one or more circuits connected to the T1 and the T2. In some such embodiments, the control logic 3305 may be configured to test the first MEMS switch module 3302a, during the normal operation period, by continuously or intermittently activating the first MEMS switch module 3302a and deactivating the second MEMS switch module 3302b to maintain electric connection during the testing process. In some cases, the second MEMS switch module 3302b may stay deactivated during normal potation of the one or more circuits connected to reduce the resistance between T1 and T2.

In some embodiments, the MEMS switch circuit 3300 may comprise a fault detection logic 3310 configured to receive one or both first and second current sensor signals from the first and second current sensing modules 3303a, 3303b and determine whether performance of at least the first MEMS switch module 3302a is within an acceptable range with respect to a specified performance metric. In some cases, during the testing process when the control logic 3305 activates (e.g., opens) the first MEMS switch module 3302a and deactivates (e.g., closes) the second MEMS switch module 3302b, the fault detection logic 3310 may determine a current drop indicated by the first current sensor signal received from the first current sensing module 3303a and/or a current rise indicated by the second current sensor signal received from the second current sensing module 3303b, is within an acceptable range associated with opening the first MEMS switch module 3302a and closing the second MEMS switch module 3302b. For example, if the MEMS switch modules 3302a, 3302b are functions normally, when the first MEMS switch module 3302a is activated and the second MEMS switch module 3302b is deactivated, the current detected by the first current sensing module 3303a may drop to about zero and the current detected by the second current sensing module 3303b may increase according to the resistances of the two paths between the T1 and the T2, e.g., approximately double if the resistances of the two paths are about equal. In some such examples, a non-zero current indicated by the first current sensor signal and/or a current rise indicated by the second current sensor less than a specified tolerance may indicate a malfunction of the first MEMS switch module 3302a.

In some embodiments, during the testing process, the fault detection logic 3310 may determine the performance of the second MEMS switch module 3302b, in addition to determining the performance of the first MEMS switch module 3302a, by performing an analogous testing sequence.

As described above, in some embodiments, the second MEMS switch module 3302b can be an auxiliary switch configured to be deactivated at least during a testing process, when the performance of the first MEMS switch module 3302a is tested. In some cases, the second MEMS switch module 3302b may be activated when the testing process is complete. In some cases, the second MEMS switch module 3302b may stay deactivated when the testing process is complete. In some such cases, the control logic 3305 may be configured to activate both the first and second MEMS switched 3302a, 3302b, when one or both current sensing modules 3303a, 3303b, detect a current exceeding a threshold level (e.g., indicating an EOS event).

In some embodiments, both the first and second MEMS switch modules 3302a, 3302b, may be deactivated during a normal operation of one or more circuits connected to the T1 and the T2 to electrically connect the T1 to the T2. For example, both the first and second MEMS switch modules 3302a, 3302b may be configured to serve as circuit breakers to protect one or more circuits connected to T1 and/or T2 under the control of the control logic 3305.

In some such embodiments, during a testing process the fault detection logic 3310 may test the performance of both the first and second MEMS switch modules 3302a, 3302b. For example, the first and second MEMS switch modules 3302a, 3302b can alternatively activated such that the fault detection logic 3310 can determine their performance using the first and second current sensor signals received from the first and second current sensing modules 3303a, 3303b. Advantageously, resistance of a conductive path established between the T1 and the T2 using both the first and second MEMS switch modules 3302a, 3302b, can be lower than a conductive path established between the T1 and the T2 using one of the first and second MEMS switches 3302a, 3302b. As such, during testing process, when the first and second MEMS switch modules 3302a, 3302b are alternatively activated, the resistance of the electrical path between the T1 and the T2 may increase; however, duration of the testing process can be configured (e.g., can be small enough) such that performance of one or more circuits connected to T1 an T2 is not significantly affected by the temporarily larger resistance of the electric path.

In some embodiments, the first and second MEMS switch modules 3302a, 3302b, can be part of a larger MEMS switch module (e.g., a circuit breaker) configured to provide controllable electric connection between the T1 and the T2.

In some embodiments, the control logic 3305 may be configured to initiate the testing process and control the states (OFF/ON or open/close) of the first and second MEMS switch modules 3302a, 3302b, and transmit signals indicative of the states of the first and second MEMS switch modules 3302a, 3302b, to the fault detection logic 3310. In some such embodiments, the fault detection logic 3310 may use the signals received from the control logic 3305 and the current sensor signals received from the first and second current sensing modules 3303a, 3303b, to determine the performance of the first MEMS switch module 102a and, in some cases, the second MEMS switch module 3302b. In some embodiments, determining the performance of a MEMS switch module or a MEMS switch therein may comprise determining whether the MEMS switch module or the MEMS switch therein can be activated and/or deactivated by providing a control signal (e.g., a control voltage) having a magnitude within a specified range. In some embodiments, determining the performance of a MEMS switch module or a MEMS switch therein may further comprise measuring or estimating a resistance of the electric path established between the T1 and the T2 by the MEMS switch module or the MEMS switch therein, and determine whether the measured or estimated resistance is within a specified range.

In some embodiments, in response to determining that MEMS switch module or MEMS switch therein cannot be activated (opened) or its activation voltage exceeds a specified value, the fault detection logic 3310 may determine that the MEMS switch module or MEMS switch therein is malfunctioning (e.g., it cannot disconnect the T1 and the T2 with an specified activation signal).

In some embodiments, in response to determining that an activation voltage of MEMS switch module or MEMS switch therein, or a resistance of an electric path provided by the MEMS switch module or MEMS switch therein exceeds, a specified value, the fault detection logic 3310 may determine that the MEMS switch module or MEMS switch therein is malfunctioning (e.g., it cannot reconnect the T1 and the T2 with sufficiently low resistance).

In some cases, in response to determining that the MEMS switch module or the MEMS switch therein is malfunctioning, the fault detection logic 3310 may generate an alert signal and transmit the alert signal to a switch monitoring system and/or a user interface to trigger an action for replacing or repairing the MEMS switch module.

In some embodiments, the fault detection logic 3310 may be configured to initiate the testing process and control the states (OFF/ON or open/close) of the first and second MEMS switch modules 3302a, 3302b, using the control logic 3305 by transmitting signals indicative of the states of the first and second MEMS switch modules 3302a, 3302b, to the control logic 3305. In some such embodiments, the fault detection logic 3310 may use the signals received from the current sensor signals received from the first and second current sensing modules 3303a, 3303b, to determine the performance of the first MEMS switch module 102a and, in some cases, the second MEMS switch module 3302b.

In some cases, the fault detection logic 3310, control logic 3305, and the first and second MEMS switch modules 3302a. 3302b, can be fabricated in a common substrate. In some such cases, at least a portion of the first and second MEMS switch modules 3302a, 3302b, may be co-fabricated with the fault detection logic 3310 and control logic 3305.

In some cases, fault detection logic 3310 and control logic 3305, may comprise a field programable gate array (FPGA), or otherwise an integrated circuit comprising a processor configured to execute machine-readable instruction stored in a non-transitory memory.

In some cases, fault detection logic 3310 and control logic 3305, can be included in a control and processing system of the MEMS switch circuit 3300. For example, fault detection logic 3310 and control logic 3305, can be circuit blocks of the control and processing system and can be communicatively coupled to the first and second MEMS switch modules 3302a, 3302b.

In some embodiments, when the second MEMS switch module 3302b is used as an auxiliary module for usage during the testing process, the second MEMS switch module 3302b may be replaced with a solid-state switch.

In some embodiments, duration of testing process may be configured to allow reliable testing of one or both MEMS switch modules 3302a, 3302b, by one or more activation-deactivation cycles to ensure one or both MEMS switch modules 3302a, 3302b can be opened by providing a control voltage within a specified acceptable range. In some cases, during a testing process a MEMS switch module or a MEMS switch therein may be activated one, two, three, or more times to obtain one or more open and/or close circuit current measurements. After completion of the testing process the MEMS switch module may stay inactive (in ON state).

In some embodiments, a MEMS switch may comprise an on-chip structure comprising two MEMS switches configured to be electromechanically deactivated to electrically connect two terminals or activated electrically isolate the two terminals. In various implementations, the MEMS switch may comprise a cantilever or teeter-totter structure formed on or over a substrate.

In some embodiments, the MEMS switch circuit 3300 may comprise one or more MEMS switch modules in addition to the first and second MEMS switch modules 3302a, 3302b. In some such embodies, the control logic 3305 and the fault detection logic 3310 may be configured to test three or more MEMS switch modules by alternatingly testing one of the MEMS switch modules to evaluate its performance. As described above, the testing process of a MEMS switch module may comprise measuring magnitudes of one or more currents during one or more activation-deactivation cycles.

In some embodiments, the first and second MEMS switch modules 3302a, 3302b each may comprise the teeter-totter switch 150 in FIG. 1B. In some cases, when a deactivation voltage is provided between front control electrode 110 and the conductive beam 107 (an activation signal provided to the front control electrode 110), the conductive beam 107 may be tilted such that the conductive tip 118 (switching end of the conductive beam 107) contacts the front contact electrode 109 to establish a conductive path between an input switch port 102 connected to the middle electrode 125 and an output switch port 104 connected to the front contact electrode 109. In some cases, when an activation voltage is provided between back control electrode 108 and the conductive beam 107 (an activation signal provided to the back control electrode 108), the conductive beam 107 may be tilted such that the conductive tip 118 is disconnected from the front contact electrode 109 to open (or break) the conductive path between an input switch port 102 and the output switch port 104 connected to the front contact electrode 324. In some cases, when the teeter-totter switch is defective or damaged, the conductive beam may not sufficiently tilt to close or open the electric connection between the input and output switch ports 102, 104, in response to providing and the deactivation signal to the frond control electrode 110 or providing an activation signal to back control electrode 108, respectively. In some cases, when the teeter-totter switch 150 is defective or damaged, the conductive path established between the input and output switch ports 102, 104, by the conductive beam 107 may have a resistance larger than a specified value. In some cases, when the teeter-totter switch 150 is defective, the conductive tip 118 may connect to or disconnect from the front contact electrode 109 with a large delay after the deactivation or activation signals are applied to the front and back contact electrodes 110 and 108, respectively. In some cases, the large delay can be a delay greater than a specified value stored in the fault detection logic 3310.

In some cases, each of the input and output switch ports 102, 104, may be electrically connected to T1 or T2, or to input or output switch ports or another MEMS switch. In some embodiments, evaluation of the performance of a MEMS switch module or a MEMS switch may comprise determining whether the MEMS switch module (e.g., the MEMS switches therein) or the MEMS switch electrically disconnect (isolate) the corresponding input and output switch ports in response to receiving an activation signal. In some embodiments, evaluation of the performance of a MEMS switch module or a MEMS switch may comprise determining whether the MEMS switch module (e.g., the MEMS switches therein) or the MEMS switch electrically connects the corresponding input and output switch ports in response to receiving a deactivation signal and, in some cases, may further comprise determining resistance of the electrical path between the input and output switch ports.

In some embodiments, one or both the first and second MEMS switch modules 102a, 102b, may comprise two or more teeter-totter switches electrically connected in series and/or parallel to form a MEMS switch network capable of switching voltages and/or currents larger than those that can be switched by a single teeter-toter switch.

FIG. 34 schematically illustrates an example MEMS switch network 3430 comprising a plurality of MEMS switches 3420-(m,n) arranged in m branches connected in parallel between a common input port 3435 and a common output port 3437. In some cases, an individual branch may comprise n MEMS switches (e.g., teeter-totter switches) connected between the common input port 3435 and the common output port 3437 (in series when n is greater than 1). In some examples, the MEMS switch network 3430 may be included in a MEMS switch module or serve as a MEMS switch module. In some embodiments, the plurality of MEMS switches 3420-(m,n) may be configured to be activated and deactivated concurrently to control electric connection between the common input and output ports 3435, 3437.

In some embodiments, a MEMS switch circuit may be configured to measure a parameter (e.g., temperature) other than electric current passing through a MEMS switch module or a MEMS switch therein to evaluate the performance of the MEMS switch module or the MEMS switch. For example, when a MEMS switch module of a plurality of MEMS switch modules, connected in parallel between two terminals, is activated and opens, the overall temperature of a die on which the MEMS switch modules are formed may rise due to a larger resistance of the conductive path provided by the remaining MEMS switch modules that are closed (inactive).

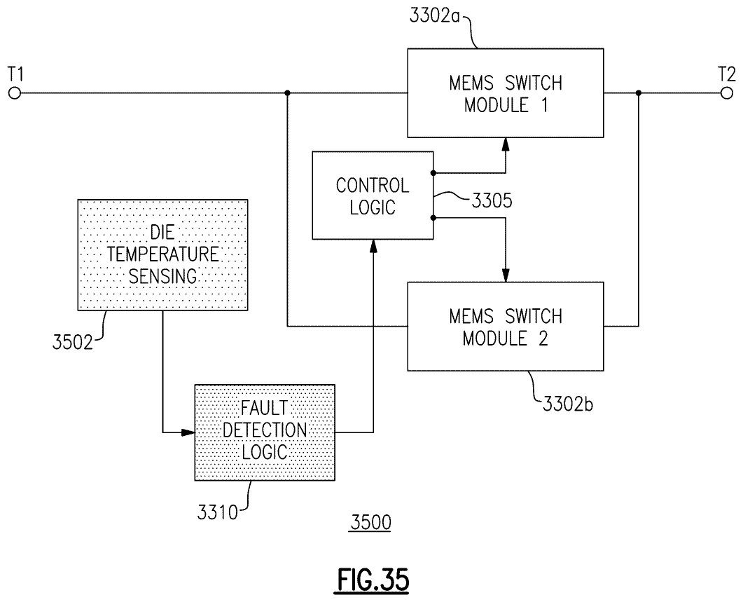

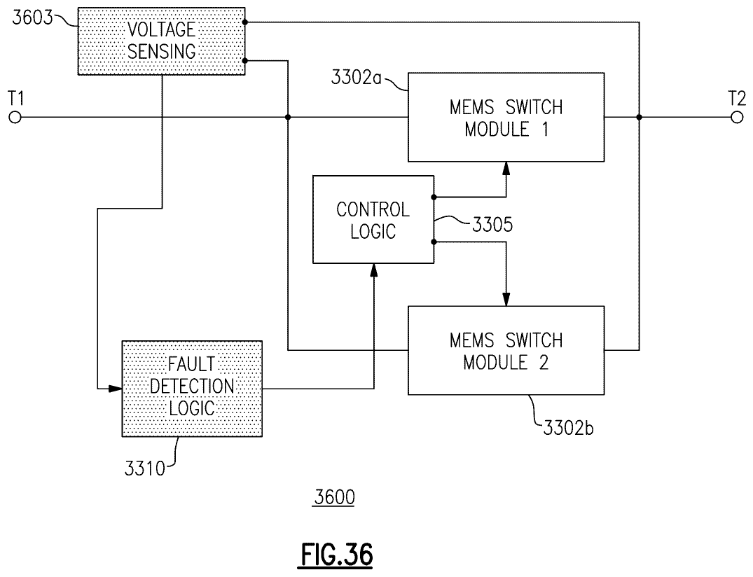

FIG. 35 schematically illustrates an example of MEMS switch circuit 3500 configured to test one or more MEMS switches by measuring temperature of a die or substrate on which the one or more MEMS switches are formed. In some embodiments, the MEMS switch circuit 3500 may comprise one or more features described above with respect to the MEMS switch circuit 3300. In some embodiments, the MEMS switch circuit 3500 may comprise a temperature sensor (e.g., thermistor) 3502 formed on/over a substrate or die on/over which the one or more MEMS switches are formed. In some embodiments, the MEMS switch circuit 3500 may not include the current sensing modules 3303a, 3303b between the first and second MEMS switch modules 102a. 102b, and T1. In some embodiments, the fault detection logic may determine the performance of one or both the first and the second MEMS switch modules 3302a, 3302b, using a temperature signal received from the temperature sensor 3502 in addition or alternative to using the current sensor signals that may be received from the first and second current sensing modules. Advantageously, eliminating the current sensors and determining the performance of the multiple MEMS switch modules using the temperature sensor 3502, may reduce the cost and complexity of the MEMS switch circuit 3500 compared to the MEMS switch circuit 3300 since a single terminator may be used to test multiple MEMS switch modules while current based testing may require at least one current sensor per MEMS switch module. Moreover, to test a subset of MEMS switches in a MEMS switch module (e.g., the MEMS switch network 3430), at least one current sensor per a parallel branch of the MEMS switch module may be needed.

In some embodiments, when a testing process is performed, e.g., during a normal operational period of one or more circuits connected to the T1 and the T2, first the fault detection logic 3310 may receive a first temperature signal from the temperature sensor 3502 while both the first and second MEMS switches 3302a, 3302b, are deactivated, then the control logic 3305 (e.g., in response to a signal received from the fault detection logic) may activate the first MEMS switch module 3302a, while keeping the second MEMS switch module 3302b inactive, and concurrently or after a specified period the fault detection logic 3310 may receive a second temperature signal from the temperature sensor 3502. The fault detection logic 3310 may compare the first temperature signal, indicative of a first die temperature when both MEMS switch modules 3302a, 3302b, are deactivated, with the second temperature signal, indicative of a second die temperature when the first MEMS switch module 102a is activated but the second MEMS switch module 3302b is deactivated, and determine a performance of the first MEMS switch module 3302a based on the comparison. For example, if the second die temperature is greater than the first die temperature (e.g., greater by a factor of 1.2, 1.5, or 2), the fault detection logic 3310 may determine that the first MEMS switch module 3302a is functioning normally (since the level of temperature rise may indicate that the current has been transmitted from T1 to T2 entirely through the second MEMS switch module 3302b). However, if the second die temperature is not greater than the first die temperature die by a specified amount the fault detection logic 3310 may determine that the first MEMS switch module 3302a has not responded to the activation signal and thereby is malfunctioning (since absence of a temperature rise may indicate that the current is still being by both first and second MEMS switch modules 3302a, 3302b). A similar temperature-based testing process may be used to test the performance of the second MEMS switch module 3302b.

FIG. 36 schematically illustrates an example of MEMS switch circuit 3600 configured to test one or more MEMS switch modules by measuring voltage drop(s) between the two ports of one or more MEMS switch modules (or between the T1 and the T2 connected by the one or more MEMS switches). In some embodiments, the MEMS switch circuit 3600 may comprise one or more features described above with respect to the MEMS switch circuit 3300.

In some embodiments, the MEMS switch circuit 3600 may comprise a voltage sensing module 3603 configured to generate a voltage sensor signal indicative of a voltage (electric potential) difference between the T1 and the T2. In some embodiments, the MEMS switch circuit 3600 may not include the current sensing modules 3303a, 3303b between the first and second MEMS switch modules 3302a 3302b, and T1. In some embodiments, the fault detection logic 3310 may determine the performance of one or both the first and the second MEMS switch modules 3302a, 3302b, based at least in part on the voltage sensor signals received from the voltage sensing module 3603.

In some embodiments, when a testing process is performed, e.g., during a normal operational period of one or more circuits connected to the T1 and the T2, when both the first and second MEMS switch modules 3302, 3302b are deactivated, the control logic 3305, (e.g., in response to a signal received from the fault detection logic) may activate the first MEMS switch module 3302 while keeping the second MEMS switch module 3302b inactive. Concurrently or within a specified period after activation of the first MEMS switch module 3302a, the fault detection logic 3310 may receive a voltage sensor signal from the voltage sensing module 3603 and determine whether the voltage is within a specified voltage range associated with resistance of a single MEMS switch module (e.g., the second MEMS switch module 3302b). Alternatively, the fault detection logic 3310 may compare the voltage sensor signal with another voltage sensor signal prior to activation of the first MEMS switch module 3302a (when both MEMS switch module 3302a, 3302b are inactive) and determine the performance of the first MEMS switch module. For example, if the voltage sensor signal measured receive after activation of the first MEMS switch module 3302a is greater (by a specified value) than voltage sensor signal measured receive before activation of the first MEMS switch module 3302a (when both MEMS switch modules are inactive), the fault detection logic 3310 may determine that the first MEMS switch module 3302a is functioning normally (since the level of voltage rise may indicate that the current has been transmitted from T1 to T2 entirely through the second MEMS switch module 3302b). However, if the first MEMS switch module 3302a is equal (by a specified value) than the voltage sensor signal measured receive before activation of the first MEMS switch module 3302a the fault detection logic 3310 may determine that the first MEMS switch module 3302a has not responded to the deactivation signal and thereby is malfunctioning (since absence of a voltage rise may indicate that the current is still being by both first and second MEMS switch modules 3302a, 3302b). A similar voltage-based testing process may be used to test the performance of the second MEMS switch module 102b.

The MEMS switch circuits 3300, 3500, and 3600, described above with respect to FIGS. 33, 35, and 36, may be configured to test a MEMS switch module that is configured to stay inactive (closed or deactivated) during a normal operation period of one or more circuits electrically connected to the terminal the T1 and the T2, to electrically connect T1 to T2. As described above, the MEMS switch modules of the MEMS switch circuits 3300, 3500, and 3600, may serve as circuit breakers for protecting the one or more circuits against EOS events. In some embodiments, the EOS event may be determined to have occurred based on sensor signals generated by one or more sensors (e.g., current sensors 3303a, 3303b) electrically connected to the first and second MEMS switched 3302a, 3302b. In various implementations, the control logic 3305, or another circuit that controls the operation of the first and second MEMS switches 3302a, 3302b during an operational period of the MEMS switch circuit, may determine that the EOS event has occurred based on the sensor signals generated by the one or more sensors. In some embodiments, a MEMS switch circuit may be configured to test a MEMS switch module that is configured to stay activated during a normal operational period to electrically isolate one or more circuits electrically connected to the terminal the T1 and the T2, and be deactivated occasionally, e.g., to electrically connect T1 to T2 for a specified period.

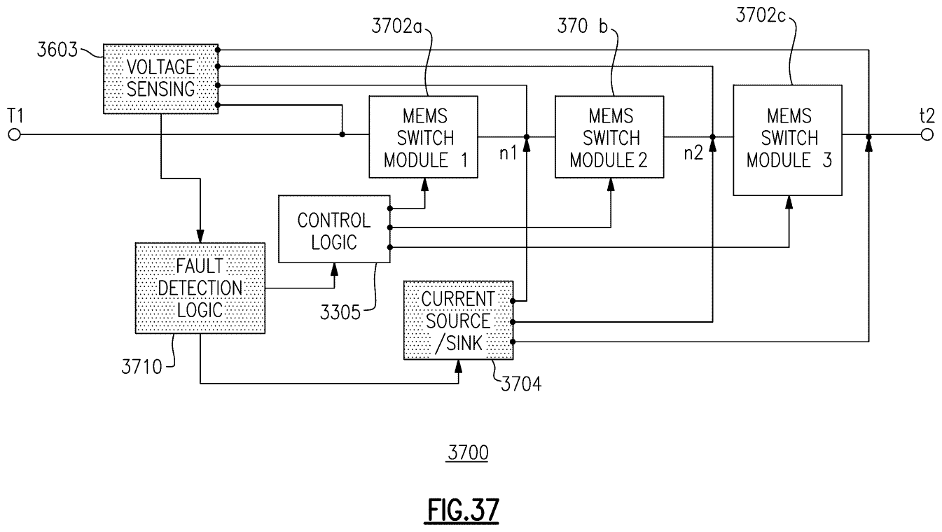

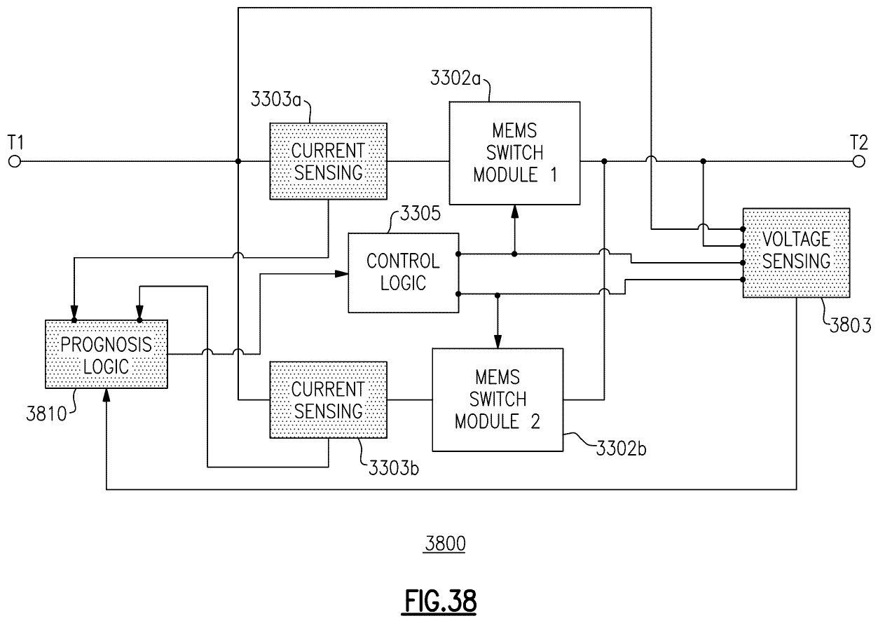

FIG. 37 schematically illustrates an example of MEMS switch circuit 3700 configured to test one or more MEMS switch modules connected in series between the T1 and the T2 and configured to stay open to electrically isolate the T1 and the T2 during a normal operational period of one or more circuits connected to the T1 and the T2. In the example shown, the MEMS switch circuit 3700 may comprise three MEMS switch modules 402a, 402b, 402c, connected back-to-back in series between the T1 and the T2, a control logic 3305 configured to control the state of the MEMS switches 3302a, 3302b, 3302c. In some cases, a first MEMS switch module 3702a may be connected between the T1 and a first node n1, a second MEMS switch module 3702b may be connected between the first node n1 and a second node n2, and third MEMS switch module 3702c may be connected between the second node n2 and the T2. The MEMS switch circuit 3700 may further comprise a current source/sink module 3704 electrically connected to the first node n1, second node n2, and the T2, a voltage sensing module 3603 electrically connected to the T1, the T2, the n1, the n2, and a fault detection logic 3710 electrically connected to the control logic 3305, the current source/sink module 3704 and the voltage sensing module 3603. In some embodiments, the fault detection logic 3710 may be configured to test the first, second, and third MEMS switch module 3702a by deactivating the first MEMS switch module 3702a, while keeping the second and third MEMS switch modules 3702b, 3702b, active (open), triggering the current source/sink module 3704 to drive a specified electric current through the first MEMS switch module 3702a, and concurrently or after a specified period receive a voltage sensor signal indicative a measured voltage between T1 and n1. In some cases, in response to receiving a voltage sensor signal indicative of a voltage within a specified range from an expected voltage, the fault detection logic 3710 may determine that the function of the first MEMS switch module 3702a is normal. In some examples, expected voltage can be associated with the specified current and an expected or specified resistance of the first MEMS switch module 3702a. In some cases, in response to receiving a voltage sensor signal indicative of a voltage larger than the expected voltage by a threshold amount, the fault detection logic 3710 may determine that the first MEMS switch module 3702a is malfunction (e.g., cannot establish an electric connection between T1 and n1 with sufficiently low resistance). In some cases, in response to determining that the first MEMS switch module 3702a or the MEMS switch therein is malfunctioning, the fault detection logic 3310 may generate an alert signal and transmit the alert signal to a switch monitoring system and/or a user interface to trigger an action for replacing or repairing the first MEMS switch module 402b. In some cases, the second and third MEMS switch modules 3702b, 3702c, may be tested using a similar method. In some cases, when one MEMS switch module is deactivated, to be tested, one or both remaining MEMS switch modules may stay open or active. In some cases, two MEMS switch modules may be deactivated and tested concurrently while the last MEMS switch module stays open to keep the T1 and the T2 electrically isolated to allow the corresponding circuits connected to the T1 and the T2 function normally without being perturbed or interrupted by the testing process.

In some embodiments, the MEMS switch circuit 400 may include additional MEMS switch modules, e.g., connected between the third MEMS switch module 3702c and T2 to ensure the overall device meets the required voltage rating.

In some embodiments, a MEMS switch circuit may be configured to predict a future failure or estimate a lifetime of the MEMS switch module without interrupting the operation of one or more circuit that rely or use a MEMS switch module of the MEMS switch circuit for protection and/or normal operation. In some such embodiments, during a predictive testing process the MEMS switch circuit may be configured to collect data indicative of a measured values of one or more of activation voltage, deactivation voltage, and resistance of an electric path provided upon deactivation, for a MEMS switch module or MEMS switch therein and analyze the collected data to predict a future failure or, estimate a lifetime of the MEMS switch module, or determine a number of switching cycles left before MEMS switch module has to be replaced.

FIG. 38 schematically illustrates an example MEMS switch circuit 3800 configured to predict a future failure or estimate a lifetime of the MEMS switch modules therein without interrupting an electric connection between first and second terminals T1, T2 that can be electrically connected to one or more circuits. The MEMS switch circuit 3800 may comprise one or more features described above with respect to the MEMS switch circuit 3300. In some embodiments, in addition to the first and second current sensing modules 3303a, 3303b, the MEMS switch circuit 3800 may comprise a voltage sensing module 3803 configured to generate a first voltage sensor signal indicative of a voltage difference between the T1 and the T2, a second voltage sensor signal indicative of an deactivation (or activation) signal provided by the control logic 3305 to the first MEMS switch module 3302a, a third voltage sensor signal indicative of an deactivation (or activation) signal provided by the control logic 3305 to the second MEMS switch module 3302b. In some cases, the first voltage sensor signal may comprise a transient voltage between the T1 and the T2 during activation or deactivation of the first and second MEMS switch modules 3302a, 3302b.

In embodiments, the MEMS switch circuit 3800, in addition to or in place of the fault detection logic 3710, may comprise a prognosis logic 3810 configured to receive current sensor signals from the first and second current sensing modules 3303a, 3303b and voltage sensor signals from the voltage sensing module 3803 during a testing process and generate data pertaining a future change in functionality, potential future failure, estimated lifetime of one or both the first and second MEMS switch modules 102a, 102b. In some embodiments, control logic 3305 may initiate the testing process by alternatively activating the first and second MEMS switch modules 3302a, 3302b and the prognosis logic 3810 may evaluate parameters associated with performance of the MEMS switch modules based on the received voltage and current signals during the testing process. In some cases, the control logic 3305 may be configured to keep at least one of the first and second MEMS switch modules 3302a, 3302b deactivated (closed) to maintain an electrical connection between the T1 and the T2.

In some embodiments, the prognosis logic 3810 may initiate the testing process by alternatively activating the first and second MEMS switch modules 3302a, 3302b use the received voltage and current signals during the testing process for determining a current of future health state of one or both the first and second MEMS switch modules 3302a, 3302b.

In some embodiments, prognosis logic 3810 may use the first voltage signal received from the voltage sensing module 3803, and/or the first current signal received from the first current sensing module 3303a to measure variation of voltage and current across the first MEMS switch module 3302a within a specified period starting from a time when a activation signal (indicated by the second voltage signal) is provided to the first MEMS switch module 102a.

Similarly, the prognosis logic 3810 may use the second voltage signal received from the voltage sensing module 3803 and/or the second current signal received from the second current sensing module 3303b to respectively measure variations of voltage and/or current across the second MEMS switch module 3302b within a specified period starting from a time when a activation signal (indicated by the third voltage signal) is provided to the second MEMS switch module 3302b.

In some embodiments, the first and second voltage signals received from the voltage sensing module 3803 may indicate the magnitudes of control voltages applied to the control electrodes of the first and second MEMS switches 3302a and 3302b, respectively. In such embodiments, the prognosis logic 3810 may use these voltages to determine the activation and deactivation voltages of the respective MEMS switches. The prognosis logic 3810 may monitor variations in one or both of the activation and deactivation voltages to predict potential future failures based on, e.g., the timing of or a parameter correlated to such failures, of the MEMS switches. By way of one specific examples, a failure may predicted to occur when the activation or deactivation voltage of at least one of the MEMS switches exceeds a threshold value.

In some embodiments, prognosis logic 3810 may use the measured variations of voltage and current across the first (or second) MEMS switch module 3302a (3302b), to determine an estimated activation voltage (e.g., a threshold activation voltage for establishing a conductive path having a resistance below a specified value) and/or an estimated deactivation voltage (e.g., a threshold deactivation voltage for electrically disconnecting T1 from T2). In some cases, an activation (or deactivation voltage) may comprise a voltage provided by the control logic 3305 to the first and second MEMS switch modules 3302a, 3302b, and thereby the second and third voltage sensor signals provided to the prognosis logic 3810 by the voltage sensing module 3803. In some cases, the estimated activation voltage (or measured deactivation voltage) may comprise a voltage estimated based on variation of measured voltages and/or current across the first and second MEMS switch modules 3302a, 3302b, and the corresponding activation voltage (or deactivation voltage).

In some embodiments, prognosis logic 3810 may use the measured variations of voltage and current across the first (or second) MEMS switch module 3302a (3302b), to determine variation of a resistance of the conductive electric path established by the first (or second) MEMS switch module 3302a (or 3302b), as a function of the deactivation voltage.

In some embodiments, prognosis logic 3810 may use the measured variations of voltage and current across the first (or second) MEMS switch module 3302a (3302b), to determine activation and deactivation response times of the first (or second) MEMS switch module 3302a (3302b).

In some embodiments, prognosis logic 3810 may use the variation of a resistance of the conductive electric path, estimated values of activation and deactivation voltages, the activation and deactivation response times, and other parameters that may be extracted from current and voltage measurements, to determine anomalies that potentially can indicate early signs of failure. In some cases, prognosis logic 3810 may generate and transmit data pertaining the detected or estimated anomalies to another system or a user interface to trigger automatic or user actions to prevent potential future failures indicated by the data.

Multi-Node Systems with MEMS Switch Modules for Protection and Monitoring

In some embodiments, a system may comprise a plurality of nodes each configured to provide a functionality to the system. An individual node may comprise different functional elements depending on the application requirements.

In some embodiments, in addition to providing a functionality to the system, an individual node may generate information (herein referred to as “node data”) usable for monitoring a device in the node and assessing the health of the device for predictive maintenance of the device. In some cases, the information generated by the node may be further used to monitor the performance of another part of the system and to assess the health of the other part for predictive maintenance of the part.

In some embodiments, an individual node of the system can be in communication with a processing, control and alerting (PCA) system, and transmit node data generated by the node during an operational or testing period of a device or component in the node to the PCA system. The PCA system may be configured to use the node data to evaluate performance of the device or a component in the node, or another part of the system connected to or in communication with the node. In some cases, node data may comprise a measured value and/or variation of a current, a voltage, a temperature, or other parameters indicative of an input to a device or component in the node of an environmental condition of the node. In some cases, the PCA system may comprise a command center.

In some embodiments, the node data may be used to monitor excursions beyond specific operational thresholds of a device or component in the node. In some embodiments, the PCA system may receive, store, and/or process the node data to determine a failure or malfunction of a device, component, or a portion of the system, estimate a lifetime of a device or component in the node or the system, monitor mission profile of a device or component in the node or the system, generate a warning, an alarm, or an alert message indicative of a malfunction, generate recommendation for predictive maintenance, and the like. However, embodiments are not so limited, and node data may be used for determining other aspects of the node or the system or trigger other action.

In some cases, node data may be collected at service intervals and used for prognostic predictive maintenance, e.g., informing subsequent actions (e.g. replacement of certain parts within the system, some other physical intervention).

In some cases, the node data may be used to create a digital twin for a component or device in the node. In some such cases, the digital twin may comprise a model (e.g., a parametric model of a component or device in the node) updated using the node data. In some cases, the digital twin may be informed by monitoring the functional safety status, temperature exposure, mission profile, and the like.

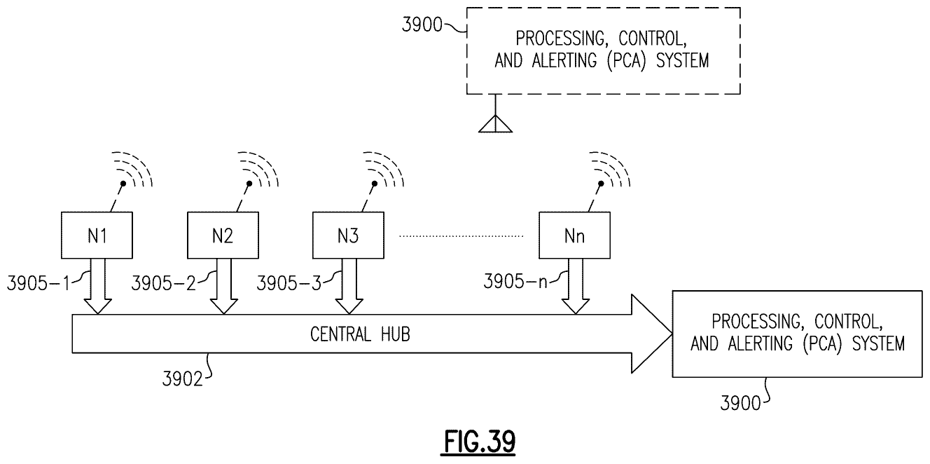

FIG. 39 schematically illustrates a plurality of nodes N1, N2, N3, . . . , Nn, of a system in communication with a PCA system 3900. In some cases, individual nodes can be in communication with the PCA system 3900 via a central hub configured to transmit node data 3905-1, 3905-2, 3905-3, . . . , 3905-n, received from individual nodes to the PCA system 3900. In some cases, the central hub may comprise a wired communication link. In some such cases, the central hub may be connected to the PCA system 3900 via wireless communication link or another wired link. In some cases, individual nodes can be in communication with the PCA system 3900 via individual wireless links established between individual nodes and the PCA system 3900.

In some embodiments, a node (Nn) may comprise an electrical overstress (EOS) sensor (e.g., a spark gap) or other types of sensors, a MEMS switch (e.g., a MEMS circuit breaker), a wireless communication circuit, a power source (e.g., a battery or energy harvesting circuit). In some cases, a node may include an encryption module configured to encrypt the node data 3905 prior to transmission to the PCA system 3900. In some implementations, an individual node may comprise a MEMS switch, MEMS switch module, or MEMS switch system, or MEMS-based circuit breaker configured to provide switching functionality to a main circuit, e.g., provide protection functionality to a system from an electrical overstress (EOS) event, or provide a control functionality to the system. In some embodiments, the MEMS switch, MEMS switch module, MEMS switch system, or MEMS switch breakers may comprise one or more features described above with respect to FIGS. 1A-FIG. 38.

In some embodiments, a functional safety status can be established and fed into a predictive maintenance system, which can be managed remotely. The predictive maintenance system may receive node data from multiple nodes throughout the systems to build an accurate picture of a portion or the entire system and comprise the system picture with the functional safety status to establish a preventive maintenance program. The preventive maintenance program may include corrective actions or replacement activities escalated depending on recorded functional safety events (aside from standard schedules of maintenance/replacement of components and parts).

In some embodiments, a node may comprise a high voltage device (e.g., a high voltage MEMS switch) that is isolated from a low voltage portion of the node connected to the central hub 3902 or comprising a wireless transceiver in communication with the PCA system 3900.

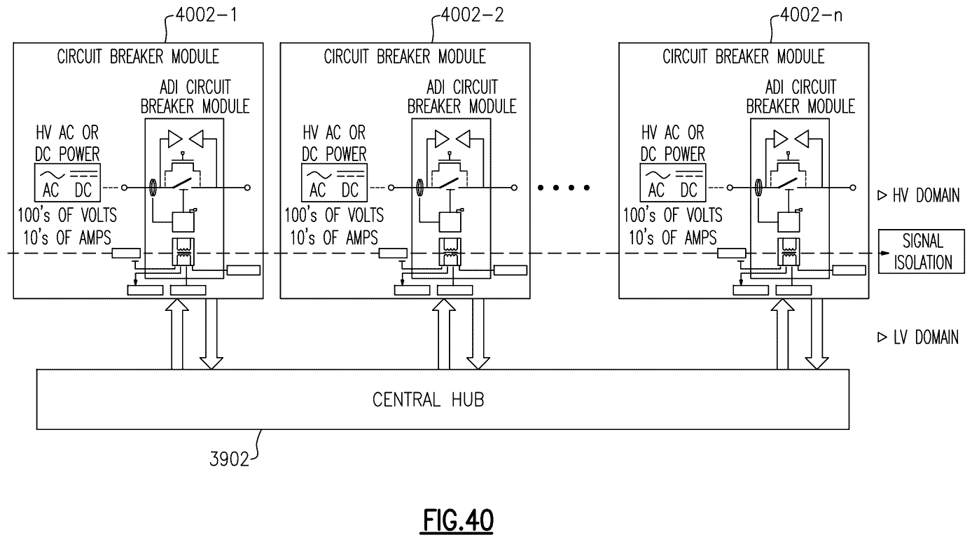

FIG. 40 schematically illustrates an example system comprising multiple nodes each comprising a circuit breaker module, e.g., circuit breaker modules 4002-1, 4002-2, . . . , 4002-n, having at least one MEMS switch or MEMS switch module (e.g., a plurality of MEMS switches configured to collectively control an electric connection). In some cases, where the MEMS switch in a circuit breaker comprises a high voltage MEMS switch (e.g., a high voltage teeter-totter switches or switch networks described with respect to FIGS. 1B, 2A-2C, 3A-3C, 4A-4B, 5A-5B, 6A-6C, 7, 8, and 9A-9C), the circuit breaker may include an isolator configured to isolate the high voltage and low-voltage circuitry within the circuit breaker. For example, the sensor signals generated by a sensor connected to or positioned near the high voltage MEMS switch may be transmitted to the central hub 3902 or a wireless transceiver in the circuit breaker or the node via the isolator. In some cases, the circuit braker modules 4002-1, 4002-2, . . . , 4002-n may comprise certain sensing capabilities incorporated therein (e.g., temperature sensing, vibration sensing, EOS monitoring, and the like). In some embodiments, these sensing capabilities may enable monitoring immediate and/or surrounding environment of a node to be monitored.

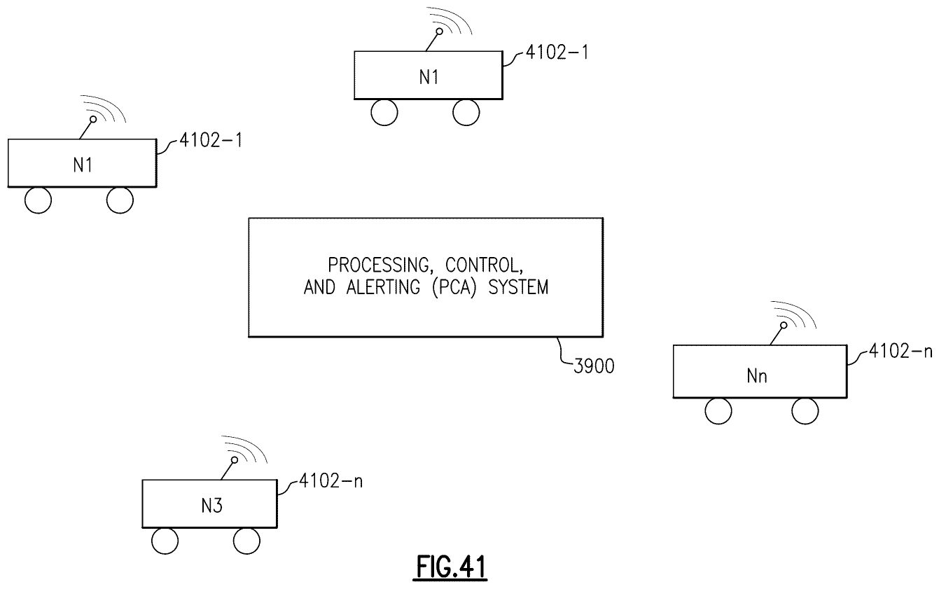

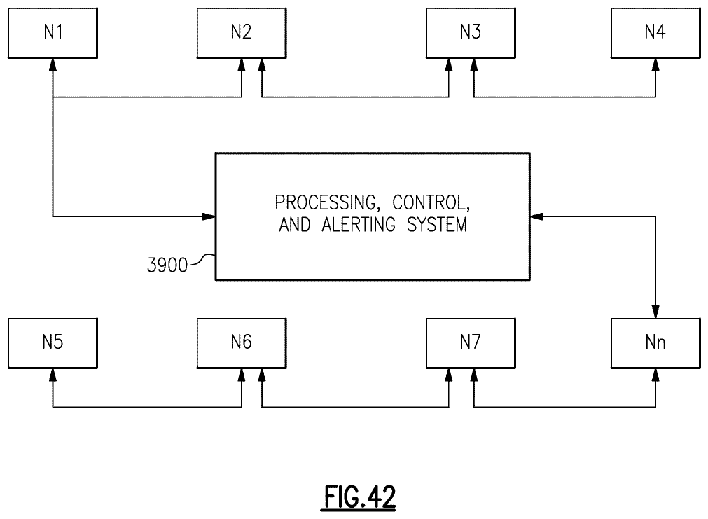

In some embodiments, a system may comprise dynamic or mobile nodes 4102-1, 4102-2, . . . , 4102-n, that can change their positions with respect to the PCA system 3900 while being in wireless communication with the PCA system 3900. FIG. 41 schematically illustrates an example system comprising dynamic nodes having time varying locations. An individual dynamic node can be in communication the PCA (e.g., serving as a central processing system) to transmit information (e.g., sensor data such as temperature, vibration, EOS events etc.) associated with the mobile node to the PCA module. In some cases, the configuration shown in FIG. 41 may facilitate remote tracking and central management of mobile nodes. In some cases, a dynamic node may comprise a vehicle (e.g., an electric vehicle and/or an autonomous vehicle etc., a drone, or the like) or another mobile system comprising components/systems within which detection of an EOS event/transient currents and/or temperature could be indicative of degradation of a device and/or a potential safety issue. In some examples, the node data from an individual dynamic node may be wirelessly transmitted to the PCA system 3900 and then analyzed to identify a malfunction in a component in the corresponding node, determine an effective lifetime of the component, or update a model (e.g., a digital twin of the component).

FIG. 42 schematically illustrates another example system comprising a plurality of nodes (N1, N2, N3, . . . , Nn) communicatively connected to a PCA system 3900. In some cases, a portion of the plurality of nodes can be serially interconnected and connected to the PCA system 3900 via one of the nodes. In the example shown, a first group of serially interconnected nodes (N1, N2, N3, and N4) are connected to the PCA system 3900 via N1, and a second group of serially interconnected nodes (N5, N6, N7, . . . , Nn) are connected to the PCA system 3900 via Nn. In some cases, the different nodes shown in FIG. 42 may comprise nodes of a manufacturing system. In some cases, an individual node may contain an embedded module/system containing a MEMS switch, a MEMS switch module, or a MEMS-based circuit breaker and/or and other components described herein. The data generated in a node can be combined (e.g., within the PCA system) and used to monitor a portion or the entire system, e.g., with respect to functional safety, operational status, and the like. In some cases, monitoring may be performed in real time.

In various implementations, a wired link or network may comprise CAN, RS-485, Industrial Ethernet, 10BASE-TIL, Home, bus, LVDS, or the like.

In various implementations, an individual node may comprise a MEMS switch module and the node data may comprise measured data generated by the MEMS switch module and/or a control and monitoring circuit connected to the MEMS switch module. In some cases, the measured data may be provided to a PCA system 3900 configured to use the received measured data to evaluate the performance of the MEMS switch module and/or a system comprising the MEMS switch module. In some embodiments, the control and monitoring circuit may comprise one or more sensors (e.g., voltage, current, or temperature sensors) and a readout module configured to generate signals indicative of the value of a measured parameter (e.g., voltage, current, or temperature) or, in some cases, a derived parameter extracted from one or more measured parameters. The control and monitoring circuit may further comprise a control circuit (also referred to as control logic), configured to control the MEMS switch module based on signals/commands received from a processing module in the node or from the PCA system 3900 (e.g., based at least in part on the node data). In some examples, the control and monitoring circuit may comprise a MEMS switch circuit configured to periodically test the functionality or performance of the MEMS switch module without interrupting normal operation of a circuit comprising the MEMS switch module and the measured data may comprise test data generated during the testing process. In some embodiments, the MEMS switch module may comprise a teeter-totter MEMS switch comprising one or more features described with respect to the teeter-totter MEMS switches FIGS. 1B, 2A-2C, 3A-3C, 4A-4B, 5A-5B, 6A-6C, 7, 8, and 9A-9C.

In some implementations, the control and monitoring circuit may comprise a circuit breaker comprising one or more features described above with respect to circuit breaker 2500. In some implementations, the control and monitoring circuit may comprise a circuit breaker comprising one or more features described above with respect to control circuits 1001, 1101, and 1301 in FIGS. 10, 11, and 13.

MEMS Switch System with Physically Unclonable Function (PUF)

In some embodiments, a device or component in a node may be exposed to operational and/or environmental conditions that may not be captured (or at least not fully captured) by the measured data generated by the sensors connected or in communication with the device or component. For example, a MEMS switch module may be exposed to an operational (e.g., current and/or voltage) and/or environmental (e.g., temperatures, radiation, field, or the like) conditions that may not be captured (or at least not fully captured) by the measured data generated by the MEMS switch module and/or the corresponding control and monitoring circuit. Given that such operational and/or environmental conditions may affect the lifetime or future performance of the MEMS switch module, in some cases, predictions, determination, or evaluation made by the PCA system based on the measured data may not be accurate and/or reliable.

In some embodiments, in order to take into account such operational and/or environmental conditions in an evaluation, prediction, or otherwise analysis of the performance of a device such as a MEMS switch module, a physically unclonable function (PUF) unit (e.g., device or circuit) may be provided (e.g., in the node) and configured to generate a PUF signal indicative of deviation of the operational or environmental condition from a specified operational and/or environmental condition. In some cases, such deviation may not be captured by the measured data generated by the sensors or the MEMS switch module itself. In some cases, the specified operational and/or environmental condition may comprise a condition or a range of conditions that allow normal operation of the MEMS switch module.

In some embodiments, the PUF unit or circuit can be physically coupled to the MEMS switch and configured to generate a PUF signal. The PUF signal may comprise a signal (e.g., analog or digital) unique to the PUF unit or circuit. In some cases, the exposure to a threshold condition may physically alter the PUF and cause the PUF circuit to generate an altered PUF signal indicative of the threshold condition. In some examples, the threshold condition may comprise deviation of the operational or environmental condition of the MEMS switch and PUF unit from a specified operational and/or environmental condition by a threshold amount. In some examples, the PUF signal may comprise a digital signal and the PUF unit may be configured such that deviation of the operational or environmental condition of the MEMS switch and PUF unit, from the specified operational and/or environmental condition by the threshold amount, causes the digital PUF signal to change from a first digital value to second digital value (e.g., from 0 to 1 or from 1 to 0). In some examples, the PUF signal may comprise an analog signal and a processing system (e.g., processing, control, and alerting system 3900) may be configured to determine the deviation of the analog PUF signal from a specified signal. In yet other examples, the PUF signal may comprise an analog signal and a decision circuit in a node containing the PUF unitor in the processing, control, and alerting system 3900 may be configured to receive the analog PUF signal and generate a digital signal indicating whether operation and/or environmental condition of the device and the PUF satisfies a specified threshold condition or not.

In some cases, the PUF unit may be positioned near the MEMS switch module (e.g., integrated with the MEMS switch module on a common substrate) such that it is exposed to the same environmental condition experienced by the MEMS switch module. In some cases, the PUF unit and the MEMS switch module may be electrically connected to a common terminal such that the PUF unit is exposed to the same operational conditions as the MEMS switch module. In some cases, the PUF unit may be coupled to or in communication with the MEMS switch module (e.g., through direct electric connection or field coupling) such that a change on the MEMS switch module, which may not be captured by the measured data, can affect the status of the PUF and thereby the PUF signal.

In some embodiments, a PUF circuit may be configured to generate a PUF signal based on an inherent physical property of one or more PUF units. In some implementations, the PUF circuit may comprise a hardware having a unique signature manifested in the PUF signal when the PUF circuit is exposed to normal environmental conditions. In some such implementations, the unique signature can be sensitive to environmental conditions around the PUF unit and minute changes in a device (e.g., a MEMS switch module) coupled or connected to the PUF unit.

In some embodiment, a PUF unit may exploit inherent manufacturing process variations, resulting in subtle differences between nominally identical devices. By way of example, when the PUF unit includes a semiconductor device such as a transistor, semiconductor manufacturing variations such as variations in physical dimensions of device features or dopant concentrations can impart a unique measurable signature associated with the particular semiconductor device. These differences may be generally imperceptible but can be measured and used to create a unique characteristic. The resultant challenge-response behavior of the PUF unit may be consistent for a given PUF unit but may vary between different PUFs, despite being designed to be the same.

In some cases, upon being exposed to an environmental change or a perturbation by a device or circuit, the unique signature of the PUF unit can be altered. In some cases, the unique signature of the PUF unit can be irrecoverably altered. In some other cases, when the environment becomes normal or returns to its original state, PUF unit may revert to its previous (e.g., normal) state after. In some cases, when the unique signature of the PUF unit and thereby the corresponding PUF signal transmitted to the PCA system is altered, the PCA system may not use the measured data generated after alteration of the PUF signal to update a device model (e.g., a digital twin) or analyze performance of a device or component (e.g., a MEMS switch module) associated with the PUF unit. As such, in some embodiments, a PUF circuit may be used to prevent a portion of measured data generated by a device or circuit that is affected by an environmental or operational condition, to be used for predictive maintenance, device modeling, alert generation, or the like.

In some implementations, a PUF unit may use various circuit elements, such as SRAM cells, oscillators, arbiter circuits, or the like to generate a PUF signal. In some examples, the PUF unit may comprise two or more ring oscillators with slightly different frequencies, e.g., due to manufacturing variations, and thereby generate a unique fingerprint associated only with the particular PUF unit. In some examples, the PUF unit may comprise arbiter circuits configured to make decisions based on the timing of signals to generate unique outputs. In some examples, the PUF unit may comprise metal interconnects formed on a chip and variations in resistance values of the metal interconnects may be used to generate unique fingerprints. In some examples, the PUF unit may comprise two or more transistors and differences in the behavior of transistors, e.g., due to manufacturing variations, may be used to generate a unique PUF signal (e.g., a unique analog or digital signal).

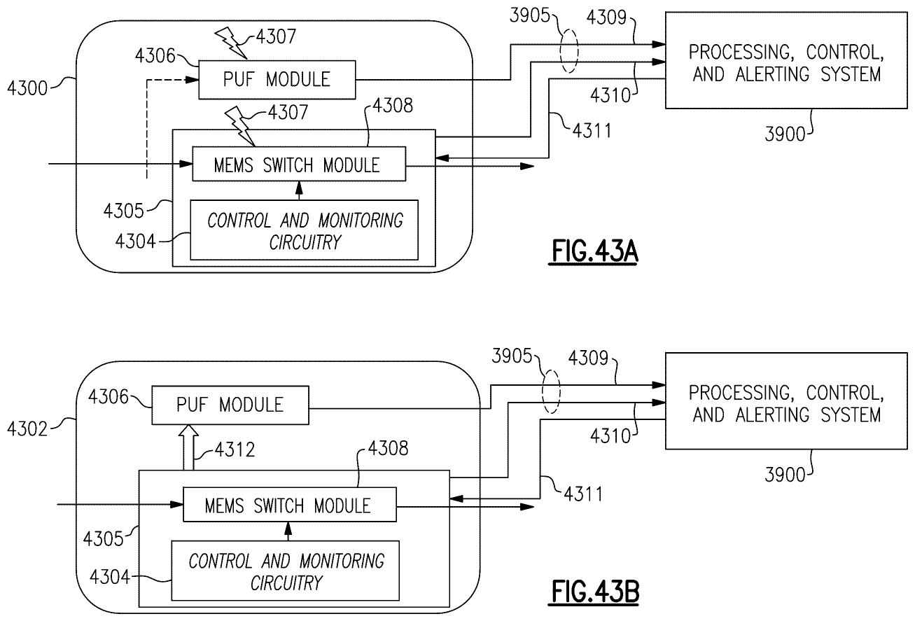

FIG. 43A schematically illustrates a node 4300 in communication with a PCA system 3900. In some embodiments, the node 4300 may comprise a MEMS switch or MEMS switch module 4308 configured to provide switching functionality or serve as a circuit breaker in a main circuit or a system comprising the node 4300. In some examples, the MEMS switch module 4308 may be connected between two terminals of the main circuit. In some cases, the node 4300 may further comprise a control and monitoring circuit 4304 configured to control and monitor the MEMS switch module 4308, and to generate and transmit measured data 4310 to the PCA system 3900. In some cases, the measured data 4310 may comprise switch evaluation data usable for assessing performance and/or a physical characteristic of the MEMS switch module 4308, or updating a model (e.g., a digital twin of the MEMS switch module). In some embodiments, the MEMS switch module 4308 and the control and monitoring circuit 4304 may be included in a switching module or a circuit breaker module 4305 of the node 4300. In some cases, the circuit breaker module 4305 may comprise the circuit breaker 2500 described with respect to FIG. 21.

In some embodiments, the PCA system 3900 may be configured to evaluate a current performance or predict a future performance of the MEMS switch module 4308 based at least in part on the received measured data 4310. In some cases, the measured data 4310 may comprise values of the operational and environmental parameters of the MEMS switch module 408. For example, switch evaluation data may comprise a measured state of the MEMS switch (e.g., ON state or OFF state), a ON resistance of the MEMS switch, or temperature of substrate region near the MEMS switch. In some cases, the measured data 4310 may comprise values of the operational and environmental parameters of the MEMS switch module 4308.

In some cases, the control and monitoring circuit 4304 may comprise one or more sensors configured to measure a current passing through the MEMS switch module, measure a voltage drop across the MEMS switch module 4308, and/or measure temperature near the MEMS switch module 4308. In some cases, the control and monitoring circuit 4304 may comprise a control logic configured to control the state of the MEMS switch module 4308 (e.g., to test the performance of the MEMS switch module 4308).

In some cases, the control and monitoring circuit 4304 may be configured to use at least one sensor and the control logic to test the operation of the MEMS switch module 4308. In some cases, the MEMS switch module 4308 may comprise two or more MEMS switches configured to collectively control electrical connection between two terminals of the system or the main circuit. In some cases, the control and monitoring circuit 4304 may be configured to use the sensors and the control logic to perform a testing process to evaluate the performance of the MEMS switch module 4308 and generate the measured data without interrupting the electric connection between the two terminals.

In some embodiments, the PCA system may be configured to generate and transmit a control signal 4311 to the control and monitoring circuit 4304 to control a parameter of the control and monitoring circuit 4304 based at least in part on outcomes of an analysis or evaluation performed based on measured data 4310.

In some embodiments, the node 4300 may comprise a PUF module 4306 configured such that the PUF module 4306 and the MEMS switch module 4308 are arranged to be exposed to substantially the same operational and/or environmental conditions. In some embodiments, the PUF module 4306 or at least a PUF circuit of the PUF module may be disposed adjacent to the MEMS switch module 4308. In some embodiments, the MEMS switch module 4308 and the PUF module 4306 (e.g., a PUF circuit of the PUF module) may be disposed or fabricated on a common substrate.

In some embodiments, the PUF module 4306 may be configured to generate and transfer a PUF signal 409 (PUF output) to the PCA system 3900. In some such embodiments, the PCA system 3900 may be configured to evaluate current performance or predict future performance of the MEMS switch module 4308 based on both measured data 4310 and the PUF signal 4309 (the measured data 410 and the PUF signal 4309 may be collectively referred to as node data). In some embodiments, the PUF module 4306 may be configured to generate a unique PUF signal 4309 when the environmental and operational parameters of the MEMS switch module 4308 (and thereby the PUF module 4306) are within a specified range. When the PCA system 3900 receives the node signal comprising the measured data 4310 and the PUF signal 4309, it may first determine whether the PUF signal 4309 is identical to a specified or reference PUF signal stored in a memory of the PCA system 3900 and upon verifying that the PUF signal 4309 is identical to the reference PUF signal 4309, and therefore the PUF signal 4309 is not altered, the PCA system 3900 may trust the measured data 4310 and process the measured data 4310 to analyze the performance of the MEMS switch module 4308 or update a digital twin model. In other words, the PUF signal 4309 may be used to authenticate the measured data 4310. Conversely, if the PCA system 3900 determines that the PUF signal 4309 has been altered and is not identical to the specified or reference PUF signal stored in the memory of the PCA system 3900, the PCA system 3900 may discard the measured data 4310. In some embodiments, the unique PUF signal 4309 may be altered when an operational and/or an environmental parameter change beyond a specified range or a specified threshold. In some embodiments, the unique PUF signal 4309 may be altered if an adversary tampers with the MEMS switch module 4308 or the control and monitoring circuitry 4304, causing the measured data 4310 to no longer accurately represent the actual condition of the MEMS switch module 4308.

Still referring to FIG. 43A, in some embodiments, the PUF signal 4309 may be used in the regeneration or recovery process of a cryptographic key. The regenerated cryptographic key may be used to authenticate the measured data, for example through the generation of a cryptographic digital signature or message authentication code. If the environmental conditions or activities of an adversary alter the behavior of the PUF module 4306 such that the regenerated cryptographic key differs from its normal value (e.g., associated with normal environmental condition or absence of adversary intervention) by more than a specified threshold number of bits, the PCA system 3900 will be unable to generate a valid digital signature. In this case, the PCA system 3900 is configured to not authenticate the data, as without the cryptographic key the PCA system 3900 does not generate a valid cryptographic digital signature or message authentication code over the measured data 4310. Thus, the PCA system 3900 or a system receiving measured data 4310 from the PCA system 3900 does not need to rely on the control and monitoring circuit 4304 operating correctly (e.g., correctly or honestly assessing the state of the MEMS switch module 4308 and generate correct and reliable measured data 4310), as the change in environmental conditions or an adversarial intervention forcibly prevents the PCA system 3900 from mis-attesting or mis-authenticating the data. In some embodiments, the PCA system 3900 may use a standard cryptographic key extractor (e.g., based on a hash function, key derivation function, or similar technique) to regenerate the cryptographic key from the PUF signal 4309. In other embodiments, the PCA system 3900 may use a fuzzy extractor to generate or regenerate the cryptographic key from the PUF signal 4309, ensuring reproducibility when the PUF signal 4309 is noisy but within the tolerance supported by the fuzzy extractor. In some embodiments, the fuzzy extractor may include an error-correcting code (ECC). The ECC is configured to enable regeneration of a cryptographic key in the presence of noise by correcting up to a specified number of erroneous bits in the PUF signal 4309. In some cases, during the regeneration process, the ECC may use helper data generated in the enrollment phase to reconstruct the original representation of the noisy input, ensuring that the same cryptographic key can be derived even when the input varies slightly.

In some embodiments, the PUF module 4306 may be located near the MEMS switch module 4308 such that an environmental event 4307 (e.g., a change in temperature, humidity, strength of an electric or magnetic field, and the like) affects both the PUF module 4306 and the MEMS switch module 404. In some embodiments, the PUF module 4306 and the MEMS switch module 404 may be connected to a common terminal so a change in the voltage or current received by the terminal affects both the PUF module 4306 and the MEMS switch module 4308.

In some embodiments, when the PUF signal 4309 is unaltered and the PCA system 3900 determines a status of the MEMS switch module by processing the measured data 4310, the PCA system 3900 may generate a control signal 4311 to change a parameter of the control and monitoring circuit or another control circuit that controls the states of the MEMS switch module 4308 during an operational period, based on an outcome or determination resulting from processing the measured data 4310. For example, by processing the measured data 4310 the PCA system 3900 may determine that an activation voltage of the MEMS switch module 4308 has increased and in response to such determination, it adjusts a voltage provided by the control and monitoring circuit or another control circuit to activate the MEMS switch module 408. In some cases, activation voltage may comprise a lower bound for a control voltage provided to a back control electrode of a MEMS teeter-totter switch to change the state of the MEMS switch from ON to OFF by disconnecting the switching end (front end) of the conductive beam and from contact electrode of the MEMS switch.

In some embodiments, the node 4300 may comprise a second MEMS switch module electrically connected in parallel with the first MEMS switch module between the two terminals of the main circuit. In some cases, the control and monitoring circuit 4304 may comprise a sensor electrically connected to the MEMS switch module 4308 and configured to generate a sensor signal, and a control logic communicatively coupled to the MEMS switch module 4308 and the second MEMS switch module and the sensor. In some examples, the sensor may comprise a current sensor connected in series with the MEMS switch module 408. In some other examples, the sensor may comprise a voltage sensor connected in parallel with the MEMS switch module 4308. In some embodiments, the control logic of the control and monitoring circuit 4304 may be configured to transmit an activation or a deactivation signal to the first MEMS switch module while the second MEMS switch module is inactive (in ON state), receive changes in the sensor signal caused by the activation or a deactivation signal and generate switch evaluation data based at least in part on the received changes in the sensor signal.

FIG. 43B schematically illustrates another node 4302 in communication with a PCA system 3900. In some embodiments, the node 4302 may comprise one or more features described above with respect to the node 4300, the details of which are not repeated herein for brevity. Unlike the node 4300 described above with respect to FIG. 43A, the MEMS switch module 4308 and the PUF module 4306 in the node 4302 may be connected or otherwise be in communication with each other via a physical coupling mechanism 4312 (e.g., mechanisms to couple thermally, electrically, magnetically, electromagnetically and the like) such that the PUF module 4306 can be affected or perturbed by minute changes in the MEMS switch module 4308 not indicated by the measured data 4310. In some cases, the state of the MEMS switch module 4308 may not be captured by the measured data 4310 due to insufficient sensitivity of the sensor used to detect its actual state. In other cases, the measured data may not reflect the correct state of the MEMS switch module 4308 because an adversary has tampered with the control and monitoring circuit 4304. Additionally, the measured data may accurately indicate the state of the MEMS switch module 4308, but that state may have been forcibly altered by an adversary. In all these scenarios, the PCA system 3900 is configured to not regenerate the cryptographic key from the PUF signal 4309 and, therefore, no electronically sign the measured data 4310. Without a digital signature, the PCA system 3900 may neither use the measured data 4310 to generate the control signal 4311 nor transmit the measured data 4310 to another system for further processing.

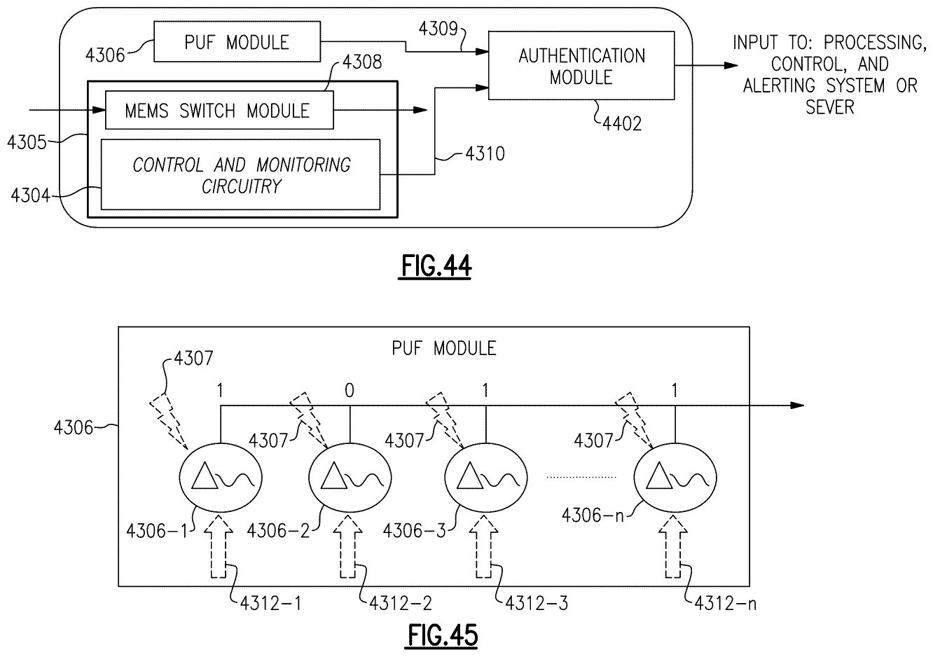

In some embodiments, an authentication module separate from the PCA system 3900 may receive the measured data 4310 and the PUF signal 4309, and control transmission the measured data 4310 to the PCA system 3900 based on the PUF signal 4309. FIG. 44 schematically illustrates a node comprising an authentication module 4402 configured to receive the measured data 4310 and the PUF signal 43309, authenticate the PUF signal 4309, and in response to authentication of the PUF signal 409, transmit the measured data 4310 to the PCA system 3900.

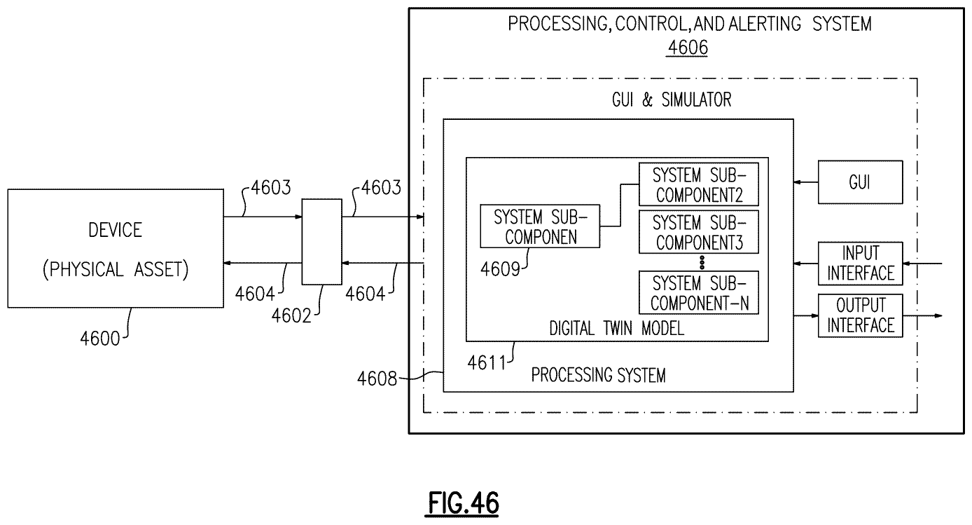

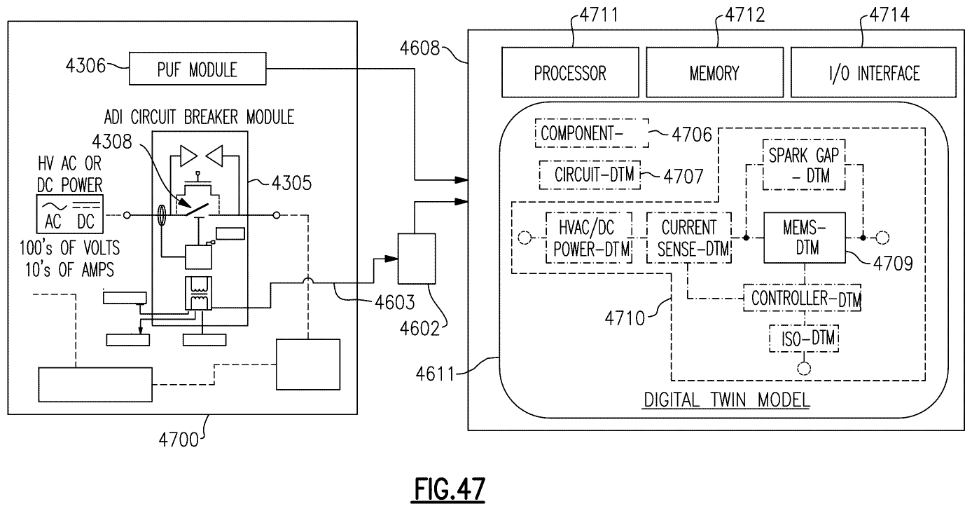

In some embodiments, the PUF module 4306 may comprise two or more PUF units or circuits and the PUF signal may comprise a code or sequence formed using the outputs of the two or more PUF units or circuits. FIG. 45 schematically illustrates an example PUF module 4306 comprising n PUF units or circuits 4306-1, 4306-2, . . . , 4306-n, which are coupled/connected to the MEMS switch module 4308, are connected to a terminal to which MEMS switch module 4308 is connected or are exposed to the same environmental condition 4307 as the MEMS switch module 4308. In some embodiments, an individual PUF units or circuits may generate a digital output and the PUF signal output by the PUF module 4306 may comprise a bit string formed by the digital outputs of the individual PUF units or circuits 4306-1, 4306-2, . . . , 4306-n.

MEMS Switch Systems with Diagnostic Capability Using Digital Twin Models

As described above, in some embodiments, the node data generated by a node in a system (e.g., the system shown in FIG. 39) may be used to generate a digital twin model (DTM) for a physical asset or a device in the node. In some such embodiments, the digital twin may comprise a digital twin model of the device (e.g., a digital mathematical model of the device capturing various features of the device) that can be updated using the data measured or received a node, herein referred to as node data. The DTM may be used to determine a current status or health of the device or predict a future behavior of the device (e.g., a probability of failure or otherwise a change requiring attention). In some cases, the DTM model may comprise a digital model (e.g., a parametric digital model) implemented using a computing system (e.g., by a hardware processor executing machine readable instructions). In some cases, the DTM may comprise a digital model stored in a non-transitory memory of a computing system. In some cases, an outcome generated using the DTM model may be used to determine a characteristic or variation of a characteristic of the device. In some such cases, the system may use the DTM to determine a wear rate or potential failure of the device at a later time. In some embodiments, in response to determining the wear rate or the potential failure of the device, the system may trigger a preventive action (e.g., repair or replace the device) or adjust an operational condition or control parameter of the device to delay the potential failure or prolong the lifetime of the device.

In some embodiments, the digital twin model (DTM) may be implemented in a processing, control, and alerting (PCA system) system that receives the node data from the node (e.g., a device in the node) via a wired link (e.g., the central hub 3902) or a wireless link. In some embodiments, the DTM may be implemented in a system (e.g., computing system) separate from the PCA system and in communication (e.g., via a wired or wireless link) with the PCA system. In some cases, the PCA system or the computing system may comprise a graphical user interface (GUI) configured to allow a user to update a model, run the model based or parameter values received from a node or provided by the user, explore different aspects of the device behavior in the past or future, or otherwise interact with the DTM to generate a desired output. In some cases, the computing system can be a remote computing system (e.g., a cloud network) that is in communication with the PCA system (e.g., via internet). In some cases, one or more user computing systems may be in communication with the remote computing system to modify or update the DTM, generate data using the DTM and the node data (e.g., received from the PCA system), and/or receive/analyze outcomes of a data generated by the DTM using the node data.

In some embodiments, digital twin model (DTM) may comprise a virtual digital representation of the device, a component in the device, a circuit, and/or a sub-circuit in the device, generate by a hardware processor by executing machine readable instructions stored in a non-transitory memory of the system (e.g., a non-transitory memory of the PCA system). In some cases, a DTM may comprise a virtual digital representation of a single device or multiple devices in the node. In some embodiments, the DTM for a device or module can be developed based on a set of industry standards and a specified format allowing for modular approach where the DTM can be incorporated into a variety of systems. In some embodiments, the PCA system or the computing system (e.g., the remote computing system) may generate the virtual digital representation of the device by executing machine-readable instructions stored in a non-transitory memory, received from a communication link, and/or provided by a user. In some such embodiments, the machine-readable instructions may comprise a mathematical model of the device, a portion of the device, or function of the device. In some cases, the virtual digital representation, also referred to as digital representation, of the device may comprise a computer model of the device that can replicate a characteristic and/or a behavior of the device and allow determination of temporal variation of the characteristic under given operational conditions (e.g., given mission profile) and given input parameters. In some cases, the input parameters of the DTM or digital representation may comprise a parameter that its value can be measured at a node (e.g., by a sensor) or extracted (e.g., calculated) from the node data. In some embodiments, the digital representation or computer model may comprise one or more device parameters that can be adjusted or updated such that the digital representation closely replicates a characteristic, variation of the characteristic or behavior of the device. In some such embodiments, the digital representation or the computer model of a device may comprise a parametric model of the device and one or more parameters of the of the digital representation or the computer model may be adjusted based on diagnostic data (also referred to as diagnostic information or evaluation data) received from the device or a monitoring circuit in communication with the device, e.g., to capture changes of a characteristic of the device. For example, the digital representation or the computer model of a MEMS device used in a node may comprise a generalized parametric model for MEMS devices of the same type where one or more parameters of the of the model are adjusted based on the diagnostic data received from an individual MEMS device to capture deviation of a characteristic or behavior of the MEMS device from a corresponding base characteristic or behavior, e.g., due to exposure to a specific set of inputs and environmental conditions, aging, a specific mission profile, or the like. In some implementations, the diagnostic data may be generated by a specific procedure (e.g., a test procedure such as the self-test process described above with respect to FIGS. 33-38) or collected during the operation of the device (e.g., without using a test procedure or testing circuit). In some examples, the evaluation or diagnostic data may include, a die temperature, an environmental temperature, a voltage, a current (provided to and transmitted through a device), a number of operations or cycles (e.g., switching operations), a resistance (e.g., an ON resistance of a MEMS switch), an electrical over stress (EOS) event (e.g., transient EOS event), and excursion beyond a specified threshold (e.g., temperature, current, or voltage threshold), a mission profile parameter, on-time (e.g., cumulative on-time of a switch), off-time (e.g., cumulative off-time of a switch), energy usage (e.g., including peak, and/or quiescent), an inrush current, an activation or deactivation voltage of the MEMS switch, a response time of the MEMS switch or the like. In some cases, the response time of a MEMS switch may comprise a delay between providing an activation (or deactivation) voltage to a control electrode of the MEMS switch and physical activation or deactivation of the MEMS switch (e.g., formation or breaking of an electrical connection via the MEMS switch). In some cases, diagnostic data may be included in the node data. In some cases, the diagnostic data may be encrypted prior to transmission to the PCA system or the computing system (e.g., through the central hub 3902). In some cases, the diagnostic data may comprise a source identification (source ID) indicating a source or origin of the diagnostic data. In some cases, the source ID can be a device ID of a device from which the diagnostic data is originated (e.g., the device under test). In some cases, source ID may be encrypted prior to transmission. In some examples, the source ID may uniquely identify the device. In some embodiments, a PUF circuit exposed to a common operation or environmental condition as the device under test may generate a PUF signal that can be used to evaluate validity and/or reliability of diagnostic data received from the device. In some embodiments, a DTM of a device may be updated (e.g., sporadically or periodically) by the system based at least in part on diagnostic data received from the device or from a sensor that is either physically connected to the device (e.g., via thermal, electrical, or similar means) or commonly exposed to the same physical conditions as the device. In some embodiments, the DTM of the device may be updated (e.g., sporadically or periodically) by a user via a user interface (e.g., a user interface of the PCA system or a remote user interface). For example, a user may update, revise, or replace a mathematical model used by the system to generate the DTM of the device. In some cases, a module or system containing a MEMS switch or MEMS switch module, MEMS-based circuit breaker or other systems/subsystem described above may comprise a portal through which DTMs of the systems or nodes in which the MEMS switch or MEMS switch module, MEMS-based circuit breaker is embedded. In some cases, this may enable multiple different nodes/systems to be monitored and functional safety and operational status to be compared and monitored in parallel and real time.

In some embodiments, the diagnostic data (at least a portion of the diagnostic data) may be fed to the DTM to generate a predicted lifetime, an efficiency metric, functional safety status, operational status, a recommended action (e.g., replace, repair), a recommended time (e.g., replacement time, repair time) for the recommended action, a status of the corresponding device, or the like. The diagnostic data could also include monitor data related to the immediate/surrounding environment (e.g., temperature, vibration, EOS event etc.)

In some embodiments, PCA system may comprise an action module configured to process output data generated by the DTM (e.g., a DTM updated based on diagnostic data) to generate: a recommendation for preventive maintenance, an alert indicative of a potential or actual failure, or a control signal to adjust an operational condition or control parameter based. In some cases, output data generated by the DTM may be provided (e.g. transmitted via a wired/wireless link) to the action module for preventive maintenance or alert generation. In some examples, recommendation for preventive maintenance may comprise a recommendation for repairing a device or replacing the device (including a suggested time for replacing or repairing a device).

In some embodiments, a DTM may be updated, optimized, or debugged based at least in part on node data (e.g., diagnostic data) received from a node comprising the device, component or circuit associated with the DTM. In some cases, updating and/or optimizing the DTM may comprise improving a functionality or a timing performance of the DTM. In some cases, the computing system or a user may check validity of evaluation/diagnostic data prior to processing the evaluation/diagnostic data (e.g., to identify and discard invalid data). In some cases, the computing system or a user may test the DTM by running test simulations that generate debugging information usable for debugging the DTM.

In some embodiments, diagnostic data (diagnostic information) may be received from plurality of probes or sensors configured to generate sensor signals indicative of value of a device parameter (e.g., temperature of a device, mechanical stress in the device, functional safety status of a device), or value of a voltage or current provide to (or received) from the device. As such, in some examples, diagnostic data may comprise diagnostics arising from combination of events intrinsic and external to a device.

FIG. 46 illustrates a block diagram of a system comprising a device 4600 (or otherwise a physical asset) that is controlled and/or monitored by a control and processing system 4606. The control and processing system (or circuit) 4606 may be in communication (e.g., two-way communication) with the device 4600 via a communication link 4602. In some examples, the communication link 4602 may comprise a wired link, a wireless link, or a combination thereof. The PCA system 4606 may receive diagnostic data (diagnostic information) 4603 from the device 4600 and may send control data/signals (commands) 4604 to the device 4600. In some cases, the diagnostic data 4603 may comprise the measured data 410 described above with respect FIGS. 43A, 43B, and 5. In some cases, the diagnostic data 4603 may comprise measured characteristics and parameters associated with the device 4600 (e.g., a circuit breaker) or a component (e.g., a MEMS switch). In some cases, the diagnostic data 4603 may comprise extracted characteristic of the device 4600 or extracted value of a parameters associated with the device 4600. For example, a processor or a circuit of the device 4600 may be configured to use measured data and/or signals (e.g., sensor signals received from a sensor) to calculate or determine the characteristic or the value. In some embodiments the PCA system 4606 may be in communication (e.g., two-way communication) with the device 4600 via communication link 4602. In some cases, the device 4600 can be a device in one of the nodes of the system shown in FIG. 1A and the PCA system 4606 may comprise (or may be included in) the PCA system 3900 or a computing system. The communication link 4602 may comprise a wired or wireless link (e.g., the central hub 3902, wired links, or wireless links described above with respect to FIGS. 39, FIG. 40, FIG. 41, and FIG. 42, respectively.

In some embodiments, the PCA system 4606 may compromise a processing system 4608 configured to process/use diagnostic data 4603 received from the device 4600, generate control signals 4604 and transmit them to the device 4600, receive and output data via input/output interfaces, or a graphical user interface (GUI). In some embodiments, the processing system 4608 may comprise a DTM 4611 or the device 4600 implement in a computing system and configured to serve as dynamic and updatable digital representation of the device 4600. In some embodiments, the PCA system 4606 can be an edge computing. In some cases, at least a portion of the processing system 4608 may reside in a remote computing system in communication with the control and processing system 4606. system. In some cases, the entire digital model may reside in the PCA system 4606 and may be updated locally. In some embodiments, the DTM 4611 may comprise DTM of one or more components or sub-components of the device 4600. In some examples, DTM 4611 may comprise a DTM of a main component (e.g., a MEMS switch module) and one or more components (e.g., controllers, sensors, spark gaps, and the like) connected to the main component. In some examples, comprise a DTM of a main component (e.g., a MEMS switch module) comprising DTMS of multiple sub-components (e.g., multiple MEMS switch modules). In some embodiments, the device 4600 may comprise a MEMS switch (e.g., a teeter-totter MEMS switch), or a circuit breaker comprising a MEMS switch. In some such embodiment, the MEMS switch, or the circuit breaker may comprise the teeter-totter MEMS switches described with respect to FIGS. 1A-1B, 2A-2C, 3A-3C, 4A-4B, 5A-5B, and 6A-6C, and circuit breakers described with respect to FIGS. 20-21, respectively. In some cases, the diagnostic data 4603 may comprise measured characteristics and parameters associated with a MEMS switch (e.g., voltage across the MEMS switch, current passing through the MEMS switch, ON resistance of a MEMS switch, number switching cycles in a period, temperature of the MEMS switch substrate, and the like). In some cases, a main DTM 4609 may comprise DTM of a MEMS switch or module implemented based on an analytical or empirical mathematical model. In some cases, the mathematical model may comprise features determined based on a series of measurements, experiments, and tests configured to capture certain aspects of the MEMS switch, its performance, and variations of its characteristics. In some cases, the mathematical model that may be updated based on diagnostic data 4603 and configured to predict variation of characteristics of a MEMS switch (e.g., under a given or measured mission profile).

In some embodiments, diagnostic data 4603 may be provided to the DTM 4611, and the DTM 4611 may configured to determine or predict a characteristic or variation of the characteristic of the device 4600. In some such embodiments, the DTM 4611 may be further configured to and the DTM 4611 may configured to generate control signals 4604 based at least in part of the determined or predicted characteristic or variation of the characteristic of the device 4600 and transmit the control signals 4604 to the device 4600 or a circuit controlling the device 4600 and/or one or more extrinsic parameters affecting or influencing the device 4600. As such, in some embodiments, the DTM 4611 can be in bidirectional communication with the device 4600.

FIG. 47 illustrates a block diagram of a system comprising a node or system 4700 and a processing system 4608 configured to generate a DTM 4611 of one or more modules, components, and/or circuits of the system 4700. In some embodiments, the system 4700 may comprise a circuit breaker 4305 implemented based on a MEMS switch module 408. In some cases, the DTM 4611 may comprise a DTM 4709 of the MEMS switch 4308. In some such cases, the DTM 4611 may comprise a DTM 4710 comprising the DTM 4709 of the MEMS switch 4308, a component-DTM 4706 of a component or device (e.g., in the circuit breaker 4305), and/or a circuit-DTM 4707 of a circuit (e.g., in the circuit breaker 4305), where the component/device and/or circuit can be connected to or otherwise be associated with the MEMS switch 4308. The processing system 4608 may comprise a processor 4711, a memory 4712 (e.g., a non-transitory memory), and input/output interface 4714. In some cases, the processor 4711 may execute machine readable instructions stored in the memory 4712 to generate the DTM 4611 and the DTMs 4710, 4709, 4706, and 4707 therein. In some cases, cases at least a portion of the DTMs 4710, 4709, 4706, and 4707 may be stored in the memory 4712. In some such cases, the processor 4711 may be configured to receive diagnostic data or updated values of a device parameter generated based diagnostic date to update the digital.

In some embodiments, the circuit breaker module 4305 may generate diagnostic data 4603 associated with the MEMS 4308, and one or more other components/devices/circuits in the circuit breaker module 4305, or otherwise in the system 4700 and transmit the diagnostic data 4603 to the processing system 4608 via the communication link 4602 to update the DTM 4611 and/or the DTMs 4710, 4709, 4706, and 4707 therein. In some embodiments, the system 4700 may include a PUF module 4306 configured to transmit a PUF signal to the processing system 4608. In some such embodiments, the processing system 4608 may use the PUF signal to determine the validity and/or reliability of the diagnostic data 4603.

As described above, diagnostic data (e.g., diagnostic data 4603) may comprise values of a device parameter (herein referred to as intrinsic parameter), or a parameter external to the device (e.g., a parameter associated with a mission profile of the device). In some embodiments, an intrinsic parameter may comprise an intrinsic parameter of a device that can be measured and quantified independent of external (or extrinsic) parameters and when the device is isolated (e.g., disconnected from a circuit to which it may be connected in an operational period). In some embodiments, an extrinsic parameter may cause an intrinsic parameter change or shift. In some such embodiments, the DTM of the device may comprise a model (e.g., an analytical, empirical experimental, or semi-empirical model) configured to determine a variation of an intrinsic parameter as a function of an extrinsic parameter. In some cases, this model may be used by the processing system (e.g., processing system 4608) to estimate a value or a variation (e.g., a current or future blue) of an intrinsic parameter based on diagnostic data. In some such cases, the processing system may use the estimated value/variation to determine a time left until the value of the intrinsic parameter satisfies a threshold condition. In some examples, the threshold condition may comprise a failure of the device. In some embodiments, the estimated value/variation of the intrinsic parameter may be used (e.g., by an action module of the processing system) to trigger an action by a user or the processing system to prevent, manage or mitigate the predicted failure. In some embodiments, the device may comprise a MEMS switch module the intrinsic parameters may comprise an intrinsic property of the MEMS switch module (e.g., associated with a design, geometry, material properties, and the like)) and the extrinsic (external) parameters may comprise operational and environmental parameters that can affect the intrinsic parameter, e.g., during particular an extend period.

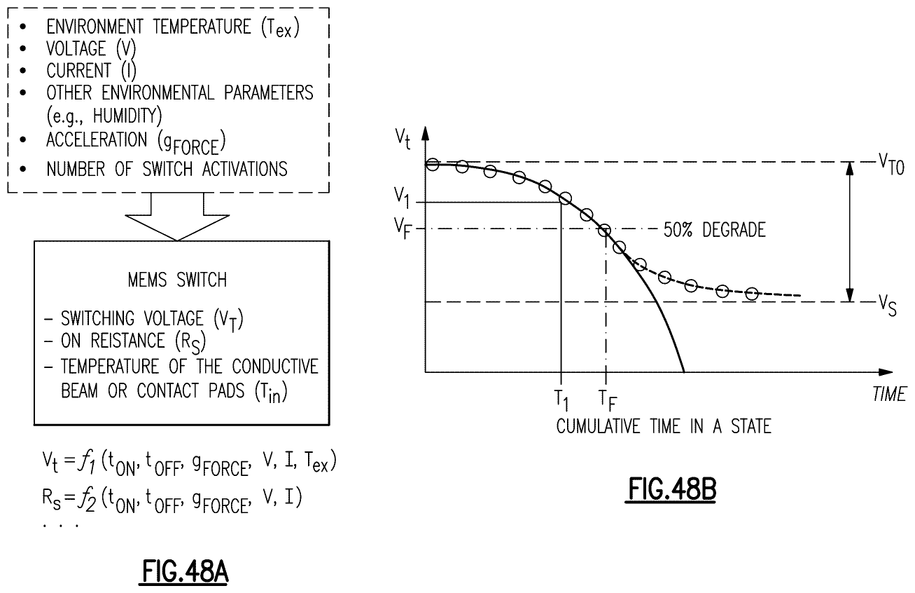

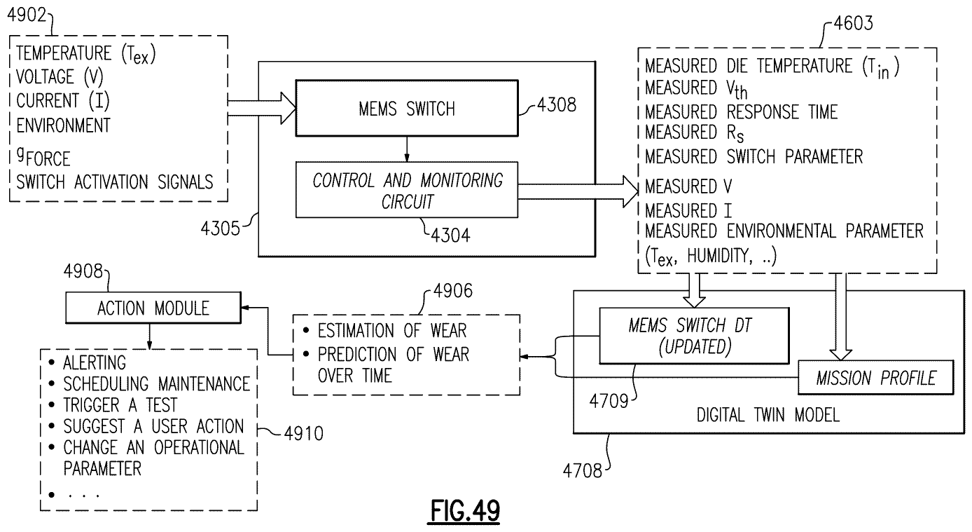

FIG. 48A schematically illustrates some of the extrinsic and intrinsic parameters of a MEMS switch indicating that the intrinsic parameter can be affected/influenced by the extrinsic. Nonlimiting examples of extrinsic parameters may include: environmental temperature (Tₑₓ), a voltage (V) applied to the MEMS switch, a current (I) passing through the MEMS switch, number of switch activations, acceleration (g_{Force}), or humidity. Nonlimiting examples of intrinsic parameters may include: switching voltage (V_{T}), ON resistance (Rₛ), or temperature of the conductive beam or a contact pad (Tᵢₙ). In some embodiments, dependence of an intrinsic parameter to an extrinsic parameter may be modeled using a function (ƒ) determined based on a theoretical analysis of the MEMS switch, experimental data generated by a characterization process, or a combination thereof. In some cases, the characterization process may comprise testing one or MEMS switch under varying conditions and/or extended periods. In some examples, experimental data may be used to generate an statistical analysis over a large number of test cycles or large number of MEMS switches. The outcomes of the statistical analysis may be used to generate the DTM and/or the function (ƒ) therein. In some embodiments, ƒ may be used to determine a value or variation of an intrinsic parameter based on values of intrinsic parameter included in the diagnostic data. For example, the impact of a cumulative ON time (tₒₙ), a cumulative OFF time, g_{Force}, V, I, and/or Tₑₓ, on V_{T} may be quantified by a function (ƒ₁) implemented in the DTM, and an calculated value of V_{T} using ƒ₁ may be compared to a specified value to determine a status of the MEEMS switch.

In some embodiments, DTM of a MEMS switch or module may be configured to determine and/or predict variation or degradation level of a conductive beam (e.g., conductive beam creep or fracture), a contact pad (e.g., melting, wear, or deformation of the contact pad), or changes in dielectric dielectrics charge. In some cases, the structure or material properties of the conductive beam and/or contact pad of MEMS switch may degrade over time as a result of: extended exposure to elevated temperature (e.g., a temperature above the room temperature), cumulative ON time or OFF time (e.g., sum of time intervals during which the MEMS switch is an ON state or OFF state respectively), switching voltages larger than a safe level, transmitting electric current larger than a safe level, extended exposure to current and voltages within a safe level, acceleration, or other factors.

In some embodiments, a system and/or a user may use a combination of mathematical modeling and experimental characterization to determine dependence of a characteristics of the MEMS switch on one or more extrinsic parameters (e.g., the function ƒ₁). In one example, for a given ƒ₁, which may be provided by a user or stored in a memory of the processing system 4608, the processing system may use a DTM configured based on ƒ₁ and the diagnostic data 4603 received at time t₁ to determine V_{T} (V_{T,ON}: threshold voltage for switching ON the MEMS switch, or V_{T, OFF}: threshold voltage for switching OFF the MEMS switch) at a later time t₂ (t₂>t₁) for a MEM module deployed in the field. In this example, the diagnostic data 4603 can include a value of V_{T} extracted based on one or more measurements performed during operation of the MEMS switch or during a test process, which may have been triggered by the processing system 4608 using controlled signals 4604. In some embodiments, the processing system 4608 may trigger a test process performed by a control and monitoring circuit (e.g., the control and monitoring circuit 4304) where activation (or deactivation) voltage provided to a control pad of the MEMS switch is increased (continuously or stepwise) while measuring conductance between corresponding contact and conductive beam of the MEMS switch (e.g., by measuring a current or voltage) to determine V_{T}. In some cases, the processing system 4608 may further use the DTM to determine variation of creep or mechanical yield of a at least portion of the corresponding MEMS structure, or stickiness of a contact electrode/pad of the MEMS switch.

In some cases, when a switch is held in the on-state for long periods, the conductive or cantilever therein may weaken due to mechanical creep. Such mechanical creep can be manifested as V_{T} drop.

FIG. 48B illustrates an example variation of V_{T} (e.g., V_{T, ON}, or V_{T, OFF}) for a MEMS switch as a function of cumulative time that MEMS switch is kept in a state (e.g., ON state or OFF state) during a measurement period. The solid line can represent an expected behavior of V_{T} based on a theory, the circles can be experimentally measured data points, or average values calculated based on a series of measured data points, collected during a characterization period, during a previous test process, or during a previous operation period. The dashed line may represent V_{T}'s based on a modified model/theory corrected or adjusted based on the measured data (circles). In some cases, measured data may be compiled based on characterization data collected using a plurality of MEMS switched of the same type (e.g., having the same design, geometry, and material properties) expected to have substantially the same characteristics.

In some cases, the modified model/theory may comprise a saturated power law indicating that is the MEMS switch is used V_{T} degrades from an initial value V_{T0} to values that asymptotically move toward a saturated value V_{S}. In some cases, the dashed line and/or the corresponding modified model/theory may be used to develop a DTM of the MEMS switch to determine variation of V_{T}. For example, the processing system 4608 may use the measured/extracted value of V_{T}=V₁ at T₁ to predict a future value of V_{T} at a later time. In some cases, the DTM may be used to predict a cumulative time at a certain state before V_{T} degrades to a specified threshold value V_{F} at which a maintenance, a warning, or otherwise a corrective action may be required. For example, the specified threshold value can be a percentage (e.g., 50%) of the difference between the initial value V_{T0} and a saturated value V_{S} and a failure time TF can be a time at which V_{T} becomes substantially equal to V_{F} (e.g., within a specified margin of error). A such, a DTM based on the modified model/theory may be used to generate an output indicative of a time or time frame for maintenance, warning, or corrective action based on diagnostic data 4603.

FIG. 49 is a block diagram illustrating data flow from the circuit breaker 4305 to the DTM 4611 of the MEMS switch 4308 therein, and from the DTM 4611 to an action module (e.g., a control and alerting subsystem) 4908 configured to generate a recommendation, an alerts, or a control signal to adjust an operational condition or control parameter of the circuit breaker 4305 or the MEMS switch 4308 based on data (e.g., modeling results) received from the DTM 4611. In some embodiments, the performance of the MEMS switch (or MEMS switch module) 4308 may be affected by one or more external (or extrinsic) parameters 4902 (parameters external to the MEMS switch) and/or one or more internal (or intrinsic) parameters. Examples of external parameters, can include but are not limited to: ambient temperature, a voltage applied across the MEMS switch 4308, a current passing through the MEMS switch 4308, a g_{force} or acceleration of the MEMS switch 4308, an activation or deactivation signal provided to a control electrode of the MEMS switch, other environmental conditions (e.g., humidity), and the like. Examples of internal parameters can include but are not limited to: die or substrate temperature, activation threshold voltage, deactivation threshold voltage, response time, ON resistance (Rₛ), response time, and the like. In some embodiments, the control and monitoring circuit 4304 may be configured to measure one or more extrinsic parameter and intrinsic parameter of the MEMS switch and generate diagnostic data 4603 diagnostic data 4603 comprising measured values of the measured intrinsic and extrinsic parameters.

In some cases, the diagnostic data 4603 may be provided to a DTM 4611 which may include a DTM 4709 of the MEMS switch module 4308 and, in some cases, a model for determining a mission profile of the MEMS switch model based on the measured extrinsic parameters. In some embodiments, the control and monitoring circuit 4304, the circuit breaker 4305, and/or a system that includes the MEMS switch (or MEMS switch module 4308) may comprise sensor (e.g., temperature, vibration, EOS monitor, and the like), a storage or memory (e.g., a non-transitory memory) where measured values of internal parameter, external parameters, and/or other data associated with the MEMS switch 4308 or the MEMS-based circuit breaker 4305 may be stored. In some cases, one or more of these sensors can be used to monitor the environment in which the MEMS switch 4308 and the circuit breaker 4305 are placed. In some cases, the memory/storage can also contain thresholds/limits/mission profiles that can be used to compare/review against the data being recorded.

In some embodiments, the model for determining the mission profile may comprise a machine learning classification algorithm configured to determine the mission profile based on diagnostic data 4603 received during an extended period. In some cases, at least a portion of the mission profile of the MEMS switch module 4308 may provided to the processing system 4608 by a user (e.g., via the I/O interface 4714).

In some embodiments the MEMS switch module 4308 may contain sensors (e.g. a temperature sensor, a vibration sensor, a voltage sensor, an EOS monitor) such that the immediate/surrounding environment can be monitored. This could enable digital twin models to be created where multiple remote locations could be centrally monitored.

In some embodiments, the DTM 4611 may generate DTM outcomes 4906 comprising an estimation of wear or prediction or wear over time based on the calculations performed by DTM 4709 based on diagnostic data 4603 and, in some cases, taking into account a determined mission profile. In some cases, taking into account the mission profile may improve the accuracy of estimations (e.g., wear estimation or prediction) provided by the DTM 4611.

In some embodiments, an action module 4908 may receive the DTM outcomes 4906 and use the DTM outcomes 4906 to generate an alert, schedule a maintenance, trigger a test, suggest a user action, a change an operational parameter, or the like.

In some embodiments, a DTM 4611 may be used to model at least a portion of a system comprising the circuit breaker 4305 to provide insightful monitoring and control over the circuit breaker 4305 and the MEMS switch module 4308 therein.

In some embodiments, one or both DTM 4611 and DTM 4709 may be updated by diagnostic data 4603, which comprises measured and calculated data indicative of a value of an intrinsic and extrinsic parameter, to generate DTM data for predictive maintenance and/or mission profile monitoring. In some cases, predictive maintenance may comprise generating a control signal to change or adjust value of an extrinsic parameter, value of a device control parameter, providing instructions/recommendations for a manual device/module repair, replacement, or upgrade, e.g., on determined wear or wear rate, or initiating a test (e.g., a self-test procedure as described with respect to FIGS. 33-38).

In some embodiments, the circuit breaker 4305 may also contain sensors capable of monitoring the surrounding environment (e.g., temperature sensor, vibration sensor, EOS monitor and the like). In some cases, the signals generated by these sensors may be used to generate and/or update DTM 4710. In some cases, the node or system 4700 may be used to monitor, diagnose and model multiple remote systems communicatively connected to the node or system 4700.

TABLE 2 below includes example parameters of a MEMS switch or MEMS switch module that may be measured (first column), a feature of the MEMS switch that may be modelled based on the measured parameter (second column), and an outcome of the modelling with respect a performance of the MEMS switch (last column). In some cases, measured value of a MEMS switch parameter may be transmitted to a digital twin model of the MEMS switch as diagnostic data 4603 for determining a current and/or future health state of the MEMS switch, and/or a MEMS-based circuit breaker.

TABLE 2

| | | | Typical |
|---|---|---|---|
| Category | Parameter | What to Model | Drift/Degradation |
| Electrical - | Turn-on | Switching | Response-time |
| Switching | delay and | delay, gate- | drift which may |
| | Turn-off | driver | be caused by |
| | delay | behavior | aging charge |
| | | | trapping in |
| | | | the MEMS switch |
| | | | (e.g., within |
| | | | a capacitor |
| | | | formed between |
| | | | the conductive |
| | | | beam and a |
| | | | control |
| | | | electrode of |
| | | | the MEMS |
| | | | switch. |
| | Rise/fall | Switching | Slowed |
| | times | transition | transitions |
| | | | due to aging |
| | dv/dt/di/dt | Safe | Capability |
| | capability | switching | reduction over |
| | | speed | cycles |
| | Propagation | Sense → trip → | Delay drift |
| | delay | activation | due to control |
| | | | aging |
| Electrical - | On-state | Conduction | Rₒₙ drift can |
| Conduction | resistance | quality for | indicate solder |
| Path | (Rₒₙ) | the junction | fatigue, die |
| | | formed between | attach voiding, |
| | | a from | oxidation of |
| | | electrode | conductive |
| | | and a front | contacts. |
| | | end of the | |
| | | conductive | |
| | | beam of the | |
| | | MEMS switch | |
| | Leakage | Off-state | Leakage increase |
| | current | blocking | (junction |
| | | integrity | degradation) |
| | Current | Shunts, Hall | Gain drift, |
| | sensing | sensors, ADCs | offset drift |
| | calibration | | |
| Electrical - | Trip | Overcurrent | Threshold drift |
| Protection/ | threshold | protection | (component |
| Control | | point | aging) |
| | Trip curve | Time-current | Calibration drift |
| | accuracy | characteristics | |
| Thermal | Junction | Real-time | Higher peaks |
| | temperature | thermal load | from degraded |
| | | | thermal paths |
| Mechanical/ | Terminal/connector | Mechanical | Contact resistance |
| Structural | resistance | contacts | drift |
| Lifecycle/ | Switching cycle | Total switching | End-of-life |
| Reliability | count | operations | prediction |
| | Thermal cycle | Power cycling | Coffin-Manson |
| | count | load | fatigue |
| | I²t accumulation | Fault energy | Reduced fault |
| | | exposure | withstand |
| | | | capability |
| | Weibull | Failure | Parameter drift |
| | reliability | probability | over aging |
| | parameters | curve | |

In some embodiments, the turn-on delay refers to the time interval between applying a deactivation signal to a control electrode of the MEMS switch (e.g., front control electrode of a tetter-totter MEMS switch) and the establishment of a conductive path through the switch, while the turn-off delay refers to the time interval between applying an activation signal to a control electrode of the MEMS switch (e.g., back control electrode of a tetter-totter MEMS switch) and the disconnection of a conductive path previously established via the MEMES switch. In some cases, turn-on delay may be measured by measuring the time interval between applying a deactivation signal to a control electrode of the MEMS switch and a change of the current passing through the MEMS switch from zero to Iₘₐₓ. In some cases, turn-off delay may be measured by measuring the time interval between applying an activation signal to a control electrode of the MEMS switch and a change of the current passing through the MEMS switch from Iₘₐₓ to zero. Here Iₘₐₓ can be the current passing through MEMS switch when the switch is on ON state fully deactivated (e.g., a steady state current established after providing a given activation signal to a control electrode of the MEMS switch).

In some embodiments, rise time can be a delay between proving a deactivation signal to a control electrode of the MEMS switch and a time at which the current passing through the MEMS switch reaches a first specified value less than Iₘₐₓ (e.g., 0.8×Iₘₐₓ, or 0.9×Iₘₐₓ, or other values). In some embodiments, fall time can be a delay between proving an activation signal to a control electrode of the MEMS switch and a time at which the current passing through the MEMS switch reaches a second specified value less than Iₘₐₓ (e.g., 0.1×Iₘₐₓ, or 0.2×Iₘₐₓ, or other values).

In some embodiments, leakage current can be value electric current passing through a previously established conductive path via the MEMS switch at specified time delay after providing an activation signal to a MEMS switch. In some such embodiments, the specified time can be from 10 microseconds to 50 microseconds, from 50 microseconds to 100 microseconds, from 100 microseconds to 150 microseconds, from 150 microseconds to 200 microseconds, or any range formed by any of these values or values of larger or smaller value. In other words, the leakage current can be an electric current passing through the MEMS switch at the earliest expected OFF time, where expected OFF time is a time after providing an activation signal at which it is expected that a previously established conductive path is disconnected. Generally detecting a non-zero electric current at the earliest expected OFF time can be indicative of a malfunction or performance issue with the MEMS switch.

In some embodiments, dv/dt/di/dt capability may comprise a ratio of rate of change of control voltage provided to a control electrode of a MEMS switch and the resulting rate of change of the current passing through the MEMS switch. In some cases, such ratio may indicate how fast the current passing through the MEMS switch responds to a change of the control voltage.

In some embodiments, propagation delay may comprise a delay between sensing or measuring a magnitude of electric current passing through a MEMS switch and a change of the state of the MEMS switch (from ON to OFF or from OFF to ON) in response to the measured current magnitude. In some cases, when a measured current passing through a MEMS that is in ON state exceeds a threshold level, an activation voltage may be provided by to the back control electrode of the MEMS switch to turn the switch OFF and the propagation delay can be the time interval between measuring the current and the time the previously conductive path established via the MEMS switch is disconnected.

In some cases, current sensing calibration may comprise testing accuracy and/or calibration of a current sensor used to measure an electric current passing through a conductive path established via the MEMS switch. In some examples, during a current sensing calibration period a calibration path may be established to test the performance of a current sensor. For example, a current passing through the MEMS switch (when it is in ON state or deactivated), may be measured by another sensor (different from the main current sensor configured to monitor current passing through the MEMS switch) and the outcome may be compared to a measurement performed by the main current sensor. In some cases, such comparison may indicate a drift in the precision of the main current sensor. The drift, which can be a drift in a measured voltage, may be recorded and fed to a digital twin model of the MEMS switch, and/or may be used to recalibrate the main current sensor.

In some embodiments, trip threshold, may comprise a threshold current above which the MEMS switch is activated to stop the current flow.

In some embodiments, trip curve accuracy may comprise a difference between a target or desired trip curve and a measured trip curve where trip curve can be a time-current characteristics associated with an EOS event.

In some embodiments, junction temperature may comprise a measured temperature indicative of (e.g., proportional to or substantially equal to) of temperature of a conductive junction formed between form end of the conductive beam and the front contact electrode of a MEMS switch when the MEMS switch is in OFF state (deactivated) to establish an electric path between two terminals.

In some embodiments, terminal/connector resistance may comprise a resistance of a portion of an electric path between two terminals controllably connected by a MEMS switch, excluding the resistance of MEMS switch (e.g., a resistance of a portion of the electric path between a wired screwed to one of the terminals). In some cases, a calibration routine could be implemented to extract this value.

In some embodiments, switching cycle count may comprise a number of time a MEMS switch is activated and deactivated, e.g., in response to a number of EOS events, other events that may trigger activation of the MEMS switch, or an operational switching cycle.

In some embodiments, the thermal cycle count can refer to the number of thermal cycles experienced by the ambient environment of the MEMS switch. For example, in some cases, the MEMS switch may reside in a module where temperature can change aggressively, e.g., between −20° C. to 70° C., and periodically. Such thermal cycles can affect the MEMS switch that therefore should be taken into account when modeling the MEMS switch.

In some embodiments, I²t accumulation may comprise an accumulation of electrical overstress faults. For example, a voltage drop along the MEMS switch and a corresponding electric current passing through the MEMS switch may be measured, and the measured values may be recorded. These values or the corresponding electric power transmitted via the MEMS switch over a period may be fed to a digital twin model of the MEMS switch to determine or predict structural and/or functional degradation of the MEMS switch over time.

In some embodiments, Weibull reliability parameters may comprise a shape parameter (β) that characterizes the failure rate trend over time, a scale parameter (η) that represents the characteristic life or number of switching cycles at which a specified percentage of MEMS switches are expected to fail, and optionally a location parameter (γ) that defines the minimum guaranteed life before any failure occurs. In some cases, Weibull reliability parameters may be determined using data from a plurality of MEMS switch in the field. In some cases, Weibull reliability parameters may be used to model and predict the lifetime and failure behavior of the MEMS device under operational and environmental stresses and/or a mission profile of the system.

In some embodiments, the DTM 4611 and DTM 4709 may comprise a trained model (e.g., a trained neural network model) configured to receive diagnostic data 4603 (as input) and generate the DTM outcomes 4906. In some such embodiments, the trained neural network may better reason and present bounded and explainable results. In some cases, the trained model may add certain level of physical intelligence to the DTM to provide more accurate predictions/evaluations or provide predictions/evaluations that may not be provided by a mathematical model of a device (e.g., the MEMS module or switch). In some cases, DTM may comprise a mathematical/physical model of the device or module integrated with the trained neural network.

In some examples, the device control parameter may comprise an activation voltage of a MEMS switch, a gate voltage provided to a field-effect transistor, a bias voltage of a transistor, or the like. In some cases, the control signal may be configured to turn off or a faulty device and, in some cases, turn on another (e.g., a backup) device. In some cases, turning ON or activating a device may comprise switching a signal path to disconnect the faulty device from a circuit and connecting the other device to the circuit. In some cases, the control signa may be configured to put a faulty device in a safe mode.

In some embodiments, the processing system 4608 may include one or more features listed below:
A modem configured to establish communication between the processing systems and the device.
An application programing interface (API) to send data (e.g., control data or signal) to the device and receive data (e.g., diagnostic data) from the device. In some embodiments the API may be configured to allow an authenticated user to interact with a user interface to view a representation of the DTN, change a parameter of the DTM, view messages and results generate by DTM.
In some cases, the processing system may be configured to establish a secure communication link with a device or another system (e.g., a server, or serverless cloud service) using public/private key pair or an equivalent cryptographic method.
A user interface (e.g., the GUI) established in the processing system, a website, a mobile device, a desktop computer, or another computing system in wired or wireless communication with the processing system. The user interface may allow the user to take and action (e.g., disconnect a device, adjust an intrinsic or extrinsic parameter of the device, schedule maintenance, view a recommendation generated by the processing system (e.g., by an action module in response to receiving an output from the DTM) shut down the system.

In some embodiments, the processing system 708 may comprise a remote computer system (e.g., a server such as cloud server) in communication with system 800, the circuit breaker 4305, and/or MEMS switch module 4308. For example, the processing system 4608 may be configured to generate the DTM 4611, DTM 4710, or DTM 4709 in response to receiving diagnostic data 4603 from the system 800, the circuit breaker 4305, and/or MEMS switch module 4308 or based on a specified schedule. In some configured to run analytics on a database to generate the DTM.

In some embodiments, the processing system 4608 may be in communication with a computing external system (e.g., a server such as cloud server) that can be separated from the processing system 4608 and in communication with the external processing system 4608 via wired or wireless link. In some embodiments, the processing system 4608 may be configured to receive data (e.g., reference data) from the external processing system to generate, update, or modify the DTM 4611, DTM 4710, or DTM 4709. In some cases, the external processing system may generate at least a portion of the DTM 4611, DTM 4710, or DTM 4709 and transmit it to the processing system 708.

In some embodiments, the DTM 4611 may comprise a model configured to determine probability of EOS events for a specific configuration of system (e.g., the system 4700), e.g., by performing analytics such as linear regression or a similar method to predict the probability of EOS events. In some cases, the outcomes of this model may be used to notify a user to inspect the system or initiate an automatic action to reduce the probability of EOS events. For example, the processing system 4608 or a cloud infrastructure connected to the processing system 4608 may use a work scheduling system to automatically assign an engineer/technician to perform maintenance, or cause an action module to shut down a portion of system 4700 (e.g., a portion determined to be responsible for EOS events) or switch to a safe mode which is less likely to cause failure/EOS.

In some cases, an integrated DSP or neural net accelerator core may allow a DTM to run in the system 800 itself. Such local DTM may allow safe shutdown before a failure or before any damage is done.

In another example, the diagnostic data may include measured or determined ON resistance of a MEMS switch module in field. In this example, the processing system may use the DTM to determine wear-level of a MEMS switch contact (e.g., the surfaces of contact end of a conductive beam and/or a corresponding contact pad/electrode).

In some examples, the DTM may comprise various modelling and extrapolation algorithms for predicting a parameter or characteristic and the output may be fed into an action module to trigger an action, example actions may include automatically initiating a self-test assessment, powering down module, or providing a message to user, e.g., via a user interface of the processing system, for a manual action.

In some embodiments, the DTM may comprise a machine learning model trained based on training data. In some cases, the training data may be generated using one or more devices (e.g., MEMS switches having known characteristics) during a data generation period. In some cases, the machine learning model may comprise a convolutional neural network), or a combination of both using the data from the system to train the model with expected limits of normal operation.

In some embodiments, the DTM may be configured to provide an instantaneous estimation of the condition of a device, a sub-system, or a system (e.g., the MEMS switch module 4308, the circuit breaker 4305, or the system 4700).

In some embodiments, the DTM may process a combination of intrinsic data (indicative of characteristic of the device) and external data (indicative a mission profile) to determine and or predict a characteristic or variation of a characteristic of a device or predict a change of condition of a system. In some embodiments, the processing system may use a linear regression of previous estimations (e.g., wear estimations) and extrapolate that into a future time, in some cases, without using a specified mission profile.

In some embodiments, predictive maintenance or a preventive action may comprise comparing determined/predicted characteristic or in ternal parameter of a device, and/or a determined/predicted condition of a system with a predetermined threshold value, threshold wear level, or a threshold health condition. In some cases, in response to determining that processing system may the determined/predicted characteristic or in ternal parameter of a device, and/or a determined/predicted condition satisfies a threshold condition with respect to the predetermined threshold value, threshold wear level, or threshold health condition. For example, the processing system may trigger a predictive or a preventive action (manual or automatic) in response to determining that the predicted value of an intrinsic parameter of a MEMS switch (e.g., V_{T}, Rₛ, or the like) less than a threshold value. As another example, the processing system may schedule maintenance (or recommend scheduling maintenance) before a predicted wear level exceed a percentage of a threshold wear level (e.g., an allowable wear limit) where the percentage can be from 70% to 75%, from 75% to 80%, from 80% to 85%, from 85% to 90%, from 90% to 95%, or any ranges formed by these values or larger or smaller.

In some implementations, data and information used by the processing system (e.g., in the DTM) to determine, estimate, or predict a value, characteristic, or condition may be stored in a non-transitory memory of the processing system, or in a server (e.g., a cloud server) in communication with the processing system. In some implementations, data and information used by the processing system (e.g., in the DTM) to determine, estimate, or predict a value, characteristic, or condition may be provided by user and received from a user interface (e.g., a GUI).

In some cases, extrinsic parameters that may be measured and provided to DTM of a MEMS switch can include: a threshold deactivation voltage (V_{T,ON}), a threshold activation voltage (V_{T,OFF}), ON resistance, local temperature, and the like.

In some cases, extrinsic parameters that may be measured and provide to DTM of a MEMS switch may comprise usage time, number of toggles, electrical load (e.g., applied voltage and transmitted current), or other parameters.

As described above, dependence of an intrinsic parameter of a MEMS switch on one or mor extrinsic parameters can be characterized during a characterization period (e.g., form an isolated MEMS switch in a controlled environment) to determine a function (ƒ) that may be used by the DTM of a MEMS switch to predict a future value for given of the intrinsic parameter based on a measured initial (current value) of the intrinsic parameter for a given mission profile or operational condition or given values of extrinsic parameters and/or their variation. In some cases, the measured variation of an intrinsic parameter of a device in the field with respect to an extrinsic parameter may be compared with a behavior expected/predicted based on ƒ and a deviation from the expected/predicted behavior may be considered as abnormal behavior of the device (e.g., accelerated aging, wear or degradation). In some embodiments, the extrinsic parameter may comprise one or more of an environmental temperature, a die temperature, a voltage across the two terminals, a current transmitted through the MEMS switch, an acceleration of the MEMS switch module, and/or a cumulative number of switching actions performed by the MEMS switch module.

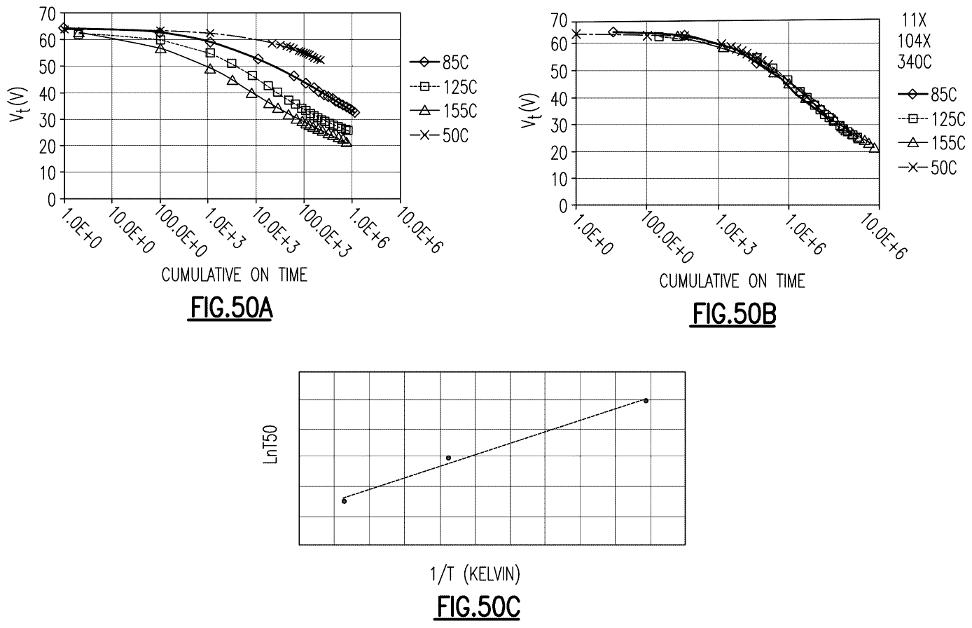

FIG. 50A shows results of characterizing V_{T,ON} for a MEMS switch or plurality of MEMS switches of the same type as a function of cumulative ON time (time kept in ON state) ranging from 1 to 106 seconds at four different temperatures T=50, 85, 100, and 125° C. (depicted by different markers), indicating that V_{T,ON} may decrease with cumulative ON time and temperature. In some embodiments, high temperature behavior of V_{T,ON} during a shorter period can be used to verify an expected behavior at a lower temperature during a longer period (that may not be practical to characterize).

FIG. 50B shows results of multiplying the high temperature measurements at 85, 100, and 125° C., shown in FIG. 50A, by temporal scaling factors to predict long term behavior at 50° C. The overlap and consistency of the scaled high temperature curves indicate that operation at high temperature may have the same effect as operation at lower temperature during a longer time. In some cases, one a V_{T,ON} curve is verified as a reliable predictor of the V_{T,ON} behavior of a MEMS switch module, a MEMS switch (or a specific type of MEMS switch or MEMS switch module), the verified V_{T,ON} curve may be used within a corresponding DTM to monitor the same or same type of MEMS switch module in the field. In some embodiments, when a measured value of V_{T,ON} (received as diagnostic data) indicates decay of V_{T,ON} with a rate faster than a predicted rate by the DTM, the DTM may generate DTM data indicative or abnormal wear and the action module 4908 may initiate an action to mitigate such abnormal wear. In some embodiments, when a measured values of V_{T,ON} (received as diagnostic data) indicate decay of V_{T,ON} with a rate faster than a predicted rate by the DTM, the DTM may update the model and adjust certain parameter of the model to match the model with the observed/measured decay rate and use the updated model for predicting future behavior and thereby generate DTM data indicative of an earlier maintenance time or DTM data causing the action module 4908 to change an operational parameter of the MEMS switch to prolong the lifetime of the MEMS switch or MEMS switch module.

FIG. 50C shows natural logarithm of the time (T50) it takes for V_{T,ON} of the MEMS switch (characterized in FIGS. 50A and 50B) to decay to 50% of its original value (V_{T,ON,0}) as a function of inverse temperature of the MEMS switch. The near linear behavior verifies a near exponential decay of V_{T,ON} with respect to temperature.

As another example, the variation of the ON resistance (Rₛ) of a MEMS switch (also labeled as R_{ON}) of a MEMS switch/module can be characterized as a function of cumulative ON time at T=25° C.

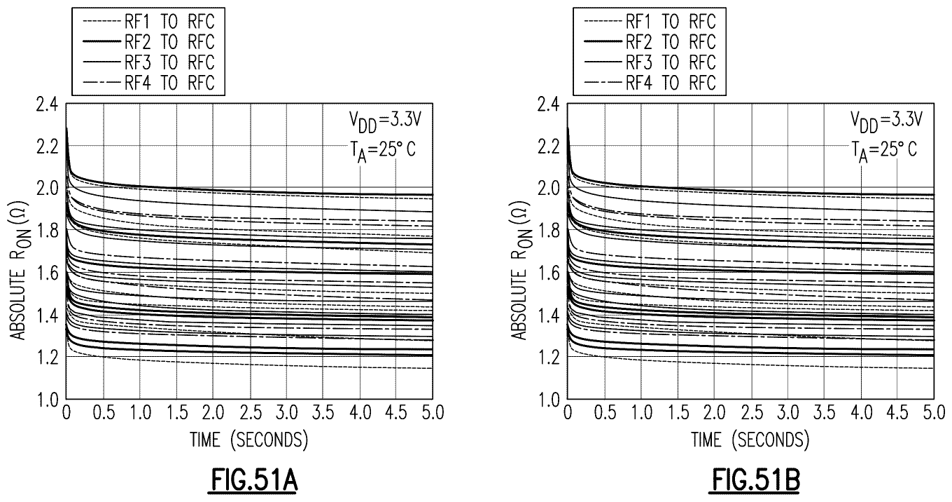

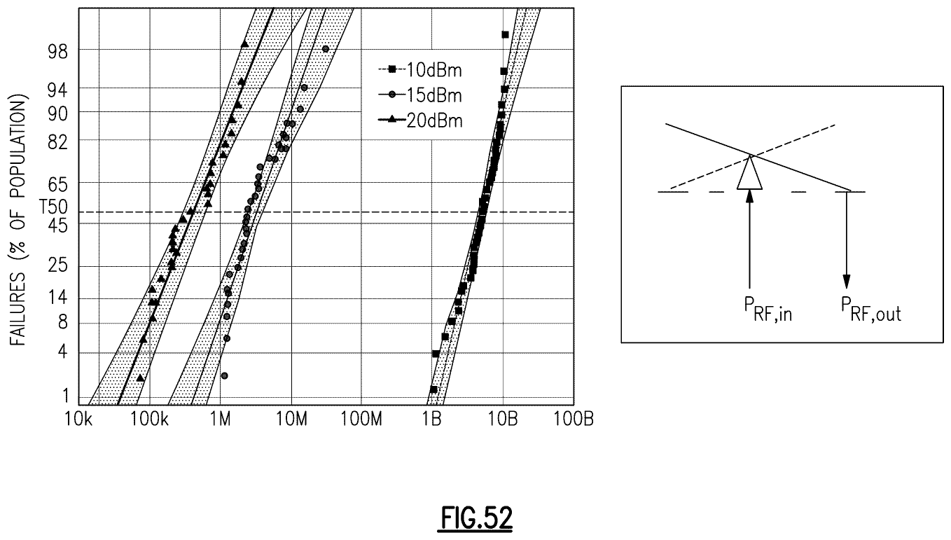

FIG. 51A shows measured values of absolute R_{ON} as a function of versus cumulative ON time for the MEMS switch characterized in FIGS. 50A-50C.

FIG. 51B shows measured values of absolute R_{ON} as a function of number of switching actions for the MEMS switch characterized in FIGS. 50A-50C.

Different curves in FIGS. 51A and 51B, depict R_{ON} for different MEMS switches within different modules (20 different MEMS switches are measured). Each module includes multiple MEMS switches and different colors depict R_{ON} for different MEMS switches in the same module, in some cases, measured at different RF powers.

FIG. 52 shows failure probability distribution on Log-normal with 95% confidence interval (CI) for different RF powers transmitted/switched by a MEMS switch, plotted against number of switching actions (number activation-deactivation cycles). The RF power is transmitted between a conductive post through which the conductive beam of the MEMS switch is anchored over the substrate to a contact electrode of the MEMS switch through an electric contact formed between a switching end of the conductive beam and the contact electrode (as shown in the inset on the left). Different levels of transmitted RF power are depicted by different colors.

Micro-Electromechanical Switch Systems with Self-Prognosis and Control Capability

In some embodiments, a system may comprise or may be in communication with a smart motoring system configured to receive monitoring data from the system and use the monitoring data to determine a state, functional safety, health and/or a mission profile of one or more modules, circuits, and/or devices in the system. In some such embodiments, the smart monitoring system may use monitoring data, determined device/module states, and/or mission profiles to determine, monitor, and predict an overall health of the system. In some cases, determining the state and health of a module, circuit and/or device may comprise determining a health metric and/or an operational metric of the module, circuit and/or device, and in some cases, predicting future variation of the health metric and/or an operational metric. In some cases, determining the mission profile of a module, circuit and/or device may comprise monitoring and predicting future variation of an environmental parameter and/or a system parameter coupled to the module, circuit and/or device (e.g., voltage, field, current, applied or provided to the device). In some cases, the overall health of the system may comprise performance of the system with respect to two or more modules, circuits, or devices therein, which can be connected, coupled, or otherwise interact with each other, to provide a function. In some cases, the smart monitoring system may predict changes in the overall health of the system using determined mission profiles and health status of one or more modules, circuits, or devices in the system.

In some embodiments, the smart monitoring system may use the determined state, health and/or a mission profile of one or more modules, circuits and/or devices, to predict deterioration of an internal parameter of the modules, circuits and/or devices, which can affect their performance. In some embodiments, the smart monitoring system may use one or more DTMs to determine values or predict changes of a health and/or operational metric (e.g., an intrinsic parameter) of a module, circuit and/or device.

In some embodiments, the system may comprise a MEMS switch module and the smart monitoring system may be configured to determine a state, a health and/or a mission profile of the MEMS switch module and, in some cases, those of a module, circuit, and/or a device connected or coupled to the MEMS switch module. In some such embodiments, a health metric or operational metric of the MEMS switch module may comprise the value of an intrinsic parameter (e.g., V_{T} or Rₛ) of the MEMS switch with respect to a threshold value or a specified range. In some cases, the intrinsic parameter of the MEMS switch module can include a response time of the MEMS switch to an activation or deactivation signal for a given V_{T}. In some embodiments, Rₛ may be determined by measuring an electrical current passing through the MEMS switch (e.g., using a current sensor) and a voltage between the two terminals of the MEMS switch (e.g., using a voltage sensor) when the MEMS switch is in a deactivated (ON) state. In some cases, a controller of the MEMS switch module or a corresponding circuit breaker may use the measured values of the electrical current and voltage to calculate the Rₛ. In some embodiments, V_{T} may be measured by measuring a control voltage provided to a control electrode of the MEMS switch and a current passing through the MEMS switch and determining the control voltage at which the current changes from zero to a non-zero value or vice versa. In some cases, a controller of the MEMS switch module or a corresponding circuit breaker may gradually increase the control voltage while monitoring a current transmitted through the MEMS switch and record the value of the control voltage at which the current starts or stop flowing through the MEMS switch, which may be determined to be the V_{T}.

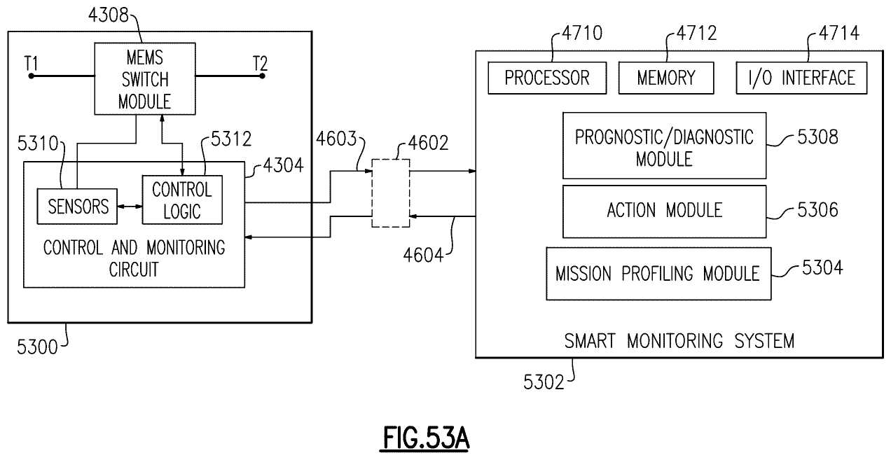

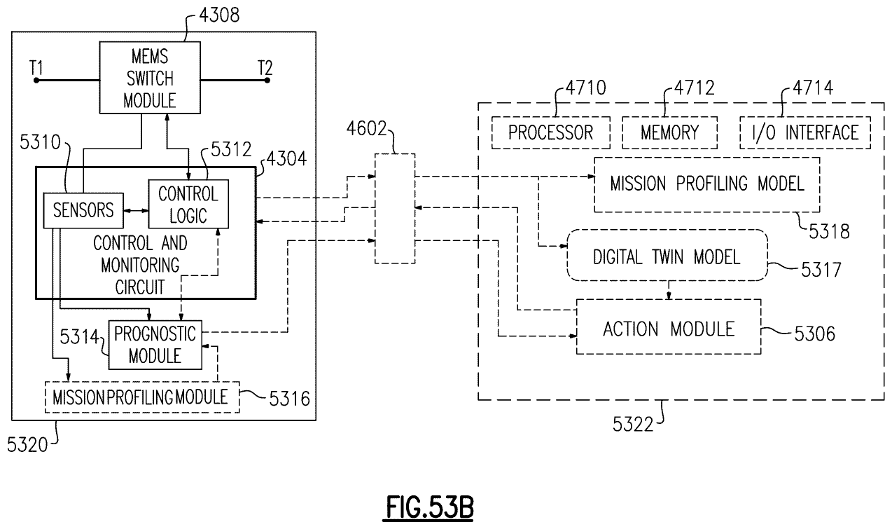

FIG. 53A is a block diagram of a smart monitoring system 5302 configured to receive a diagnostic signal or data 4603 from a system 5300 and monitor one or more modules, circuits, and devices of the system 5300 based at least in part on the diagnostic data 703. In some cases, the smart monitoring system 5302 and the system 5300 can be a sub-system within a system (e.g., they may be placed/integrated together in a package or fabricated on common board/substrate). In some cases, the smart monitoring system 5302 may receive the diagnostic signal or data 4603 via a communication link 4602 (e.g., wired or wireless link). In some cases, the system 5300 can be included in a node of the plurality of nodes and may receive the diagnostic data 4603 via a central hub connected to the plurality of nodes. In some embodiments, the diagnostic signal or data 4603 generated by the system 5300 may be encrypted prior to transmission to the smart monitoring system 5302. Further details about data encryption in the context of system monitoring are described above with respect to FIGS. 43A-45. In some embodiments, system 5300 may comprise a PUF circuit configured to generate a PUF signal having a unique signature that can be used to determine whether the PUF circuit is exposed to normal or abnormal environmental conditions. In some such embodiments, the PUF signal may be used prevent a portion of the diagnostic signal or data 4603 corresponding to a device or circuit that can be affected by an environmental or operational condition, to be used for predictive maintenance, device modeling, alert generation, or the like. In some embodiments, the system 5300 may comprise sensors (e.g., temperature sensor, vibration sensor, EOS monitor and the like), configured to monitor the environment surrounding one or more components of the system 5300. In some such embodiments, the smart monitoring system 5302 may use the sensor signals received from one or more sensors of the system 5300 to trigger an action in response to a change in the environment using the action module 5306.

In some embodiments, the system 5300 may comprise a MEMS switch module 4308 configured to control the electrical connection between two terminals T1, T2, in the system 5300. In some embodiments, the smart monitoring system 5302 may comprise a prognosis/diagnosis module 5308 configured to use the diagnostic signal or data 4603 received from the system 5300, process/analyze the diagnostic signal or data 4603 to evaluate performance of the MEMS switch module 4308, determine a value of an intrinsic parameter of the MEMS switch module 4308 or an extrinsic parameter affecting or influencing the MEMS switch module 4308, predict future performance of the MEMS switch module 4308 and/or a future variation of the intrinsic parameter, or determine a mission profile of the MEMS switch module 4308.

In some embodiments, the extrinsic parameter may comprise one or more of an environmental temperature, a die temperature, a voltage across the two terminals T1, T2, a current transmitted through the MEMS switch, a mechanical acceleration of the MEMS switch module, and/or a cumulative number of switching actions performed by the MEMS switch module. In some cases, the die temperature may be measured using a temperatures sensor (e.g. a thermistor) integrated with MEMS switch on common substrate. In some cases, the temperature sensor may comprise a resistor integrated with the MEMS switch on a common substrate (e.g., resistors 2134 and 2132 described above with respect to FIGS. 20A and 20B). For example, a controller of the corresponding MEMS switch module or circuit breaker may determine the die temperature by measuring a current passing through the resistor.

In some embodiments, the smart monitoring system 5302 may comprise an action module 5306 configured to generate an alert/message or initiate an action based at least in part of an output generated by the prognosis/diagnosis module 5308 as result of processing the diagnostic data. In some cases, the action module 5306 may initiate the generation of the alert/message automatically by sending control data/signals (commands) 704 to the system 5300, or by generating a message comprising a recommendation for a specific action and, in some cases, description of the recommended action.

In some embodiments, the smart monitoring system 5302 may comprise a mission profiling module 5304 configured to receive and store at least a portion of the diagnostic signal or data 703, in a non-transitory memory of the smart monitoring system 5302, during a specified period to generate a mission profile of the MEMS switch module 4308 comprising variation of an environmental parameter and/or an extrinsic parameter associated with the MEMS switch module 4308 (e.g., applied to, or affecting the MEMS switch module 4308), during the specified period. In some cases, the mission profiling module 5304 may comprise a mission profiling model configured to generate the mission profile of the MEMS switch module based on a present value of an extrinsic parameter in the diagnostic signal or data 4603 and previously stored values of the extrinsic parameter.

In some embodiments, the prognosis/diagnosis module 5308 may receive a mission profile of the MEMS switch module 4308 generated by the mission profiling module 5304, e.g., to take into account the variation of environmental and extrinsic parameter and their impact on a performance and/or an intrinsic parameter of the MEMS switch module 4308, when predicting a future variation of the performance and/or the intrinsic parameter.

In some embodiments, the system 5300 may comprise a diagnostic circuit or a control and monitoring circuit 4304 configured to measure one or more extrinsic parameters associated with the MEMS switch module 4308 and/or an intrinsic parameter of the MEMS switch module 4308, using one or more sensors 5310, and generate the diagnostic signal or data 703. In some examples, the one or more sensors 5310 may comprise a current sensor, a voltage sensor, a temperature senso, a humidity sensor, a mechanical accelerometer, or other types of sensors. In some examples, the sensor signal generated by the sensors 5310 can be indicative of a transient voltage, a transient current, a vibration level (e.g., acoustic vibrations), temperature, mechanical acceleration, and the like during operation of the MEMS switch module 4308.

In some cases, the diagnostic signal or data 4603 may comprise a measured value of a parameter or a calculated/extracted value of a parameter (e.g., by a processor of the control and monitoring circuit 4304). In some embodiments, the control and monitoring circuit 4304 may further comprise a control logic 5312 configured to control the MEMS switch module 4308 (e.g., by generating activation or deactivation signals). In some cases, the control logic 5312 may be configured to control the MEMS switch module 4308 based at least in part on control data/signals (commands) 704 received from the smart monitoring system 5302 and/or the sensors 5310. For example, the smart monitoring system 5302 may generate a control signal to increase a voltage level of the activation control signal after a specified time in response to receiving an outcome from the prognosis/diagnosis module 5308 indicating that close to or at the specified time V_{T,OFF} of the MEMS switch module 4308 may increase (e.g., based on the diagnostic signal or data 4603 and/or a predict mission profile generated by the mission profiling module 5304). In some embodiments, the control and monitoring circuit 4304 may comprise one or more isolators configured to isolate a high voltage portion from a low voltage portion of the control and monitoring circuit 4304 (e.g., similar to isolators used in circuit breakers described above with respect to FIGS. 10, 11A, 13, 15-16, 18-19, and 21).

In some embodiments, the smart monitoring system 5302 may include at least one non-transitory medium such as a memory 4712 for storing machine-readable instructions and at least one processor 4711 configured to execute the stored machine-readable instructions to implement, one or more modules of the smart monitoring system 5302. In some embodiments, the smart monitoring system 5302 may include an input/output (I/O) interface 4753 configured to receive data from another computing system (e.g., a server such as cloud server), e.g., to update or provide data (e.g., reference data) to a module, or output a portion of the diagnostic data 4603, and/or outcomes, data, instructions, messages generated by one of the modules of the smart monitoring system 5302. In some cases, the I/O interface may comprise a wired/wireless data interface and/or a user interface (e.g., a graphical user interface, a keyboard, a display, and the like), configured to receive data/commands from a user to present data, messages, or instructions to the user.

In some embodiments, the system 5300 may comprise a circuit breaker configured to provide protection against electric over stress (EOS). In some embodiments, a circuit breaker may comprise a high voltage and/or high current circuit breaker comprising the MEMS switch module 4308 configured to protect and/or control an electrical connection as part of a normal operation of the system or in response to receiving a sensor signal from a sensor indicating a malfunction or a transient event accompanied by unsafe levels of current and/or voltage (e.g., exceeding a damage threshold of the MEMS switch module 4308 or a portion of the system protected by the MEMS switch module 4308). As such, the system 5300 may comprise a MEMS-based circuit breaker (e.g., the MEMS-based circuit breakers described above with respect to FIGS. 10, 11A, 13, 15-16, 18-19, and 21). In some embodiments, in addition to protecting or controlling a system, circuit breakers and EOS devices may be used to monitor a system and generate data usable for evaluating the health of different circuits, devices of the system (e.g., for prognostic predictive maintenance and/or generating alerts), predicting potential future failures (e.g., avoid such failures by taking necessary action), or extracting other information useful for evaluating the performance of the system and subsystems/device therein.

In various implementations, the diagnostic signal or data 4603 generated by system 5300 (circuit breaker) may include excursions (e.g., EOS and other transient events) that may be recorded (e.g., stored in a non-transitory memory of the smart monitoring system 5302) and processed to generate data indicative of a predicted lifetime, a predicted future failure, an alarm condition and the like. In some cases, a portion of the diagnostic signa or data 4603 may be generated by the MEMS switch module 4308 and the sensors 5310 (e.g., a current sensor, voltage sensor, temperature sensor and the like). In some such cases, the system 5300 (e.g., the control and monitoring circuit 4304 of the system 5300) may include circuitry configured to store, process, and encrypt data generated by the MEMS switch module 4308 or by the sensors 5310.

In some embodiments, a module of the system that includes a protective/control device may be in communication with an application programing interface (API) configured to process the data received from the module similar to the API described above with respect to the processing system 4608 (FIG. 46).

In some embodiments, the functionalities (e.g., system monitoring) described above with respect to a circuit breaker or the MEMS switch module therein may be provided by another device or subsystem connected to a node of the system. Such device or subsystem may comprise optical switches, MEMS switches, spark gaps, various sensors, optical or magnetic isolators, or other components and devices configured to generate data usable for monitoring the system.

In some embodiments, the system 5300 may comprise components and circuitry configured to allow testing the MEMS switch module 4308 and generating the diagnostic data 4603 without interrupting the operation of the system 5300 or a system controlled and/or protected by the system 5300 (e.g., a circuit breaker). In some implementations, the system 5300 may include two MEMS switches, or two MEMS switch modules connected in parallel between the two terminals T1, T2, such that each MEMS switch or MEMS switch module is individually configured to protect and/or control the electric connection between the two terminals T1, T2 within the operational ranges of voltages and currents applied between and passing through the two terminals. Advantageously, such configuration may allow testing one of the MEMS switches (or MEMS switch networks) offline while the other MEMS switches (or MEMS switch network) is protecting the system and can be used the electric connection between the two terminals. Additional examples of MEMS switch circuit with self-testing capability are described with respect to FIGS. 33 to 38, the details of which are omitted herein for brevity. In some cases, the diagnostic signal or data 4603 may be generated using a testing process described above with respect to FIGS. 33 to 38, and initiated by the control and monitoring circuit 4304 or the smart monitoring system 5302.

In some embodiments, at least a portion of the smart monitoring system 5302 may be included in the system 5300 (e.g., integrated with one or both the control and monitoring circuit 4304 and MEMS switch module 4308). For example, the system 5300 may include (e.g., included in the control and monitoring circuit 4304) one or more of a prognosis module, a diagnosis module and a mission profiling module, where each is configured to process diagnostic signal or data generated by the control and monitoring circuit 4304 (e.g., suing the sensors 5310) to determine present and/or future functionalities of the MEMS switch module 4308 (e.g., to determine and predict a degradation, malfunction or failure of the MEMS switch module 4308).

In some embodiments, the system 5300 may comprise one or more circuits, devices, and/or subsystems protected by a circuit breaker comprising the MEMS switch module 4308. In some cases, the circuit breaker may comprise the control and monitoring circuit 4304. In some embodiments, the smart monitoring system 5302 may be configured to monitor the circuit breaker and the MEMS switch module 4308 therein. In some such embodiments, the smart monitoring system 5302 may be further configured to monitor at least one circuit, device, and/or subsystem of the system 5300 other than the circuit breaker. As such, in some embodiments, one or more of the prognosis/diagnostic module 5308, action module 5306, and mission profiling module 5304 of the smart monitoring system 5302 may be configured monitor, determine, and/or predict health status of at least one circuit, device, and/or subsystem of the system 5300 other than the circuit breaker, e.g., by generating a digital twin model for the at least one circuit, device, and/or subsystem, initiate an action for predictive maintenance of the at least one circuit, device, and/or subsystem, and/or generate and store mission profile for the at least one circuit, device, and/or subsystem. In some embodiments, the smart monitoring system 5302 may be configured to use prognosis/diagnosis module 5308 and, in some cases, the DTM of the at least one circuit, device, to detect a fault (e.g., an EOS event or possibility of an EOS even), and use the MEMS switch module 4308 to protect the at least one circuit, device, and/or subsystem (e.g., by disconnecting power to the at least one circuit, device, and/or subsystem). In some embodiments, the smart monitoring system 5302 may provide functions and initiate actions describe above with respect to monitoring and maintenance of the MEMS switch module 4308, to monitor and maintain at least one circuit, device, and/or subsystem different than a circuit breaker comprising the MEMS switch module 4308. In some embodiments, the smart monitoring system 5302 may use the control and monitoring circuit 4304 or another circuit or system of the system 5300 to monitor and maintain the at least one circuit, device, and/or subsystem.

FIG. 53B is a block diagram of a system 5320 comprising a MEMS switch module 4308 that is capable of determining/predicting present and future functionality of the MEMS switch module 4308 and/or generating a mission profile for the MEMS switch module 4308. In some embodiments, the system 5320 may comprise one or more features described above with respect to the system 5300 and the smart monitoring system 5302, the details of such features may not be repeated for brevity. In some embodiments, the features/functionalities described above with respect to the smart monitoring system 5302 may be selectively distributed between the system 5320 and an auxiliary processing system 5322. In some embodiments, the system 5320 may comprise sensors (e.g., temperature sensor, vibration sensor, EOS monitor and the like), configured to monitor the environment surrounding one or more components of the system 5320. In some such embodiments, the auxiliary processing system 5322 may use the sensor signals received from one or more sensors of the system 5320 to trigger an action in response to a change in the environment using the action module 4908.

In some embodiments, the control and monitoring circuit 4304 of the system 5320 may be configured to use the control logic 5312 and the sensors 5310 to run tests (e.g., one or the self-tests described above with respect to FIGS. 31-38), generate diagnostic data, and use the diagnostic data to determine a present functionality of the MEMS switch module 4308 (e.g., by determining present values of one or more intrinsic parameters of the MEMS switch module 4308). In some embodiments, the system 5320 may further comprise a prognosis module 5314 configured to process diagnostic data to predict future functionality of the MEMS switch module 4308. In some embodiments, the system 5320 may comprise a mission profiling module 5316 to determine a mission profile, and/or to compare a mission profile with a stored mission profile. In some such embodiments, the mission profiling module 5316 may be configured to determine a mission profile of the MEMS switch module 4308 based at least in part on the diagnostic data (e.g., measured extrinsic parameters) generated by the control and monitoring circuit 4304.

In some cases, the system 5320 may comprise a non-transitory computer-readable medium such as a memory storing machine-readable instructions and a processor configured to execute the stored machine-readable instructions to provide the mission profiling module 5316. In some examples, the mission profiling module 5316 may store values of one or more extrinsic parameters in the non-transitory medium (e.g., memory) and use a mission profiling model to determine the mission profile of the MEMS switch module 4308 based at least in part on the stored values of the extrinsic parameters. In some embodiments, the prognosis module 5314 and/or the control and monitoring circuit 4304 may receive a mission profile generated by the mission profiling module 5316 and use the information therein to predict future functionality or determine present functionality of the MEMS switch module 4308.

In some embodiments, one or more of the control and monitoring circuit 4304, the prognosis module 5314, and the mission profiling module 5316 of the system 5320 may use one or more computing resources in an auxiliary computing system 5322, which can be physically separate from but in communication with the system 5320 (e.g., via a wired or wireless communication link 4602), to determine present and/or future functionality, or a mission profile of the MEMS switch module 4308. In some embodiments, the auxiliary computing system 5322 may comprise one or more features described above with respect to the smart monitoring system 5302. In some examples, the control and monitoring circuit 4304 and/or the prognosis module 5314 may use a digital twin model 5317 of the MEMS switch module 4308 generated by the auxiliary processing system 5322 to determine present and/or future functionality of the MEMS switch module 4308. In some embodiments, the mission profiling module 5316 may use a mission profiling model generated by the auxiliary processing system 5322 to generate a mission profile of the MEMS switch module 4308.

In some embodiments, the system 5320 may comprise a circuit breaker configured to protect a circuit using the MEMS switch module 4308 and be configured predict a future failure or estimate a lifetime of the MEMS switch module 4308 without interrupting an electrical connection between first and second terminals T1, T2 that can be electrically connected to the protected circuits. In embodiments, the prognosis module 5314 may be configured to receive sensor signals from the sensors 5310 during a testing process and generate data pertaining to a condition, a potential future failure, and an estimated lifetime of the MEMS switch module 4308, among others. In some embodiments, the control logic 5312 may initiate the testing process by alternatingly deactivating the MEMS switch module 4308 and another MEMS switch module (not shown), and the prognosis module 5314 may evaluate parameters associated with performance of the MEMS switch module 4308 based on the received sensor signals during the testing process. In some cases, the control logic 5312 may be configured to keep the MEMS switch module 4308 and the other MEMS switch module activated (closed) to maintain an electrical connection between the T1 and the T2.

In some embodiments, the prognosis module 5314 may initiate the testing process by alternatingly deactivating the MEMS switch module 4308 and another MEMS switch module and use the received sensor signals during the testing process to predict a future failure or estimate a lifetime of the MEMS switch module 4308.

In some embodiments, prognosis module 5314 may use a sensor signal received from the sensors 5310 to measure variation of an extrinsic parameter within a specified period starting from a time when an activation signal (indicated by the second voltage signal) is provided to the MEMS switch module 4308.

Similarly, the prognosis module 5314 may use the first voltage signal received from the sensors signal received from the sensors 5310 to measure variation of an extrinsic parameter across the other MEMS switch module within a specified period starting from a time when an activation signal (indicated by the third voltage signal) is provided to the other MEMS switch module.

In some cases, an activation (or deactivation voltage) may comprise a voltage provided by the control logic 5312 to the MEMS switch module 4308. In some cases, the estimated deactivation voltage (or measured deactivation voltage) may comprise a voltage estimated based on variation of measured voltages and/or current across the MEMS switch module 4308 as a function of the corresponding deactivation voltage.

In some embodiments, prognosis module 5314 or the prognosis/diagnosis module 5308 may use the measured variations of voltage and current across the MEMS switch module 4308, to determine variation of a resistance of the conductive electric path established by the MEMS switch module 4308, as a function of the deactivation voltage.

In some embodiments, prognosis module 5314 or the prognosis/diagnosis module 5308 may use the measured variations of an extrinsic parameter affecting the MEMS switch module 4308, to determine an estimated value of an intrinsic parameter (e.g., deactivation voltage for establishing a conductive path having a resistance below a specified value and/or an estimated activation voltage for electrically disconnecting T1 from T2).

In some embodiments, prognosis module 5314 or the prognosis/diagnosis module 5308 may use the measured variations of voltage and current across the MEMS switch module 4308, to determine activation and deactivation response times of the MEMS switch module 4308.

In some embodiments, prognosis module 5314 or the prognosis/diagnosis module 5308 may use the variation of a resistance of the conductive electric path, estimated values of activation and deactivation voltages, the activation and deactivation response times, and other parameters that may be extracted from current and voltage measurements, to determine anomalies that potentially can indicate early signs of failure. In some cases, prognosis module 5314 may generate and transmit data pertaining the detected or estimated anomalies to another system or a user interface to trigger automatic or user actions to prevent potential future failures indicated by the data.

In some embodiments, the system 5320 may comprise at least one circuit, device, and/or subsystem protected by a circuit breaker comprising the MEMS switch module 4308. In some embodiments, the system 5320 may be configured to use a monitoring and protection system included in the system 5320 to monitor, maintain, and/or protect the at least one circuit, device, and/or subsystem using the MEMS switch module 4308. In some cases, the monitoring and protection system may comprise one or more of the prognosis module 5314, the mission profiling module 5316, and the control and monitoring circuit 4304. In some cases, the monitoring and protection system may comprise a digital twin model of at least one circuit, device, and/or subsystem. In some embodiments, the system 5320 may be configured to additionally use one or more modules of an external system in communication with the system 5320 for monitoring the MEMS switch module 4308 and, in some cases, other modules in communication with the system 5320. For example, the system 5320 may use one or more modules or models in the auxiliary processing system 5322 (e.g., the digital twin model 5317, the action module 5306, mission profiling model 5318). In some embodiments, to protect the at least one circuit, device, and/or sub-system, the monitoring and protection system, individually or combined with the auxiliary processing system 5322, may provide functions and initiate actions describe above with respect to protection, monitoring, and maintaining the MEMS switch module 4308 using the prognosis module 5314, control and monitoring circuit 4304, the mission profiling module 5316, and the auxiliary processing system 5322.

In some embodiments, the smart monitoring system 5302 or a portion of the system 5320 may serve as a portal through which a digital twin model of at least one device, circuit, or sub-system, other than the circuit breaker and the MEMS switch module 4308 therein is generated to monitor, determine, and/or track a feature or a parameter of the at least one device, circuit, or sub-system and, in some cases, compare the monitored, determined, and/or tracked feature or parameter with stored features or parameter values.

In some embodiments, a system may comprise a smart monitoring system configured with self-prognosis capability and to monitor, protect, and maintain one or more circuits, modules, or sub-systems in the system (collectively referred to as system modules) using one or more of the methods and circuits described above. In some embodiments, the smart monitoring system may comprise: a MEMS switch system or a circuit breaker comprising a MEMS switch module, a system diagnostic circuit communicatively coupled to the system modules, and a system processing module. In some embodiments, the circuit breaker or the MEMS switch system may be configured to control a connection to one or more of the system modules upon receiving a fault signal indicative of the state of health being below a predetermined threshold. In some examples, the predetermined threshold can be a minimum performance with respect to at least one function of the module. In some examples, the fault signal may indicate that the value of a parameter of the system module is out of a predefined range. In various implementations, the predetermined threshold and/or the predefined range can be stored in a memory of the system and/or can be received from a user via a user interface of the system.

In some cases, the system diagnostic circuit may be configured to generate a system diagnostic signal indicative of a state of health of the system, e.g., using one or more sensors. In some cases, the state of health of the system may comprise present and/or future functionality and performance of one or more system modules. In some cases, the system processing module may be configured to determine the state of health of the system based at least in part on the system diagnostic signal. In some such cases, the system processing module may generate a digital twin model for the one or more system modules and use an outcome of a calculation or determination performed using the digital twin model to determine the state of health of the system. In some cases, the system processing module may update the digital twin model based at least in part on the system diagnostic signal.

In some embodiments, the system diagnostic circuit and system processing module of a smart monitoring system may be configured to monitor and maintain a system module and a MEMS switch system, or a circuit breaker, configured to protect the same or another system module. In some such embodiments, the system diagnostic circuit and system processing module may comprise a diagnostic sub-system and a processing subsystem, respectively, where the diagnostic sub-system and the processing subsystem are configured to monitor and maintain a MEMS switch system or a circuit breaker configured to protect a module of the system.

In some embodiments, a system (e.g., a node in an electric system with in a multiple notes) with monitoring, diagnosis, and/or prognosis capability may comprise a PUF circuit or PUF module configured to generate a unique PUF signal used to authenticate (e.g., certify the validity) of the diagnostic data prior to transferring the monitoring or diagnostic data or using the diagnostic data for determining present and/or future health status of a MEMS switch, MEMS switch system, and/or other systems, sub-systems, or modules that may send diagnostic data to the system. In some cases, authenticating or certifying of the diagnostic data may comprise authenticating a PUF signal associated with the diagnostic data by comparing the PUF signal with the unique PUF signal (expected to be generated by the PUF module) and the determining that they are substantially the same. In some cases, the PUF signal associated with the diagnostic data can be a PUF signa generated by a PUF circuit/module physically coupled to the device/module under test (e.g., a MEMS switch) or exposed to substantially the same environmental condition as the device under test. In some cases, the PUF circuit/module and its interaction or cooperation with system may comprise one or more features described above with respect to FIGS. 43A-43B, 44, and 45. For example, the system 5300 may comprise a PUF module configures to generate a unique PUF signal that may be used, e.g., by a processing system (not shown), to authenticate the diagnostic data 4603 generated by the control and monitoring circuit 4304 prior to being transmitted to the smart monitoring system. In some cases, the PUF signal may be transmitted to the smart monitoring system 5302, e.g., along with the diagnostic data 4603, and the prognosis/diagnostic module 5308 may use the PUF signal to authenticate or validate the diagnostic data prior to using it for modeling, diagnosis, prognosis, and/or triggering an alert. Similarly, in some embodiments, the system 5320 may comprise a PUF module configured to generate a unique PUF signal that may be used, e.g., by the prognostic module 5314, to authenticate the diagnostic data generated by the control and monitoring circuit 4304 prior to being transmitted to auxiliary processing system 5322. In some cases, the PUF signal may be transmitted to the auxiliary processing system 5322, e.g., along with the diagnostic data, and the auxiliary processing system 5322 may use the PUF signal to authenticate or validate the diagnostic data prior to using it for modeling, diagnosis, prognosis, and/or triggering an alert.

High Current and High Voltage Systems with Fault Protection Capability Using MEMS Switch

In various embodiments disclosed herein, a system includes an electrical overstress (EOS) protection device configured to protect a circuit, device, module, or sub-system therein against an EOS event, e.g., electrostatic discharge (ESD) event such as an arcing event. In some cases, the system may comprise at least one circuit, module, device, or sub-system that operates a high current or high voltage level during its normal operation. In some examples, a high voltage level can be from 20 to 50 volts, from 50 to 100 volts, from 100 to 150 voltage, from 150 to 200 volts, from 200 to 400 volts, from 400 to 500 voltages, or any ranges formed by these values or larger values. In some examples, a high current level can be from 5 to 10 amps, from 10 to 20 amps, from 20 to 50 amps, from 50 to 100 amps or any ranges formed by these values or larger values. In some cases, the EOS protection device may comprise a device providing a controlled electrical connection between two terminals of the system and configured to interrupt the electrical connection between the two terminals when an electric potential difference between the two terminals or current transmitted between the two terminals exceeds a threshold condition. In some examples, the threshold condition may comprise a threshold voltage or current condition, a rise time shorter than a specified value, or the like. In some of the existing systems, the EOS protection device may comprise a thermal/magnetic or a solid-state switch. A thermal/magnetic switch can be configured to disconnect electric connection between two terminals in response to a current passing through the switch exceeding a threshold value and using a thermal and/or a magnetic actuation mechanism. A solid-state switch can be configured to disconnect an electrical connection between two terminals in response to receiving a control signal and using a semiconductor switch (e.g., a transistor) indicative of voltage between the two terminals or current transmitted between the two terminals exceeding threshold values. The control signal may indicate that a current or voltage at a node has exceeded a threshold value. In some examples, the control signal may be generated by a sensor or a sensor circuit electrically connected to one or both terminals (directly or via solid state switch). In some cases, the sensor or sensor circuit may be connected to other parts of the system that may not be directly connected to the two terminals. In some cases, a thermal/magnetic switch can be large and bulky in particularly when designed to handle high current or high voltage. As such, it can be difficult to integrate thermal/magnetic switches with certain systems, e.g., systems having a large number of modules that should be individually protected by individual switches. Moreover, while thermal/magnetic switches can automatically break electric connection between two terminals, typically they cannot automatically reestablish the electric connection without manual intervention. Additionally, a thermal/magnetic switch is typically configured to trip based on fixed threshold condition that may not be adjusted. A solid-state switch is much smaller than a thermal/magnetic switch and given that it is triggered based on a control signal (as opposed to an internal self-driven mechanism), it can be used to provide programable EOS protection when combined with a programable sensor circuit configured to generate the control signal based on an adjustable threshold condition. While, compared to thermal/magnetic switches, the solid-state switches provide the advantages of being compact and providing programable protection, typical solid-state switches may not be able to handle large operating currents and voltages. In addition, certain solid-state switches (e.g., those based on silicon carbide) can be very expensive and thereby significantly increase the cost associated with protecting a high-voltage or high-current system against EOS events, in particular a system comprising a large number or modules that may be individually protected by separate EOS protection devices. As such, there is a need for EOS protection devices that can support large operational currents and/or voltages, are compact, can be integrated with circuits, modules, or devices in a corresponding system, can control an electric connection based on a control signal, can provide programable EOS protection), are low cost and can be fabricated at large scale.

To address the above-indicated needs, a microelectromechanical system (MEMS) switch according to embodiments can satisfy at least some or nearly all the conditions described above. In some cases, a MEMS switch may comprise an electromechanically controlled conductive beam configured to provide controllable electrical connection between at least a pair of electric terminals. In some cases, the geometry, material composition, and electrical design of a MEMS switch may allow the switch to transmit high currents and control electric connection between two terminals having large voltage difference (e.g., larger than 100, 300, 500 volts or larger). An example of such MEMS switch is a teeter-totter MEMS switch. In some cases, a MEMS switch (e.g., a teeter-switch) may be controlled by a control circuit configured to improve high voltage operation of the MEMS switch, e.g., using a hot switch configured to prevent formation of arcs during activation or deactivation of a MEMS switch (e.g., a teeter-totter switch) in the presence of large voltage difference between the two terminals connect by the MEMS switch. Examples of teeter-totter MEMS switches and circuit breakers comprising teeter-totter MEMS switches are described above with respect to FIGS. 1A to 6C. In some embodiments, a circuit breaker (e.g., one of the circuit breakers described above with respect to FIGS. 10-21) may comprise a control or control and monitoring circuit configured to control, protect, and/or monitor a MEMS switch or MEMS switch module. In some embodiments, a circuit breaker may include or may be in communication with a smart monitoring system configured to monitor a MEMS switch (or MEMS switch module) and initiate protective and preventive action to ensure proper operation of the circuit breaker and prolong the life of the MEMS switch. Examples of smart monitoring systems and computational modules therein are described above with respect to FIGS. 46-53B. In some cases, a smart monitoring system or another system may use a digital tween model for predictive maintenance of the MEMS switch. Example MEMS switch monitoring and protection systems and methods are described above with respect to FIGS. 33-38 and FIGS. 46-53B. In some embodiments disclosed below, a MEMS switch and in some cases, a circuit breaker, a smart monitoring system, and/or a digital tween model may be used to protect one or more devices, circuits, modules, and/or sub-systems in a system.

In some embodiments, the MEMS-based circuit breaker and/or the MEMS switch module included therein may be integrated with a module or a circuit, e.g., on a common substrate or board and/or in a common enclosure. In some embodiments, the MEMS switch module can be controlled by a controller (e.g., a microcontroller) of the module or circuit protected by the MEMS switch and/or whose connection to a power supply is controlled by the MEMS switch. In some cases, the circuit breaker circuit that controls and/or monitors the MEMS switch and the module/circuit protected by the circuit breaker may use a common controller. For example, a microcontroller may be configured to provide closed loop booting control for a system and also be used by a circuit breaker protecting the system. In some examples, at least a portion of the system and the circuit breaker may be co-fabricated on a common printed circuit board (PCB).

In some embodiments, a controller used by a MEMS-based circuit breaker and circuit, module, or system protected or connected to the MEMS-based circuit breaker, may comprise a field-programable gate array (FPGA), a microcontroller, a programmable logic controller (PLC) and the like.

In some such cases, the circuit breaker can be integrated with the controller on a common board or substrate. Advantageously, using the controller of a module or circuit for controlling a circuit breaker and/or a MEMS switch therein may allow usage of advanced control methods and computational resources provided by the controller that is configured to handle computation and control tasks within the module or circuit. Moreover, by using a common controller to control a module and a circuit breaker that protects the module from EOS events can reduce the cost and make the corresponding system more compact. In some embodiments, a circuit breaker may one or both software and hardware resources available in a module or circuit protected by the circuit breaker (e.g., hardware on a printed circuit board and the machine-readable instructions stored therein).

In some embodiments, a MEMS-based circuit breaker or MEMS switch module and a module or circuit protected by the circuit breaker or the MEMS switch module may use one or more common sensors to measure a parameter (e.g., a voltage or a current) at a node (e.g., a common node). Advantageously, usage of a common sensor by the circuit or module and circuit breaker may reduce the cost and complexity of a corresponding system and enable the system to be more compact.

In some embodiments, a MEMS-based circuit breaker or MEMS switch module and a module or circuit protected by circuit breaker or the MEMS switch may use one or both of a common controller (e.g., a microcontroller) and a common sensor to measure a parameter (e.g., a voltage or a current) at a node (e.g., a common node) and process the measurement results to provide a function, generate a signal, initiate an action, or the like. For example, the circuit breaker may use the common sensor and controller to detect an EOS event and generate a control signal to activate a MEMS switch module (e.g., an open switch condition) therein and the module or circuit may use the common sensor and controller to support a specified functionality (e.g., controlling the speed of a motor, regulating a current or voltage provided to a server module, a rechargeable battery, adjust a high-voltage provided to a device, or the like).

In some cases, the MEMS-based circuit breaker or MEMS switch module and the circuit or module may use the common sensor and/or the common controller during the same, different, or overlapping periods.

In some embodiments, integrating a MEMS-based circuit breaker with a module or a circuit protected by the circuit breaker may reduce the response time of the circuit breaker to an EOS event, e.g., by reducing delay between a sensor measurement and a corresponding determination of presence of an EOS event based on the sensor measurement, and/or generation of a control signal to activate a MEMS switch to prevent damage to the module and circuit.

In various embodiments, a MEMS-based circuit breaker (or a MEMS switch) that is integrated with a module or circuit in a system may comprise or can be in communication with a smart monitoring system and/or a digital twin model, examples of which are described above with respect to FIGS. 46-53B and 31-38, to monitor the performance of a MEMS switch for predictive maintenance (e.g., by initiating preventive actions). In some cases, the smart monitoring system may be configured to monitor and maintain one or more circuits, devices, modules, and/or sub-systems other than the MEMS-based circuit breaker and the MEMS switch module therein. In some such cases, the MEMS-based circuit breaker MEMS-based circuit breaker may be configured to protect the one more circuits, devices, modules, and/or sub-systems from a fault (e.g., a present or future EOS event) based, e.g., at least in part on a determination made by the smart monitoring system. Example smart monitoring systems that can monitor, control, and/or maintain the MEMS-based circuit breaker and at least one system module of a system, which may be protected by MEMS-based circuit breaker, are described in communication with a smart monitoring system and/or a digital twin model, examples of which are described above with respect to FIGS. 46-53B and 31-38.

In some embodiments, a MEMS-based circuit breaker or a MEMS switch (e.g., the circuit breakers and MEMS switches described above with respect FIGS. 1A-1B, 2A-2C, 3A-3C, 4A-4B, 5A-5B, and 6A-6C.), may be used in certain industrial systems or consumer products to provide fault protection (e.g., to protect a module, circuit, device or a sub-system against an EOS event) by controlling (automatically or manually) electrical connection between two terminals. In some cases, the MEMS-based circuit breaker or MEMS switch may provide superior performance, e.g., compared to its electronic (e.g., solid-state) counterpart, in particular when it is used to control electrical connections comprising terminals having voltage differences (e.g., greater than 50 volts, greater than 100 volts, greater than 400 volts, greater than 500 volts or larger values). For example, the MEMS-based circuit breaker or and the MEMS switch may have a faster response to a control signal, e.g., with respect to disrupting an electrical connection in response to detection of an EOS event.

### Example Systems High Voltage/High Current Systems Protected by MEMS-Based Circuit Breaker

1) Motor Drives with Integrated Circuit Breaker

In some embodiments, a MEMS switch or a MEMS-based circuit breaker can be used in conjunction with an isolated gate driver to provide improved protection and control for an electric motor (e.g., an industrial motor). For example, in the event of a catastrophic failure, the MEMS switch or MEMS-based circuit breaker may quickly disconnect the motor from an electric power source to protect the system).

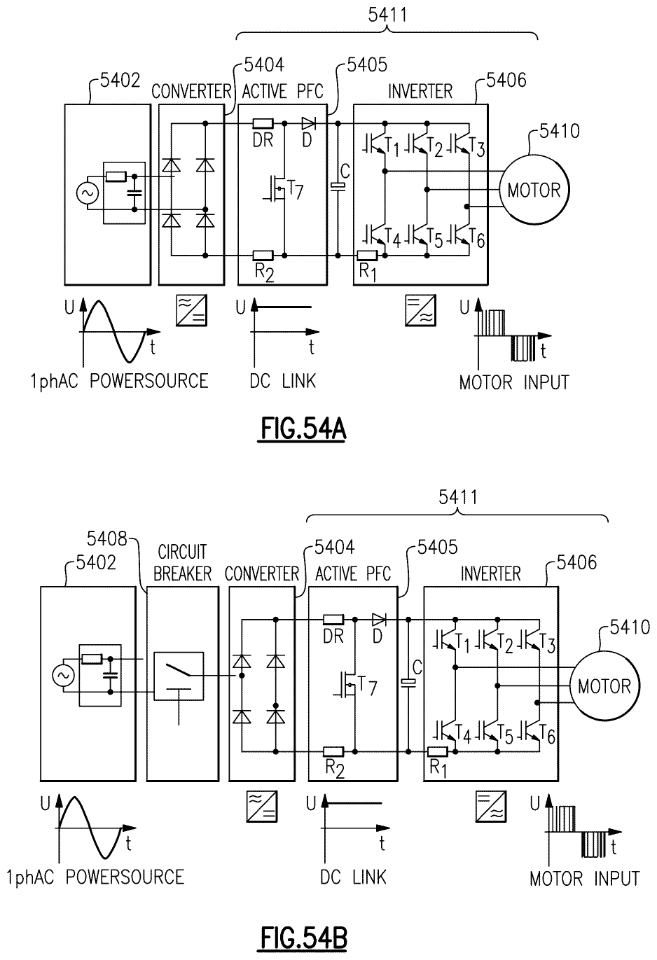

FIG. 54A is a block diagram of an example drive circuit 5411 for an electric motor 5410 (e.g., a three-phase motor, a stepper motor, and the like). In some cases, the drive circuit 5411 may comprise a power supply 5402, a converter 5404, an active power factor corrector (PFC) and an inverter 5406. In some cases, the power supply 5402 may generate and provide AC electric power to the converter 5404, the converter 5404 may rectify the AC power and output DC power, the active PFC may correct the power factor, e.g., by adjusting the input current to be in phase with the input voltage, the inverter 5406 may receive the DC power from the active PFC 5405 and use high-speed electronic switches (like insulated-gate bipolar transistors (IGBTs) or metal-oxide-semiconductor field-effect transistors (MOSFETs)) to generate a simulated AC waveform and provide it to the motor 5410.

In some embodiments, a circuit breaker may be used to protect the motor 5410, the power supply 5402 and one or more of the converter 5404, the PFC 5405, and the inverter 5406. In some cases, the drive circuit 5411 and the motor 5410 may be driven by different levels of voltage and current during different operational modes and phases of the motor 5410 (e.g., start-up, acceleration, steady-state, load variation, deceleration, or idle). As such, it can be advantageous to use a programable circuit breaker (such as a MEMS-based circuit breaker) such that its trip point/threshold can be adjusted during different operational phases/modes of motor. For example, during startup phase a first current threshold for tripping the circuit breaker can be adjusted to be larger compared to a second current threshold during steady state phase such to allow for normal operation of the motor 5410 while protecting the motor 5410, and the modules of the drive circuit 5411.

FIG. 54B is a block diagram of motor 5410 driven by a drive circuit 5411 connected to the power supply 5402 via a circuit breaker 5408, according to embodiments. The circuit breaker 5408 is configured to disconnect the power supply 5402 from the drive circuit 5411 in response to detection of an EOS event by a controller of the circuit breaker 5408 using one or more sensors. In some embodiments, the controller may be configured to adjust a threshold for generating a control signal (e.g., activation or deactivation signal) based on an operational phase of the motor 5410. In some embodiments, the circuit breaker 5408 may comprise a MEMS switch or a MEMS switch module. For example, the circuit breaker 5408 may comprise one of the circuit breakers and MEMS switched therein, e.g., as described above with respect to FIG. 1A to FIG. 21. In some embodiments, the circuit breaker 5408 may use a controller used by the drive circuit 5411 to control one or more of the modules therein, to control a MEMS switch, process a sensor signal received from a sensor, generate a switch control signal (e.g., activation or deactivation signal) and the like. In some cases, the circuit breaker 5408 may use a sensor used by one or more modules of the drive circuit 5411, to generate a switch control signal, monitor a MEMS switch, initiate a preventive action or preventive maintenance. For example, the circuit breaker 5408 may use a field-programmable gate array (FPGA) or microcontroller of the drive circuit 5411 to perform current monitoring, fault logging and the like. In some embodiments, the MEMS-based circuit breaker 5408 may be integrated with one or more modules of the drive circuit 5411.

Advantageously, using a MEMS-based circuit breaker for protecting one or more of the motor 5410, power supply 5402 and the drive circuit 5411 allows for protecting the motor 5410 under a variety of operational conditions. In addition, integrating the circuit breaker 5408 with modules of the drive circuit 5411, e.g., using a common controller and/or common sensors can advantageously reduce cost and complexity of the system. Moreover, integrating the circuit breaker 5408 with drive circuit 5411 may reduce a response time of the circuit breaker 5408 to various events (e.g., EOS events) or controlled signals, and thereby enable faster fault detection. For example, when the circuit breaker 5407 is formed with a controller of the drive circuit 5411 on a common board or common substrate, the sensor and control signals may be transmitted between the controller, sensors, and or the circuit breaker 5408 with lower delay compared to a system using an external circuit breaker (e.g., a bulky thermal/magnetic circuit breaker) due to close coupling via short transmission lines.

In some embodiments, the circuit breaker 5408 may be configured to log detected faults and overtime build a mission profile and/or trend indicative of the quality of power delivered to the motor 5410.

In some cases, a trip point of the circuit breaker 5408 may be adjusted or tuned by a controller or firmware (e.g., commonly used with the drive circuit 5411) to provide proper EOS protection during different operational phases of the motor 5410. For example, during a start-up phase, where an in-rush current from the power supply 5402 to the drive circuit 5411 is expected, the trip point can be set to higher value. In some embodiments, during the deceleration phase where the electric power provided to the motor 5410 is reduced or discontinued, the kinetic mechanical energy of the electromotor 5410 may be converted to electric power and transmitted to the drive circuit and thereby to the power supply 5402. As such, in some cases, the circuit breaker 5408 may be configured to protect the power supply 5402 from excessive electric power flowing back to the power supply 5402, e.g., by activating the MEMS switch therein in response to detection of electric power (or electric current) having an amplitude greater than a set threshold, flowing back to the power supply 5402.

Advantageously, using a MEMS-based circuit breaker 5408 can provide more reliable protection under different conditions and during different operational phases compared to thermal/magnetic circuit breakers that usually break the circuit when exposed to a voltage/current larger than a fixed threshold and for fixed period.

In some embodiments, by integrating the MEMS-based circuit breaker 5408 with the drive circuit 5411, some of the challenges associated with maintenance, installation, inconsistencies, and damage to motor 5410 or drive circuit 5411 can be mitigated to prolong the lifetime damage to motor 5410, or drive circuit 5411, and the circuit breaker 5408 itself.

In some embodiments, a MEMS switch module used in the circuit breaker 5408 may have a lower ON-resistance, when in an ON state (e.g., when it is deactivated), compared to a solid-state switch. As such, using a MEMS-based switch may overcome challenges associated with heat dissipation, in particular when the switch is integrated with the drive circuit 5411 on a common substrate.

In some embodiments, the MEMS-based circuit breaker 5408 may comprise a hot switch configured to prevent arcing events during activation and deactivation of the MEMS switch module therein (e.g., similar to example circuit breakers described above with respect to FIGS. 16, 18, and 29-31.

In some cases, e.g., when the motor 5410 operates at high currents, using the MEMS-based circuit breaker may significantly reduce the cost of the system, compared to a sold-state circuit breaker, as typically a high-current/high-voltage MEMS switch can have a much lower cost per unit current compared to a solid-state switch (e.g., a silicon carbide transistor) capable of handling similar current and voltage levels.

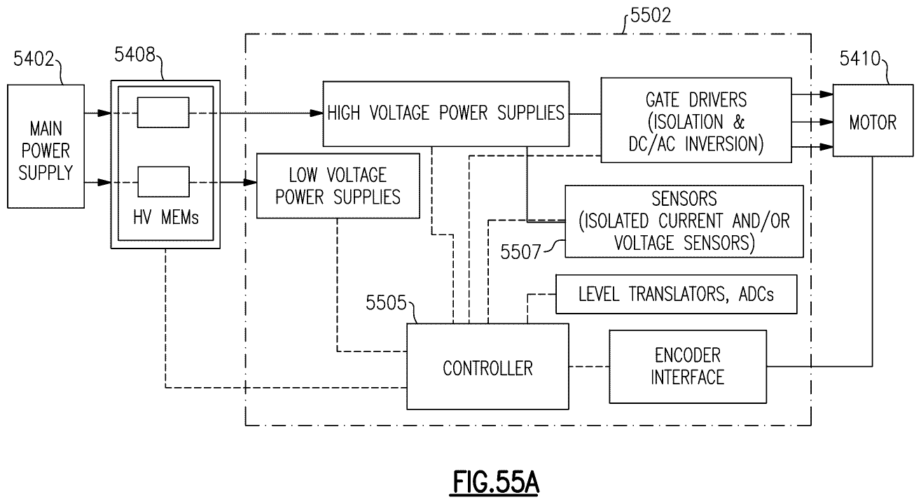

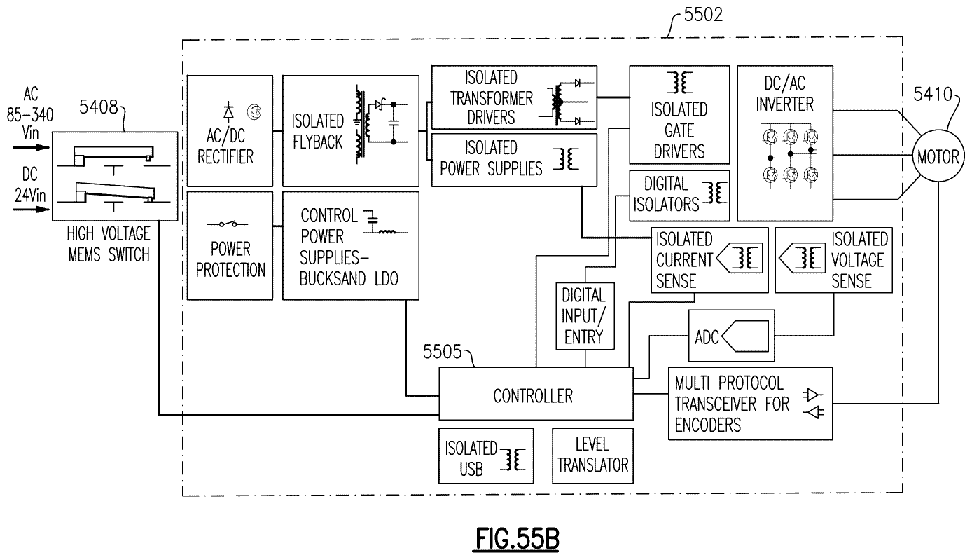

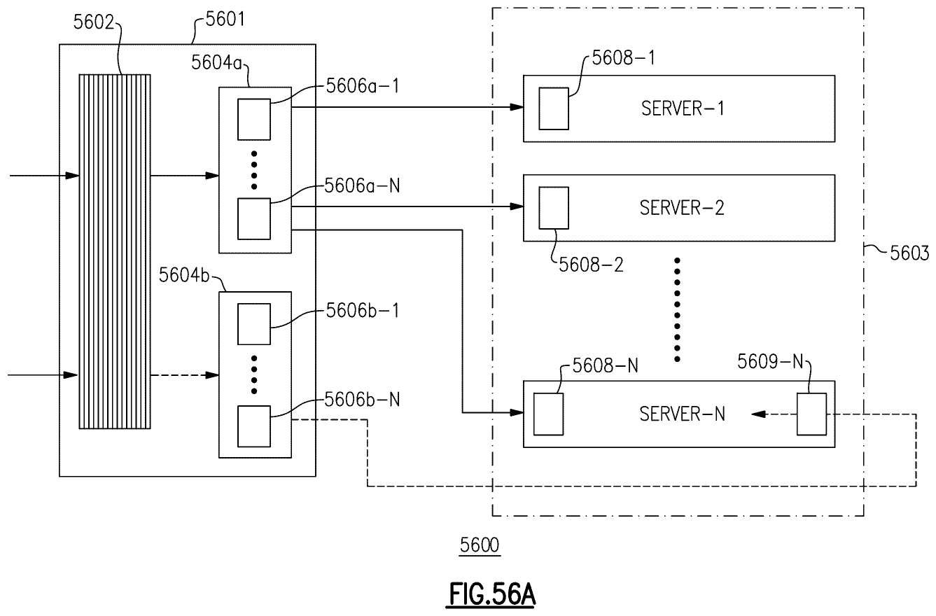

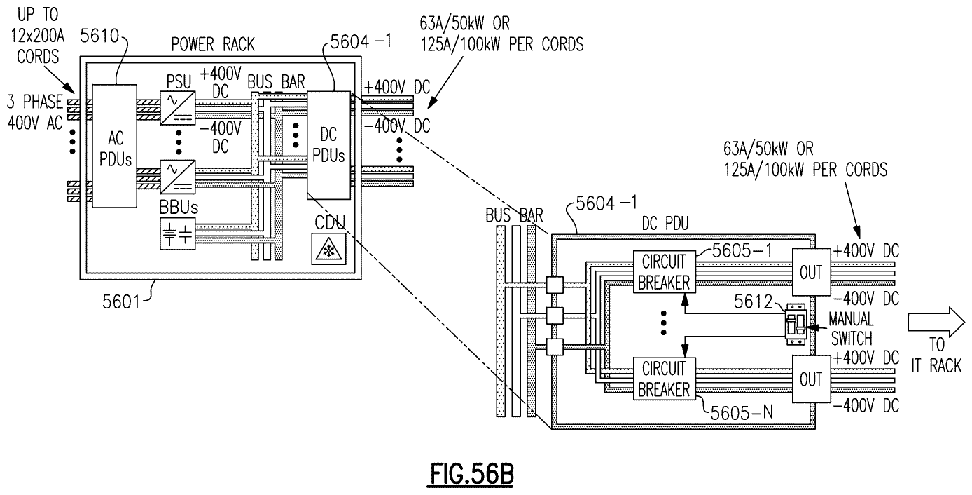

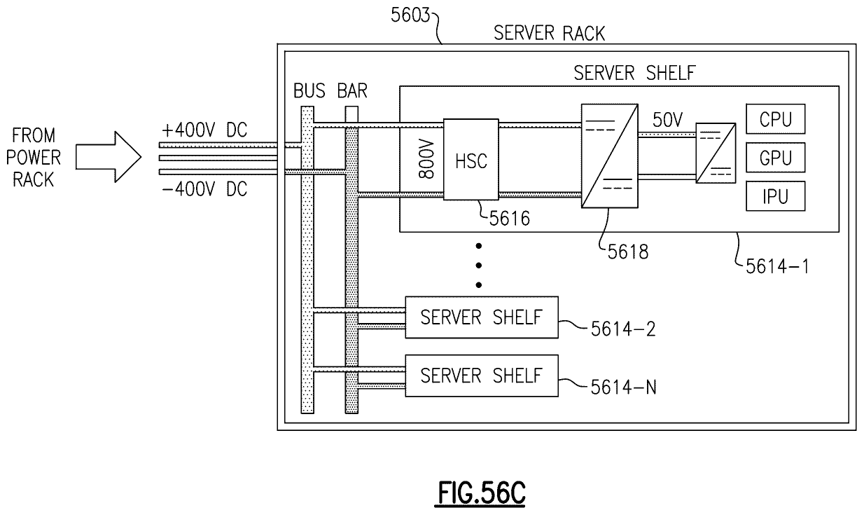

FIG. 55A is a block diagram of motor drive system comprising a drive circuit 5502 configured to drive and control an electric motor 5410 using the power received from a main power supply 5402, according to another embodiment. In some cases, the drive circuit 5502 may comprise one or more features described above with the drive circuit 5411 (FIGS. 1A and 1B), the details of which may be omitted herein for brevity. In some embodiments, the motor drive system may comprise a MEMS-based circuit breaker 5408 used to control one or more electrical connections between the main power supply 5402 and the drive circuit 5502 to protect one or both the drive circuit 5502 and the main power supply 5402 against faults such as EOS events during various operational phases of the motor 5410. In some embodiments, the MEMS-based circuit breaker 5408 can be integrated with one or more of the modules of the drive circuit 5502 (shown with the dashed-dotted box) on a common board or substrate. For example, the MEMS-based circuit breaker 5408 can be integrated with the controller 5505 of the drive circuit 5502.

In some embodiments, the controller 5505 may be commonly used by the MEMS-based circuit breaker 5408 and the drive circuit 5502 to perform at least a portion of the corresponding computational tasks. For example, the circuit breaker 5408 may use the controller 205 to control and monitor one or more MEMS switch modules of the circuit breaker 5408 and the drive circuit 5502 may use the controller 5505 to control one or more of high/low voltage supplies, gate drivers, sensors, encoder interface, level translators and ADCs, among other components. In some embodiments, the controller 5505 may be configured to monitor, control, and/or maintain one or more modules of the drive circuit 5502, in some cases, using a digital twin model, an action module, and/or other modules as described with respect to FIGS. 33-38 and 46-53B.

FIG. 55B is a block diagram illustrating some of the circuits devices, modules and sub-systems of the drive circuit 5502.

In some embodiments, the MEMS-based circuit breaker 5408 in FIGS. 1B, and 2A-2B, may be connected two modules of the drive circuit 5502 (or the drive circuit 5411), or between the drive circuit 5502 (or the drive circuit 5411) and the motor 5410, to control one or more electrical connections therebetween and to protect one or more devices, circuits, and/or modules of the drive circuit 5502 (or the drive circuit 5411) and/or the motor 5410 against a fault such as an EOS event.

### 2) Fault Protection for Servers

In some embodiments, MEMS-based circuit breakers (e.g., circuit breakers described above with respect to FIGS. 10, 11A, 13, 15-16, 18-19, and 21) may be used to provide EOS protection for modules components, and server shelves in a server rack comprising a plurality of server shelves. In some such embodiments, these circuit breakers may provide self-prognosis capability, comprise digital twin and/or a smart monitoring system, or be in communication with a digital twin and/or a smart monitoring system. Some examples of circuit breakers with self-prognosis capability, digital twins and smart monitoring systems are described above with respect to FIGS. 46-53B.

As described above with respect to FIG. 22, in various implementations, the server shelves of a server system can be powered by a DC voltage about 48-50 volts or DC voltages about ±400 Volts. While MEMS-based circuit breakers can provide protection against EOS (electrical overstress) events for server shelves powered by either 48-50 V or ±400 V electric supply, they may offer greater advantages in ±400 V systems. This is because MEMS-based circuit breakers can use high-voltage MEMS switches (e.g. the MEMS switches described above with respect to FIGS. 1A-9C) that can provide more reliable switching performance and lower ON resistance compared to their electronic counterparts (e.g., transistors).

In conventional 48-50 V DC server systems, the architecture typically consist of rack-level AC power distribution and localized conversion modules. Each server rack receives AC mains input (120/240 V AC), which is routed to rack-mounted power supply units (PSUs) or individual server PSUs. These PSUs convert AC to 48 V DC. The conversion is decentralized, as each server rack handles its own AC/DC conversion, resulting in multiple conversion stages and higher energy losses.

Advanced high voltage DC (HVDC) server systems use centralize power conversion in a dedicated HVDC power rack. This power rack receives AC mains and converts it to ±400 V DC, which is then distributed directly to server racks via high-voltage DC busbars or cables. Inside the server rack, there are no traditional AC PSUs. This architecture minimizes conversion stages, reduces cable thickness, and improves efficiency.

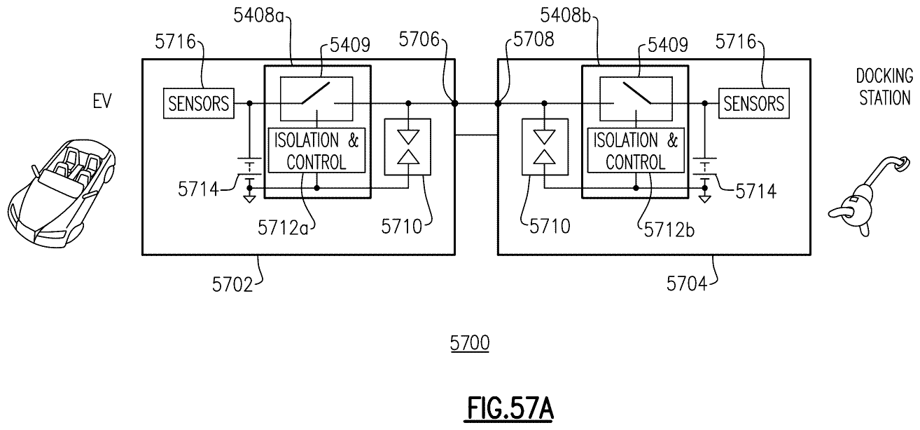

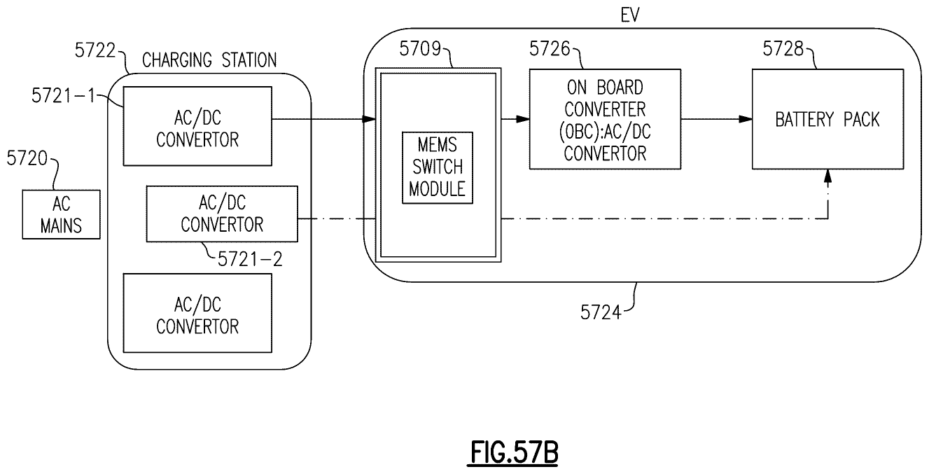

FIG. 56A is a block diagram of an example server rack or server system 5600 comprising a server rack 5603 powered by a power rack 5601. In some cases, the server system 5600 can be a HVDC server system. In some cases, the server rack 5603 may be configured to house a plurality of server shelves 1, 2, . . . , N. In some embodiments, the power rack 5601 may comprise an AC-DC converter 5602 that may receive 400 volts AC as an electric supply inputs, convert the received AC voltage to a DC voltage. The power rack 5601 may further comprise one or more power distribution units (PDUs), 5604a, 5604b configured to receive the DC voltages generated by the AC-DC converter 5602 and DC electric supply to each of the server shelves 1, 2, . . . , N in the server rack 5600. In some embodiments, an individual server shelf may comprise a main board having a processor and a memory and other elements of a computational system or an expansion card (e.g., a network interface card, additional processors, and the like). In some cases, a PDU 5604a may provide electric power from the AC-DC converter 5602 to a server shelf (e.g., SERVER-1) via one or more MEMS-based circuit breakers configured to protect the server shelf and the PDU 5604a against a fault (e.g., an EOS event). In some embodiments, a first circuit breaker 5606a-1 may reside in the PDU 5604a and a second circuit breaker 5608-1 may reside in the sever shelf.

In some cases, a server shelf (e.g., SERVER-N) may receive electric power from two or more PDUs, e.g., 5604a and 5604b, each configured to provide a different level electric power and/or voltage. In some such cases, the server card may receive power from two or more different PDUs via two or more MEMS-based circuit breakers. In some cases, an individual server shelf (SEVER-N) may receive electric power from first and second PDUs 5604a, 5604b via a first circuit breaker 5606a-N in the first PDU 5604a and a second circuit breaker 5606b-N in the second PDU 5604b. In some cases, SEVER-N may comprise a third circuit breaker 5608-N through which electric power is received from the first PDU 5604a and a fourth circuit breaker 5609-N through which electric power is received from the second PDU 5604b.

In some embodiments, circuit breakers 5608-1, 5608-2, . . . , 5608-N may reside in the HSC units of the respective server shelves. In some embodiments, any one of the circuit breakers 5608-1, 5608-2, . . . , 5608-N and circuit breakers 5606a-1, . . . , 5606a-N, and 5606b-1, . . . , 5606b-N may comprise a MEMS-based circuit breaker (e.g., the circuit breakers described above with respect to FIGS. 14-21). In some cases, a MEMS-based circuit breaker may be integrated with the server shelf (e.g., with a module of the server shelf on a common substrate or board). In some cases, one or both circuit breakers through which electric power is delivered to a server shelf may use a processor or controller of the server card to control and/or monitor a MEMS switch module of the circuit breaker.

FIG. 56B schematically illustrates a portion of a high voltage direct current (HVDC) power rack 5601 configured to receive high voltage supplies (e.g., 3-phase 400 AC voltage). In some cases, the power rack 5601 may comprise one or more AC power distribution units (AC PDUs) 5610 configured to receive one or more high voltage supplies via one or more input ports, one or more power supply units (PSUs) configured to receive AC voltages from the one or more AC PDUs 5610 and generate corresponding DC voltages (e.g., at ±400 volts). The power rack 5601 may further comprise one or more DC power distribution units (DC PDUs) 5604 configured to receive DC output voltages generated by the power supply units (PSUs) and output DC voltages. The inset in FIG. 56B shows a portion of the internal circuitry of a PDU 5604-1 of the power rack 5601. In some cases, the PDU 5604-1 may receive an input electric supply from a bus bar fed by the one or more PSUs and distribute the electric supply between a plurality of outputs. In some cases, the input electric supply and electric supply provided to each of the outputs may comprise a +400 volt, a −400 volt, and a reference voltage (e.g., a ground terminal). In some cases, the DC PDU 5604-1 may comprise one or more circuit breakers 5605-1 . . . 5605-N, each configured to provide a controlled electric connection between the bus bar and a respective output. In some cases, at least one of the circuit breakers 5605-1 . . . 5605-N may comprise a MEMS-based circuit breaker (e.g., one of the circuit breakers described above with respect to FIGS. 10-21). In some cases, individual ones of the circuit breakers 5605-1 . . . 5605-N, may be configured to be activated in response to detection of an EOS event (e.g., by a sensor of the corresponding circuit breaker) to electrically disconnect the respective output ports from the bus bar. In some cases, the PDU 5604-1 may comprise a manual switch 5612 (e.g., an electro-mechanical relay) to provide additional protection in particular to handle emergency scenarios where electric power supplied from the PDU 5604-1 to a server rack (e.g., the server rack 5603). In some cases, the manual switch 5612 can be configured manually activate one or more of the circuit breakers 5605-1 . . . 5605-N to electrically disconnect a portion of electrical power provided from the PDU 5604-1 to the server rack 5603. In some cases, the PDU 5604-1 may further comprise and electrotechnical switch configured to electrically disconnect PDU 5604-1 from one or more of the PSUs that provide DC volage to the PDU 5604-1.

FIG. 56C schematically illustrates a portion of a high voltage direct current (HVDC) server rack 5603 and a portion of internal circuitry of a server shelf 5614-1 of the HVDC server rack 5603. In some embodiments, the server rack 5603 may comprise a plurality of sever shelves 5614-1 . . . 5614-N, where each is receiving a high voltage supply (e.g., ±400 volts) from a bus bar of the sever rack 5603 fed by power rack 5601 (e.g., by one of the PDUs 5604). In some cases, a serve shelf 5614-1 may comprise a hot swab controller (HSC) 5616. In some cases, the server shelf 5614-1 may comprise one or more features described above with respect to server shelf 2212. In some cases, the HSC 5616 may comprise one or more features described above with respect to HSC 2214 described above (FIG. 22).

3) Electric Vehicle (EV) Charging Systems with MEMS-Based Circuit Breaker

In some embodiments, MEMS switches or MEMS-based circuit breakers (e.g., teeter-totter MEMS switches and circuit breakers described above with respect to FIGS. 1A-21) may be used in one or both of an electric vehicle (EV) and an EV charging system.

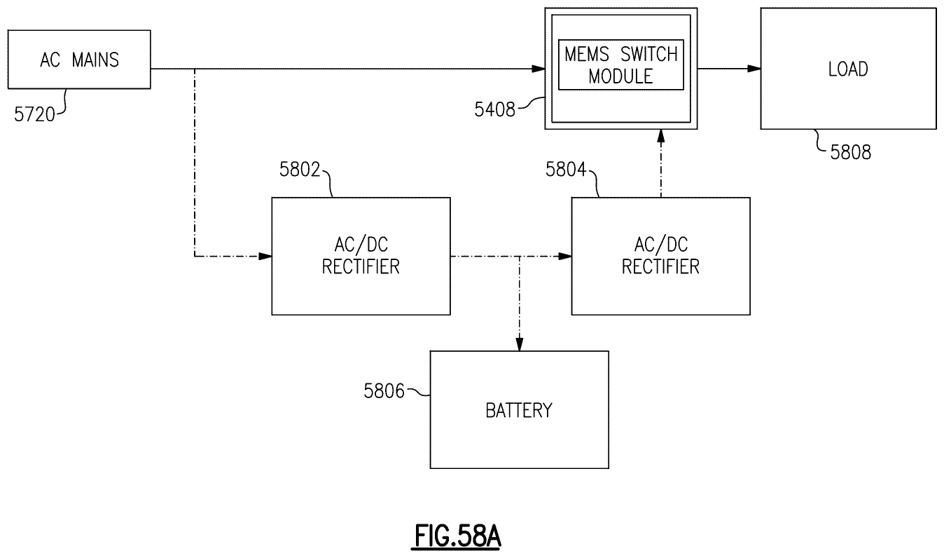

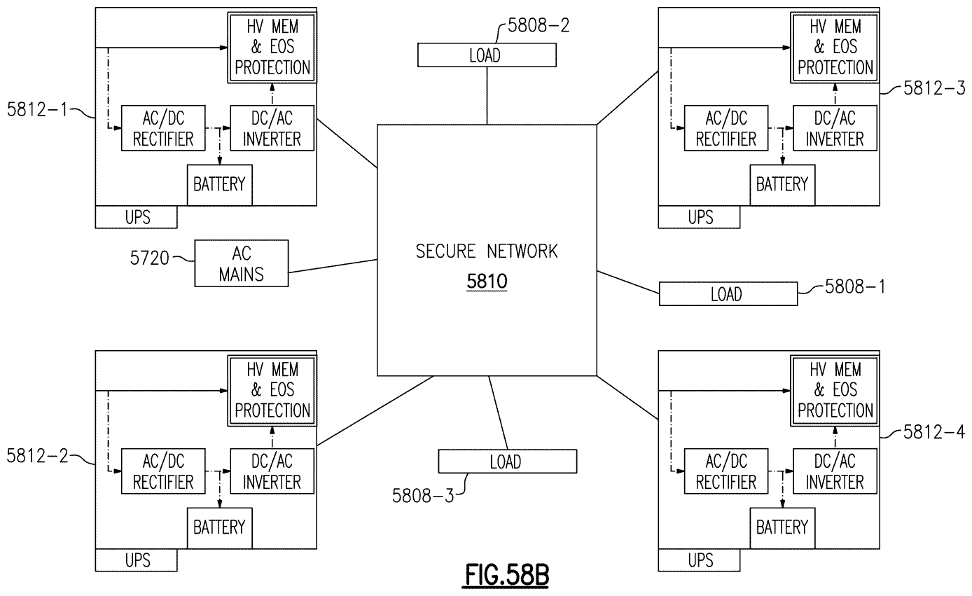

FIG. 57A illustrates an example front end protection system 5700 for an EV charging system that may include one or more MEMS-based circuit breakers 5408a, 5408b, which may be combined/integrated with isolating elements and additional EOS protection devices (e.g., spark gaps). In some cases, the front-end protection system 5700 may be implemented between an EV (e.g., rechargeable batteries of the EV) and a docking station. In some embodiments, the front-end protection system 5700 may comprise a first protection circuit 5702 (e.g., integrated with the EV energy storage system) and a second protection circuit 5704 (e.g., integrated with an energy storge or source in the docking station). In some cases, the first and second protection circuits 5702, 5704 can be electrically connected via one or more cables and connectors (e.g., when the EV is charged via the docking station). For example, during an EV charging period, an input port 5706 of the first protection circuit 5702 can be electrically connected to an output port 5708 of the second protection circuit 5704. In some examples, the first and second protection circuits 5702, 5704 may comprise different or similar configurations and/or components. In some embodiments, the first protection circuit 5702 may be configured to protect the components of the EV energy storage system and the second protection circuit 5704 may be configured to protect the components of the docking station.

In some embodiments, one or both of the first and second protection circuits 5702, 5704 may comprise a MEMS-based circuit breaker 5408a or 5408b comprising a MEMS switch module (e.g., circuit breakers and MEMS switch modules described above for example with respect to FIGS. 1A-21), another EOS protective device 5710 (e.g., a spark gap), a controller 5712a (or 5712b), and a sensor 5716. In some implementations, one of the ports 5706, 5708 of the circuit breaker switches 5408a, 108b can be electrically connected to a first pole of a battery 5714 (e.g., a battery in the EV or docking station) and the output port 5706, the controller 5712a (or 5712b) can connect the second pole of the battery 5714 to the circuit breaker 5408a (or 108b), the controller 5712a (5712b) can connect the second pole of the battery 5714 to the control electrode of a MEMS switch module 5409 of the circuit breaker 5408a (5408b), and the EOS protective device 5710 may connect the second pole of the battery 5714 to the input port 5706. In some cases, the sensor 5716 may be connected to the first pole of the battery 5714. In some examples, the second pole of the battery 5714 can be connected to the ground potential. In various implementations, the battery 5714 may comprise a plurality of battery packs, e.g., an array of battery packs. In some cases, the sensor 5716 may be configured to detect a malfunction or tampering attempt. In some examples, upon detecting a malfunction or tampering attempt the sensor 5716 may activate the circuit breaker 5408 to disconnect the battery 5714 from the input port 5706 (or the output port 5708).

In some embodiments, the circuit breaker 5408 may be configured to disconnect the battery 5714 and the sensor 5716, from the input port 5706 (or the output port 5708) in response to a fault detection, to limit correct flow between the EV and the docking system and thereby prevent damage to the sensor 5716 and/or the battery 5714.

In some embodiments, one or both the circuit breaker 5408a or circuit breaker 5408b may comprise a MEMS switch module 5409 comprising one or more of the teeter-totter switches described above for example with respect to FIGS. 1A-1B, 2A-2C, 3A-3C, 4A-4B, 5A-5B, 6A-6C. Advantageously, the MEMS switch module 5409 can be more compact and can respond faster to a fault compared to other types of switches (such as solid-state switches).

In some cases, one or both the circuit breaker 5408a or circuit breaker 5408b may comprise a circuit breaker described above for example with respect to FIGS. 10, 11A, 13, 14, 16, 18, 19, and 21 or features described above with respect to FIGS. 10, 11A, 13, 14, 16, 18, 19, and 21. In some embodiments, the first circuit breaker 5408a can be integrated with one or more modules of the EV and the second circuit breaker 5408b can be integrated with one or more modules of the docking station. In some embodiments, the controller 5712a may be commonly used by the first circuit breaker 5408a and a module or a system of the EV. In some embodiments, the controller 5712b may be commonly used by the second circuit breaker 5408b and a module or a system of the docking station.

In some embodiments, the controller 5712a may be configured to monitor and control the MEMS switch module 5409a of the first circuit breaker 5408a to protect the sensors 5716, the battery 5714, and in some cases, one or more electronic modules of the EV. In some embodiments, the controller 5712b may be configured to monitor and control the MEMS switch module 5409b of the second circuit breaker 5408b to protect the sensors 5716, the battery 5714, and in some cases, one or more electronic modules of the docking station.

In some embodiments, the first protection circuit 5702 may comprise a smart monitoring system and/or a digital twin model configured to determine one or both present and future state of health of the MEMS switch module 5409a and initiate preventive actions (manually or automatically) or preventive maintenance to maintain functionality of the MEMS switch module 109a and prolong its lifetime. In some such embodiments, the smart monitoring system and/or the digital twin model may comprise one or more features of the smart monitoring system and/or the digital twin models described above with respect to FIGS. 46-53B or other monitoring system and/or the digital models.

In various implementations, the EOS protective device 5710 may comprise a spark gap device (e.g., a vertical or a lateral spark gap device), a conventional solid-state shunt protection device (e.g., a diode or a field-effect transistor) or other EOS protective devices.

In various implementations, the controller 5712 may be configured to turn off the circuit breaker 5408a (or 5408b) when the EOS protection device 5710 is triggered by an EOS event without electrically connecting the EOS protection device 5710 to the gate terminal of the circuit breaker 5408.

FIG. 57B schematically illustrates another example of EV charging system comprising a MEMS switch module or a MEMS-based circuit breaker configured to protect at least a module or sub-system of the electric vehicle (EV) and/or charging station (e.g., a battery, a converter, a sensor, or the like) from a fault such as EOS event.

In some embodiments, the EV charging system shown in FIG. 57B may include an EV comprising an on-board charger (OBC). In some examples, the OBC may comprise an AC-to-DC converter connected to a battery pack. In some such embodiments, the charging station may be connected to the OBC via a MEMS switch module and/or MEMS-based circuit breaker configured to electrically isolate the charging station and the EV upon detection of an EOS event, e.g., by a sensor of the MEMS switch module. In various implementations, the EV charger may be configured to handle a voltage about 120V and a current of about 15 Amps, or a voltage about 220V and a current about 40 Amps, and thereby an electric power from about 3.3 kW to 6.6 kW.

In some embodiments, to provide fast charging a charging station may include one or more AC-to-DC converter modules configured to directly provide a DC current/voltage to the battery pack of the EV via a charging inlet of a plug-in EV (bypassing EV's on-board charger to deliver high current to plug-in EV's traction batteries). In some cases, such fast-charging configuration may be configured to provide a voltage about 480V and a current about 125 Amps to 125 Amps), to the battery pack. In some such embodiments, an AC-to-DC converter module of the charging station may be electrically connected to the battery back via a MEMS switch module and/or MEMS-based circuit breaker configured to electrically isolate the charging station and the EV upon detection of an EOS event by a sensor, e.g., a sensor of the MEMS circuit breaker. In some examples, the MEMS switch module and/or MEMS-based circuit breaker may be integrated with the EV. In some examples, the MEMS switch module and/or MEMS-based circuit breaker may be integrated with the charging station.

### 4) Fault Protection for Uninterruptible Power Supply (UPS)

In some embodiments, one or more functionalities provided by an Uninterruptible Power Supply (UPS) may be provided by an integrated sub-system comprising one or more MEMS switches or MEMS-based circuit breaker (e.g., teeter-totter MEMS switches and circuit breakers described above with respect to FIGS. 1A-21). Examples of such functionalities may include, but are not limited to, surge suppression, filtering and transfer switching. In some examples, one or mor of these functions can be integrated into a single chip comprising a HV MEMS switch, and in some cases, an EOS protection device.

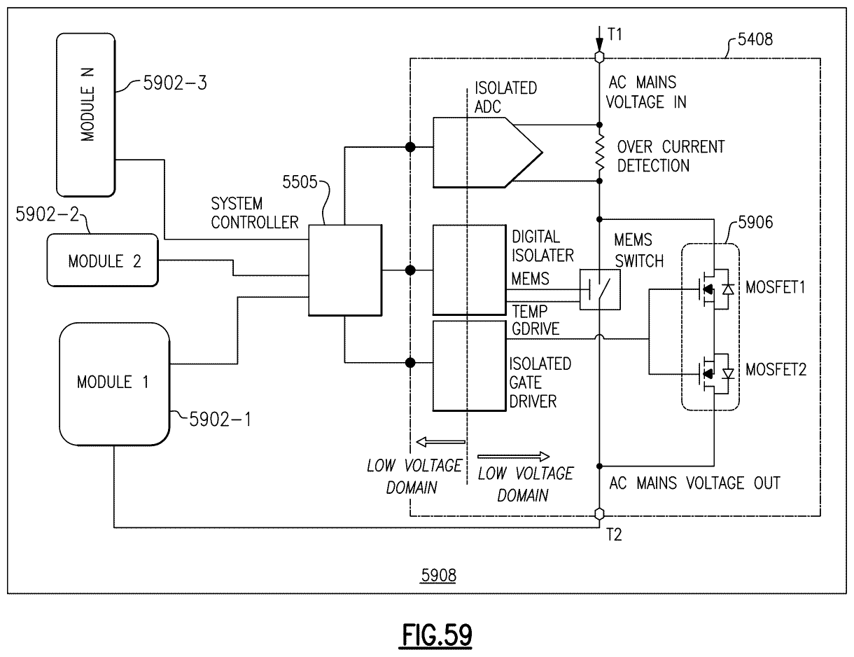

The block diagram illustrated in FIG. 58A schematically illustrates an example UPS systems that may use a MEMS switch module and/or a MEMS-based circuit breaker between an AC electric source and load.

The block diagram on FIG. 58B schematically illustrates an example system comprising a plurality of UPS units operating in parallel to supply power to several loads via a secure network (e.g., a power network). In some cases, individual UPS units of the plurality of UPS units may comprise a MEMS switch module and/or a MEMS-based circuit breaker, e.g., between the UPS unit and a secure network.

Systems with High Voltage MEMS-Based Circuit Breaker

FIG. 59 is a block diagram of an electrical system configured to perform a specified function or task using a plurality of modules. In some embodiments, the system may comprise a controller or processing module 5505 configured to perform the function or task using one or more system modules (module-1, module-2 . . . module-N) of the system. In some embodiments, the system may comprise a MEMS-based circuit breaker 5408 configured to control electrical connection between two terminals T1, T2, to protect at least one system module (e.g., module-1, module-2, . . . , and/or module-N) of the system or the processing module 5505 from a fault (e.g., an EOS event). In some examples, the two terminals may comprise two terminals of the system (e.g., within a system module or between two or more system modules). In some examples, the two terminals T1, T2, may comprise a terminal of the system and another terminal external to the system (e.g., a terminal of an external power supply). In some embodiments, the circuit breaker 5408 may use the processor module 5505 to control and monitor a MEMS switch module therein. In some embodiments, the controller 5505 may be configured to monitor, control, and/or maintain one or more of the system modules (module-1, . . . module-N), in some cases, using a digital twin model, an action module, and/or other modules as described above with respect to FIGS. 33-38 and FIGS. 46-53B. In some embodiments, the controller 5505 may use the outcomes of an evaluation or prediction (e.g., based on the digital twin model) to initiate an action (e.g., automatically or by a user) to maintain a system module or prolong its life time (e.g., by adjusting a parameter of the system module or another system module connected with the system module). In some embodiments, the controller 5505 may use the outcomes of an evaluation or prediction (e.g., based on the digital twin model) to control (e.g., activate) the MEMS switch module of the circuit breaker 5408 to protect one of the system modules (module-1, . . . module-N).

In some embodiments, the circuit breaker 5408 may further comprise one or more protective switches 5906 electrically connected in parallel with a MEMS switch module therein between the two terminals T1, T2. In some embodiments, the one or more protective switches 5906 may be configured to shunt at least a portion of a current flowing between the two terminals prior to a completion of open circuiting an electric path between the two terminals T1, T2.

In some embodiments, the MEMS-based circuit breakers 5408, 5408a/5408b, the MEMS switch module 5709 in FIGS. 57B, 58A and the HV MEMS and EOS protection modules in FIG. 58B, may comprise one or more features of the circuit breakers and MEMS switch systems described above with respect to FIGS. 33-38 and FIGS. 46-53B.

In various embodiments, any one of the systems described above with respect to FIGS. 56, 57A-57C, 58A-58B, and 59 may comprise a control and processing system configured to monitor and maintain one or more modules, circuits, devices, or sub-systems of those systems on the methods and modules described above with respect to FIGS. 33-38 and 46-53B (e.g., by generating a digital twin model and initiating automatic or manual preventive actions)

MEMS-Based Circuit Breakers with Power Out State Hold and Restoration

In some embodiments, when a system loses power, one or more MEMS switches used in various nodes or sub-systems of the systems may become dysfunctional and thereby when the power to system is restored, randomly connect or disconnect two terminals within the system depending on the state of the MEMS switch at time of power loss. In some embodiments, the MEMS switch or the system can be configured to enable holding a state of the MEMS switch during power outage or restoring a last state of the MEMS switch after power is restored.

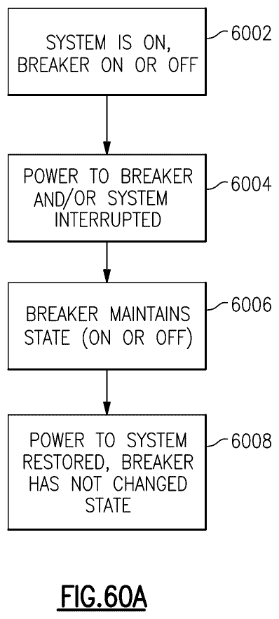

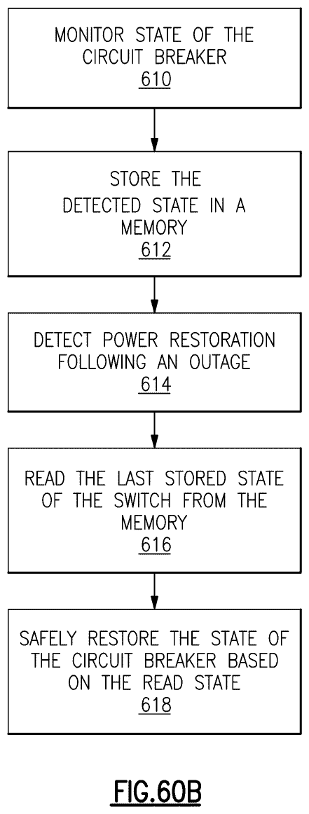

In some embodiments, a MEMS-based circuit breaker may be configured to keep a MEMS switch functional during power loss, e.g., using an auxiliary power source, or maintain an ON or OFF state of the MEMS switch after power loss (e.g., using a latching switch structure). In one embodiment, the system may comprise a backup power source configured to provide to the MEMS switch module (e.g., to a drive circuit of the MEMS switch module) when the electric power transmission to the system is interrupted. In various implementations, the backup power source may comprise an electric storage device (e.g., a battery, a reservoir capacitor-based circuit, and the like), or an energy harvester (e.g., a photocell, a thermos-electric generator, a magnetic-to-electric converter, and the like). In some embodiments, the MEMS switch may comprise a mechanical latching switch structure. In some such cases, the mechanical latching switch structure may comprise a thermally positioned and latch-able switch cell, an electro-statistically positioned and latch-able switch cell, or a magnetically positioned and latch-able switch cell. FIG. 60 is a flow diagram illustrating a series of event associated with maintaining the state of a MEMS switch during a power outage.

In one embodiment, a MEMS-based circuit breaker may comprise a MEMS switch state restoration circuit configured to record a state of a MEMS switch module (e.g., by writing the state to a non-transitory memory). In some cases, upon detecting a power interruption, the MEMS switch state restoration circuit may record the current state of the MEMS switch and turn the switch OFF if it was ON prior to the interruption. When power to the system is restored, the MEMS switch state restoration circuit may retrieve the stored state from memory and return the MEMS switch to its pre-interruption state. FIG. 61 is a flow diagram illustrating an example process 6100 for recording and restoring the state of a MEMS switch after a power outage. The process 6100 may be performed by a processor of the restoration circuit (e.g., a processor of the MEMS-based circuit breaker). At block 6102 the processor may monitor the state of the MEMS switch based on a sensor signal, e.g., a sensor signal received from a current sensor where the sensor signal indicates the MEMS switch is deactivated (is ON state) or activated (is in OFF state). At block 6104 the processor may store the detected switch state in a non-transitory memory. In some cases, the processor may store the detected switch state at specified time intervals. In some examples, the processor may store the detected switch state periodically or any time there is a change in the state of the system. At block 6106 the processor may detect a power restoration following a power outage e.g., by detecting an interruption. At block 6108 the processor may read the last stored state of the MEMS switch from the non-transitory memory. At block 6110 the processor may safely restore the state of the MEMS switch based on the read state.

### Example Embodiments

Some additional nonlimiting examples of embodiments discussed above are provided below. These should not be read as limiting the breadth of the disclosure in any way.
Clause 1. A switching device for controlling current flow between a modular circuit and a powered main circuit, the switching device comprising: a first terminal to electrically connect to the circuit; a second terminal to electrically connect to a load of the modular circuit; a current sense device and a micro-electro-mechanical systems (MEMS) switch module electrically connected in series to each other and between the first terminal and the second terminal; and a controller communicatively coupled to the current sense device and the MEMS switch module, the controller configured to cause the MEMS switch module to switch current flow therethrough based on a detected level of current flow through the current sense device during insertion or removal of the modular circuit.
Clause 2. The switching device of Clause 1, wherein the controller is further configured to cause the MEMS switch module to regulate current flow therethrough based on one or both of: the detected level of current flow through the current sense device during the insertion or the removal of the modular circuit; and a detected change of current flow through the current sense device during the insertion or the removal of the modular circuit.
Clause 3. The switching device of any one of Clauses 1-2, wherein the controller is configured such that, upon detecting a magnitude of current flow above a predetermined threshold value during the insertion or the removal of the modular circuit, the MEMS switch module forms an open circuit.
Clause 4. The switching device of any one of Clauses 1-3, wherein the MEMS switch module comprises a conductive beam anchored over a substrate, a contact electrode configured to contact a switching end of the conductive beam, and a control electrode configured to electrostatically tilt the conductive beam to contact the switching end thereof with the contact electrode upon receiving an activation voltage.
Clause 5. The switching device of Clause 4, wherein when deactivated, the switching device is configured to regulate a magnitude of the current flow by varying a deactivation voltage on the control electrode.
Clause 6. The switching device of any one of Clauses 1-5, wherein the MEMS switch module comprises a plurality of MEMS switches electrically connected in parallel, and wherein when deactivated, the switching device is configured to regulate a magnitude of the current flow by varying a number of deactivated MEMS switches or by deactivating different ones of the plurality of MEMS switches.
Clause 7. The switching device of any one of Clauses 1-6, wherein the current sense device comprises one or more of a resistor, a Hall sensor and an anisotropic magnetoresistive sensor.
Clause 8. The switching device of any one of Clauses 1-7, wherein the main circuit comprises a plurality of connection interfaces each configured to receive the modular circuit.
Clause 9. The switching device of Clause 8, wherein the modular circuit comprises a circuit card and the main circuit comprises a backplane or a motherboard.
Clause 10. The switching device of any one of Clauses 1-9, further comprising a field-effect transistor electrically connected in parallel to the MEMS switch module.
Clause 11. A system comprising a main circuit configured to electrically couple a plurality of modular circuits inserted into respective coupling slots, the system comprising: a switching device configured to switch current flow between a modular circuit of the plurality of modular circuits and the main circuit in a powered state during insertion or removal of the modular circuit; a power source powering the main circuit in the powered state and further powering the modular circuit when electrically coupled to the main circuit; wherein the switching device comprises: a first terminal to electrically connect to the main circuit, a second terminal to electrically connect to a load of the modular circuit, and a current sense device and a micro-electro-mechanical systems (MEMS) switch module electrically connected in series to each other and between the first terminal and the second terminal, the MEMS switch module configured to switch current flow therethrough based on a detected level of current flow through the current sense device.
Clause 12. The system of Clause 11, wherein the current sense device and the MEMS switch module are communicatively coupled to regulate the current flow between the first and second terminals.
Clause 13. The system Clause 12, wherein the MEMS switch module regulates the current flow based on one or both of: the detected level of current flow through the current sense device during insertion or removal of the modular circuit; and a detected change of current flow through the current sense device during inserting or removing of the modular circuit.
Clause 14. The system of any one of Clauses 11-13, further comprising a transistor switch electrically connected in parallel with the micro-electro-mechanical systems (MEMS) between the first terminal and the second terminal, wherein the current sense device is communicatively coupled to the MEMS switch module and the transistor switch to regulate current flow between the first and second terminals based on one or both of: the detected level of current flow through the current sense device during insertion or removal of the modular circuit; and a detected change of current flow through the current sense device during inserting or removing of the modular circuit.
Clause 15. The system of any one of Clauses 11-14, wherein the switching device further comprises a controller communicatively coupled to the current sense device and the MEMS switch module, the controller configured to cause the MEMS switch module to regulate current flow between the first and second terminals based on the detected level of the current flow through the current sense device during insertion or removal of each of the modular circuits into the respective coupling slots.
Clause 16. The system of Clause 15, wherein the controller is configured such that, upon detecting a current flow above a predetermined threshold value during inserting or removing of the modular circuit, causes the MEMS switch module form an open circuit.
Clause 17. The system of any one of Clauses 11-16, wherein the switching device is integrated as part of the modular circuit.
Clause 18. The system of any one of Clauses 11-17, wherein the MEMS switch module comprises a conductive beam anchored over a substrate, a contact electrode configured to contact a switching end of the conductive beam, and a control electrode configured to electrostatically tilt the conductive beam to contact the switching end thereof with the contact electrode upon receiving a deactivation voltage.
Clause 19. The system of Clause 18, wherein when deactivated, the switching device is configured to regulate a magnitude of the current flow by varying a deactivation voltage provided to the control electrode.
Clause 20. The system of anyone of Clauses 11-19, wherein the MEMS switch module comprises a plurality of MEMS switches electrically connected in parallel, and wherein when deactivated, the switching device is configured to regulate a magnitude of the current flow by varying a number of deactivated MEMS switches.
Clause 21. The system of any one of Clauses 11-20, further comprising a field-effect transistor electrically connected in parallel to the MEMS switch module.
Clause 22. A method of controlling current flow between a modular circuit and a powered main circuit, method comprising: providing power to a system comprising the main circuit and a plurality of coupling slots for electrically coupling the main circuit and a plurality of modular circuits inserted into the coupling slots; inserting a modular circuit into one of the coupling slots or removing a modular circuit from one of the coupling slots; and switching current flow between the main circuit and the modular circuit being inserted into or removed from the one of the coupling slots using a switching device comprising a current sense device and a micro-electro-mechanical systems (MEMS) switch module electrically connected in series to each other.
Clause 23. The method of Clause 22, further comprising using a controller to cause the MEMS switch module to regulate the current flow based on one or both of: a detected level of the current flow through the current sense device; and a detected change of the current flow through the current sense device.
Clause 24. The method of Clause 23, wherein the switching device further comprises a transistor switch and the method further comprises using the controller to cause the transistor switch to regulate the current flow based on one or both of: the detected level of the current flow through the current sense device; and the detected change of the current flow through the current sense device.
Clause 25. The method of any one of Clauses 22-24, further comprising, upon detecting a current flow above a predetermined threshold value during inserting, booting, or removing of the modular circuit, causing the MEMS switch module to form an open circuit.
Clause 26. An apparatus for protection of a high voltage system from electrical overstress (EOS) events, the apparatus comprising: a protection device configured to be electrically connected between a high voltage module and a power supply for delivering power to the high voltage module; the protection device comprising a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from the power supply to the high voltage module.
Clause 27. The apparatus of Clause 26, wherein the MEMS switch module comprises a conductive beam anchored over a substrate, a contact electrode configured to contact a switching end of the conductive beam, and a control electrode to electrostatically modulate a tilt of the conductive beam.
Clause 28. The apparatus of Clause 27, wherein during normal operation of the high voltage module, the MEMS switch module is deactivated such that the contact electrode contacts the switching end of the conductive beam, and upon detecting the EOS event, the controller causes the MEMS switch module to form the open circuit by activating the MEMS switch module to separate the contact electrode from the switching end of the conductive from the contact electrode.
Clause 29. The apparatus of Clause 28, further comprising a field-effect transistor electrically connected in parallel with the MEMS switch module.
Clause 30. The apparatus of Clause 29, wherein the controller is configured to turn on the field-effect transistor (FET) during activation and deactivation of the MEMS switch module.
Clause 31. The apparatus of Clause 29, wherein the power supply is an alternating current (AC) power supply and the apparatus further comprises a second FET in series with the FET, and wherein the FET and the second FET are in a back-to-back arrangement such that body diodes of the FET and the second FET have opposite polarities.
Clause 32. The apparatus of any one of Clauses 26-31, wherein the EOS sense device comprises a current sense device electrically connected in series to the MEMS switch module.
Clause 33. The apparatus of any one of Clauses 26-32, wherein the EOS sense device is configured to detect the EOS event comprising an arcing event.
Clause 34. The apparatus of any one of Clauses 26-33, wherein the high voltage module comprises a plasma processing chamber.
Clause 35. A power supply for a high voltage system with protection from electrical overstress (EOS) events, the power supply comprising: an output voltage generator; a protection device electrically connected to the output voltage generator and configured to further connect to a high voltage module; the protection device comprising a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from the output voltage generator to the high voltage module.
Clause 36. The power supply of Clause 35, wherein the MEMS switch module comprises a conductive beam anchored over a substrate, a contact electrode configured to contact a switching end of the conductive beam, and a control electrode to electrostatically modulate a tilt of the conductive beam.
Clause 37. The power supply of Clause 36, wherein during normal operation of the high voltage module, the MEMS switch module is deactivated such that the contact electrode contacts the switching end of the conductive beam, and upon detecting the EOS event, the controller causes the MEMS switch module to form the open circuit by activating the MEMS switch module to separate the contact electrode from the switching end of the conductive from the contact electrode.
Clause 38. The power supply of Clause 37, further comprising a field-effect transistor electrically connected in parallel with the MEMS switch module.
Clause 39. The power supply of Clause 38, wherein the controller is configured to turn on the field-effect transistor (FET) during activation and deactivation of the MEMS switch module.
Clause 40. The power supply of Clause 38, wherein the power supply is an alternating current (AC) power supply and the power supply further comprises a second FET in series with the FET, and wherein the FET and the second FET are in a back-to-back arrangement such that body diodes of the FET and the second FET have opposite polarities.
Clause 41. The power supply of any one of Clauses 35-40, wherein the EOS sense device comprises a current sense device electrically connected in series to the MEMS switch module.
Clause 42. The power supply of any one of Clauses 35-41, wherein the high voltage module comprises a plasma processing chamber.
Clause 43. A high voltage system with protection from electrical overstress (EOS) events, the high voltage system comprising: a high voltage module; a power supply for delivering power to the high voltage module; a protection device connected between the high voltage module and the power supply; the protection device comprising a micro-electro-mechanical systems (MEMS) switch module; an EOS sense device electrically connected to the high voltage module and configured to detect an EOS event in the high voltage module; and a controller communicatively coupled to the protection device and the EOS sense device and configured such that upon detecting the EOS event in the high voltage module, the controller causes the MEMS switch module to form an open circuit to interrupt power from power supply to the high voltage module.
Clause 44. The high voltage system of Clause 43, wherein the MEMS switch module comprises a conductive beam anchored over a substrate, a contact electrode configured to contact a switching end of the conductive beam, and a control electrode to electrostatically modulate a tilt of the conductive beam.
Clause 45. The high voltage system of Clause 44, wherein during normal operation of the high voltage module, the MEMS switch module is deactivated such that the contact electrode contacts the switching end of the conductive beam, and upon detecting the EOS event, the controller causes the MEMS switch module to form the open circuit by activating the MEMS switch module to separate the contact electrode from the switching end of the conductive from the contact electrode.
Clause 46. The high voltage system of any one of Clauses 43-45, wherein the high voltage system comprises a semiconductor processing system.
Clause 47. The high voltage system of any one of Clauses 43-46, further comprising a shunt device electrically connected to the high voltage module and configured to conduct current caused by the EOS event.
Clause 48. The high voltage system of Clause 47, wherein the shunt device comprises a spark gap.
Clause 49. The high voltage system of any one of Clauses 43-48, wherein the high voltage module comprises a plasma processing chamber.
Clause 50. A micro-electromechanical systems (MEMS) switch system configured with self-testing capability, the MEMS switch system comprising: a first and second MEMS switch modules electrically connected in parallel between two terminals; a current sensor electrically connected in series with the first MEMS switch module and configured to generate a sensor signal; and a control logic communicatively coupled to the first and second MEMS switch modules and the current sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.
Clause 51. A micro-electromechanical systems (MEMS) switch system configured with self-testing capability, the MEMS switch system comprising: a first and second MEMS switch modules electrically connected in parallel between two terminals; a temperature sensor in thermal communication with one or both of the first and second MEMS switch modules and configured to generate a sensor signal; a control logic communicatively coupled to the first and second MEMS switch modules and the temperature sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.
Clause 52. A micro-electromechanical systems (MEMS) switch system configured with self-testing capability, the MEMS switch system comprising: a first and second MEMS switch modules electrically connected in parallel between two terminals; a voltage sensor connected between the two terminals and configured to generate a sensor signal; a control logic communicatively coupled to the first and second MEMS switch modules and the voltage sensor, the control logic configured to: sequentially transmit an activation signal and a deactivation signal to the first MEMS switch module while the second MEMS switch module is in a deactivated state, and receive changes in the sensor signal caused by one or both of the activation signal and the deactivation signal and determine therefrom a functionality of the first MEMS switch module.
Clause 53. The MEMS switch system of any one of Clauses 50-52, wherein determining the functionality of the first MEMS switch comprises determining that the first MEMS switch performs one or more of: activating to electrically establish an electrical short between the two terminals; deactivating to establish an electrical connection between two terminals with a resistance lower than a threshold resistance; activating with a delay less than a threshold time value with respect to receiving the activation signal; and deactivating with a delay less than a threshold time value with respect to receiving the deactivation signal.
Clause 54. The MEMS switch system of any one of Clauses 50-53, wherein the control logic is further configured to control the first and second MEMS switch modules to maintain an electrical connection between the two terminals during the self-testing and during normal operation of an electric system connected to the two terminals.
Clause 55. The MEMS switch system of any one of Clauses 50-54, wherein the first MEMS switch module comprises a first conductive beam anchored over a substrate, a first contact electrode configured to contact a first switching end of the first conductive beam, and a first control electrode to electrostatically modulate a tilt of the first conductive beam.
Clause 56. The MEMS switch system of Clause 55, wherein during normal operation of the electric system, at least the first MEMS switch module is deactivated such that the first contact electrode contacts the first switching end of the first conductive beam to electrically connect the two terminals and upon detecting an electrical overstress (EOS) event, the first MEMS switch module is activated to electrically disconnect the two terminals by separating the first contact electrode from the first switching end of the first conductive beam.
Clause 57. The MEMS switch system of Clause 56, wherein the second MEMS switch module comprises a second conductive beam anchored over the substrate, a second contact electrode configured to contact a second switching end of the second conductive beam, and a second control electrode to electrostatically modulate a tilt of the second conductive beam.
Clause 58. The MEMS switch system of Clause 57, wherein during the normal operation of the electric system, the second MEMS switch module is deactivated such that the second contact electrode contacts the second switching end of the second conductive beam to electrically connect the two terminals and upon the MEMS switch system detecting an EOS event, at least the second MEMS switch module is activated to electrically disconnect the two terminals by separating the second contact electrode from the second switching end of the second conductive beam from the second contact electrode.
Clause 59. The MEMS switch system of any of Clauses 56 to 58, further comprising an EOS sense device configured for detecting the EOS event.
Clause 60. The MEMS switch system of Clause 54, wherein, during the normal operation of the electric system, the control logic is configured to activate the second MEMS switch module when the first MEMS switch module is deactivated.
Clause 61. The MEMS switch system of Clause 50, further comprising a second current sensor serially connected to the second MEMS switch module and configured to generate a second sensor signal.
Clause 62. The MEMS switch system of Clause 52, wherein the voltage sensor is connected in parallel with the first and second MEMS switch modules between the two terminals.
Clause 63. The MEMS switch system of Clause 52, wherein the voltage sensor is electrically connected to the control logic to measure one or both of a deactivation voltage associated with the deactivation signal and an activation voltage signal associated with the activation signal.
Clause 64. The MEMS switch system of Clause 63, wherein the system further comprises prognosis logic configured to receive one or both of the deactivation voltage and the activation voltage and to detect a change in at least one of the deactivation voltage or the activation voltage.
Clause 65. The MEMS switch system of Clause 51, wherein the temperature sensor indicates a temperature of a substrate on which the first and second MEMS switch modules are formed.
Clause 66. The MEMS switch system of any one of Clauses 50-65, wherein upon determining that the first MEMS switch module remains closed after receiving the activation signal, the control logic generates an alert signal indicating that the first MEMS switch module is malfunctioning.
Clause 67. The MEMS switch system of Clause 54, wherein the control logic is configured to electrically connect the two terminals by deactivating both first and second MEMS switch modules during normal operation of the electric system.
Clause 68. A micro-electromechanical systems (MEMS) switch system configured with self-testing capability, the MEMS switch system comprising: first and second MEMS switch modules electrically connected in series between two terminals, wherein each of the first and second MEMS switch modules is disposed between a pair of nodes; a current source configured to inject current into one or both of the nodes; a voltage sensing module configured to sense a voltage across the pair of nodes; and a control logic configured to: transmit a deactivation signal to the first MEMS switch module in an activated state while the second MEMS switch module remains in an activated state, inject current into a first pair of nodes having the first MEMS switch module disposed therebetween, flow the current through the first MEMS switch module and collect the current from the other of the first pair of nodes, detect a change in voltage across the first pair of nodes caused by the current, and determine a functionality of the first MEMS switch module from the change in voltage.
Clause 69. The MEMS switch system of Clause 68, wherein the control logic is further configured to control the first and second MEMS switch modules to maintain an electrical open circuit between the two terminals during the self-testing and during normal operation of an electric system connected to the two terminals.
Clause 70. The MEMS switch system of any one of Clauses 68-69, wherein the first MEMS switch module comprises a first conductive beam anchored over a substrate, a first contact electrode configured to contact a first switching end of the first conductive beam, and a first control electrode to electrostatically modulate a tilt of the first conductive beam.
Clause 71. A micro-electromechanical systems (MEMS) switch system configured with switch self-evaluation, the MEMS switch system comprising: a control and monitoring circuit; a MEMS switch electrically connected between two terminals and configured to serve as a circuit breaker providing a controlled electrical connection between the two terminals controlled by the control and monitoring circuit; and a physically unclonable function (PUF) circuit physically coupled to the MEMS switch and configured to repeatably generate a signal unique to the PUF circuit, in conjunction with operation of the MEMS switch, until a threshold condition causes the PUF circuit to be physically altered such that the PUF circuit no longer generates a same signal unique to the PUF circuit, wherein the control and monitoring circuit is configured to transmit switch monitoring data associated with the operation of the MEMS switch and a corresponding unique signal to an authentication circuit for authentication of the switch monitoring data using the corresponding unique signal.
Clause 72. The MEMS switch system of Clause 71, wherein the switch monitoring data indicates activation or deactivation of the MEMS switch.
Clause 73. The MEMS switch system of any one of Clauses 71-72, wherein the PUF circuit comprises a semiconductor device and a uniqueness of the signal is associated with a uniqueness of a physical parameter of the semiconductor device caused by manufacturing variability of a process used to fabricate the semiconductor device.
Clause 74. The MEMS switch system of Clause 73, wherein the threshold condition sufficient to cause the PUF circuit to be physically altered is associated with reliability degradation of the MEMS switch.
Clause 75. The MEMS switch system of Clause 74, wherein the threshold condition comprises an environmental threshold condition.
Clause 76. The MEMS switch system of Clause 75, wherein the threshold condition comprises one or more occurrences of a temperature condition, a current condition and an electric field condition associated with the MEMS switch.
Clause 77. The MEMS switch system of Clause 76, wherein the PUF circuit is electrically coupled to the MEMS switch.
Clause 78. The MEMS switch system of Clause 77, wherein the threshold condition is associated with current flow through the MEMS switch.
Clause 79. The MEMS switch system of Clause 78, wherein the threshold condition is associated with an electrical overstress (EOS) event.
Clause 80. The MEMS switch system of any one of Clauses 71-79, wherein the authentication circuit is configured to authenticate the switch monitoring data in response to receiving the corresponding unique signal that is the signal unique to the PUF circuit.
Clause 81. The MEMS switch system of Clause 80, wherein the authentication circuit is configured to report the switch monitoring data in conjunction with authenticating the switch monitoring data.
Clause 82. The MEMS switch system of Clause 80, wherein the authentication circuit is configured to authenticate the switch monitoring data by generating a cryptographic key based on the corresponding unique signal that is the signal unique to the PUF circuit and generating a digital signal using the cryptographic key.
Clause 83. The MEMS switch system of clause 82, wherein the authentication circuit generates the cryptographic key using a fuzzy extractor comprising an error correcting code.
Clause 84. A micro-electromechanical systems (MEMS) switch system with environment monitoring capability, the MEMS switch system comprising: a first MEMS switch module electrically connected between two terminals; a control and monitoring circuit configured to control switching of the first MEMS switch module and to generate switch monitoring data associated with operation of the first MEMS switch module; and a physically unclonable function (PUF) circuit adjacently disposed to the first MEMS switch module and configured to repeatably generate a signal unique to the PUF circuit until a threshold environmental condition causes the PUF circuit to be physically altered such that the PUF circuit no longer generates a same signal unique to the PUF circuit, wherein the control and monitoring circuit is configured to transmit the switch monitoring data and a corresponding unique signal to an authentication circuit for authentication of the switch monitoring data using the corresponding unique signal.
Clause 85. The MEMS switch system of Clause 84, wherein the PUF circuit and the MEMS switch module are disposed on a common substrate.
Clause 86. The MEMS switch system of any one of Clauses 84-85, wherein the PUF circuit and the MEMS switch module are configured to be exposed to substantially common environmental conditions.
Clause 87. The MEMS switch system of any one of Clauses 84-86, wherein the PUF circuit is electrically connected to at least one of the two terminals.
Clause 88. The MEMS switch system of any one of Clauses 84-87, wherein the PUF circuit is physically coupled to the MEMS switch module.
Clause 89. The MEMS switch system of any one of Clauses 84-88, wherein the PUF circuit is electrically connected to the MEMS switch module.
Clause 90. The MEMS switch system of any one of Clauses 84-89, further comprising a second MEMS switch module electrically connected in parallel with the first MEMS switch module between the two terminals, wherein the control and monitoring circuit comprises: a sensor electrically connected to the first MEMS switch module and configured to generate a sensor signal; a control logic communicatively coupled to the first and second MEMS switch modules and the sensor, the control logic configured to: sequentially transmit an activation signal and a deactivation signal to the first MEMS switch module while the second MEMS switch module is in a deactivated state, and receive changes in the sensor signal caused by the activation signal and generate the switch monitoring data based at least in part on the received changes in the sensor signal.
Clause 91. The MEMS switch system of Clause 90, wherein the sensor comprises a current sensor connected in series with the first MEMS switch module.
Clause 92. The MEMS switch system of any one of Clauses 90-91, wherein the sensor comprises a voltage sensor connected in parallel with the first and second MEMS switch modules between the two terminals.
Clause 93. The MEMS switch system of any one of Clauses 84-92, wherein the first MEMS switch module comprises a first conductive beam anchored over a substrate, a first contact electrode configured to contact a first switching end of the first conductive beam, and a first control electrode to electrostatically modulate a tilt of the first conductive beam.
Clause 94. The MEMS switch system of clause 93, wherein during normal operation, at least the first MEMS switch module is deactivated such that the first contact electrode contacts the first switching end of the first conductive beam to electrically connect the two terminals and, upon detecting an electrical overstress (EOS) event, at least the first MEMS switch module is activated to electrically disconnect the two terminals by separating the first contact electrode from the first switching end of the first conductive beam.
Clause 95. The MEMS switch system of any one of Clauses 84-94, wherein the MEMS switch system comprises a plurality of PUF circuits each configured to generate a respective signal unique to each of the PUF circuits.
Clause 96. The MEMS switch system of any one of Clauses 84-95, wherein the PUF circuit comprises two or more ring oscillators, SRAM cells, or arbiter circuits.
Clause 97. The MEMS switch system of any one of Clauses 84-96, wherein the same signal is an unaltered PUF signal in the absence of the environmental condition that causes the PUF circuit to be physically altered.
Clause 98. The MEMS switch system of any one of Clauses 84-97, wherein the authentication circuit is configured to: receive the corresponding unique signal and the switch monitoring data from the control and monitoring circuit; authenticate the corresponding unique signal; in conjunction with authenticating the corresponding unique signal, authenticate the switch monitoring data; and process the authenticated switch monitoring data to evaluate a performance of the first MEMS switch module.
Clause 99. The MEMS switch system of Clause 98, wherein the authentication circuit is configured to evaluate the performance of the first MEMS switch module by updating a model based on the switch monitoring data.
Clause 100. The MEMS switch system of any one of Clauses 98-99, wherein authenticating the PUF signal comprises determining that the corresponding unique signal is identical to the same signal unique to the PUF circuit.
Clause 101. The MEMS switch system of any one of Clauses 98-99, wherein in response to determining that the corresponding unique signal is different from the same signal unique to the PUF circuit, the authentication circuit is configured discard the switch monitoring data.
Clause 102. The MEMS switch system of Clause 98, wherein the authentication circuit is configured to authenticate the switch monitoring data by generating a cryptographic key using the corresponding unique signal and use the cryptographic key to generate a digital signature.
Clause 103. The MEMS switch system of Clause 102, wherein the authentication circuit generates the cryptographic key using a fuzzy extractor comprising an error correcting code.
Clause 104. The MEMS switch system of any one of Clauses 84-103, wherein the control and monitoring circuit comprises a sensor configured to generate a sensor signal indicative of an operational or environmental condition of the first MEMS switch module.
Clause 105. The MEMS switch system of Clause 104, wherein the sensor comprises a temperature sensor indicative of a temperature of a substrate on which the first MEMS switch module is formed.
Clause 106. The MEMS switch system of Clause 104, wherein the sensor comprises a current sensor connected in series with the first MEMS switch module.
Clause 107. The MEMS switch system of Clause 104 or Clause 106, wherein the sensor comprises a voltage sensor connected in parallel with the first MEMS switch module between the two terminals.
Clause 108. A micro-electromechanical systems (MEMS) switch system comprising: a MEMS switch module configured to control an electrical connection between two voltage nodes; and a digital twin model comprising a digital representation of a physical state of the MEMS switch module, wherein the MEMS switch module and the digital twin model are communicatively coupled to each other and the digital twin model is configured to receive diagnostic data associated with the physical state of the MEMS switch module for determining a characteristic of the MEMS switch module.
Clause 109. The MEMS switch system of Clause 108, further comprising a monitoring system, the monitoring system comprising: a memory storing the digital twin model; and a processing system configured to receive the diagnostic data from the monitoring system and to update the digital twin model based on the received diagnostic data.
Clause 110. The MEMS switch system of Clause 109, wherein the monitoring system is configured to remotely communicate with the MEMS switch module.
Clause 111. The MEMS switch system of Clause 109, wherein the diagnostic data comprises a measured or extracted value of an intrinsic parameter of the MEMS switch module, wherein the intrinsic parameter is measurable from the MEMS switch module.
Clause 112. The MEMS switch system of Clause 111, wherein the intrinsic parameter comprises one or both of a switching voltage and an ON resistance of the MEMS switch module in a deactivated state.
Clause 113. The MEMS switch system of Clause 112, wherein determining the characteristic comprises determining variations in the intrinsic parameter.
Clause 114. The MEMS switch system of Clause 112, wherein the diagnostic data comprises a measured or extracted value of an extrinsic parameter associated with the MEMS switch module, wherein the extrinsic parameter is externally measurable outside of the MEMS switch module.
Clause 115. The MEMS switch system of Clause 114, wherein the extrinsic parameter comprises one or more of an environmental temperature, a die temperature, a voltage applied to the MEMS switch module, a current applied to the MEMS switch module, a mechanical acceleration of the MEMS switch module, and a number of switching signals sent to the MEMS switch module.
Clause 116. The MEMS switch system of Clause 109, wherein the monitoring system comprises a sensor used to generate the diagnostic data.
Clause 117. The MEMS switch system of Clause 115, wherein the MEMS switch module comprises a conductive beam anchored over a substrate, a contact electrode configured to contact a switching end of the conductive beam, and a control electrode to electrostatically modulate a tilt of the conductive beam to deactivate or activate the MEMS switch module.
Clause 118. The MEMS switch system Clause 117, wherein the switching voltage comprises a threshold voltage provided to the control electrode to tilt the conductive beam to establish an electrical connection between the switching end and the contact electrode and the ON resistance comprises a resistance of the electrical connection.
Clause 119. The MEMS switch system Clause 117, wherein: the die temperature comprises a temperature of the substrate, the voltage applied to the MEMS switch module comprises an electric potential applied between the switching end and the contact electrode prior to deactivating the MEMS switch module, and the current applied to the MEMS switch module comprises an electrical current transmitted between conductive beam and the contact electrode after deactivating the MEMS switch module.
Clause 120. The MEMS switch system of Clause 114, wherein the digital twin model comprises a parametric digital model of the MEMS switch module.
Clause 121. The MEMS switch system of Clause 120, wherein the digital twin model comprises one or more device parameters configured to be adjusted or updated to replicate a characteristic or variation of the characteristic of the MEMS switch module.
Clause 122. The MEMS switch system of Clause 121, wherein the processing system is configured to update the digital twin model by adjusting the one or more device parameter of the digital twin model based on the diagnostic data.
Clause 123. The MEMS switch system of Clause 121, wherein the processing system is configured to use the updated digital twin model to estimate a value or variation of the intrinsic parameter of the MEMS switch module at a future time.
Clause 124. The MEMS switch system of Clause 123, wherein the processing system is configured to initiate an action based at least in part on the estimated value or variation of the intrinsic parameter.
Clause 125. The MEMS switch system of Clause 124, wherein the processing system is further configured to initiate an action based at least in part on the estimated value or variation of the extrinsic parameter.
Clause 126. The MEMS switch system of Clause 124, wherein the action comprises one or more of: generating a message; automatically scheduling a maintenance; adjusting an operational parameter of the MEMS switch module; and adjusting a control parameter of the MEMS switch module.
Clause 127. The MEMS switch system of Clause 126, wherein the processing system is configured to compare the estimated value or variation of the intrinsic parameter with a specified value or variation stored in the memory and to initiate the action based at least in part on an outcome of the comparison.
Clause 128. The MEMS switch system of Clause 127, wherein the specified value comprises a reference value received from a user interface or from a computing system.
Clause 129. The MEMS switch system of Clause 128, wherein the computing system comprises a cloud server.
Clause 130. The MEMS switch system of Clause 127, wherein the processing system is configured to adjust one or both of the operational parameter and the control parameter by generating a control signal based at least in part on the outcome of the comparison.
Clause 131. The MEMS switch system of Clause 126, wherein the message comprises recommendation for maintaining, repairing, or replacing the MEMS switch module.
Clause 132. The MEMS switch system of Clause 127, wherein the message comprises an alert message comprising a failure time estimated based on the outcome of the comparison.
Clause 133. The MEMS switch system of Clause 127, wherein automatically scheduling a maintenance comprises: determining a type and a time of failure based at least in part on the outcome of the comparison; connecting to a scheduling system to receive a schedule; selecting a maintenance based at least on the determined type of failure; and scheduling the maintenance based on the selected maintenance and the determined time of failure.
Clause 134. A micro-electromechanical systems (MEMS) switch system configured with self-prognosis capability, the MEMS switch system comprising: a MEMS switch module electrically connected between two terminals; a diagnostic circuit communicatively coupled to the MEMS switch module, the diagnostic circuit configured to generate a diagnostic signal indicative of a state of health of the MEMS switch module; and a processing module configured to determine the state of health of the MEMS switch module based at least in part on the diagnostic signal.
Clause 135. The MEMS switch system of Clause 134, wherein the MEMS switch system is part of a system comprising a plurality of system modules, and wherein the processing module is further configured to determine a state of health of one or more of the system modules.
Clause 136. The MEMS switch system of Clause 135, wherein the MEMS switch module is configured to protect one or more of one or more of the system modules.
Clause 137. The MEMS switch system of Clause 134, wherein the diagnostic signal comprises an intrinsic parameter of the MEMS switch module, wherein the intrinsic parameter is measurable from the MEMS switch module.
Clause 138. The MEMS switch system of Clause 137, wherein the intrinsic parameter comprises one or both of a switching voltage and an ON resistance of the MEMS switch module in a deactivated state.
Clause 139. The MEMS switch system of any one of Clauses 134-138, wherein the diagnostic signal comprises an extrinsic parameter influencing an operation of the MEMS switch module, wherein the extrinsic parameter is externally measurable outside of the MEMS switch module.
Clause 140. The MEMS switch system of Clause 139, wherein the extrinsic parameter comprises one or more of an environmental temperature, a die temperature, a voltage across the two terminals, a current transmitted through the MEMS switch, an acceleration of the MEMS switch module, and a cumulative number of switching actions performed by the MEMS switch module.
Clause 141. The MEMS switch system of any one of Clauses 134-140, wherein the state of health comprises an indication of one or both present and future functional health of the MEMS switch module.
Clause 142. The MEMS switch system of any one of Clauses 134-141, wherein the processing module further comprises a prognosis module configured to determine a future performance of the MEMS switch module based at least in part on a present performance of the MEMS switch module.
Clause 143. The MEMS switch system of any one of Clauses 134-142, wherein the processing module comprises a non-transitory computer readable medium storing machine-readable instructions and a processor configured to execute the stored machine-readable instructions to provide a predictive model to determine one or both present and future functional health of the MEMS switch module.
Clause 144. The MEMS switch system of Clause 143, wherein the predictive model comprises a digital twin model of the MEMS switch module, and wherein the digital twin model is updated based at least in part on the diagnostic signal.
Clause 145. The MEMS switch system of Clause 142, wherein the processing module comprises a diagnosis module configured to determine the present performance of the MEMS switch module based at least in part based on a value of the intrinsic parameter.
Clause 146. The MEMS switch system of Clause 145, wherein the diagnostic circuit comprises a sensor coupled to the MEMS switch module and is configured to: generate the diagnostic signal comprising a sensor signal comprising the value of an intrinsic parameter; or determine the value of the intrinsic parameter using the sensor signal.
Clause 147. The MEMS switch system of Clause 146, wherein the sensor comprises a current sensor or a voltage sensor.
Clause 148. The MEMS switch system of any one of clauses 143-147, wherein the processor is further configured to execute the stored machine-readable instructions to provide a second predictive model to determine future or present functional health of one or more of the system modules.
Clause 149. The MEMS switch system of Clause 148, wherein the predictive model comprises a digital twin model of the one or more of the system modules, and wherein the digital twin model is updated based at least in part on additional diagnostic data indicative of the state of health of the one or more system modules.
Clause 150. The MEMS switch system of any one of Clauses 139-149, wherein the processing module further comprises a mission profiling module configured to determine a mission profile of the MEMS switch module based at least in part on the extrinsic parameter.
Clause 151. The MEMS switch system of Clause 150, wherein the processing module comprises a non-transitory computer readable medium storing machine-readable instructions and a processor configured to execute the stored machine-readable instructions to store the extrinsic parameter in the non-transitory computer readable medium and provide a mission profile model configured to determine the mission profile of the MEMS switch module based at least in part on the stored extrinsic parameter.
Clause 152. The MEMS switch system of Clause 150, further comprising a sensor configured to generate a sensor signal indicative of a value of the extrinsic parameter.
Clause 153. The MEMS switch system of Clause 152, wherein the sensor comprises a temperature sensor, a humidity sensor, or an accelerometer.
Clause 154. The MEMS switch system of Clause 146, further comprising a second MEMS switch module connected in parallel with MEMS switch module and in communication with the diagnostic circuit, wherein the diagnostic circuit is configured to determine the intrinsic parameter of the MEMS switch module while maintaining an electrical connection between the two terminals using the second MEMS switch module.
Clause 155. The MEMS switch system of Clause 154, wherein the diagnostic circuit is configured to: transmit an activation signal to the MEMS switch module while the second MEMS switch module is in a deactivated state; receive changes in the sensor signal caused by the activation signal; and determine from the changes in the sensor signal the intrinsic parameter of the MEMS switch module.
Clause 156. The MEMS switch system of any one of Clauses 154-155, wherein the MEMS switch module comprises a first conductive beam anchored over a substrate, a first contact electrode configured to contact a first switching end of the first conductive beam, and a first control electrode to electrostatically modulate a tilt of the first conductive beam.
Clause 157. The MEMS switch system of Clause 156, wherein during normal operation of the electric system, at least the MEMS switch module is deactivated such that the first contact electrode contacts the first switching end of the first conductive beam to electrically connect the two terminals and upon detecting an electrical overstress (EOS) event, the MEMS switch module is activated to electrically disconnect the two terminals by separating the first contact electrode from the first switching end of the first conductive beam.
Clause 158. The MEMS switch system of Clause 156, wherein the second MEMS switch module comprises a second conductive beam anchored over the substrate, a second contact electrode configured to contact a second switching end of the second conductive beam, and a second control electrode to electrostatically modulate a tilt of the second conductive beam.
Clause 159. The MEMS switch system of Clause 158, wherein during normal operation of the electric system, the second MEMS switch module is deactivated such that the second contact electrode contacts the second switching end of the second conductive beam to electrically connect the two terminals and upon the MEMS switch system detecting an EOS event, at least the second MEMS switch module is activated to electrically disconnect the two terminals by separating the second contact electrode from the second switching end of the second conductive beam from the second contact electrode.
Clause 160. The MEMS switch system of Clause 159, further comprising an EOS sense device configured for detecting the EOS event.
Clause 161. The MEMS switch system of any one of Clauses 134-160, wherein monitoring and control system, and the MEMS switch module connected to a common board.
Clause 162. The MEMS switch system of any one of Clauses 134-160, wherein the processing module is integrated with the diagnostic circuit.
Clause 163. The MEMS switch system of any one of Clauses 134-160, wherein diagnostic circuit is separated from the processing module.
Clause 164. The MEMS switch system of Clauses 163, wherein diagnostic circuit is in communication with the processing module by a wired or wireless link through which the diagnostic signal is transmitted from the diagnostic circuit is in communication with the processing module.
Clause 165. The MEMS switch system of Clauses 164, wherein the diagnostic signal comprises diagnostic data and the diagnostic circuit is configured to encrypt the diagnostic data prior to transmission to the processing module.
Clause 166. The MEMS switch system of any one of Clauses 139-160, wherein the processing module is further configured to generate a control signal based at least in part on one or both the determined present and future functional health of the MEMS switch module to mitigate a potential malfunction of the MEMS switch module.
Clause 167. The MEMS switch system of any one of Clauses 141-160, wherein the processing module is further configured to generate a message based at least in part on one or both the determined present and the future functional health of the MEMS switch module and transmit the message to an output interface of the processing module.
Clause 168. The MEMS switch system of Clause 154, wherein the diagnostic circuit is communicatively coupled to a current sensor electrically connected in series with the MEMS switch module and configured to generate a sensor signal and the processing module is configured to perform a self-test procedure by: sequentially transmitting an activation signal and a deactivation signal to the MEMS switch module while the second MEMS switch module is in a deactivated state, and receiving changes in the sensor signal caused by one or both the activation signal and the deactivation signal and determine therefrom a functionality of the MEMS switch module.
Clause 169. The MEMS switch system of Clause 154, wherein the diagnostic circuit is communicatively coupled to a temperature sensor in thermal communication with one or both of the MEMS switch module and the second MEMS switch module and configured to generate a sensor signal, and the processing module is configured to perform a self-test procedure by: sequentially transmitting an activation signal fand a deactivation signal to the MEMS switch module while the second MEMS switch module is in a deactivated state, and receiving changes in the sensor signal caused by one or both the activation signal and the deactivation signal and determine therefrom a functionality of the MEMS switch module.
Clause 170. The MEMS switch system of Clause 154, wherein the diagnostic circuit is communicatively coupled to a voltage sensor connected between the two terminals and configured to generate a sensor signal, and the processing module is configured to perform a self-test procedure by: sequentially transmitting an activation signal and a deactivation signal to the MEMS switch module while the second MEMS switch module is in a deactivated state, and receiving changes in the sensor signal caused by one or both the activation signal and the deactivation signal and determine therefrom a functionality of the MEMS switch module.
Clause 171. A system configured with self-prognosis capability, the system comprising: a plurality of system modules including the MEMS switch system of any one of Clauses 134-170; a system diagnostic circuit communicatively coupled to the system modules and configured to generate a system diagnostic signal indicative of a state of health of the system; and a system processing module configured to determine the state of health of the system based at least in part on the system diagnostic signal, wherein the MEMS switch system is configured to control a connection to one or more system modules of the plurality of system modules upon receiving a fault signal indicative of the state of health being below a predetermined threshold.
Clause 172. The system of Clause 171, wherein the system diagnostic circuit includes the diagnostic circuit.
Clause 173. The system of Clause 171, wherein the system processing module includes the processing module.
Clause 174. A system configured with self-prognosis capability, the system comprising: a plurality of system modules; a system diagnostic circuit communicatively coupled to the plurality of system modules and configured to generate a system diagnostic signal indicative of a state of health of the system; a system processing module configured to determine the state of health of the system based at least in part on the system diagnostic signal; and a micro-electromechanical systems (MEMS) switch module configured to control a connection to one or more of the system modules of the plurality of system modules, upon receiving a fault signal indicative of the state of health being below a predetermined threshold.
Clause 175. The system of Clause 174, further comprising the MEMS switch system of any one of Clauses 134-170, and wherein the MEMS switch module of Clause 41 is according to the MEMS switch module of any one of Clauses 134-170.
Clause 176. The system of Clauses 174, wherein the system processing module is configured to generate a predictive model to determine a future or present functionality of one or more system modules of the plurality of system modules.
Clause 177. The system of Clause 176, wherein the predictive model comprises a digital twin model of one or more system modules of the plurality of system modules, and wherein the digital twin model is updated based at least in part on the system diagnostic signal.
Clause 178. A micro-electromechanical systems (MEMS) switch system configured with self-prognosis capability, the MEMS switch system comprising: a MEMS switch module configured to control an electrical connection between two voltage nodes of a system; and a monitoring system configured to generate diagnostic data indicative of a physical state of the MEMS switch module; and a processing system configured to receive the diagnostic data from the monitoring system and use a digital twin model to determine one or both of a characteristic and a state of health of the MEMS switch module based on the received diagnostic data, wherein the digital twin model comprises a digital representation of at least the MEMS switch module.
Clause 179. The MEMS switch system of Clause 178, wherein the processing system is configured to update the digital twin model based on the received diagnostic data.
Clause 180. The MEMS switch system of Clause 179, wherein the monitoring system is configured to remotely communicate with the MEMS switch module.
Clause 181. The MEMS switch system of Clause 179, wherein the diagnostic data comprises a measured or extracted value of an intrinsic parameter of the MEMS switch module.
Clause 182. The MEMS switch system of Clause 181, wherein the intrinsic parameter comprises one or both of a switching voltage and a resistance in a deactivated state of the MEMS switch module.
Clause 183. The MEMS switch system of Clause 182, wherein determining the characteristic comprises determining variations in the intrinsic parameter.
Clause 184. The MEMS switch system of Clause 182, wherein the diagnostic data comprises a measured or extracted value of an extrinsic parameter associated with the MEMS switch module.
Clause 185. The MEMS switch system of Clause 184, wherein the extrinsic parameter comprises one or more of an environmental temperature, a die temperature, a voltage switched by the MEMS switch module, a current transmitted through the MEMS switch module, an acceleration of the MEMS switch module, and a number of switching actions.
Clause 186. The MEMS switch system of Clause 179, wherein the monitoring system comprises a sensor used to generate the diagnostic data.
Clause 187. The MEMS switch system of Clause 185, wherein the MEMS switch module comprises a conductive beam anchored over a substrate, a contact electrode configured to contact a switching end of the conductive beam, and a control electrode to electrostatically modulate a tilt of the conductive beam to deactivate or activate the MEMS switch module.
Clause 188. The MEMS switch system Clause 187, wherein the switching voltage comprises a threshold voltage provided to the control electrode to tilt the conductive beam to establish an electric connection between the switching end and the contact electrode and the ON resistance comprises a resistance of the electric connection.
Clause 189. The MEMS switch system Clause 187, wherein: the die temperature comprises temperature of the substrate, the voltage comprises an electric potential difference between the switching end and the contact electrode prior to deactivating the MEMS switch module, and the current comprises an electric current transmitted between conductive beam and the contact electrode after deactivating the MEMS switch module.
Clause 190. The MEMS switch system of Clause 184, wherein the digital twin model comprises a parametric digital model of the MEMS switch module.
Clause 191. The MEMS switch system of Clause 190, wherein the digital twin model comprises one or more device parameters configured to be adjusted or updated to replicate a characteristic or variation of the characteristic of the MEMS switch module.
Clause 192. The MEMS switch system of Clause 191, wherein the processing system is configured to update the digital twin model by adjusting the one or more device parameters of the digital twin model based on the diagnostic data.
Clause 193. The MEMS switch system of Clause 191, wherein the processing system is configured to use the updated digital twin model to estimate a value or variation of the intrinsic parameter of the MEMS switch module at a future time or during a period ending at the future time.
Clause 194. The MEMS switch system of Clause 193, wherein the processing system is configured to initiate an action based at least in part on the estimated value or variation of the intrinsic parameter.
Clause 195. The MEMS switch system of Clause 194, wherein the processing system is further configured to initiate an action based at least in part on the estimated value or variation of the extrinsic parameter.
Clause 196. The MEMS switch system of Clause 194, wherein the action comprises one or more of: generating a message; automatically scheduling a maintenance; adjusting an operational parameter of the MEMS switch module; and adjusting a control parameter of the MEMS switch module.
Clause 197. The MEMS switch system of Clause 196, wherein the processing system is configured to compare the estimated value or variation of the intrinsic parameter with a specified value or variation stored in a non-transitory memory of the processing module and to initiate the action based at least in part on an outcome of the comparison.
Clause 198. The MEMS switch system of Clause 197, wherein the specified value comprises a reference value received from a user interface or from a computing system.
Clause 199. The MEMS switch system of Clause 198, wherein the computing system comprises a cloud server.
Clause 200. The MEMS switch system of Clause 197, wherein the processing system is configured to adjust one or both the operational parameter and the control parameter by generating a control signal based at least in part on the outcome of the comparison.
Clause 201. The MEMS switch system of Clause 196, wherein the message comprises recommendation for maintaining, repairing, or replacing the MEMS switch module.
Clause 202. The MEMS switch system of Clause 197, wherein the message comprises an alert message comprising a failure time estimated based on the outcome of the comparison.
Clause 203. The MEMS switch system of Clause 197, wherein automatically scheduling a maintenance comprises: determining a type and a time of failure based at least in part on the outcome of the comparison, connecting to a scheduling system to receive a schedule, selecting a maintenance based at least on the determined type of failure, and scheduling the maintenance based on the selected maintenance and the determined time of failure.
Clause 204. The MEMS switch system of Clause 179, wherein the digital twin model further comprises a digital representation of a physical state of at least one system module of the system.
Clause 205. The MEMS switch system of Clause 204, wherein the at least one system module and the digital twin model are communicatively coupled to each other.
Clause 206. The MEMS switch system of Clause 204, wherein the digital twin model is communicatively coupled to processing system configured to control and monitor the at least one system module.
Clause 207. The MEMS switch system of any one of Clauses 204-206, wherein the digital twin model is configured to receive system diagnostic data associated with the physical state of the system module for determining one or both present and future state of health of the at least one system module.
Clause 208. The MEMS switch system of Clause 207, wherein the digital twin model is configured to receive the system diagnostic data from the processing system.
Clause 209. The MEMS switch system of any one of Clauses 207-208, wherein the processing system is further configured to update the digital twin model based on the system diagnostic data.
Clause 210. The MEMS switch system of any one of Clauses 207-209, wherein the system diagnostic data comprises a measured or extracted value of an intrinsic parameter of the at least one system module.
Clause 211. The MEMS switch system of any one of Clauses 207-209, wherein the system diagnostic data comprises a measured or extracted value of an extrinsic parameter associated with the at least one system module.
Clause 212. The MEMS switch system of Clauses 210, wherein determining the one or both the present and future state of health of the at least one system module comprises determining a value of the intrinsic parameter.
Clause 213. The MEMS switch system of Clauses 211, wherein determining the one or both the present and future state of health of the system module comprises determining variation in the extrinsic parameter.
Clause 214. A system configured with self-prognosis capability, the system comprising: a plurality of system modules including the MEMS switch system of any one of Clauses 178-213; wherein the processing module further comprises a system digital twin model comprising a digital representation of a physical state of one or more of the system modules, wherein the system modules and the system digital twin model are communicatively coupled to each other and the system digital twin model is configured to receive system diagnostic data associated with the physical state of the one or more of the system modules for determining a characteristic of the one or more of the system modules.
Clause 215. The system of Clause 214, wherein the MEMS switch system is configured to control a connection to one or more of the system modules upon receiving a fault signal indicative of the physical state of the one or more of the system modules being outside a predetermined range.
Clause 216. The system of Clause 214, wherein the system digital twin model includes the digital twin model of the MEMS module.
Clause 217. A system configured with self-prognosis capability, the system comprising: a plurality of system modules; a system digital twin model comprising a digital representation of a physical state of one or more of the system modules, wherein the system modules and the system digital twin model are communicatively coupled to each other and the system digital twin model is configured to receive system diagnostic data associated with the physical state of the one or more of the system modules for determining a characteristic of the one or more of the system modules; and a micro-electromechanical systems (MEMS) switch module configured to control a connection to one or more of the system modules upon receiving a fault signal indicative of the physical state of the one or more of the system modules being outside a predetermined range.
Clause 218. The system of Clause 217, further comprising the MEMS switch system of any one of Clauses 1-36, and wherein the MEMS switch module of Clause 40 is according to the MEMS switch module of any one of Clauses 178-213.
Clause 219. A micro-electromechanical systems (MEMS) switch system configured with self-prognosis capability, the MEMS switch system comprising: a MEMS switch electrically connected between two terminals and configured to serve as a circuit breaker; a control and monitoring circuit configured to generate diagnostic data indicative of a physical state of the MEMS switch; a physically unclonable function (PUF) circuit physically coupled to the MEMS switch and configured to repeatably generate a signal unique to the PUF circuit until a threshold condition causes the PUF circuit to be physically altered such that the PUF circuit no longer generates a same signal unique to the PUF circuit; and a prognosis module configured to: authenticate the diagnostic data upon receiving the unique signal; and predict a future functionality of the MEMS switch module based at least in part on the authenticated diagnostic data.
Clause 220. The MEMS switch system of clause 219, wherein the PUF circuit comprises a semiconductor device and a uniqueness of the signal is associated with a uniqueness of a physical parameter of the semiconductor device caused by manufacturing variability of a process used to fabricate the semiconductor device.
Clause 221. The MEMS switch system of clause 220, wherein the threshold condition sufficient to cause the PUF circuit to be physically altered is associated with reliability degradation of the MEMS switch.
Clause 222. The MEMS switch system of clause 221, wherein the threshold condition comprises an environmental threshold condition.
Clause 223. The MEMS switch system of clause 222, wherein the threshold condition comprises one or more occurrences of a temperature condition, a humidity condition, a current condition and an electric field condition that causes the PUF circuit to be physically altered.
Clause 224. The MEMS switch system of clause 223, wherein the one or more occurrences of the temperature condition, the humidity condition, the current condition and the electric field condition contemporaneously affect the MEMS switch.
Clause 225. The MEMS switch system of clause 221, wherein the PUF circuit is electrically coupled to the MEMS switch.
Clause 226. The MEMS switch system of clause 225, wherein the threshold condition is associated with current flow through the MEMS switch caused by a switch deactivation event.
Clause 227. The MEMS switch system of clause 225, wherein the threshold condition is associated with an electrical overstress (EOS) event which causes a switch deactivation event.
Clause 228. The MEMS switch system of clause 219, wherein the control and monitoring circuit is configured to report occurrence of the diagnostic data so long as the diagnostic data is authenticated based on the unique signal.
Clause 229. A micro-electromechanical systems (MEMS) switch system configured with switch self-evaluation, the MEMS switch system comprising: a first MEMS switch module electrically connected between two terminals; a control and monitoring circuit configured to generate switch evaluation data; a physically unclonable function (PUF) module configured to capture an operational or environmental condition of the first MEMS switch module and generate a PUF signal indicative of deviation of the operational or environmental condition from a specified condition, a control and processing module configured to receive the switch evaluation data and the PUF signal, and in conjunction with authenticating the PUF signal, process the switch evaluation data to evaluate performance of the first MEMS switch module.
Clause 230. The MEMS switch system of clause 229, further comprising a second MEMS switch module electrically connected in parallel with the first MEMS switch module between the two terminals, wherein the control and monitoring circuit comprises: a sensor electrically connected with the first MEMS switch module and configured to generate a sensor signal; a control logic communicatively coupled to the first and second MEMS switch modules and the sensor, the control logic configured to: sequentially transmit an activation signal and a deactivation signal to the first MEMS switch module while the second MEMS switch module is in a deactivated state, and receive changes in the sensor signal caused by the activation signal and generate the switch evaluation data based at least in part on the received changes in the sensor signal.
Clause 231. The MEMS switch system of clause 230, wherein the sensor comprises a current sensor connected in series with the first MEMS switch.
Clause 232. The MEMS switch system of Clause 230, wherein the sensor comprises a voltage sensor connected in parallel with the first and second MEMS switch modules between the two terminals.
Clause 233. The MEMS switch system of any one of clauses 229-232, wherein the first MEMS switch module comprises a first conductive beam anchored over a substrate, a first contact electrode configured to contact a first switching end of the first conductive beam, and a first control electrode to electrostatically modulate a tilt of the first conductive beam.
Clause 234. The MEMS switch system of clause 233, wherein during normal operation of the electric system, at least the first MEMS switch module is deactivated such that the first contact electrode contacts the first switching end of the first conductive beam to electrically connect the two terminals and upon detecting an electrical overstress (EOS) event, the first MEMS switch module is activated to electrically disconnect the two terminals by separating the first contact electrode from the first switching end of the first conductive beam.
Clause 235. The MEMS switch system of clause 229, wherein the control and processing module is configured to evaluate performance of the first MEMS switch module by updating a model based on the switch evaluation data.
Clause 236. The MEMS switch system of clause 229, wherein the control and monitoring circuit comprises a sensor configured to generate a sensor signal indicative of an operational or environmental condition of the first MEMS switch module.
Clause 237. The MEMS switch system of clause 236, wherein the sensor comprises a temperature sensor indicative of a temperature of a substrate on which the first MEMS switch module is formed.
Clause 238. The MEMS switch system of clause 236, wherein the sensor comprises a current sensor connected in series with the first MEMS switch module.
Clause 239. The MEMS switch system of clause 236, wherein the sensor comprises a voltage sensor connected in parallel with the first MEMS switch module between the two terminals.
Clause 240. The MEMS switch system of clause 229, wherein the PUF module comprises a circuit configured to generate an unaltered PUF signal in the absence of a perturbation.
Clause 241. The MEMS switch system of Clause 240, wherein the PUF module comprises a plurality of PUF circuits each configured to generate an unaltered PUF signal in the absence of a perturbation, and the PUF signal comprises individual PUF signals generated by individual ones of the plurality of PUF circuits.
Clause 242. The MEMS switch system of any one of clauses 240 and 241, wherein authenticating the PUF signal comprises determining that the PUF signal is substantially identical to the unaltered PUF signal.
Clause 243. The MEMS switch system of any one of clauses 240 and 241, wherein in response to determining that the PUF signal is substantially different from the unaltered PUF signal the control and processing module is configured discard the switch evaluation data.
Clause 244. The MEMS switch system of clause 241, wherein the PUF circuit or an individual PUF circuit of the plurality of PUF circuits comprises two or more ring oscillators, SRAM cells, or arbiter circuits.
Clause 245. The MEMS switch system of clause 229, wherein the PUF module and the MEMS switch module are fabricated on a common substrate.
Clause 246. The MEMS switch system of clause 229, wherein the PUF module and the MEMS switch module are configured to be exposed to common environmental conditions.
Clause 247. The MEMS switch system of clause 229, wherein the PUF module is electrically connected to at least of the two terminals.
Clause 248. The MEMS switch system of clause 229, wherein the PUF module is physically coupled to the MEMS switch module.
Clause 249. The MEMS switch system of clause 229, wherein the PUF module is electrically connected to the first MEMS switch module.
Clause 250. A high current and high voltage system with integrated fault protection capability, the system comprising: one or more system modules configured to be electrically connected to a power supply; a fault detection sensor coupled to the one or more system modules; a micro-electro-mechanical system (MEMS) switch module, the MEMS switch module integrated with the one or more system modules and configured to be electrically connected between the one or more system modules and the power supply; and a common processing module configured to control the one or more system modules and to protect the one or more system modules from an electrical fault by activating the MEMS switch module upon sensing the electrical fault with the fault detection sensor.
Clause 251. The system of Clause 250, wherein the one or more system modules are configured to receive current having a magnitude greater than 40 amps from the power supply.
Clause 252. The system of Clause 250, wherein the one or more system modules are configured to receive a voltage having a magnitude greater than 100 volts from the power supply.
Clause 253. The system of Clause 250, wherein the MEMS switch module is integrated with the one or more system modules on a common substrate.
Clause 254. The system of Clause 250, wherein the electrical fault comprises an electrical overstress (EOS) event.
Clause 255. The system of Clause 250, wherein the common processing module is configured to determine one or both a present performance and a future performance of the MEMS switch module.
Clause 256. The system of Clause 255, wherein the common processing module is configured to generate digital a twin model of the MEMS switch module to determine one or both the present performance and the future performance of the MEMS switch module.
Clause 257. The system of any one of Clauses 250-256, further comprising a circuit breaker comprising the MEMS switch module and a control and monitoring circuit configured to control and monitor the MEMS switch module.
Clause 258. The system of Clause 257, wherein at least a portion of the circuit breaker is integrated with the one or more system modules.
Clause 259. The system of Clauses 258, wherein the circuit breaker and the one or more system modules are fabricated on a common substrate.
Clause 260. The system of Clause 257, wherein the control and monitoring circuit comprises the common processing module.
Clause 261. The system of Clauses 260, wherein the common processing module is configured to use the fault detection sensor to sense the electrical fault.
Clause 262. The system of Clause 261, wherein the fault detection sensor comprises a current sensor, a voltage sensor or a temperature sensor.
Clause 263. The system of any one of Clauses 257-262, wherein the circuit breaker comprises a protective switch electrically connected in parallel to the MEMS switch module between two terminals.
Clause 264. The system of Clause 263, wherein the protective switch is configured to shunt at least a portion of a current flowing between the power supply and the MEMS switch module during and prior to completion of deactivation of the MEMS switch module to complete open circuiting an electrical path between the two terminals.
Clause 265. The system of any one of Clauses 250-264, wherein one of system modules is a motor drive system comprising an electric motor.
Clause 266. The system of Clause 265, wherein the MEMS switch module is electrically connected between a drive circuit and the power supply.
Clause 267. The system of any one of Clauses 265 and 266, wherein the common processing module is configured to activate the MEMS switch module in response to determining that excessive current is flowing between the power supply and the electric motor.
Clause 268. The system of Clause 267, wherein the common processing module is configured to activate the MEMS switch module based on different threshold conditions during one or more of startup, deceleration, and steady state operation of the electric motor.
Clause 269. The system of any one of Clauses 250-264, wherein the one or more system modules comprise a computer server comprising a server shelf.
Clause 270. The system of Clause 269, wherein the common processing module is configured to activate the MEMS switch module to protect the server shelf from the electrical fault during booting of the computer server.
Clause 271. The system of Clause 270, wherein the MEMS switch module is integrated with the server shelf.
Clause 272. The system of Clause 270, wherein the MEMS switch module is included in a hot swap controller of the server shelf.
Clause 273. The system of any one of Clauses 269-272, further comprising a second MEMS switch module connected between the server shelf and the power supply, wherein the processing module or a second processing module is configured to protect the one or more system modules from another electrical fault by activating the second MEMS switch.
Clause 274. The system of Clause 273, wherein the power supply comprises a power rack configured to provide electric power to the computer server and the second MEMS switch is included in the power rack.
Clause 275. The system of Clause 274, wherein the power rack power comprises a power distribution unit (PDU) and the MEMS switch is included in the PDU.
Clause 276. The system of any one of Clauses 269-275, wherein the power supply is configured to receive a three-phase alternative current supply and provide a positive and a negative voltage with respect to a common reference potential to the sever shelf.
Clause 277. The system of any one of Clauses 250-264, wherein the one or more system modules comprise an uninterruptible power supply (UPS).
Clause 278. The system of Clause 277, wherein the MEMS switch module is connected between a load and the power supply.
Clause 279. The system of Clause 278, wherein the processing module is configured to activate the MEMS switch module to protect the load from the electrical fault when power is transmitted from the UPS to the load.
Clause 280. The system of any one of Clause 250-279, wherein the MEMS switch module comprises a conductive beam anchored over a substrate, a contact electrode configured to contact a switching end of the conductive beam, and a control electrode configured to electrostatically tilt the conductive beam to contact the switching end thereof with the contact electrode upon receiving a deactivation voltage.
Clause 281. The system of Clause 280, wherein during normal operation of the system, the MEMS switch module is deactivated such that the contact electrode contacts the switching end of the conductive beam, and upon detecting the electrical fault, the common processing module causes the MEMS switch module to form the open circuit by activating the MEMS switch module to separate the contact electrode from the switching end of the conductive from the contact electrode.
Clause 282. A motor drive system with integrated fault protection capability, the system comprising: one or more system modules comprising a drive circuit electrically connected to a power supply and configured to drive an electric motor using electric power received from the power supply; a fault detection sensor coupled to the one or more system modules; a micro-electro-mechanical system (MEMS) switch module, the MEMS switch module integrated with the one or more system modules and configured to be electrically connected between the one or more system modules and the power supply; and a common processing module configured to control the one or more system modules and to protect the one or more system modules from an electrical fault by activating the MEMS switch module upon sensing the electrical fault with the fault detection sensor.
Clause 283. The system of Clause 282, wherein the MEMS switch module is integrated with the one or more system modules on a common substrate.
Clause 284. The system of Clause 282, wherein the electrical fault comprises an electrical overstress (EOS) event during a start up period of the electric motor.
Clause 285. The system of Clause 282, wherein the common processing module is configured to determine one or both a present performance or a future performance of the MEMS switch module.
Clause 286. The system of Clause 285, wherein the common processing module is configured to generate digital a twin model of the MEMS switch module to determine the one or both the present and future performance of the MEMS switch module.
Clause 287. The system of any one of Clauses 282-286, comprising a circuit breaker comprising the MEMS switch module and a control and monitoring circuit configured to control and monitor the MEMS switch module.
Clause 288. The system of Clause 287, wherein at least a portion of the circuit breaker is integrated with the one or more system modules.
Clause 289. The system of Clause 288, wherein the circuit breaker and the one or more system modules are fabricated on a common substrate.
Clause 290. The system of Clause 287, wherein the control and monitoring circuit comprises the common processing module.
Clause 291. The system of Clause 290, wherein the common processing module is configured to use the fault detection sensor to detect the electrical fault and activate the MEMS switch module in response to detecting the electrical fault.
Clause 292. The system of Clause 291, wherein the fault detection sensor comprises a current sensor, a voltage sensor or a temperature sensor.
Clause 293. The system of any one of Clauses 287-292, wherein the circuit breaker comprises a protective switch electrically connected in parallel to the MEMS switch module between two terminals.
Clause 294. The system of Clause 293, wherein the protective switch is configured to shunt at least a portion of a current flowing between the power supply and the MEMS switch module during and prior to completion of deactivation of the MEMS switch module to complete open circuiting an electric path between the two terminals.
Clause 295. The system of any one of Clauses 282-294, wherein the MEMS switch module comprises a conductive beam anchored over a substrate, a contact electrode configured to contact a switching end of the conductive beam, and a control electrode configured to electrostatically tilt the conductive beam to contact the switching end thereof with the contact electrode upon receiving a deactivation voltage.
Clause 296. The system of Clause 295, wherein during normal operation of the motor drive system, the MEMS switch module is deactivated such that the contact electrode contacts the switching end of the conductive beam, and upon detecting the fault, the common processing module causes the MEMS switch module to form the open circuit by activating the MEMS switch module to separate the contact electrode from the switching end of the conductive from the contact electrode.

### Terminology

Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

Unless the context clearly requires otherwise, throughout the disclosure and the claims, the words “comprise,” “comprising,” “include,” “including,” and the like are to be construed in an inclusive sense, as opposed to an exclusive or exhaustive sense; that is to say, in the sense of “including, but not limited to.” The words “coupled” or connected”, as generally used in this disclosure, refer to two or more elements that may be either directly connected, or connected by way of one or more intermediate elements. Additionally, the words “herein,” “above,” “below,” and words of similar import, when used in this application, shall refer to this application as a whole and not to any particular portions of this application.

Where the context permits, words in this disclosure using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

While certain embodiments have been described, these embodiments have been presented by way of example only, and are not intended to limit the scope of the disclosure. Indeed, the circuit breakers, modules, systems, and methods of this disclosure may be embodied in a variety of other forms. Furthermore, various omissions, substitutions and changes in the form of the methods, circuits, modules, and systems described herein may be made without departing from the spirit of the disclosure. Such changes and modifications are to be understood as being included within the scope of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described herein can be combined to provide further embodiments. The various features and processes described above may be implemented independently of one another or may be combined in various ways. All possible combinations and sub-combinations of features of this disclosure are intended to fall within the scope of this disclosure.

What is claimed is:

1. A micro-electromechanical systems (MEMS) switch system comprising:
a MEMS switch module configured to control an electrical connection between two voltage nodes; and
a digital twin model comprising a digital representation of a physical state of the MEMS switch module,
wherein the MEMS switch module and the digital twin model are communicatively coupled to each other and the digital twin model is configured to receive diagnostic data associated with the physical state of the MEMS switch module for determining a characteristic of the MEMS switch module.

2. The MEMS switch system of claim 1, further comprising:
a memory storing the digital twin model; and
a processing system configured to receive the diagnostic data and to update the digital twin model based on the received diagnostic data.

3. The MEMS switch system of claim 2, wherein the processing system is configured to remotely communicate with the MEMS switch module.

4. The MEMS switch system of claim 2, wherein the diagnostic data comprises a measured or extracted value of one or both an intrinsic parameter and an extrinsic parameter of the MEMS switch module, wherein the intrinsic parameter is measurable from the MEMS switch module while the extrinsic parameter is measurable outside of the MEMS switch module.

5. The MEMS switch system of claim 4, wherein the intrinsic parameter comprises one or both of a switching voltage and an ON resistance of the MEMS switch module in a deactivated state.

6. The MEMS switch system of claim 4, wherein the extrinsic parameter associated with the MEMS switch module, wherein the extrinsic parameter is externally measurable outside of the MEMS switch module.

7. The MEMS switch system of claim 4, wherein the MEMS switch module comprises a conductive beam anchored over a substrate, a contact electrode configured to contact a switching end of the conductive beam, and a control electrode to electrostatically modulate a tilt of the conductive beam to deactivate or activate the MEEMS switch module.

8. The MEMS switch system of claim 7, wherein the intrinsic parameter comprises one or both of a switching voltage and an ON resistance of the MEMS switch module in a deactivated state, and wherein the switching voltage comprises a threshold voltage provided to the control electrode to tilt the conductive beam to establish an electrical connection between the switching end and the contact electrode and the ON resistance comprises a resistance of the electrical connection.

9. The MEMS switch system of claim 7, wherein the extrinsic parameter comprises one or more of an environmental temperature, a die temperature, a voltage applied to the MEMS switch module, a current applied to the MEMS switch module, a mechanical acceleration of the MEMS switch module, and a number of switching signals sent to the MEMS switch module.

10. The MEMS switch system of claim 9, wherein:
the die temperature comprises a temperature of the substrate,
the voltage applied to the MEMS switch module comprises an electric potential applied between the switching end and the contact electrode prior to deactivating the MEMS switch module, and
the current applied to the MEMS switch module comprises an electrical current transmitted between conductive beam and the contact electrode after deactivating the MEMS switch module.

11. The MEMS switch system of claim 10, wherein the digital twin model comprises one or more device parameters configured to be adjusted or updated to replicate a characteristic or variation of the characteristic of the MEMS switch module.

12. The MEMS switch system of claim 11, wherein the processing system is configured to update the digital twin model by adjusting the one or more device parameter of the digital twin model based on the diagnostic data.

13. The MEMS switch system of claim 11, wherein the processing system is configured to use the updated digital twin model to estimate a value or variation of the intrinsic parameter of the MEMS switch module at a future time.

14. The MEMS switch system of claim 13, wherein the processing system is configured to initiate an action based at least in part on the estimated value or variation of one or both the intrinsic and extrinsic parameters.

15. The MEMS switch system of claim 14, wherein the action comprises one or more of:
generating a message;
automatically scheduling a maintenance;
adjusting an operational parameter of the MEMS switch module; and
adjusting a control parameter of the MEMS switch module.

16. The MEMS switch system of claim 15, wherein the processing system is configured to compare the estimated value or variation of the intrinsic parameter with a specified value or variation stored in the memory and to initiate the action based at least in part on an outcome of the comparison.

17. The MEMS switch system of claim 16, wherein the specified value comprises a reference value received from a user interface or from a computing system.

18. The MEMS switch system of claim 17, wherein the computing system comprises a cloud server.

19. The MEMS switch system of claim 16, wherein the processing system is configured to adjust one or both of the operational parameter and the control parameter by generating a control signal based at least in part on the outcome of the comparison.

20. The MEMS switch system of claim 16, wherein automatically scheduling a maintenance comprises:
determining a type and a time of failure based at least in part on the outcome of the comparison;
connecting to a scheduling system to receive a schedule;
selecting a maintenance based at least on the determined type of failure; and
scheduling the maintenance based on the selected maintenance and the determined time of failure.
